(19) United States
(12) Patent Application Publication
(10) Pub. No.: US 2025/0167511 A1
(43) Pub. Date: May 22, 2025

(54) OPTOELECTRONIC DEVICE

(71) Applicant: iReach Corporation, Hsinchu (TW)

(72) Inventors: Hsin-Chan CHUNG, Hsinchu (TW); Shou-Lung CHEN, Hsinchu (TW); Ying-Kai HONG, Hsinchu (TW); Chi-Hsun HSIEH, Hsinchu (TW); Tzu-Chieh HSU, Hsinchu (TW); Chun-Yi LU, Hsinchu (TW)

(21) Appl. No.: 18/951,786

(22) Filed: Nov. 19, 2024

Related U.S. Application Data
(60) Provisional application No. 63/601,902, filed on Nov. 22, 2023.
(60) Provisional application No. 63/567,473, filed on Mar. 20, 2024.
(60) Provisional application No. 63/667,861, filed on Jul. 5, 2024.

(51) Int. Cl. H01S 5/0234; H01S 5/02234; H01S 5/02257; H01S 5/183

(52) U.S. Cl. CPC H01S 5/0234; H01S 5/02234; H01S 5/02257; H01S 5/18388

(57) ABSTRACT

An optoelectronic device includes a base layer, a functional area, a semiconductor element, and a encapsulation layer. The base layer has a first side and a second side opposite to the first side. The functional area is on the first side of the base layer. The semiconductor element is on the second side of the base layer. The semiconductor element includes a first electrode and a second electrode, and the semiconductor element corresponds to the functional area. The encapsulation layer is on the second side of the base layer to surround the semiconductor element. A portion of the first electrode and a portion of the second electrode are exposed out of the encapsulation layer.

### TECHNICAL FIELD

The disclosure relates to a semiconductor structure, and particularly to an optoelectronic device.

### BACKGROUND

The vertical cavity surface emitting laser (VCSEL) is a type of semiconductor laser device. Due to its advantages of the epi-surface emitting structure and driven by the increasing application demands and market needs for various Internet of Things (IoT) products, smart electronic products, and intelligent sensing products, VCSEL devices have gradually expanded from the network communication product market into various smart products (for example, optical communication light source modules, proximity sensors in smart tablets and smart headphones, depth/distance/3D sensors, LiDAR sensors for advanced driver assistance systems, light sources or panels for micro-projection displays, eye trackers in interactive devices, photonic integrated circuits, etc.).

In most of the aforementioned current application products, due to various requirements in product development and usage (such as low cost, portability, miniaturization, high integration compatibility with other components, strict environmental reliability for automotive applications, long product lifespan, low power consumption/long usage time, high-frequency electrical driving operation, etc.), more and more VCSEL devices are adopting flip-chip packaging technology to meet these specification requirements.

### SUMMARY

In view of above, one embodiment of the present disclosure provides an optoelectronic device.

In some embodiments, an optoelectronic device is provided, which comprises a base layer, a functional area, a semiconductor element, and an encapsulation layer. The base layer comprises a first side and a second side, the second side being opposite to the first side. The functional area is disposed on the first side of the base layer. The semiconductor element is disposed on the second side of the base layer, the semiconductor element comprises a first electrode and a second electrode, wherein the semiconductor element corresponds to the functional area. The encapsulation layer is disposed on the second side of the base layer and surrounds the semiconductor element, wherein a portion of the first electrode and a portion of the second electrode are exposed outside the encapsulation layer.

In some embodiments, the semiconductor element is a flip-chip vertical cavity surface emitting laser chip.

In some embodiments, the optoelectronic device further comprises a plurality of the functional areas and a plurality of the semiconductor elements, wherein the number of the functional areas is the same as the number of the semiconductor elements.

In some embodiments, the optoelectronic device further comprises a light-transmitting substrate disposed on the first side of the base layer.

In some embodiments, the light-transmitting substrate is disposed between the functional area and the base layer.

In some embodiments, the functional area comprises a microstructure with dimensions ranging from nanometers to micrometers.

In some embodiments, the microstructure comprises a metasurface structure, a diffractive optics structure, a microlens array structure, or a combination of at least two of the aforementioned structures.

In some embodiments, at least one of the first electrode and the second electrode is coplanar with the encapsulation layer.

In some embodiments, the size of the functional area is smaller than the optoelectronic device and larger than that of the semiconductor element.

In some embodiments, the width of the first side of the base layer is smaller than the width of the encapsulation layer.

In some embodiments, the width of the first side of the base layer is smaller than the width of the semiconductor element.

According to some embodiments, a semiconductor laser is provided, which comprises: a first type semiconductor layer comprises a light-emitting aperture; a second type semiconductor layer; an active structure disposed between the first type semiconductor layer and the second type semiconductor layer; and a spacing layer. The active structure and the spacing layer are stacked to form an optical resonator cavity in a vertical space. The spacing layer comprises a first spacing layer and a second spacing layer, wherein the first spacing layer is disposed between the first type semiconductor layer and the active structure, and the second spacing layer is disposed between the second type semiconductor layer and the active structure. The active structure comprises at least one first quantum well layer, at least one second quantum well layer, and a barrier layer structure disposed between the at least one first quantum well layer and the at least one second quantum well layer, wherein the at least one second quantum well layer is farther away from the light-emitting aperture compared to the at least one first quantum well layer, and the emission wavelength of the at least one second quantum well layer is greater than the emission wavelength of the at least one first quantum well layer. In some embodiments, the total thickness of the optical resonator cavity is an integer multiple (nλp) of the peak resonance wavelength (λp) of the semiconductor laser, where n is a positive integer.

In some embodiments, the semiconductor laser comprises a conductive substrate, a semiconductor stack layer, a contact electrode layer, a metal bonding layer, a first conductive structure, a plurality of insulating structures, a plurality of anti-reflection structures, and a plurality of second conductive structures. The semiconductor stack layer is disposed on the conductive substrate, wherein the semiconductor stack layer comprises: a first type semiconductor layer, a second type semiconductor layer, and an active structure. The active structure is disposed between the first type semiconductor layer and the second type semiconductor layer. The contact electrode layer is disposed on a side of the conductive substrate opposite to the semiconductor stack layer. The metal bonding layer is disposed between the conductive substrate and the second type semiconductor layer of the semiconductor stack layer. The plurality of first conductive structures are disposed between the metal bonding layer and the second type semiconductor layer of the semiconductor stack layer. The plurality of insulating structures extend from the metal bonding layer, pass through the first conductive structures, the second type semiconductor layer, and the active structure, and extend to at least a portion of the first type semiconductor layer, thereby defining the second type semiconductor layer and the active structure as a plurality of columnar structures. The plurality of anti-reflection structures are disposed on a side of the first type semiconductor layer of the semiconductor stack layer opposite to the metal bonding layer and correspond to the columnar structures. The plurality of second conductive structures are disposed on a side of the first type semiconductor layer of the semiconductor stack layer opposite to the metal bonding layer, wherein the second conductive structures are disposed between the anti-reflection structures and correspond to the insulating structures.

In some embodiments, the semiconductor laser comprises a transparent substrate, a semiconductor stack layer, a light-transmissive bonding layer, a plurality of insulating structures, a plurality of first conductive structures, a plurality of second conductive structures, a first electrode structure, a second electrode structure, and a passivation layer. The semiconductor stack layer is disposed on the transparent substrate. The semiconductor stack layer comprises: a first type semiconductor layer, a second type semiconductor layer, and an active structure disposed between the first type semiconductor layer and the second type semiconductor layer. The light-transmissive bonding layer is disposed between the transparent substrate and the first type semiconductor layer of the semiconductor stack layer. The plurality of insulating structures extend from the second type semiconductor layer of the semiconductor stack layer, pass through the active structure, and extend to at least a portion of the first type semiconductor layer, thereby defining the second type semiconductor layer, the active structure, and a portion of the first type semiconductor layer as a plurality of columnar structures. The plurality of first conductive structures are disposed between the first type semiconductor layer of the semiconductor stack layer and the light-transmissive bonding layer and correspond to the insulating structures. The plurality of second conductive structures are disposed on a side of the second type semiconductor layer of the semiconductor stack layer opposite to the light-transmissive bonding layer. The first electrode structure is disposed on the second type semiconductor layer of the semiconductor stack layer and extends to a sidewall of the semiconductor stack layer to connect to at least one of the first conductive structures, wherein the first electrode structure is electrically connected to the first type semiconductor layer through the first conductive structures. In some embodiments, the first electrode structure covers at least one columnar structure. The second electrode structure is disposed on the second type semiconductor layer of the semiconductor stack layer. The passivation layer is disposed between the semiconductor stack layer and the first electrode structure, as well as between the semiconductor stack layer and the second electrode structure, wherein the passivation layer has an opening, and the second electrode structure is further distributed into the opening and contacts the second conductive structures, such that the second electrode structure is electrically connected to the second type semiconductor layer through the second conductive structures.

In some embodiments, the semiconductor laser comprises a conductive substrate, a semiconductor stack layer, a contact electrode layer, a metal bonding layer, a plurality of first conductive structures, a plurality of insulating structures, a plurality of anti-reflection structures, and a plurality of second conductive structures. The semiconductor stack layer is disposed on the conductive substrate, wherein the semiconductor stack layer comprises: a first type semiconductor layer, a second type semiconductor layer, and an active structure. The active structure is disposed between the first type semiconductor layer and the second type semiconductor layer. The contact electrode layer is disposed on a side of the conductive substrate opposite to the semiconductor stack layer. The metal bonding layer is disposed between the conductive substrate and the second type semiconductor layer of the semiconductor stack layer. The plurality of second conductive structures are disposed between the metal bonding layer and the second type semiconductor layer of the semiconductor stack layer. The plurality of insulating structures extend from the metal bonding layer, pass through the second conductive structures, the second type semiconductor layer, and the active structure, and extend to at least a portion of the first type semiconductor layer, thereby defining the second type semiconductor layer, the active structure, and a portion of the first type semiconductor layer as a plurality of columnar structures. The plurality of anti-reflection structures are disposed on a side of the first type semiconductor layer of the semiconductor stack layer opposite to the metal bonding layer and correspond to the columnar structures. The plurality of first conductive structures are disposed on a side of the first type semiconductor layer of the semiconductor stack layer opposite to the metal bonding layer, wherein the first conductive structures are disposed between the anti-reflection structures and correspond to the insulating structures.

In some embodiments, the semiconductor laser comprises a conductive substrate, a semiconductor stack layer, a contact electrode layer, a metal bonding layer, a plurality of first conductive structures, a plurality of insulating structures, a plurality of anti-reflection structures, and a plurality of second conductive structures. The semiconductor stack layer is disposed on the conductive substrate, wherein the semiconductor stack layer comprises: a first type semiconductor layer, a second type semiconductor layer, and an active structure. The active structure is disposed between the first type semiconductor layer and the second type semiconductor layer. The contact electrode layer is disposed on a side of the conductive substrate opposite to the semiconductor stack layer. The metal bonding layer is disposed between the conductive substrate and the second type semiconductor layer of the semiconductor stack layer. The plurality of second conductive structures are disposed between the metal bonding layer and the second type semiconductor layer of the semiconductor stack layer. The plurality of insulating structures extend from the metal bonding layer, pass through the second conductive structures, the second type semiconductor layer, and the active structure, and extend to at least a portion of the first type semiconductor layer, thereby defining the second type semiconductor layer and the active structure as a plurality of columnar structures. The plurality of anti-reflection structures are disposed on a side of the first type semiconductor layer of the semiconductor stack layer opposite to the metal bonding layer and correspond to the columnar structures. The plurality of first conductive structures are disposed on a side of the first type semiconductor layer of the semiconductor stack layer opposite to the metal bonding layer, wherein the first conductive structures are disposed between the anti-reflection structures and correspond to the insulating structures.

According to some embodiments, an optoelectronic device is provided, which comprises: a light-emitting unit, comprising a substrate and a light-emitting device disposed on one side of the substrate, wherein the light-emitting device is configured to provide a light beam; a switching unit, disposed on the emission path of the light beam, wherein the switching unit is configured to allow the light beam to pass through the switching unit or to be blocked by the switching unit; a light-receiving element, configured to receive a reflected light beam after the light beam is reflected; and a driving chip, comprising a driving functional block, a modulation functional block, and a signal processing functional block that are signal-connected to each other; wherein the driving functional block is electrically connected to the light-emitting device and the light-receiving element, and the modulation functional block is electrically connected to the switching unit; wherein the signal processing functional block is signal-connected to the light-receiving element and is configured to analyze the reflected light beam.

According to some embodiments, an optoelectronic device is provided, which comprises: a light-emitting unit, including a substrate and a light-emitting device disposed on one side of the substrate, wherein the light-emitting unit is configured to provide a light beam; a light-receiving unit, configured to receive a reflected light beam after the light beam is reflected; and a driving chip, comprising a driving functional block and a signal processing functional block that are signal-connected to each other; wherein the driving functional block is electrically connected to the light-emitting unit and the light-receiving unit; wherein the signal processing functional block is signal-connected to the light-receiving unit and is configured to analyze the reflected light beam.

According to some embodiments, a semiconductor laser is provided, which comprises: a conductive substrate; a semiconductor stack layer, disposed on the conductive substrate, wherein the semiconductor stack layer comprises: a first type semiconductor layer; a second type semiconductor layer; and an active structure, disposed between the first type semiconductor layer and the second type semiconductor layer; a contact electrode layer, disposed on a side of the conductive substrate opposite to the semiconductor stack layer and electrically connected to the second type semiconductor layer through the conductive substrate; wherein the first type semiconductor layer, the active structure, and a portion of the second type semiconductor layer define a plurality of mesa structures, and there are trenches between the mesa structures; a conductive layer, disposed on the mesa structures and extending through the trenches to the first type semiconductor layer, wherein the conductive layer is electrically connected to the first type semiconductor layer; and an passivation layer, disposed between the conductive layer and the mesa structures and between the conductive layer and the trenches, wherein the passivation layer further extends over the sidewalls of the semiconductor stack layer and onto the conductive substrate.

### BRIEF DESCRIPTION OF THE DRAWINGS

To better understand the features and technical contents of the disclosure, embodiments of the disclosure are described in detail with the accompanying drawings below. However, the detailed description and the accompanying drawings are for reference and illustration purposes, and are not to be construed as limitations to the disclosure.

FIG. 1 is a schematic cross-sectional view illustrating a package structure of an optoelectronic assembly.

FIG. 2-1A is a schematic cross-sectional view illustrating a package structure of an optoelectronic unit according to an embodiment.

FIG. 2-1B is a schematic cross-sectional view illustrating a package structure of the optoelectronic unit.

FIG. 2-1C is a schematic cross-sectional view illustrating a package structure of an emitter-sensor package according to an embodiment.

FIG. 2-1D is a schematic cross-sectional view illustrating a package structure of an emitter-sensor package according to an embodiment.

FIG. 2-2A is a schematic cross-sectional view illustrating a package structure of an optoelectronic unit according to an embodiment.

FIG. 2-2B is a schematic cross-sectional view illustrating a package structure of an emitter-sensor package according to an embodiment.

FIG. 2-3 is a schematic cross-sectional view illustrating a package structure of an optoelectronic device according to an embodiment.

FIGS. 3A to 3D illustrate schematic flowcharts of a method for manufacturing the optoelectronic cell shown in FIG. 3E according to one or more embodiments.

FIG. 3E is a schematic cross-sectional view of an optoelectronic cell according to one or more embodiments.

FIGS. 4A to 4C illustrate a schematic process flow for manufacturing an optoelectronic cell, as shown in FIG. 4D, utilizing a panel-type chip scale package (CSP) fabrication process according to one or more embodiments.

FIG. 4D is a schematic cross-sectional view of a optoelectronic cell according to one or more embodiments.

FIGS. 5A to 5C illustrate a schematic process flow for manufacturing an optoelectronic cell, as shown in FIG. 5D, utilizing a panel-type chip scale package process according to one or more embodiments.

FIG. 5D is a schematic cross-sectional view of a optoelectronic cell according to one or more embodiments.

FIGS. 6A to 6C illustrate a schematic process flow for manufacturing an optoelectronic cell, as shown in FIG. 6D, utilizing a panel-type chip scale package (CSP) fabrication process according to one or more embodiments.

FIG. 6D is a schematic cross-sectional view of a optoelectronic cell according to one or more embodiments.

FIG. 7 is a schematic cross-sectional view illustrating a semiconductor light-emitting device according to an embodiment.

FIG. 8A is a schematic cross-sectional view of a semiconductor light-emitting device according to an embodiment.

FIG. 8B is a bottom view of the semiconductor light-emitting device shown in FIG. 8A.

FIG. 8C is a top view of the semiconductor light-emitting device shown in FIG. 8A.

FIG. 9 is a schematic cross-sectional view of a semiconductor light-emitting device according to an embodiment.

FIGS. 10A to 10E are respectively a bottom perspective view, a top perspective view, and cross-sectional views of different sections of a semiconductor light-emitting device according to an embodiment.

FIG. 11 is a schematic cross-sectional view of a semiconductor light-emitting device according to an embodiment.

FIG. 12A is a top perspective view of a semiconductor light-emitting device according to an embodiment.

FIGS. 12B and 12C are respectively schematic cross-sectional views of the cross-sections shown along line segments 12B-12B′ and 12C-12C′ in FIG. 12A.

FIG. 13 is a schematic cross-sectional view of a semiconductor light-emitting device according to an embodiment.

FIGS. 13A and 13B are respectively a schematic cross-sectional view and a top view of a chip package structure according to an embodiment.

FIG. 14A is a schematic cross-sectional view of a chip package structure according to an embodiment.

FIGS. 14B and 14C are respectively a top view and a cross-sectional view of a chip package structure according to an embodiment.

FIG. 15 is a schematic cross-sectional view of a chip package structure according to an embodiment.

FIG. 16 is a schematic cross-sectional view of a chip package structure according to an embodiment.

FIG. 17 is a schematic cross-sectional view of a chip package structure according to an embodiment.

FIG. 18 is a schematic cross-sectional view of a chip package structure according to an embodiment.

FIG. 19 is a schematic cross-sectional view of a chip package structure according to an embodiment.

FIG. 20 is a schematic cross-sectional view of a partial structure of a chip package structure according to an embodiment.

FIG. 21 is a schematic cross-sectional view of a chip package structure according to an embodiment.

FIGS. 22A and 22B are schematic illustrations of the shapes of the first chip in two embodiments of the chip package structure.

FIGS. 23A and 23B are respectively a top view and a cross-sectional view of a chip package structure according to an embodiment.

FIG. 23C is a schematic cross-sectional view of a chip package structure according to another embodiment.

FIG. 24A is a top view of a microscopic image of a light receiving portion of an optoelectronic converter.

FIG. 24B illustrates a schematic cross-sectional view along line 24A-24A′ in FIG. 24A.

FIGS. 25A and 25B are respectively equivalent circuit diagrams of a high-voltage optoelectronic converter and a low-voltage optoelectronic converter.

FIG. 26A is a top perspective view of a rectangular cell of an optoelectronic converter according to an embodiment.

FIGS. 26B and 26C are respectively top perspective views of a hexagonal cell of an optoelectronic converter according to an embodiment.

FIG. 27A is a top perspective view of multiple hexagonal cells of an optoelectronic converter according to an embodiment.

FIG. 27B (Part 1 through Part 6) are schematic diagrams of rectangular and hexagonal cell layout designs with different diameters of light-emitting or light-receiving areas.

FIG. 27C is a top perspective view of multiple hexagonal cells of an optoelectronic converter connected in series according to an embodiment.

FIG. 27D is a top perspective view of multiple hexagonal cells of an optoelectronic converter connected in parallel according to an embodiment.

FIG. 28A (Part 1 and Part 2) illustrates the relationship between the top layout and cross-sectional layout of a hexagonal cell.

FIG. 28B is a schematic diagram of a chip layout with series connected hexagonal cells as the light receive part of a high voltage optoelectronic converter.

FIGS. 29A to 29C illustrate the relationships between the gain spectrum of the active structures and the resonance wavelengths of the emitted light of semiconductor lasers known to the inventors at different temperatures.

FIGS. 29D to 29F illustrate the relationships between the gain spectrum of the active structures and the resonance wavelengths of the emitted light of semiconductor lasers according to some embodiments at different temperatures.

FIG. 30 is a schematic cross-sectional view of a semiconductor laser according to an embodiment.

FIG. 31 is a schematic cross-sectional view of a semiconductor laser according to an embodiment.

FIG. 32 is a schematic cross-sectional view of a semiconductor laser according to an embodiment.

FIG. 33 is a schematic cross-sectional view of a semiconductor laser according to an embodiment.

FIG. 34 is a schematic cross-sectional view of a semiconductor laser according to an embodiment.

FIG. 35 is a schematic cross-sectional view of a semiconductor laser according to an embodiment.

FIG. 36 is a schematic cross-sectional view of a semiconductor laser according to some embodiments.

FIGS. 37A to 37F are schematic cross-sectional views illustrating multiple steps of a fabrication process for a semiconductor laser according to some embodiments.

FIGS. 38A to 38F are schematic cross-sectional views illustrating multiple steps of a fabrication process for a semiconductor laser according to some embodiments.

FIG. 39 is a schematic cross-sectional view of a semiconductor laser according to some embodiments.

FIGS. 40A to 40F are schematic cross-sectional views illustrating multiple steps of a fabrication process for a semiconductor laser according to some embodiments.

FIG. 41 is a schematic cross-sectional view of a semiconductor laser according to some embodiments.

FIG. 42 is a schematic cross-sectional view of a semiconductor laser according to some embodiments.

FIG. 43 is a schematic cross-sectional view of an optoelectronic device according to some embodiments.

FIG. 44A is a schematic cross-sectional view of an optoelectronic device according to some embodiments.

FIG. 44B is a schematic cross-sectional view of an optoelectronic device according to some embodiments.

FIG. 45A is a schematic cross-sectional view of an optoelectronic device according to some embodiments.

FIG. 45B is a schematic cross-sectional view of an optoelectronic device according to some embodiments.

FIG. 46A is a schematic cross-sectional view of an optoelectronic device according to some embodiments.

FIG. 46B is a schematic cross-sectional view of an optoelectronic device according to some embodiments.

FIG. 47A is a schematic cross-sectional view of an optoelectronic device according to some embodiments.

FIG. 47B is a schematic cross-sectional view of an optoelectronic device according to some embodiments.

FIG. 47C is a schematic cross-sectional view of an optoelectronic device according to some embodiments.

FIG. 47D is a schematic cross-sectional view of an optoelectronic device according to some embodiments.

FIG. 47E is a schematic cross-sectional view of an optoelectronic device according to some embodiments.

FIG. 48 is a schematic cross-sectional view of an optoelectronic device according to some embodiments.

FIG. 49 is a schematic cross-sectional view of an optoelectronic device according to some embodiments.

FIG. 50A is a schematic cross-sectional view of an optoelectronic device according to some embodiments.

FIG. 50B is a schematic cross-sectional view of an optoelectronic device according to some embodiments.

FIG. 51 is a schematic cross-sectional view of an optoelectronic device according to some embodiments.

FIGS. 52A to 52C illustrate schematic diagrams of a switching unit according to some embodiments.

FIG. 53 illustrates a schematic diagram of a switching unit according to some embodiments.

FIG. 54 illustrates a schematic diagram of a switching unit according to some embodiments.

FIG. 55 is a schematic cross-sectional view of a semiconductor laser known to the inventors.

FIG. 56 is a schematic cross-sectional view of a semiconductor laser according to some embodiments.

FIG. 57 is a schematic cross-sectional view of a semiconductor laser according to some embodiments.

FIG. 58 is a schematic cross-sectional view of a semiconductor laser according to some embodiments.

FIG. 59 is a schematic cross-sectional view of a semiconductor laser according to some embodiments.

FIGS. 60A to 60G are schematic cross-sectional views illustrating multiple steps of a fabrication process for the semiconductor laser known to the inventors shown in FIG. 55.

FIGS. 61A to 61H are schematic cross-sectional views illustrating multiple steps of a fabrication process for a semiconductor laser according to some embodiments shown in FIG. 57.

FIGS. 62A to 62G are schematic cross-sectional views illustrating multiple steps of a fabrication process for a semiconductor laser according to some embodiments.

FIGS. 63A to 631 are schematic cross-sectional views illustrating multiple steps of a fabrication process for the semiconductor laser shown in FIG. 58 according to some embodiments.

FIG. 64A is a top view illustrating a noise test for a semiconductor laser using a photodetector.

FIG. 64B is a cross-sectional view illustrating a noise test for a semiconductor laser using a photodetector.

FIG. 64C is a comparison diagram illustrating noise test results of a semiconductor laser known to the inventors and a semiconductor laser according to some embodiments.

### DETAILED DESCRIPTION OF THE EMBODIMENTS

In the following description, reference is made to the accompanying drawings which form a part hereof, and in which exemplary embodiments are shown by way of illustration. Similar or identical elements are denoted by the same reference numerals throughout the drawings and description. Furthermore, the drawings are for illustrative purposes only, and the thicknesses and shapes of the layers shown in the drawings are not drawn to actual scale or proportions. It should be noted that elements not shown in the drawings or not described in the specification may take forms known to those of ordinary skill in the art.

The following description of various embodiments of the disclosure is provided with reference to the accompanying drawings for the purpose of promoting clear understanding. These embodiments should be considered in an illustrative sense. The term “in one embodiment” and similar expressions used in this specification are not limited to specific or same embodiments. Those of ordinary skill in the art should recognize that various modifications, combinations, or adjustments can be made to the embodiments without departing from the scope and spirit of the disclosure.

The terms “first,” “second,” “third,” etc. used in this specification are used to identify and describe features of corresponding embodiments, and do not necessarily imply any order, hierarchy, or sequence (such as spatial position, temporal order, process sequence, etc.).

Terms such as “above,” “below,” “left,” “right,” “front,” “back,” “lower,” “higher,” “top,” or “bottom” used in this specification are used to describe relative spatial relationships between one element (or one structure) and another element (or another structure) in the drawings. It is understood that if the structure shown in the drawings is inverted, elements described as being “below,” “beneath,” or on the “lower” side would become elements that are “above,” “over,” or on the “higher” side.

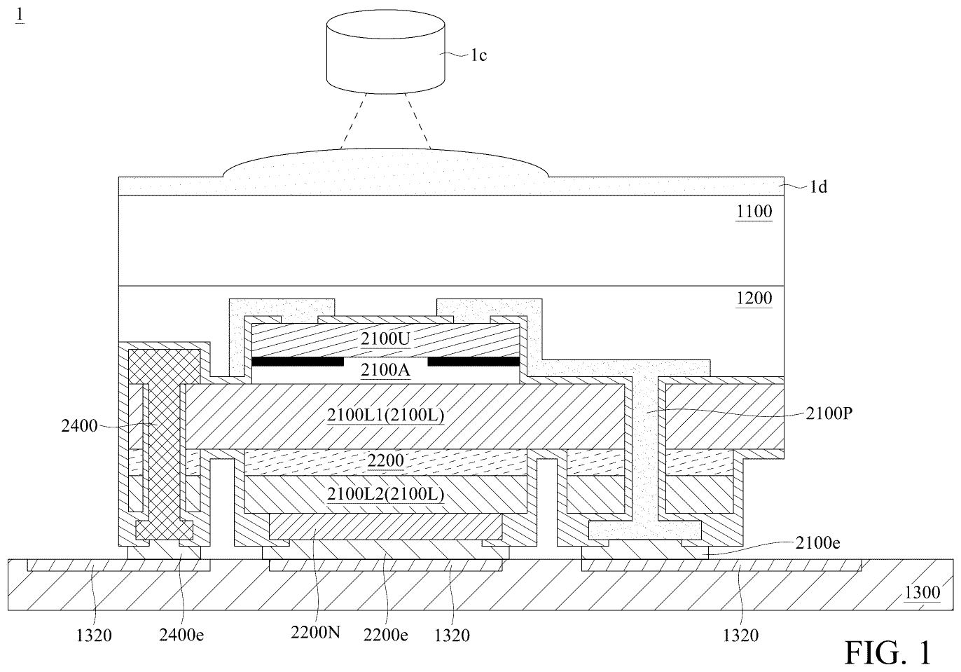

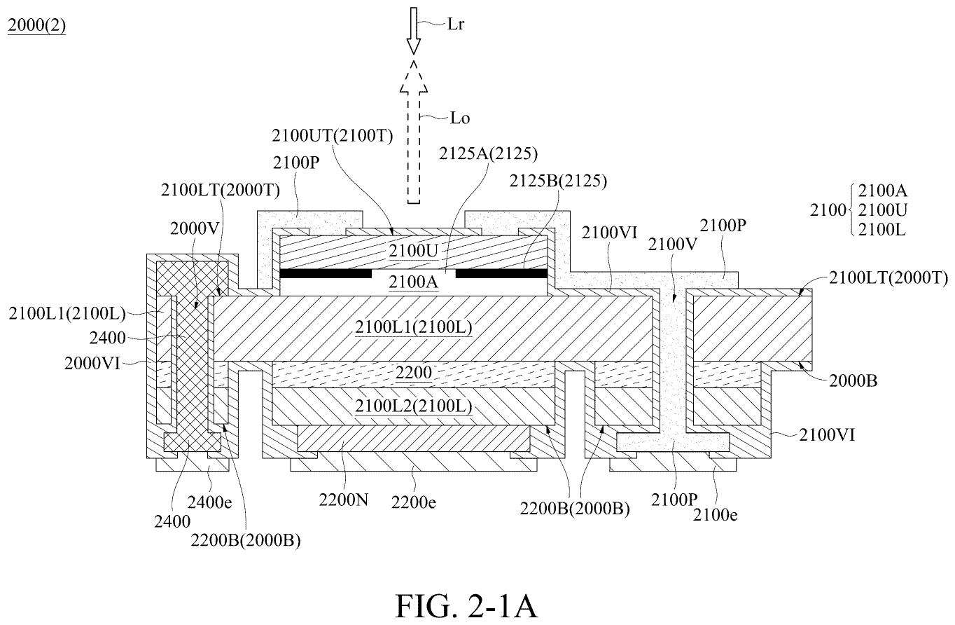

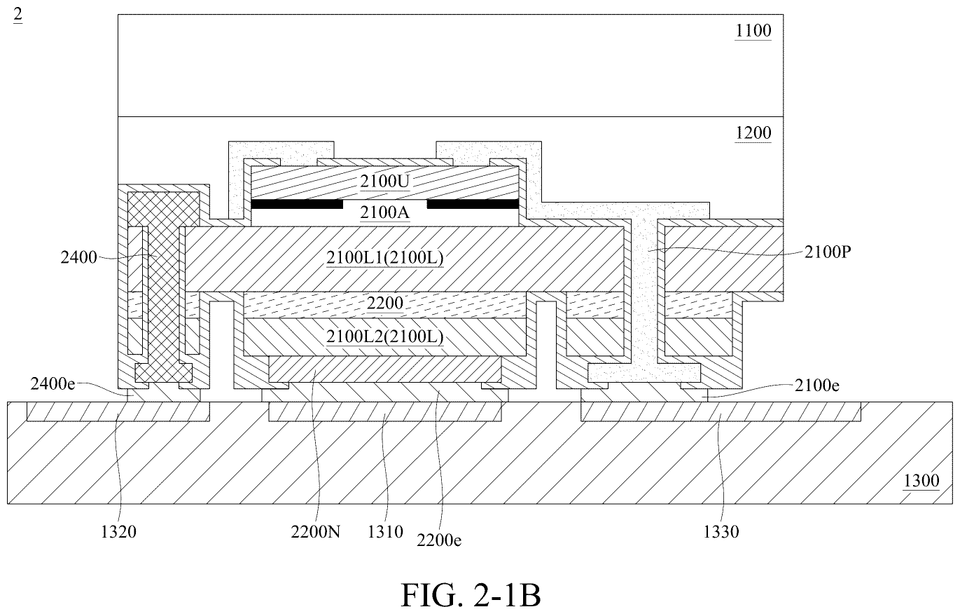

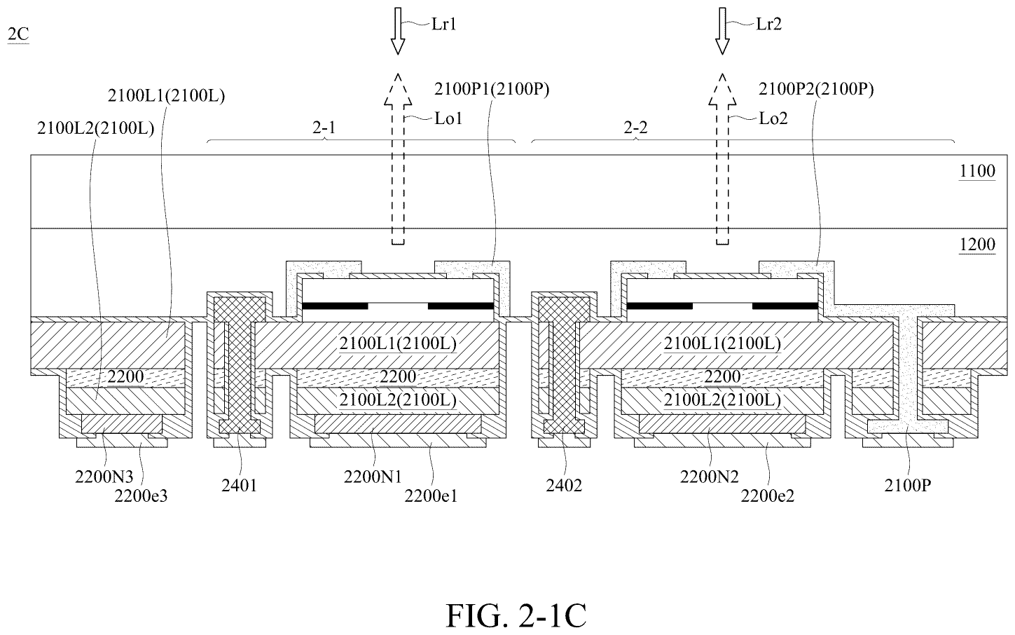

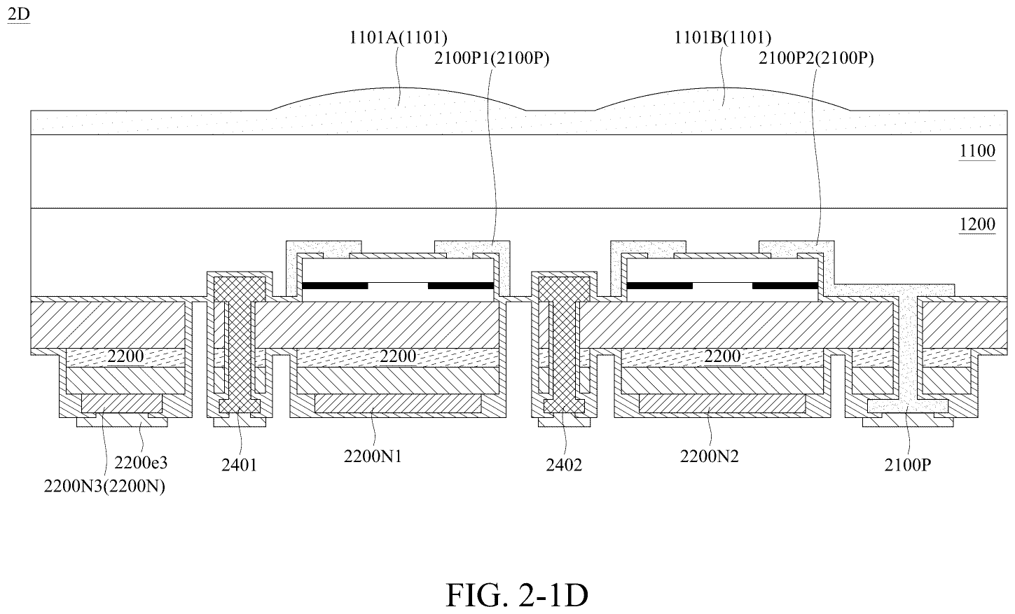

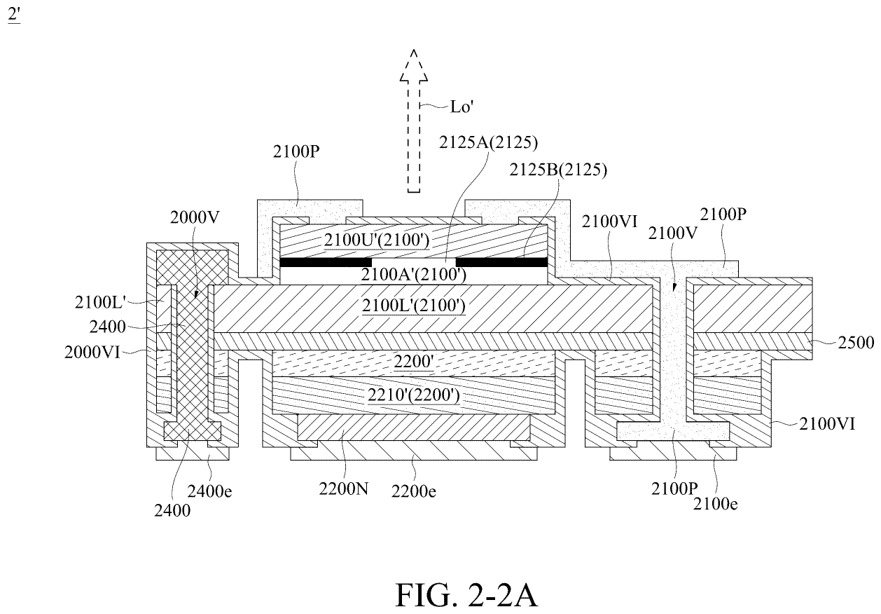

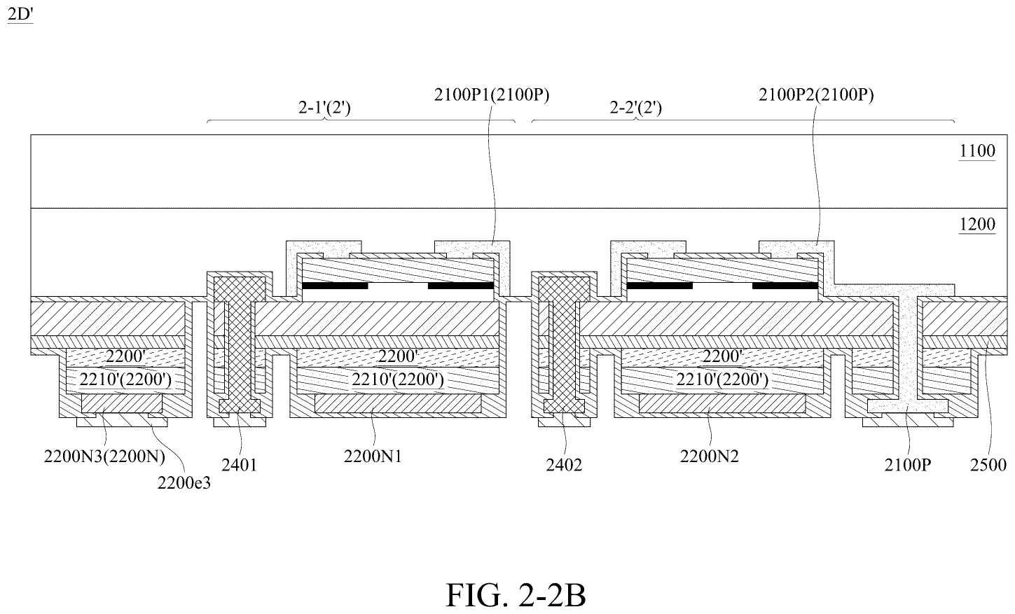

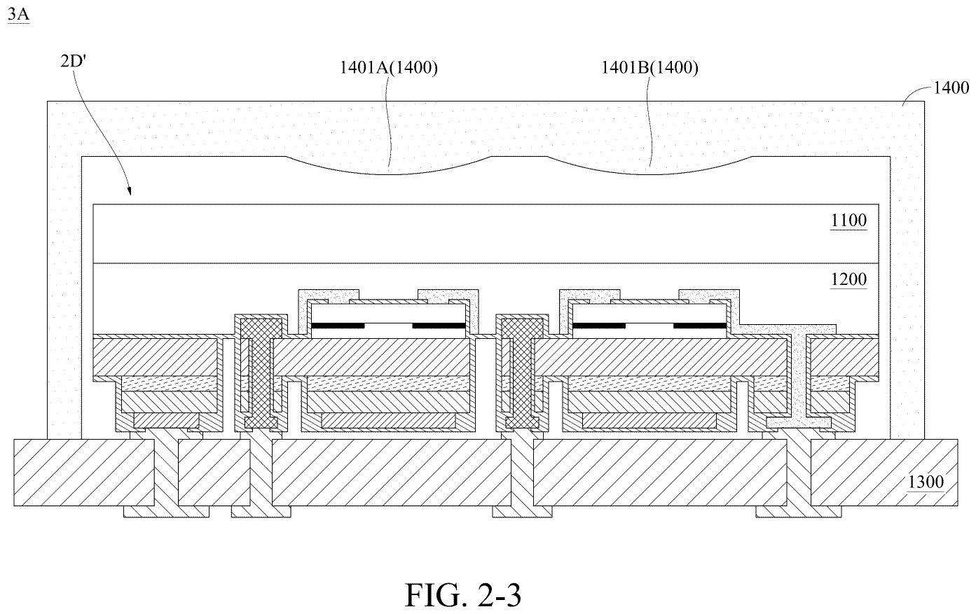

FIG. 1 is a schematic cross-sectional view illustrating a package structure of an optoelectronic assembly 1. According to an embodiment, the optoelectronic assembly 1 comprises an integrated self-mixing interferometry (SMI) sensor unit (for example, an optoelectronic unit 2 as shown in FIGS. 2-1A and 2-1B), a carrier board 1300, and a waveguide element (for example, a coupling fiber 1c as shown in FIG. 1). The SMI sensor unit includes an emitter structure and a receiver structure. In one or more embodiments, the SMI sensor unit further comprise an optics id configured to focus or collimate light from the emitter structure into the waveguide element (such as, but not limited to, a coupling fiber or a light guide element). In one or more embodiments, the optoelectronic assembly 1 functions similarly to a silicon photonic component for transmitting and receiving optical signals.

FIG. 2-1A is a schematic cross-sectional view illustrating a package structure of an optoelectronic unit 2 according to an embodiment, wherein the optoelectronic unit 2 serves as a self-mixing interferometry (SMI) sensor unit and is configured to be incorporated into the optoelectronic assembly 1 as shown in FIG. 1.

FIG. 2-1B is a schematic cross-sectional view illustrating a package structure of the optoelectronic unit 2, wherein the optoelectronic unit 2, as shown in FIG. 2-1A, is adhered to a transparent substrate 1100 according to an embodiment.

FIG. 2-1C is a schematic cross-sectional view illustrating a package structure of an emitter-sensor package 2C according to an embodiment. The emitter-sensor package 2C comprises a plurality of optoelectronic units 2, as shown in FIG. 2-1A, mounted on a transparent substrate 1100. The emitter-sensor package 2C serves as an SMI sensor device and is configured to be incorporated into the optoelectronic assembly 1 as shown in FIG. 1.

FIG. 2-1D is a schematic cross-sectional view illustrating a package structure of an emitter-sensor package 2D according to an embodiment. The emitter-sensor package 2D comprises a plurality of optoelectronic units 2, as shown in FIG. 2-1A, mounted on a transparent substrate 1100. The emitter-sensor package 2D serves as an SMI sensor device and is configured to be incorporated into the optoelectronic assembly 1 as shown in FIG. 1.

Referring to the embodiment shown in FIG. 2-1A, the optoelectronic unit 2 comprises a light-emitting structure and an light-receiving structure. The optoelectronic unit 2 is a stack structure 2000 comprising semiconductor epitaxial structures, conductive structures, and insulating structures. The stack structure 2000 has a top surface 2000T and a bottom surface 2000B opposite to the top surface 2000T. In the embodiment shown in FIG. 2-1A, the stack structure 2000 of the optoelectronic unit 2 is formed by epitaxial growth.

In the embodiment shown in FIG. 2-1A, the stack structure 2000 comprises a light-emitting epitaxial structure 2100 corresponding to the light-emitting structure of the optoelectronic unit 2. In this embodiment, the light-emitting epitaxial structure 2100 is a vertical-cavity surface-emitting laser (VCSEL), which is a stack of epitaxial structures comprising an upper distributed Bragg reflector (DBR) 2100U, a lower DBR 2100L, and an active structure 2100A disposed between the upper DBR 2100U and the lower DBR 2100L.

In the embodiment shown in FIG. 2-1A, a conductive structure 2100P is in electrical contact with the upper DBR 2100U at a top surface 2100T/2100UT thereof. The conductive structure 2100P extends continuously to cover a portion of the bottom surface 2000B through a via structure 2100V formed within the stack structure 2000. In some embodiments, there is further a ring-sharped contact metal (not shown in the figure) between the conductive structure 2100P and the upper surface 2100UT of the upper DBR 2100U, wherein the ring-sharped contact metal forms an ohmic contact with the upper DBR 2100U on the upper surface 2100UT of the upper DBR 2100U. In this embodiment, an insulating structure 2100VI is formed between the conductive structure 2100P and the stack structure 2000. The insulating structure 2100VI is configured to electrically isolate the conductive structure 2100P from the upper DBR 2100U, the active structure 2100A, and the lower DBR 2100L.

In the embodiment shown in FIG. 2-1A, the upper DBR 2100U comprises a P-type semiconductor structure, and the lower DBR 2100L comprises an N-type semiconductor structure. In this embodiment, the conductive structure 2100P serves as a P-electrode of the light-emitting epitaxial structure 2100.

In the embodiment shown in FIG. 2-1A, an light-receiving structure 2200 is integrally formed as a part of the lower DBR 2100L of the light-emitting epitaxial structure 2100 (e.g., VCSEL). In other words, in this embodiment, the lower DBR 2100L comprises a DBR structure 2100L1, the light-receiving structure 2200, and a DBR structure 2100L2 stacked in sequence.

In the embodiment shown in FIG. 2-1A, a conductive structure 2200N is in electrical contact with the light-receiving structure 2200 at a bottom surface 2200B thereof. In one embodiment, the light-receiving structure 2200 can be a photodiode, for example, an avalanche photodiode (APD) or a PIN photodiode. In the embodiment shown in FIG. 2-1A, the conductive structure 2200N serves as an N-electrode of the light-receiving structure 2200.

In the embodiment illustrated in FIG. 2-1A, the conductive structure 2400 contacts with the DBR structure 2100L1 on a upper surface 2100LT of the lower DBR 2100L. The conductive structure 2400 extends continuously to cover a portion of the bottom surface 2000B through a via structure 2000V formed inside the stack structure 2000. In some embodiments, there is further a contact layer (not shown in the figure) between the conductive structure 2400 and the upper surface 2100LT of the lower DBR 2100L, wherein the contact layer forms an ohmic contact with the lower DBR 2100L on the upper surface 2100LT of the lower DBR 2100L. In the embodiment shown in FIG. 2-1A, the insulating structure 2000VI is disposed within the via structure 2000V and extends to cover a portion of the bottom surface 2000B. The insulating structure 2000VI is configured to electrically isolate the conductive structure 2400 from the lower DBR 2100L. In the embodiment shown in FIG. 2-1A, the conductive structure 2400 contacts the DBR structure 2100L1 of N-type semiconductor, and the lower DBR 2100L of N-type semiconductor is connected to the upper part of the light-receiving structure 2200. Therefore, the conductive structure 2400 is the common electrode of the light-emitting epitaxial structure 2100 and the light-receiving structure 2200. In this embodiment, the conductive structure 2400 is simultaneously the N electrode of the light-emitting epitaxial structure 2100 and the P electrode of the light-receiving structure 2200.

In an embodiment, referring to FIG. 2-1A, the light-emitting epitaxial structure 2100 further comprises a current-confining layer 2125 disposed between the upper DBR 2100U and the active structure 2100A. The current-confining layer 2125 includes a current restriction region 2125B and a current conduction region 2125A, wherein the current conduction region 2125A is surrounded and defined by the current restriction region 2125B. The active structure 2100A can be a single-layered or a multi-layered structure; for example, the active structure 2100A includes at least one quantum well layer. Additionally, the active structure 2100A can includes at least one current-confining layer and/or at least one tunnel junction structure therein.

In an embodiment, with reference to FIGS. 2-1A and 2-1B, a transparent substrate 1100 is adhered to the top surface 2000T by an adhesive layer 1200. Wherein both the transparent substrate 1100 and the adhesive layer 1200 are optically transparent to light Lo emitted from the active structure 2100A of the light-emitting epitaxial structure 2100. In this embodiment, electrode pads 2400e, 2200e, and 2100e are individually formed on the bottom surface 2000B. The electrode pad 2400e is in electrical contact with the conductive structure 2400 and is configured for bonding to a second corresponding pad 1320 of a carrier board 1300 (as illustrated in FIG. 2-1B). The electrode pad 2200e is in electrical contact with the conductive structure 2200N and is configured for bonding to a first corresponding pad 1310 of the carrier board 1300. The electrode pad 2100e is in electrical contact with the conductive structure 2100P and is configured for bonding to a third corresponding pad 1330 of the carrier board 1300. In the embodiment depicted in FIG. 2-1A, when driven, the optoelectronic unit 2 emits coherent light Lo towards a first object, and subsequently, reflected light Lr from the first object is detectable by the light-receiving structure 2200 of the optoelectronic unit 2.

In one or more embodiments, referring to FIG. 2-1B as an example, the optoelectronic unit 2 can be coupled to a controller via the carrier board 1300. Subsequently, the light-emitting structure of the optoelectronic unit 2 and the light-receiving structure of the optoelectronic unit 2 can be individually enabled to operate by the controller through the conductive structure 2100P or the conductive structure 2200N corresponding to the respective structures (light-emitting structure or light-receiving structure) in conjunction with the common electrode (conductive structure 2400) of the light-emitting structure and the light-receiving structure. Alternatively, the light-emitting structure of the optoelectronic unit 2 and the light-receiving structure of the optoelectronic unit 2 can also be jointly enabled to operate by the controller through the common electrode (conductive structure 2400) of the light-emitting structure and the light-receiving structure in combination with the conductive structure 2100P of the light-emitting structure and the conductive structure 2200N of the light-receiving structure.

FIG. 2-1C is a schematic cross-sectional view illustrating a package structure of an emitter-sensor package 2C according to an embodiment. The emitter-sensor package 2C comprises a plurality of optoelectronic units 2 (specifically, optoelectronic units 2-1 and 2-2), as depicted in FIG. 2-1A, adhered to a transparent substrate 1100. The emitter-sensor package 2C is configured to serve as a self-mixing interferometry (SMI) sensor device. In one or more embodiments, the plurality of optoelectronic units 2 in the emitter-sensor package 2C can be arranged in an array configuration.

In the embodiment illustrated in FIG. 2-1C, the stack structures of optoelectronic units 2-1 and 2-2 have substantially identical or similar structures to that of optoelectronic unit 2. The conductive structure 2100P1 of optoelectronic unit 2-1 can be connected to the conductive structure 2100P2 of optoelectronic unit 2-2 by an interconnection structure (not shown in FIG. 2-1C). In other words, the conductive structures 2100P1 and 2100P2 can be connected to form a common conductive structure 2100P, which serves as a common electrode for optoelectronic units 2-1 and 2-2. For example, in the embodiment depicted in FIG. 2-1C, this common electrode (conductive structure 2100P) functions as a common P-electrode for the optoelectronic units of the emitter-sensor package 2C.

In the embodiment illustrated in FIG. 2-1C, the electrode pad 2200e1 of the conductive structure 2200N1 can be connected to the electrode pad 2200e2 of the conductive structure 2200N2 through bonding to a bonded common pad 1310 on a carrier board 1300 (not shown in FIG. 2-1C). In other words, the bonded common pad 1310 of the carrier board 1300 functions as a common N-electrode electrically connected to the light-receiving structures 2200 of the emitter-sensor package 2C. Furthermore, in this embodiment, the electrode pad 2200e3 of the conductive structure 2200N3 can be connected to the electrode pads 2200e1 and 2200e2 via the bonded common pad 1310 of the carrier board 1300.

In the embodiment illustrated in FIG. 2-1C, the conductive structure 2401 of the optoelectronic unit 2-1 and the conductive structure 2402 of the optoelectronic unit 2-2 are physically separated. More specifically, in this embodiment, the conductive structure 2401 and the conductive structure 2402 are substantially electrically isolated from each other. Consequently, each of the optoelectronic units 2-1 and 2-2 can be independently driven and controlled. In the embodiment depicted in FIG. 2-1C, the optoelectronic unit 2-1 is configured to emit a coherent light beam Lo1 towards a first object, and then a reflected light Lr1 from the first object is detectable by the light-receiving structure of the optoelectronic unit 2-1. Similarly, the optoelectronic unit 2-2 is configured to emit a coherent light beam Lo2 towards a second object, whereupon a reflected light Lr2 from the second object is detectable by the light-receiving structure of the optoelectronic unit 2-2.

Specifically, in some embodiments, the laser light reflected from an object inherently carries information about the object's state (e.g., distance relative to the optoelectronic unit, rotational speed, translational velocity, acceleration, etc.). This information can be extracted by comparing the phase changes between different laser light beams and performing subsequent conversion calculations.

FIG. 2-1D is a schematic cross-sectional view illustrating a package structure of an emitter-sensor package 2D according to an embodiment. The emitter-sensor package 2D comprises a plurality of optoelectronic units 2 as shown in FIG. 2-1A (for example, optoelectronic units 2-1 and 2-2, as labeled in FIG. 2-1C) adhered to the transparent substrate 1100. The emitter-sensor package 2D is configured to function as a self-mixing interferometry (SMI) sensor device. In the embodiment illustrated in FIG. 2-1D, each stack structure of the optoelectronic units 2 has substantially identical or similar stack structures to the optoelectronic units 2 shown in FIG. 2-1A.

Referring to FIGS. 2-1D and 2-1C, the structure of the emitter-sensor package 2D is similar to the emitter-sensor package 2C. The conductive structures 2100P1 and 2100P2 can be connected to form a common conductive structure 2100P serving as the common electrode (e.g., common P-electrode) of the optoelectronic unit 2 of the optoelectronic device. The conductive structure 2401 and the conductive structure 2402 are substantially electrically isolated from each other. Consequently, each of the optoelectronic unit 2 shown in FIG. 2-1D can be independently driven and controlled.

Specifically, in the embodiment illustrated in FIG. 2-1D, the conductive structures 2200N1 and 2200N2 are respectively covered by insulating structures. The conductive structures 2200N1 and 2200N2 are connected to the conductive structure 2200N3 by an interconnection structure (not shown in FIG. 2-1D). Therefore, the conductive structure 2200N3 serves as a common conductive structure, which is electrically connected to the electrode pad 2200e3 of each of the light-receiving structures 2200, functioning as a common electrode. In other words, in the embodiment depicted in FIG. 2-1D, the electrode pad 2200e3 serves as a common N-electrode electrically connected to the light-receiving structures 2200 of the emitter-sensor package 2D.

Please refer to FIG. 2-1D as an example. In one or more embodiments, the transparent substrate 1100 may comprise an integrated optics 1101. In one or more embodiments, the integrated optics 1101 may comprise multiple optics (for example, microlenses 1101A, 1101B), wherein microlens 1101A corresponds to an optoelectronic unit 2-1 below microlens 1101A, and microlens 1101B corresponds to an optoelectronic unit 2-2 below microlens 1101B. In one or more embodiments, the center position (or optical axis) of microlens 1101A is offset from the central position of the current conduction region in the optoelectronic unit 2-1 below it, and/or the center position (or optical axis) of microlens 1101B is offset from the central position of the current conduction region in the optoelectronic unit 2-2 below it, but the present application is not limited thereto.

In some embodiments, by implementing a misalignment configuration between the aforementioned optical components and the current conduction regions (i.e., the light-emitting apertures corresponding to the semiconductor lasers) of each semiconductor laser, the light beams emitted from the semiconductor lasers can be offset. This misalignment configuration enables modification of the field of illumination (FOI) of the optoelectronic device. In some embodiments, the direction and displacement of the offset configuration between each optics and the current conduction region of each semiconductor laser can be different from one another, thereby achieving a change in the field of illumination of the optoelectronic device while maintaining uniformity within the field of illumination. In some embodiments, the direction and displacement of the offset configuration between each optics and the current conduction region of each semiconductor laser can be different from one another, and the direction and displacement of each offset configuration as a whole can exhibit a symmetrical distribution.

FIG. 2-2A is a schematic cross-sectional view illustrating a package structure of an optoelectronic unit 2′ according to an embodiment. The optoelectronic unit 2′ is configured to function as a self-mixing interferometry (SMI) sensor unit and can be incorporated into the optoelectronic assembly 1 as shown in FIG. 1.

Referring to FIGS. 2-2A and 2-1A, the optoelectronic unit 2′ has a structure similar to that of the optoelectronic unit 2. In the embodiment illustrated in FIG. 2-2A, the optoelectronic unit 2′ comprises a light-emitting epitaxial structure 2100′ and an light-receiving structure 2200′, wherein the light-receiving structure 2200′ is disposed beneath the light-emitting epitaxial structure 2100′.

Specifically, unlike the embodiment shown in FIG. 2-1A where the light-receiving structure 2200 is integrally formed as part of the lower DBR 2100L of the light-emitting epitaxial structure 2100, in the embodiment illustrated in FIG. 2-2A, the optoelectronic unit 2′ further includes an adhesive layer 2500 disposed between the light-emitting epitaxial structure 2100′ and the light-receiving structure 2200′. The top surface of the light-receiving structure 2200′ is mostly adhered to the bottom surface of the light-emitting epitaxial structure 2100′ by the adhesive layer 2500. Wherein the adhesive layer 2500 is transparent to a light Lo′ emitted from the active structure 2100A′ of the light-emitting epitaxial structure 2100′.

In the embodiment illustrated in FIG. 2-2A, the light-emitting epitaxial structure 2100′ can be a VCSEL comprising a stack of epitaxial structures comprising an upper DBR 2100U′, a lower DBR 2100L′, and an active structure 2100A′ disposed between the upper DBR 2100U′ and the lower DBR 2100L′. In this embodiment as shown in FIG. 2-2A, the upper DBR 2100U′ includes a P-type semiconductor structure, and the lower DBR 2100L′ includes an N-type semiconductor structure. Consequently, the conductive structure 2100P (shown in FIG. 2-2A) serves as a P-electrode for the light-emitting epitaxial structure 2100′.

In the embodiment illustrated in FIG. 2-2A, the adhesive layer 2500 is electrically conductive, enabling the conductive structure 2400 (as shown in FIG. 2-2A) to be electrically connected to both the lower DBR 2100L′ of the light-emitting epitaxial structure 2100′ and the light-receiving structure 2200′. Consequently, the conductive structure 2400 functions as a common electrode for both the light-emitting epitaxial structure 2100′ and the light-receiving structure 2200′. In this embodiment, the conductive structure 2400 simultaneously serves as an N-electrode for the light-emitting epitaxial structure 2100′ and a P-electrode for the light-receiving structure 2200′.

In the embodiment illustrated in FIG. 2-2A, the light-receiving structure 2200′ further comprises a distributed Bragg reflector (DBR) structure 2210′ and a conductive structure 2200N. Wherein the conductive structure 2200N is in contact with the light-receiving structure 2200′ on the lower surface of light-receiving structure 2200′. In some embodiments, there is further a contact layer (not shown in the figure) between the conductive structure 2200N and the lower surface of the light-receiving structure 2200′, wherein the conductive structure 2200N forms an ohmic contact with the light-receiving structure 2200′ through the contact layer. In one embodiment, the light-receiving structure 2200′ can be a photodiode, such as an avalanche photodiode (APD) or a PIN photodiode. In the embodiment depicted in FIG. 2-2A, the conductive structure 2200N serves as an N-electrode of the light-receiving structure 2200′. The light-receiving structure 2200′ can be formed using a wafer fusion process.

FIG. 2-2B is a schematic cross-sectional view illustrating a package structure of an emitter-sensor package 2D′ according to an embodiment. The emitter-sensor package 2D′ comprises a plurality of optoelectronic units 2′ (specifically, optoelectronic units 2-1′ and 2-2′ as shown in FIG. 2-2A) adhered to a transparent substrate 1100. The emitter-sensor package 2D′ is configured to function as a self-mixing interferometry (SMI) sensor unit and can incorporated into the optoelectronic assembly 1 as illustrated in FIG. 1. In one or more embodiments, the plurality of optoelectronic units 2′ in the emitter-sensor package 2D′ are arranged in an array configuration.

In the embodiment illustrated in FIG. 2-2B, the conductive structure 2100P1 of the optoelectronic unit 2-1′ can be connected to the conductive structure 2100P2 of the optoelectronic unit 2-2′ via an interconnection structure (not shown in FIG. 2-2B). In other words, in this embodiment, the conductive structures 2100P1 and 2100P2 are connected to form a common electrode (conductive structure 2100P, as shown in FIG. 2-2B) that serves as a common electrode for the optoelectronic units 2-1′ and 2-2′. For example, in the embodiment depicted in FIG. 2-2B, this common electrode functions as a common P-electrode for the optoelectronic units of the emitter-sensor package 2D′.

In the embodiment illustrated in FIG. 2-2B, the conductive structure 2401 of the optoelectronic unit 2-1′ is separated from the conductive structure 2402 of the optoelectronic unit 2-2′. In other words, in this embodiment, the conductive structure 2401 and the conductive structure 2402 are substantially electrically isolated from each other. Consequently, each of the optoelectronic units 2-1′ and 2-2′ can be individually driven and controlled.

In the embodiment depicted in FIG. 2-2B, the conductive structures 2200N1 and 2200N2 are connected to the conductive structure 2200N3 by an internal interconnection structure (not shown in FIG. 2-2B). As a result, the conductive structure 2200N3 serves as a common conductive structure, which is electrically connected to the electrode pad 2200e3 of each light-receiving structure 2200′, functioning as a common electrode. In other words, in the embodiment illustrated in FIG. 2-2B, the electrode pad 2200e3 serves as a common N-electrode electrically connected to the light-receiving structures 2200′ of the emitter-sensor package 2D′.

Referring to FIG. 2-1D as an example, in one or more embodiments, any of the aforesaid transparent substrate 1100 may incorporates integrate optics 1101. In one or more embodiments, the integrate optics 1101 comprise multiple optical components (e.g., microlenses 1101A and 1101B). Microlens 1101A corresponds to the optoelectronic unit 2-1 positioned beneath it, while microlens 1101B corresponds to the optoelectronic unit 2-2 positioned beneath it. In one or more embodiments, the central position (or optical axis) of 1 1101A is misaligned with the central position of the current conduction region in the corresponding optoelectronic unit 2-1 beneath it, and/or the central position (or optical axis) of microlens 1101B is misaligned with the central position of the current conduction region in the corresponding optoelectronic unit 2-2 beneath it. However, the present disclosure is not limited to these configurations.

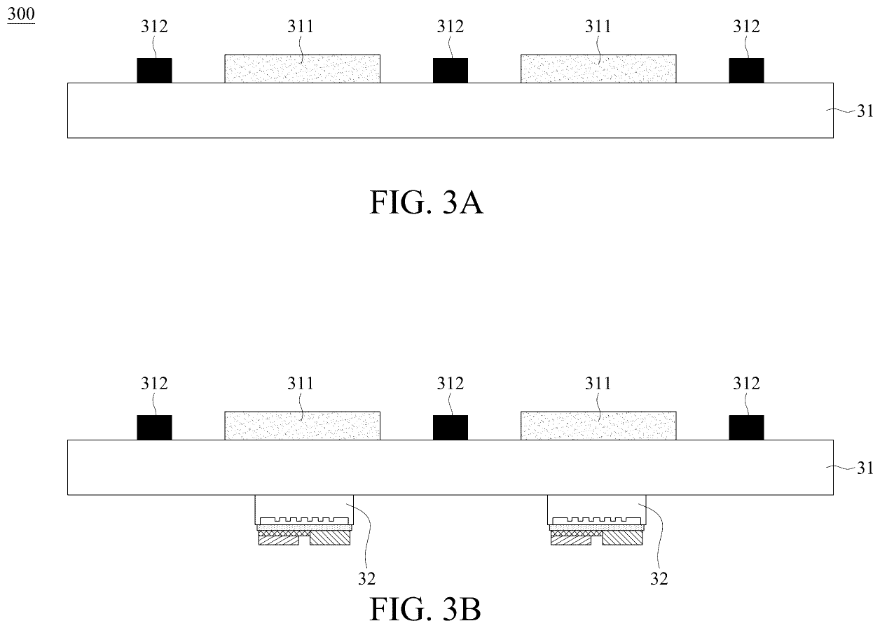

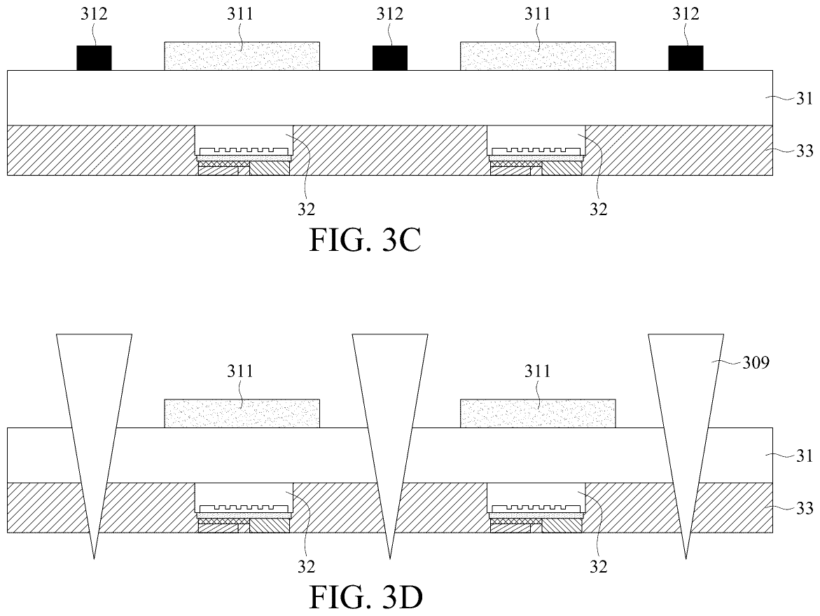

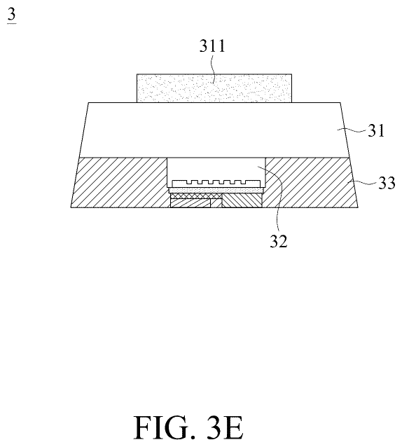

FIG. 2-3 is a schematic cross-sectional view illustrating a package structure of an optoelectronic unit 3A according to an embodiment. Referring to FIG. 2-3 as an example, in one or more embodiments, the optoelectronic unit 3A further comprises a housing 1400 encapsulating the emitter-sensor package 2D′. It should be noted that the emitter-sensor package 2D′ is substitutable with any of the aforementioned emitter-sensor packages, but the present disclosure is not limited to these configurations.

In one or more embodiments, as exemplified in the embodiment shown in FIG. 2-3, the housing 1400 may have integrate optics 1401.

In one or more embodiments, as exemplified in the embodiment shown in FIG. 2-3, the housing 1400 may comprises plural optics 1401A and 1401B. In one or more embodiments, the optics 1401A and 1401B have identical or different optical functionalities. In one embodiment, the optics 1401A and 1401B are configured for light projection. In another embodiment, the optics 1401A and 1401B are configured for light focusing. In other embodiments, optics 1401A is configured for light projection, while optics 1401B is configured for light focusing. In one embodiment, the optics 1401A and 1401B are configured to project or focus light in different directions, or to project light at different angles, thereby enlarging the field of view (FOV) of the optoelectronic unit 3A.

In one or more embodiments, as exemplified in the embodiment shown in FIG. 2-3, the carrier board 1300 can be ceramic substrate, printed circuit board, etc.

In certain embodiments, a space exists between the housing 1400 and the transparent substrate 1100. This space is fillable with various media, including but not limited to ambient air, inert gases, nitrogen, or maintained as a vacuum, thereby providing environments with different refractive index. In alternative embodiments, optics with concave lens structures are formable on the transparent substrate 1100, subsequently covered by the housing 1400. These optics similarly provide focusing and/or collimating functionalities.

In certain embodiments, exemplified by FIG. 1, FIG. 2-1D, or FIG. 2-3, the aforementioned optics include, but are not limited to, a diffractive optics (DOE) structure, a micro-lens array (MLA) structure, a metasurface structure, a metalens structure, or a combination thereof. Wherein the metasurface structure comprises a plurality of periodically arranged nanostructures.

### Optical Cell

In an embodiment illustrated in FIG. 3E, an optoelectronic device (optoelectronic cell 3) comprises: a base layer 31; a functional area 311 disposed on a first side of the base layer 31; a semiconductor device 32 disposed on a second side of the base layer 31 opposite to the first side and corresponding to the functional area 311; and an encapsulation layer 33 surrounding the semiconductor device 32. The semiconductor device 32 includes a first electrode and a second electrode, with portions of both electrodes exposed from the encapsulation layer 33. In certain embodiments, the electrodes of the semiconductor device 32 are coplanar with the surrounding encapsulation layer 33. In other embodiments, at least one of the first electrode and the second electrode of the semiconductor device 32 is coplanar with the encapsulation layer 33. The functional area 311 can be an optical structure with nanometer or micrometer dimensions, such as a metasurface structure, a diffractive optics (DOE) structure, or a micro-lens array (MLA) structure, but not limit thereto. The semiconductor device 32 can be a flip-chip vertical-cavity surface-emitting laser (VCSEL), but not limit thereto. In one or more embodiments, the optoelectronic unit 3 further comprises an adhesive layer at the interface between the base layer 31 and the light-emitting surface of the semiconductor device 32. In certain embodiments, the encapsulation layer 33 is opaque to prevent noise caused by side light emission from the semiconductor device 32. In some embodiments, the size of the functional area 311 is smaller than that of the optoelectronic cell 3 and larger than that of the semiconductor device 32. In certain embodiments, the width of the first side of the base layer 31 is smaller than the width of the encapsulation layer 33. In other embodiments, the width of the first side of the base layer 31 is smaller than the width of the semiconductor device 32.

FIGS. 3A to 3D illustrate schematic flowcharts of a method for manufacturing the optoelectronic cell 3 shown in FIG. 3E according to one or more embodiments. FIG. 3E is a schematic cross-sectional view of the optoelectronic device according to one or more embodiments. FIG. 3A illustrates a process step of manufacturing an optoelectronic wafer 300, optoelectronic wafer 300 comprising a plurality of functional areas 311 disposed on a first side of a base layer 31. In one or more embodiments, the optoelectronic wafer 300 further comprises a plurality of alignment marks 312. The base layer 31 can be a transparent substrate, such as glass or sapphire. FIG. 3B illustrates a process step of mounting a plurality of semiconductor devices 32 on a second side of the base layer 31 using a bonding material, wherein the second side is opposite to the first side of the base layer 31. FIG. 3C illustrates a process step of forming an encapsulation layer 33 surrounding the plurality of semiconductor devices 32 on the second side of the base layer 31. The encapsulation layer 33 is formed on the base layer 31 by processes including, but not limited to, molding, spraying, or spin-coating; for example, the encapsulation layer 33 comprises a resin material, without limitation. In this embodiment, the number of functional areas 311 is equal to the number of semiconductor devices 32. In one or more embodiments, the electrodes of the semiconductor devices 32 are embedded in the encapsulation layer 33 during the molding, spraying, or spin-coating processes. Subsequently, an additional grinding or polishing process to removes a portion of the encapsulation layer 33 until all electrodes of the semiconductor devices 32 are exposed. Specifically, in certain embodiments, the encapsulation layer 33 is formed on the base layer 31 and flush with the electrodes of the semiconductor devices 32, exposing all electrodes of the semiconductor devices 32. In other embodiments, the encapsulation layer 33 is formed on the base layer 31 higher than the electrodes of the semiconductor devices 32, followed by physical or chemical polishing to remove a part of the encapsulation layer 33 until all electrodes of the semiconductor devices 32 are exposed. In one or more embodiments, the exposed electrode surfaces and the polished resin surface 33 are coplanar. FIG. 3D illustrates a cutting process of singulating the optoelectronic wafer 300 into a plurality of individual dies as the optoelectronic cell 3. The cutting process includes, without limitation, laser cutting, dicing, or a combination thereof. As shown in FIG. 3D, a dicing machine 309 is utilized in this embodiment for performing the aforementioned cutting process.

In certain embodiments, the base layer 31 has a thickness ranging from 200 μm to 1 mm and a refractive index ranging from 1.4 to 1.6. The semiconductor device 32 has a thickness ranging from 50 μm to 200 μm and a refractive index of approximately 3.5. The nanometer-scale or micrometer-scale optical structure of the functional area 311 on the base layer 31 has a thickness ranging from 10 nm to 1000 nm and a refractive index ranging from 2.0 to 3.5.

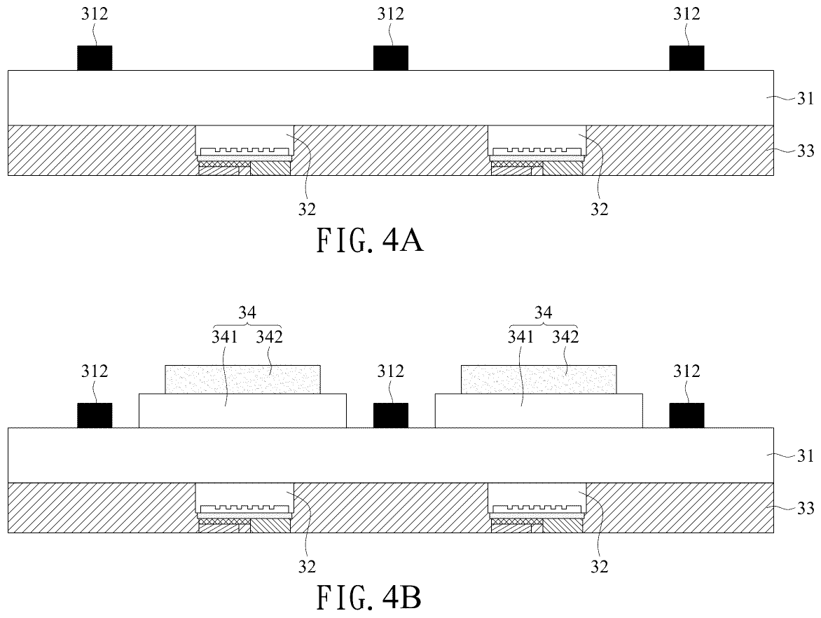

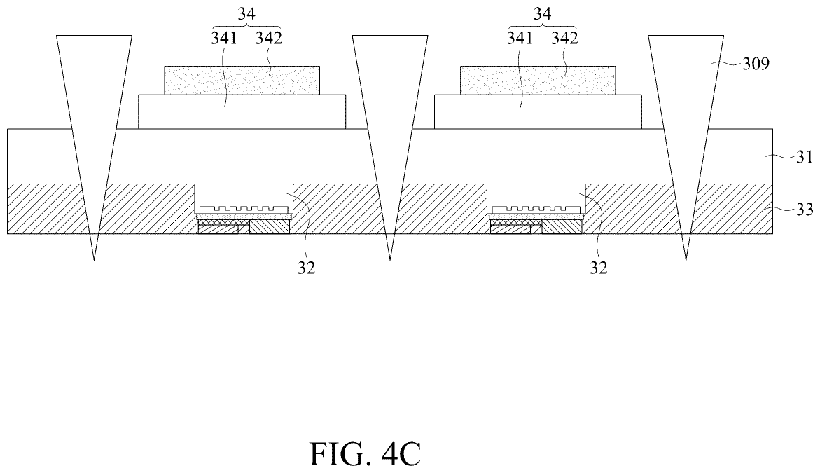

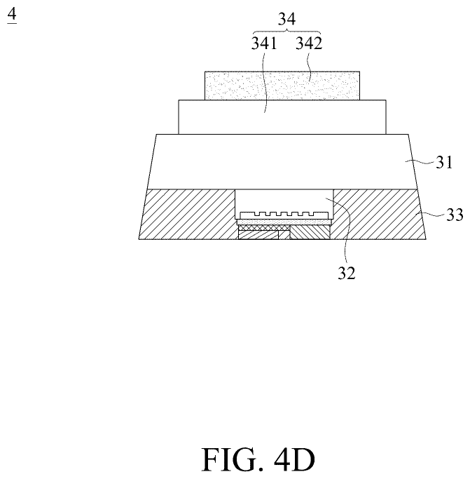

FIGS. 4A to 4C illustrate, as another embodiment, a schematic process flow for manufacturing an optoelectronic device (optoelectronic cell 4), as shown in FIG. 4D, utilizing a panel-type chip scale package (CSP) fabrication process. FIG. 4A illustrate a process step of mounting a plurality of semiconductor devices 32 on a first side of a base layer 31 using an adhesive material, followed by forming an encapsulation layer 33 surrounding the semiconductor devices 32 on the same side of the base layer 31. In one or more embodiments, a plurality of alignment marks 312 are formed on a second side of the base layer. In one or more embodiments, electrodes of the semiconductor devices 32 are embedded within the encapsulation layer 33 by processes including, but not limited to, molding, spraying, or spin-coating processes. Subsequently, an additional grinding or polishing process is performed to remove a portion of the encapsulation layer 33 until all electrodes of the semiconductor devices 32 are exposed. In one or more embodiments, the exposed electrode surfaces and the polished surface of the encapsulation layer 33 are coplanar.

FIG. 4B illustrates a process step of arranging and attaching a plurality of optics 34 to a second side of the base layer 31 using an adhesive material. The optics 34 are precisely aligned one-to-one with the plurality of semiconductor devices 32. The second side is opposite to the first side of the base layer 31. Each optics 34 comprises a transparent base layer 341 and a functional area 342. In this embodiment, the functional area 342 of the optics 34 is oriented outwards as shown in FIG. 4B; however, this orientation is not limited thereto. In one or more embodiments, the functional area 342 is disposed between the base layer 31 and the transparent base layer 341. The functional area 342 can be nanoscale or microscale optical structures such as metasurface structures, diffractive optics (DOE) structures, or micro-lens array structures, but is not limited thereto. FIG. 4C illustrates a dicing process for singulating the optoelectronic wafer into a plurality of individual dies, each serving as an optoelectronic cell 4. FIG. 4D provides a schematic representation of an optoelectronic cell 4.

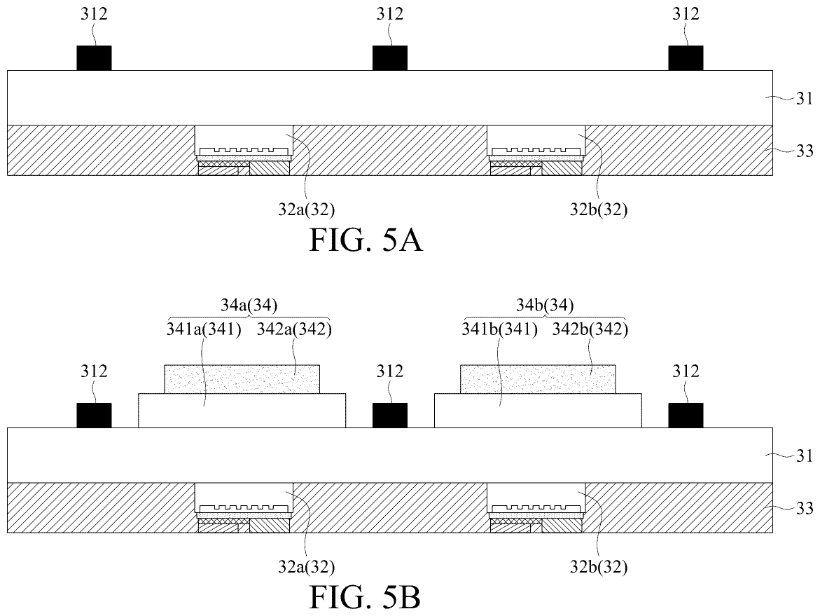

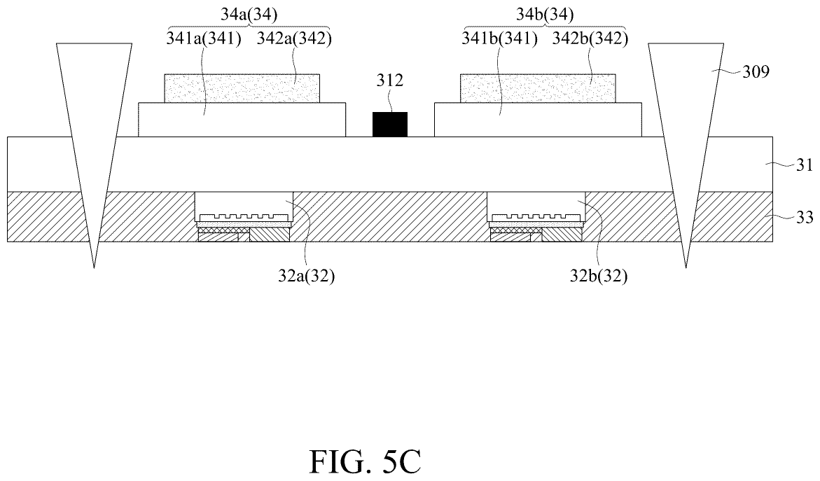

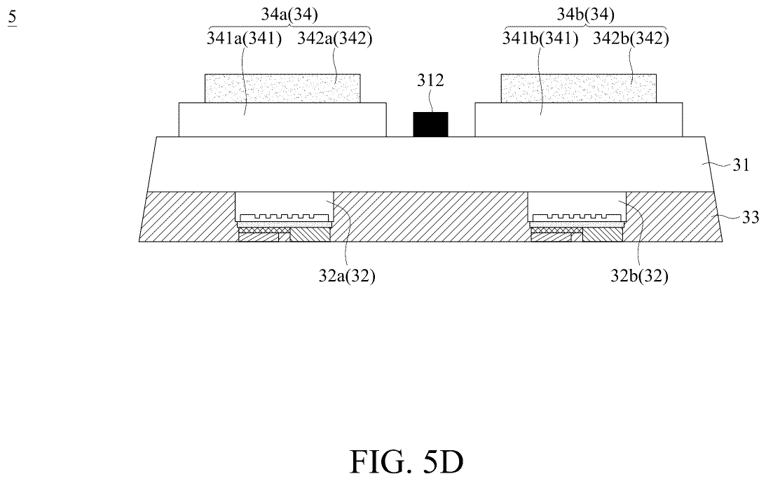

In one or more embodiments, FIGS. 5A to 5C illustrate a schematic process flow for manufacturing an optoelectronic device (optoelectronic cell 5), as shown in FIG. 5D, utilizing a panel-type chip scale package process according to one or more embodiments. FIG. 5A depicts a process step of mounting a plurality of semiconductor devices 32 on a first side of a base layer 31 using an adhesive material, followed by forming an encapsulation layer 33 surrounding all semiconductor devices 32 on the same side of the base layer 31. In one or more embodiments, the plurality of semiconductor devices 32 includes two or more types of semiconductor devices 32 (for example, a first semiconductor device 32a and a second semiconductor device 32b can be different types of semiconductor devices, as shown in FIGS. 5A to 5D), but is not limited thereto. In one or more embodiments, a plurality of alignment marks 312 are formed on a second side of the base layer 31. In one or more embodiments, electrodes of the semiconductor devices 32 are embedded within the encapsulation layer 33 by processes including, but not limited to, molding, spraying, or spin-coating processes. Subsequently, an additional grinding or polishing process is performed to remove a portion of the encapsulation layer 33 until all electrodes of the semiconductor devices 32 are exposed. In one or more embodiments, the exposed electrode surfaces and the polished surface of the encapsulation layer 33 are coplanar.

FIG. 5B illustrates a process step of arranging and attaching a plurality of optics 34 to a second side of the base layer 31 using an adhesive material. The optics 34 are aligned one-to-one with the plurality of semiconductor devices 32. The second side is opposite to the first side of the base layer 31. In one or more embodiments, the plurality of optics 34 includes two or more types of optics (for example, first optics 34a and second optics 34b, as shown in FIGS. 5B to 5D, which can be different types of optics), but is not limited thereto. In this embodiment, the transparent base layer 341 is disposed between the base layer 31 and the functional area 342, as shown in FIG. 5B; however, this configuration is not limiting. In one or more embodiments, the functional area 342 (342a/342b) is disposed between the base layer 31 and the transparent base layer 341 (341a/341b). FIG. 5C illustrates a dicing process for singulating the device wafer into a plurality of individual dies, each serving as an optoelectronic cell 5. Each optoelectronic cell 5 includes two or more types of optics 34 and two or more types of semiconductor devices 32, but is not limited thereto. FIG. 5D provides a schematic representation of an optoelectronic cell 5 comprising two types of optics 34 and two types of semiconductor devices 32.

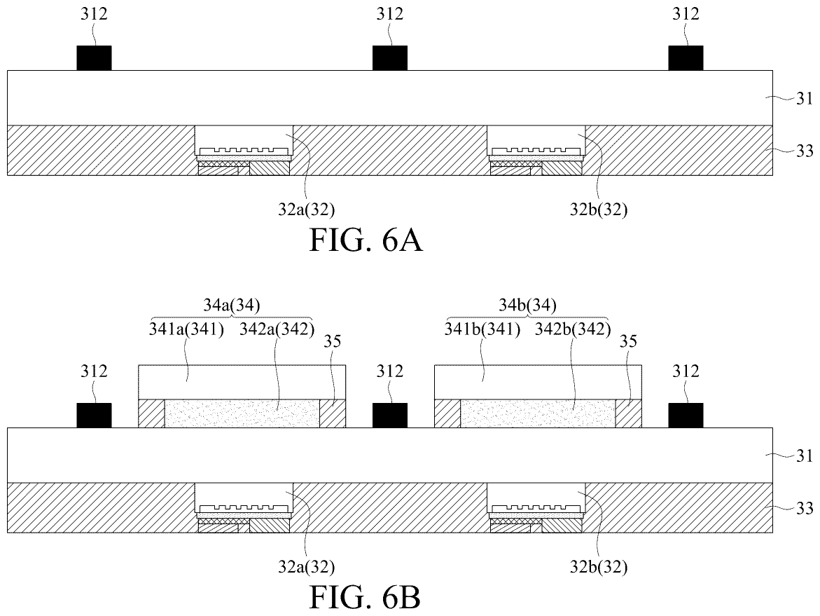

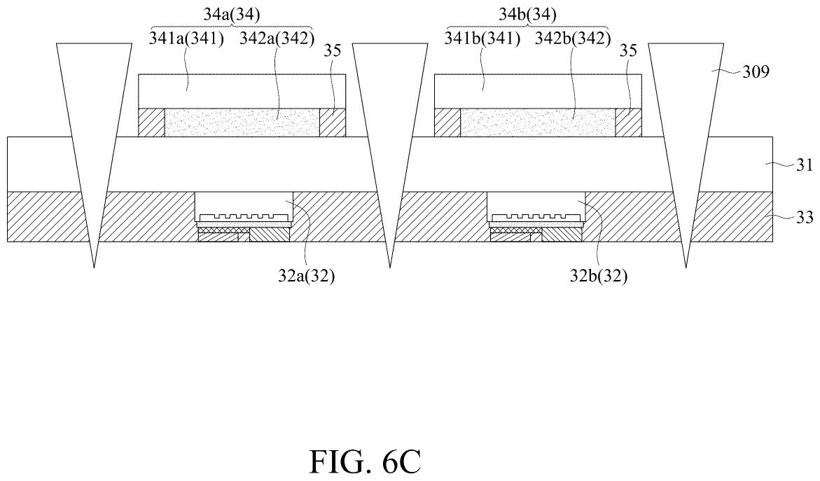

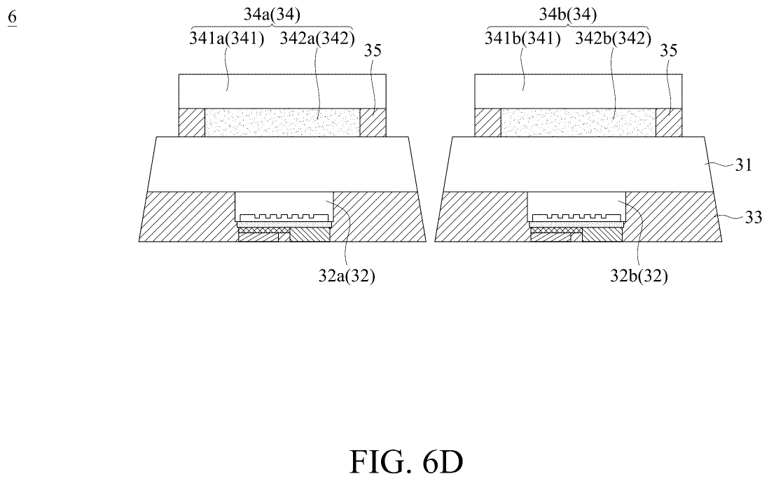

FIGS. 6A to 6C illustrate, as another embodiment, a schematic process flow for manufacturing an optoelectronic device (optoelectronic cell 6), as shown in FIG. 6D, utilizing a panel-type chip scale package (CSP) fabrication process according to one or more embodiments. FIG. 6A depicts a process step of mounting a plurality of semiconductor devices 32 on a first side of a base layer 31 using an adhesive material, followed by forming an encapsulation layer 33 surrounding the semiconductor devices 32 on the same side of the base layer 31. In one or more embodiments, the plurality of semiconductor devices 32 may comprise two or more types of semiconductor devices 32 (for example, a first semiconductor device 32a and a second semiconductor device 32b can be different types of semiconductor devices, as shown in FIGS. 6A to 6D), but is not limited thereto. In one or more embodiments, a plurality of alignment marks 312 are formed on a second side of the base layer 31. In one or more embodiments, electrodes of the semiconductor devices 32 are embedded within the encapsulation layer 33 during molding, spraying, or spin-coating processes. Subsequently, an additional grinding or polishing process is performed to remove a portion of the encapsulation layer 33 until all electrodes of the semiconductor devices 32 are exposed. In one or more embodiments, the exposed electrode surfaces and the polished surface of the encapsulation layer 33 are coplanar. FIG. 6B illustrates a step of mounting optics, wherein a plurality of optics 34 are arranged and attached to the second side of the base layer 31 using an adhesive material 35. In one or more embodiments, the plurality of optics 34 may comprise two or more types of optics (for example, first optics 34a and second optics 34b, as shown in FIGS. 6B to 6D, which can be different types of optics), but is not limited thereto. In this embodiment, the functional area 342 of the optics 34 is oriented towards the base layer 31. The second side is opposite to the first side of the base layer 31. Each optics 34 comprises a transparent base layer 341 and a functional area 342. The functional area 342 includes, but is not limited to, nanoscale or microscale optical structures such as metasurface structures, diffractive optics (DOE) structures, or micro-lens array structures. In some embodiments, the functional area 342 may first disposed on the transparent base layer 341, and then the optics 34 are attached to the base layer 31 using the adhesive material 35. In other embodiments, the functional area 342 may first disposed on the base layer 31, and then the transparent base layer 341 is attached to the base layer 31 using the adhesive material 35. FIG. 6C illustrates a dicing process for singulating the device wafer into a plurality of individual dies, each serving as an optoelectronic cell 6. FIG. 6D provides a schematic representation of an optoelectronic cell 6. In some embodiments, as shown in FIG. 6D, two or more optoelectronic units 6 can be connected together by reducing the dicing between the optoelectronic units, thereby jointly forming a single optoelectronic unit (similar to the optoelectronic unit 5 shown in FIG. 5D, wherein the single optoelectronic unit comprises two or more optics 34 and two or more semiconductor elements 32, and the two or more optics 34 may be the same type or different types of optics, and the two or more semiconductor elements 32 may be the same or different semiconductor elements).

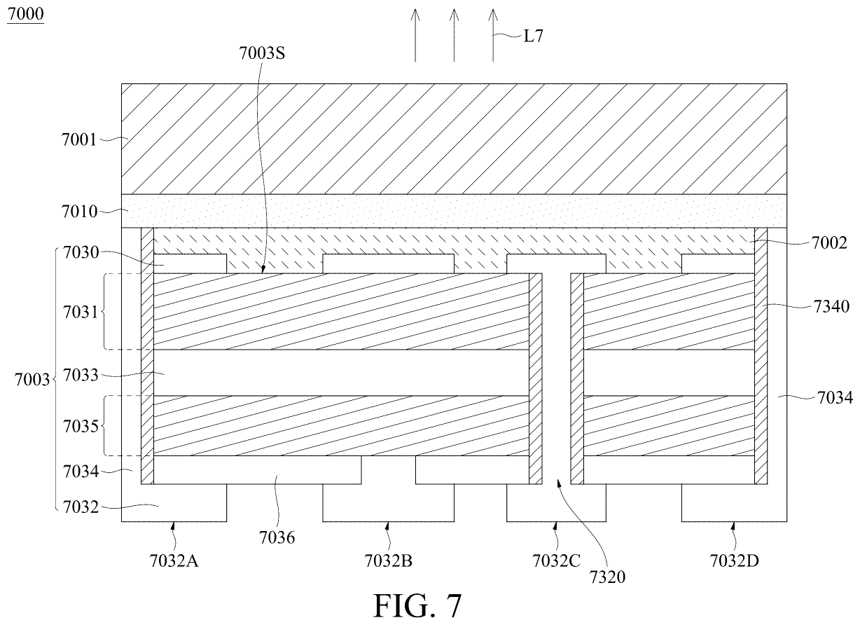

In certain embodiments, the aforementioned semiconductor devices 32 illustrated in FIGS. 3A to 3E, 4A to 4D, 5A to 5D, and 6A to 6D can be one or more combinations of the emitter-sensor package depicted in FIGS. 2-1A to 2-3 or the semiconductor light-emitting devices shown in FIGS. 7 to 13.

FIG. 7 is a schematic cross-sectional view illustrating a semiconductor light-emitting device 7000 according to an embodiment. In one or more embodiments, the semiconductor device 32 illustrated in FIGS. 3A to 3E, 4A to 4D, 5A to 5D, and 6A to 6D comprises a semiconductor light-emitting device 7000 as shown in FIG. 7. Referring to this embodiment, as illustrated in FIG. 7, the semiconductor light-emitting device 7000 comprises a transparent substrate 7001, an adhesive layer 7002, a laser unit 7003, and a plurality of first channels 7034. The transparent substrate 7001 includes a conductive layer 7010. For example, the transparent substrate 7001 comprises sapphire, glass, or silicon carbide (SiC). In some embodiments, the transparent substrate 7001 serves as an optics and may be patterned to produce specific optical effects. For instance, said optics can enable the optical transmitter to generate a patterned light source with a pattern such as a spot, flood, or multiple light patterns illuminating within a pre-determined field of illumination (FOI). The conductive layer 7010 comprises a transparent conductive oxide or a metal. The transparent conductive oxide may be indium tin oxide (ITO) or indium zinc oxide (IZO). In the present embodiment, the conductive layer 7010 is disposed between the transparent substrate 7001 and the adhesive layer 7002.

One side of the adhesive layer 7002 is attached to the conductive layer 7010 of the transparent substrate 7001, and the other side thereof is attached to a light-emitting side 7003S of the laser unit 7003. For example, the adhesive layer 7002 may comprise benzocyclobutene (BCB), silicon dioxide, or a transparent conductive film.

The laser unit 7003 comprises a front electrode structure 7030, a first type semiconductor stack 7031, an active layer 7033, a second conductivity type semiconductor layer 7035, a passivation layer 7036, and a back conductive structure 7032. The back conductive structure 32 includes a first conductive electrode 7032C and a second conductive electrode 7032D separated from each other. The first type semiconductor and the second type semiconductor herein respectively refer to semiconductors with different electrical properties. If a semiconductor uses holes as a majority carrier, it is a p-type semiconductor, and if the semiconductor uses electrons as a majority carrier, it is an n-type semiconductor. For example, the first type semiconductor stack 7031 is an n-type semiconductor stack, and the second type semiconductor stack 7035 is a p-type semiconductor stack, and vice versa. The active layer 7033 is disposed between the first type semiconductor stack 7031 and the second type semiconductor stack 7035, and includes a p-n junction to generate a depletion region for electron-hole recombination to emit light. In some embodiments, the active layer 7033 comprises multiple quantum wells (MQWs), which provide higher light-emitting efficiency compared to a p-n junction, but is not limited thereto. In one embodiment, the materials of the first type semiconductor stack 7031, the second type semiconductor stack 7035, and the active layer 7033 comprise III-V compound semiconductors, including but not limited to: GaAs, InGaAs, AlGaAs, AlInGaAs, GaP, InGaP, AlInP, AlGaInP, GaN, InGaN, AlGaN, AlInGaN, AlAsSb, InGaAsP, InGaAsN, and AlGaAsP, and the like. In the embodiments of the present disclosure, unless otherwise specified, the above chemical expressions include “stoichiometric compounds” and “non-stoichiometric compounds”. The compounds are stoichiometric when, for example, the total stoichiometric amount of group III elements is equal to the total stoichiometric amount of group V elements. The compounds are non-stoichiometric when, for example, the total stoichiometric amount of group III elements is not equal to the total stoichiometric amount of group V elements. For example, the chemical expression AlGaAs means that it includes the group III element aluminum (Al) and/or gallium (Ga) and includes the group V element arsenic (As). The total element measurement of the group III element (aluminum and/or gallium) may be the same as or different from the total element measurement of the group V element (arsenic). In addition, if the above compounds represented by the chemical expressions are stoichiometric compounds, AlGaAs represents Alₓ₁Ga₍₁₋ₓ₁₎As, where 0≤x1≤1; AlInP represents Alₓ₂In₍₁₋ₓ₂₎P, where 0≤x2≤1; AlGaInP represents (Al_{y1}Ga_{(1-y1)})₁₋ₓ₃Inₓ₃P, where 0≤x3≤1 and 0≤y1≤1; AlGaN represents Alₓ₄Ga₍₁₋ₓ₄₎N, where 0≤x4≤1; AlAsSb represents AlAsₓ₅Sb₍₁₋ₓ₅₎, where 0≤x5≤1; InGaP represents Inₓ₆Ga₍₁₋ₓ₆₎P, where 0≤x6≤1; InGaAsP represents Inₓ₆Ga₍₁₋ₓ₆₎As_{(1-y2)}P_{y2}, where 0≤x6≤1 and 0≤y2≤1; InGaAsN represents Inₓ₈Ga₍₁₋ₓ₈₎As_{(1-y3)}N_{y3}, where 0≤x8≤1 and 0≤y3≤1; AlGaAsP represents Alx₉Ga₍₁₋ₓ₉₎As_{(1-y4)}P_{y4}, where 0≤x9≤1 and 0≤y4≤1; InGaAs represents Inₓ₁₀Ga₍₁₋ₓ₁₀₎As, where 0≤x10≤1. According to the material of the active layer 7033, when the materials of the first type semiconductor stack 7031 and the second type semiconductor stack 7035 are AlGaAs series, the active layer 7033 may emit infrared light with a peak wavelength between 700 nm and 1700 nm. When the materials of the first type semiconductor stack 7031 and the second type semiconductor stack 7035 are AlGaInP series, the active layer 7033 may emit orange-red light with a peak wavelength between 610 nm and 700 nm, green-yellow light with a peak wavelength between 570 nm and 610 nm or green light with a peak wavelength between 530 nm and 570 nm. When the materials of the first type semiconductor stack 7031 and the second type semiconductor stack 7035 are InGaN series, the active layer 7033 may emit blue light or deep blue light with a peak wavelength between 400 nm and 490 nm, or green light with a peak wavelength between 490 nm and 550 nm. When the materials of the first type semiconductor stack 7031 and the second type semiconductor stack 7035 are AlGaN series, the active layer 7033 may emit ultraviolet light with a peak wavelength between 250 nm and 400 nm.

In the present embodiment, the first type semiconductor stack 7031 and the second type semiconductor stack 7035 comprise a plurality of overlapped layers to serve as distributed Bragg reflector (DBR), so that a light emitted from the active layer 7033 may be reflected between two distributed Bragg reflectors to form coherent light, and then the coherent light is emitted from the first type semiconductor stack 7031 to form a laser light L7.

In this embodiment, as illustrated in FIG. 7, the passivation layer 7036 is disposed between the back conductive structure 7032 and the second type semiconductor stack 7035. In one embodiment, the material of passivation layer 7036 includes silicon dioxide.

In the present embodiment, the contact resistance between the back conductive structure 7032 and the second conductivity type semiconductor layer 7035 is lower than 10⁻⁴ Ω·cm². An ohmic contact is formed at the interface between the back conductive structure 7032 and the second type semiconductor stack 7035. A formation mechanism of the ohmic contact is that a metal work function must be less than a semiconductor work function, so that electrons from the semiconductor to the metal and from the metal to the semiconductor can easily leap over this energy level, and current may be turned on in two directions. For example, the metal component of the second conductive electrode 324 of the back conductive structure 32 is mainly titanium aluminum alloy because titanium can form titanium nitride with the III-V compound (for example, aluminum gallium nitride) of the second type semiconductor stack 35, such that nitrogen atoms become an n-type doped surface on the surface and form a good ohmic contact after high temperature annealing.

In this embodiment, as shown in FIG. 7, the first type semiconductor layer 7031 is connected to the front conductive structure 7030, the front conductive structure 7030 is connected to the conductive electrode 7032C through the second channel 7320, the conductive electrode 7032D and the conductive electrode 7032C are separated from each other to avoid short circuit, and the second type semiconductor layer 7035 is connected to the conductive electrode 7032D. To prevent the conductive medium filled in the second channel 7320 from contacting the second type semiconductor layer 7035 of the laser unit 7003 to cause a short circuit, the laser unit 7003 further includes a passivation layer 7340 disposed on the inner wall of the second channel 7320. Through the above conductive structure, the laser unit 7003 receives the external driving voltage/current to generate the laser beam L7. The front conductive structure 7030 is disposed on the light-emitting side 7003S of the laser unit 7003 and is connected to the bonding layer 7002. Therefore, the laser beam L7 emitted by the laser unit 7003 will pass through the bonding layer 7002 and the transparent substrate 7001 then output to the outside. It needs to be explained that the transparent substrate 7001 is transparent to the laser beam L7 of the laser unit 7003, and the light may be UV light, visible light, or infrared light, but the present disclosure is not limited thereto. Therefore, the object under the transparent substrate 7001 does not need to be clearly seen by the naked eye.

In one or more embodiments, when an TOF module with the semiconductor light-emitting device 7000 is applied to a living object, such as human face or human eye, since the coherent light emitted by the semiconductor light-emitting device 7000 has a high energy, a corresponding optics, such as the transparent substrate 7001, is required for processing the coherent light to output the laser light L7 with appropriate intensity. In order to effectively monitor whether the semiconductor light-emitting device 7000 is damaged and prevent the laser light L7 that has not been properly processed through the transparent substrate 7001 from being leaked and directly irradiated to the living object, the semiconductor light-emitting device 7000 of the present embodiment has an eye safety monitoring circuit which can monitor abnormal damage of the light exiting side 7003S of the laser unit 7003 in real time. The following examples illustrate the working principle of the semiconductor light-emitting device 7000 of some embodiments.

Referring further to this embodiment, as illustrated in FIG. 7, in addition to the aforementioned semiconductor structure required for laser beam emission, the laser unit 7003 further comprises a back conductive structure 7032. The back conductive structure 7032 includes a plurality of detecting electrodes 7032A and 7032B, with the back conductive structure 7032 and the front conductive structure 7030 disposed on opposite sides of the laser unit 7003. A plurality of first channels 7034 extend from the back conductive structure 7032 and penetrate through the front conductive structure 7030 and the adhesive layer 7002, and electrically connect to the conductive layer 7010. In this embodiment, the two ends of each first channel 7034 are connected to the plurality of detecting electrodes 7032A, 7032B and the conductive layer 7010, respectively. In some embodiments, the mutually separated plurality of detecting electrodes 7032A and 7032B are bridged across the conductive layer 7010 via the first channels 7034. Consequently, by connecting the plurality of detecting electrodes 7032A and 7032B to an external control circuit, real-time monitoring of resistance variations in the conductive layer 7010 is achievable. When the semiconductor light-emitting device 7000 sustains damage due to external impact, particularly to the light-emitting side 7003S, the conductive layer 7010 will also be affected, resulting in increased resistance or even an open circuit due to damage. Accordingly, the control circuit, through the monitoring circuit, can determine whether to disconnect the power supply to the laser unit 7003 based on resistance variations in the conductive layer 7010. This prevents the laser beam L7 emitted by the laser unit 7003 from leaking through damaged areas of the transparent substrate 7001 and directly irradiating on living object, such as human eyes, thereby achieving real-time monitoring of abnormal conditions.

In this embodiment, as illustrated in FIG. 7, to prevent short-circuiting between the conductive medium filled in the first channel 7034 and the front conductive structure 7030, the first type semiconductor stack 7031, or the second type semiconductor stack 7035 of the laser unit 7003, the laser unit 7003 further comprises an passivation layer 7340 disposed between the inner wall of the laser unit 7003 and the first channel 7034.

In some embodiments, as shown in FIG. 7, the back conductive structure 7032 comprises a plurality of detecting electrodes 7032A, 7032B and a plurality of conductive electrodes 7032C, 7032D that are mutually separated and coplanar. This configuration enables the semiconductor light-emitting device 7000 to be suitable for flip-chip mounting onto a carrier board without the need for a wire bonding process, thereby reducing package volume. In one or more embodiments, the back conductive structure 7032 comprises a plurality of detecting electrodes 7032A, 7032B, which extend from the back conductive structure 7032, penetrate through the front conductive structure 7030 and the adhesive layer 7002, and connect to the conductive layer 7010.

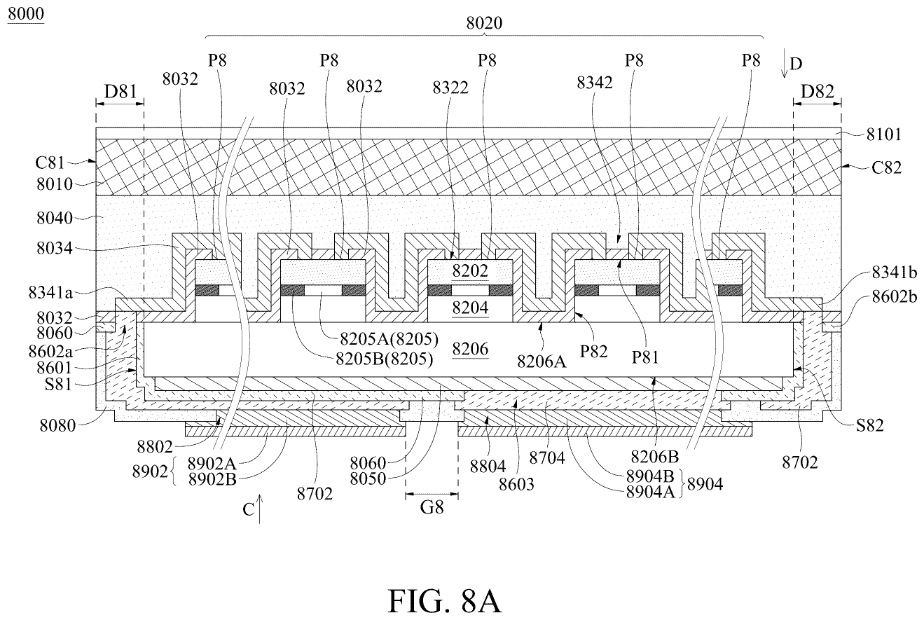

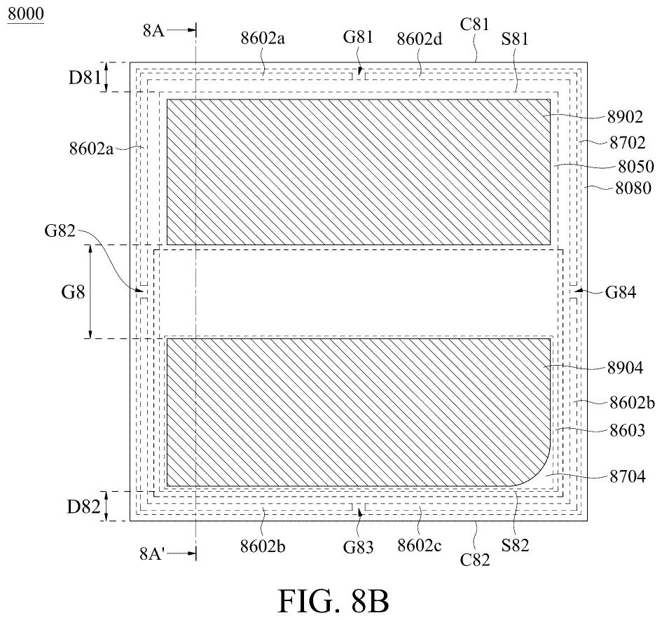

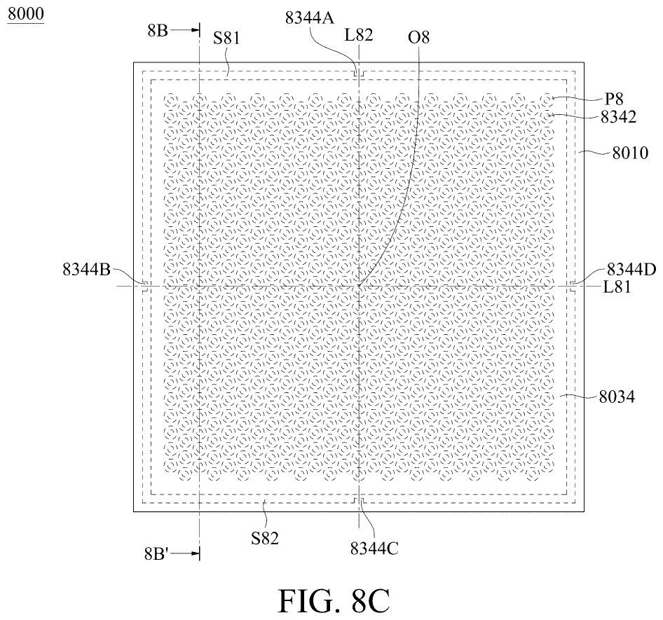

In one or more embodiments, the semiconductor device 32, as illustrated in FIGS. 3A to 3E, 4A to 4D, 5A to 5D, and 6A to 6D, may comprise a semiconductor light-emitting device 8000, as depicted in FIGS. 8A to 8C. FIG. 8B illustrates a bottom view of the semiconductor light-emitting device 8000 shown in FIG. 8A (viewed from the direction of arrow C in FIG. 8A, i.e., from the direction of the first contact pad structure 8902 and the second contact pad structure 8904). FIG. 8A presents a cross-sectional view taken along line 8A-8A′ in FIG. 8B. FIG. 8C illustrates a top view of the semiconductor light-emitting device 8000 shown in FIG. 8A, viewed from the direction of the transparent substrate 8010 (as indicated by arrow D in FIG. 8A). FIG. 8A further represents a cross-sectional view taken along line 8B-8B′ shown in FIG. 8C.

FIG. 8A illustrates a schematic cross-sectional view of a semiconductor light-emitting device 8000 according to an embodiment. In this embodiment, the semiconductor light-emitting device is a laser device comprising a transparent substrate 8010 and an epitaxial structure 8020 disposed on one side of the transparent substrate 8010. The epitaxial structure 8020 includes at least one columnar structure P8; in the present embodiment, the epitaxial structure 8020 comprises a plurality of columnar structures P8. Each columnar structure P8 comprises a first semiconductor structure 8202, a current confinement layer 8205, and an active structure 8204 which are sequentially disposed on the transparent substrate 8010.

The plurality of columnar structures P8 may be arranged in a regular or random pattern on a second semiconductor structure 8206. A regular arrangement refers to the plurality of columnar structures P8 having specific spatial relationships and being arranged in repetitive manner with identical distance. For example, in some regularly arranged columnar structures P8, adjacent columnar structures P8 are substantially equidistant from each other; in other regularly arranged columnar structures P8, the plurality of columnar structures P8 are aligned along a specific direction. Each columnar structure P8 comprises an upper surface P81 facing the transparent substrate 8010 and a lateral surface P82 connecting the upper surface P81 and the second semiconductor structure 8206. Furthermore, the epitaxial structure 8020 includes a lower surface 8206B distal to the transparent substrate 8010. The lower surface 8206B constitutes a surface of the second semiconductor structure 8206. In this embodiment, the first semiconductor structure 8202 is of P-type conductivity, while the second semiconductor structure 8206 is of N-type conductivity. For clarity, FIG. 8A depicts only five columnar structures P8 as examples; however, in an actual VCSEL product, the number of columnar structures P8 can be adjusted based on current and power requirements during application, for example, ranging from 100 to 1000, but not limited thereto.

In this embodiment, as shown in FIGS. 8A to 8C, the current confinement layer 8205 may be selectively disposed between the active structure 8204 and the first semiconductor structure 8202 or between the active structure 8204 and the second semiconductor structure 8206. The current confinement layer 8205 includes a current restriction region 8205B and a current conduction region 8205A surrounded by the current restriction region 8205B. The conductivity of the current conduction region 8205A is higher than that of the current restriction region 8205B, so that the current is concentrated and conducted in the current conduction region 8205A.

In this embodiment, as shown in FIGS. 8A to 8C, the first semiconductor structure 8202 and the active structure 8204 are partially covered on the second semiconductor structure 8206, and an end face 8206A of the second semiconductor structure 8206 is exposed. The semiconductor light-emitting device 8000 further includes a first passivation layer 8032 and a first metal connection layer 8034. The first passivation layer 8032 covers the lateral surface P82 of the columnar structure P8, the end face 8206A of the second semiconductor structure 8206, and a portion of the upper surface P81 of the columnar structure P8. The first passivation layer 8032 has a plurality of first openings 8322, which expose a portion of the upper surface P81 from the first passivation layer 8032. The first metal connection layer 8034 is disposed on the first passivation layer 8032 and is electrically connected to the first semiconductor structure 8202 through the first opening 8322. The first metal connection layer 8034 has a plurality of second openings 8342, so that the light emitted from the active structure 8204 can be emitted out of the semiconductor light-emitting device 8000 from the second opening 8342 toward the transparent substrate 8010. In addition, the second semiconductor structure 8206 has a first side S81 and a second side S82 is opposite to the first side S81. The first metal connection layer 8034 has a first protrusion 8341a extending beyond the first side S81 and a second protrusion 8341b extending beyond the second side S82. The first protrusion 8341a and the second protrusion 8341b can be used for subsequent electrical connection, the detailed structure and electrical connection method will be described in detail below.

In this embodiment, as shown in FIGS. 8A to 8C, the semiconductor light-emitting device 8000 further includes an adhesive layer 8040, and the above-mentioned epitaxial structure 8020 is connected to the transparent substrate 8010 via the adhesive layer 8040. A second metal connection layer 8050 is disposed on the second semiconductor structure 8206, away from the transparent substrate 8010, and the second metal connection layer 8050 is electrically connected to the second semiconductor structure 8206. The semiconductor light-emitting device 8000 of the present disclosure includes a second passivation layer 8060, and the second passivation layer 8060 covers the second metal connection layer 8050. The second passivation layer 8060 has two side portions 8601. Four openings (a first opening 8602a, a second opening 8602b, a third opening 8602c, and a fourth opening 8602d) further penetrate the second passivation layer 8060. The side portions 8601 cover the first side S81 and the second side S82 of the second semiconductor structure 8206. The first opening 8602a further penetrates the first passivation layer 8032 to expose the first protruding portion 8341a of the first metal connection layer 8034, and the second opening 8602b further penetrates the first passivation layer 8032 to expose the second protruding portion 8341b of the first metal connection layer 8034. The second passivation layer 8060 further has a fifth opening portion 8603 to expose the second metal connection layer 8050. The semiconductor light-emitting device 8000 of the present disclosure includes a first electrode 8702 and a second electrode 8704, wherein the first electrode 8702 and the second electrode 8704 are disposed on the same side of the transparent substrate 8010 and are physically separated from each other.

In this embodiment, as shown in FIGS. 8A to 8C, the semiconductor light-emitting device 8000 is a flip-chip laser device, and the semiconductor light-emitting device 8000 can be subsequently connected to an external carrier (e.g., PCB, or a driver IC) by a flip-chip bonding process. The first electrode 8702 is connected to the first metal connection layer 8034 through the first opening 8602a to the fourth opening 8602d, respectively, and is electrically connected to the first semiconductor structure 8202 through the first protruding portion 8341a and the second protruding portion 8341b of the first metal connection layer 8034. Furthermore, the first electrode 8702 covers the side portion 8060A of the second passivation layer 8060 and extends to cover the second metal connection layer 8050, and the second passivation layer 8060 is disposed between the first electrode 8702 and the second metal connection layer 8050 to avoid forming a short circuit path. The second electrode 8704 is connected to the second metal connection layer 8050 through the fifth opening portion 8603 so that the second electrode 8704 is electrically connected to the second semiconductor structure 8206.

In this embodiment, as shown in FIGS. 8A to 8C, the semiconductor light-emitting device 8000 of the present disclosure may further include a first pad structure 8902 and a second pad structure 8904, which are disposed on the first electrode 8702 and the second electrode 8704, respectively. The semiconductor light-emitting device 8000 of the present disclosure further includes a third passivation layer 8080 covering the first electrode 8702 and the second electrode 8704. The third passivation layer 8080 has a first hole 8802 to expose the first electrode 8702 and a second hole 8804 to expose the second electrode 8704; the first pad structure 8902 is electrically connected to the first electrode 8702 through the first hole 8802, and the second pad structure 8904 is electrically connected to the second electrode 8704 through the second hole 8804. Further, a space G8 between the first pad structure 8902 and the second pad structure 8904 is between 10 μm and 200 μm. In this embodiment, as viewed from a bottom view of the semiconductor light-emitting device 8000, the first pad structure 8902 has a shape different from that of the second pad structure 8904 for electrical identification.

In this embodiment, as shown in FIGS. 8A to 8C, the semiconductor light-emitting device 8000 of the present disclosure may optionally include an anti-reflective structure 8101 disposed on the transparent substrate 8010 and away from the first electrode 8702 and the second electrode 8704. The anti-reflective structure 8101 can be used to reduce the reflection of light emitted from the laser device 8000 at the interface between the transparent substrate 8010 and air to avoid reducing the light-emitting efficiency of the semiconductor light-emitting device 8000 or generating an unexpected beam profile.

In this embodiment, as shown in FIGS. 8A to 8C, the first semiconductor structure 8202 and the second semiconductor structure 8206 include a plurality of layers with different refractive index which are stacked alternately (for example, AlGaAs layers with high aluminum content and AlGaAs layers with low aluminum content are stacked alternately) and periodically to form Distributed Bragg Reflector (DBR) structure such that light emitted from the active structure 8204 may be reflected off between two DBR structures to form coherent light. The reflectance of the first semiconductor structure 8202 is lower than the reflectance of the second semiconductor structure 8206 such that the coherent light propagates toward the transparent substrate 8010. The first semiconductor structure 8202, the second semiconductor structure 8206, and the active structure 8204 are made of III-V compound semiconductors, such as AlGaInAs series, AlGaInP series, AlInGaN series, AlAsSb series, InGaAsP series, InGaAsN series, and AlGaAsP series, such as, AlGaInP, GaAs, InGaAs, AlGaAs, GaAsP, GaP, InGaP, AlInP, GaN, InGaN, or AlGaN. Unless otherwise specified in this embodiment, the aforesaid chemical formulas include stoichiometric compounds and non-stoichiometric compounds. The compounds are stoichiometric when, for example, the total stoichiometric amount of group III elements is equal to the total stoichiometric amount of group V elements. The compounds are non-stoichiometric when, for example, the total stoichiometric amount of group III elements is not equal to the total stoichiometric amount of group V elements. For instance, the chemical formula AlGaInAs series includes group III elements, such as aluminum (Al) and/or gallium (Ga) and/or indium (In) and includes group V element arsenic (As), wherein the total stoichiometric amount of group III elements (aluminum and/or gallium and/or indium) is the same as or different from the total stoichiometric amount of group V element (arsenic). In addition, when the aforesaid compounds expressed by chemical formulas are stoichiometric compounds, the consequence is as follows: AlGaInAs series is expressed by (Al_{y1}Ga_{(1-y1)})₁₋ₓ₁Inₓ₁As, where 0≤x1≤1, 0≤y1≤1; AlGaInP series is expressed by (Al_{y2}Ga_{(1-y2)})₁₋ₓ₃Inₓ₂P, where 0≤x2≤1, 0≤y2≤1; AlInGaN series is expressed by (Al_{y3}Ga_{(1-y3)})₁₋ₓ₃Inₓ₃N, where 0≤x3≤1, 0≤y3≤1; AlAsSb series is expressed by AlAsₓ₄Sb₍₁₋ₓ₄₎, where 0≤x4≤1; InGaAsP series is expressed by Inₓ₅Ga₁₋ₓ₅As_{1-y4}P_{y4}, where 0≤x5≤1, 0≤y4≤1; InGaAsN series is expressed by Inₓ₆Ga₁₋ₓ₆As_{1-y5}N_{y5}, where 0≤x6≤1, 0≤y5≤1; and AlGaAsP series is expressed by Alₓ₇Ga₁₋ₓ₇As_{1-y6}P_{y6}, where 0≤x7≤1, 0≤y6≤1.

Depending on the materials it is made of, the active structure 8204 emits infrared light with a peak wavelength between 700 nm and 1700 nm, red light with a peak wavelength between 610 nm and 700 nm, yellow light with a peak wavelength between 530 nm and 570 nm, green light with a peak wavelength between 490 nm and 550 nm, blue or dark blue light with a peak wavelength between 400 nm and 490 nm, or ultraviolet with a peak wavelength between 250 nm and 400 nm. In this embodiment, the active structure 8204 emits infrared light with a peak wavelength between 750 nm and 1200 nm.

The current confinement layer 8205 is made of the aforesaid III-V semiconductor materials. In this embodiment, as shown in FIGS. 8A to 8C, the current confinement layer 8205 is made of AlGaAs, and the active structure 8204, the first semiconductor structure 8202, and the second semiconductor structure 8206 are made of aluminum-containing materials. The current confinement layer 8205 has greater aluminum content than the active structure 8204, the first semiconductor structure 8202, and the second semiconductor structure 8206 do. For instance, the current confinement layer 8205 has aluminum content greater than 97%. In this embodiment, the current restriction region 8205B has greater oxygen content than the current conduction region 8205A, such that the current restriction region 8205B has lower electrical conductivity than the current conduction region 8205A does. The adhesive layer 8040 is made of a material which is highly penetrable by the light emitted from the active structure 8204 (such as with transmittance greater than 80%). The adhesive layer 8040 is made of an insulating material, such as B-staged bisbenzocyclobutene (BCB), epoxy resin, polyimide, SOG (spin-on glass), silicone, or perfluorocyclobutane (PFCB).

In this embodiment, as shown in FIGS. 8A to 8C, the first passivation layer 8032, the second passivation layer 8060, and the third passivation layer 8080 are made of electrically non-conductive materials. The electrically non-conductive materials include organic materials or inorganic materials. The organic materials include SU-8, benzocyclobutene (BCB), perfluorocyclobutane (PFOB), epoxy, acrylic resin, cyclic olefin copolymer (COC), poly(methyl methacrylate) (PMMA), polyethylene terephthalate (PET), polycarbonate (PC), polyetherimide, and fluorocarbon polymer. The inorganic materials include silicone, glass, aluminum oxide (Al₂O₃), silicon nitride (SiNx), silicon oxide (SiOx), titanium oxide (TiOx), and magnesium fluoride (MgFx). In an embodiment, the first passivation layer 8032, the second passivation layer 8060, and/or the third passivation layer 8080 include a single layer or multiple layers (such as a distributed Bragg reflector (DBR) structure formed by alternately stacking two sub-layers, such as an SiOx sub-layer and a TiOx sub-layer).

In this embodiment, as shown in FIGS. 8A to 8C, the materials of the first metal connection layer 8034 and the second metal connection layer 8050 may include metals, such as aluminum (Al), silver (Ag), chromium (Cr), platinum (Pt), nickel (Ni), germanium (Ge), beryllium (Be), gold (Au), titanium (Ti), tungsten (W), or zinc (Zn). The first electrode 8702 and the second electrode 8704 may be made of metal materials, such as gold (Au), tin (Sn), titanium (Ti), or alloys thereof. In this embodiment, the first electrode 8702 may be a multi-layer electrode structure, for example, including a titanium (Ti) layer and a gold (Au) layer, which are arranged sequentially in a direction away from the transparent base 8010. The second electrode 8704 and the first electrode 8702 are made of the same material and have the same structure. The first pad structure 8902 and the second pad structure 8904 are made of metal materials, such as gold (Au), tin (Sn), titanium (Ti), copper (Cu), nickel (Ni), platinum (Pt), or alloys thereof. The material of the first electrode 8702 is different from that of the first pad structure 8902, and the material of the second electrode 8704 is different from that of the second pad structure 8904. For example, the first pad structure 8902 and the second pad structure 8904 include an element, and the first electrode 8702 and the second electrode 8704 do not include the element to prevent the die bonding or external (tin-containing) solder from damaging the first electrode 8702 and the second electrode 8704 under high-current operation, thereby improving the reliability of the laser device 8000. The element can be used to block solder from diffusing into the first electrode 8702 and the second electrode 8704, and the element is, for example, nickel (Ni) and/or platinum (Pt). Specifically, each of the first pad structure 8902 and the second pad structure 8904 is a multilayer, sequentially including a middle layer 8902A, a middle layer 8904A, and a coupling layer 8902B, a coupling layer 8904B in the direction away from the transparent base 8010. The materials of the middle layers 8902A and 8904A are different from those of the first electrode 8702 and the second electrode 8704 to prevent the solder (for example: tin or gold-tin alloy (AuSn)) from diffusing into the first electrode 8702 and the second electrode 8704, so the materials of the middle layers 8902A, 8904A preferably include metal elements other than gold (Au), tin (Sn), and copper (Cu), such as nickel (Ni) and/or platinum (Pt). The materials of the coupling layers 8902B and 8904B include metal materials with high ductility, such as gold (Au). The middle layer 8902A, 8904A in this embodiment is made of platinum (Pt) and nickel (Ni), which are sequentially stacked in a direction away from the transparent base 8010, and the coupling layer 8902B, 8904B is made of gold (Au). In other words, in the direction away from the transparent base 8010, the first pad structure 8902 and the second pad structure 8904 include a nickel layer, a platinum layer, and a gold layer.

Referring to FIGS. 8A and 8B, the transparent base 8010 has a central region and a peripheral region surrounding the central region. The second passivation layer 8060 has a plurality of opening portions (for example, a first opening portion 8602a, a second opening portion 8602b, a third opening portion 8602c, and a fourth opening portion 8602d) distributed in the peripheral region of the transparent base 8010. In addition, there are four spaces G81-G84 between the four opening portions 8602a-8602d. More specifically, in this embodiment, the first opening portion 8602a and the fourth opening portion 8602d are separated by a first space G81, the first opening portion 8602a and the second opening portion 8602b are separated by a second space G82, the second opening portion 8602b and the third opening portion 8602c are separated by a third space G83, and the third opening portion 8602c and the fourth opening portion 8602d are separated by a fourth space G84.

Furthermore, as shown in FIG. 8C, in this embodiment, the first metal connection layer 8034 is formed with a plurality of marking structures 8344A-8344D, which are convenient for machine recognition to facilitate the subsequent packaging process. The marking structures 8344B and 8344D are opposite and connected to define a connection line L81. The marking structures 8344A and 8344C are opposite and connected to define a connection line L82. The connection line L81 and the connection line L82 intersect at a center position O8. Referring to FIG. 8B and FIG. 8C, the marking structure 8344A corresponds to the first spacing G81, the marking structure 8344B corresponds to the second spacing G82, the marking structure 8344C corresponds to the third spacing G83, and the marking structure 8344D corresponds to the fourth spacing G84. It should be noted that the dashed lines in FIG. 8B and FIG. 8C indicate that the structure cannot be directly observed from the bottom view/top view, and only the outline of the dashed lines can be seen.

In this embodiment, the second semiconductor structure 8206 may be disposed on the center region of the transparent base layer 8010. In one embodiment, the distances between any lateral surface of the second semiconductor structure 8206 and a adjacent boundary of the transparent base layer 8010 are substantially equal, thereby enabling the first pad structure 8902 and the second pad structure 8904 (or the first electrode 8702 and the second electrode 8704) to be symmetrical with respect to the connection line L81, which is advantageous for the structural design of the subsequent packaging process and increases the effective area for connecting to an external circuit. As shown in FIG. 8B, viewing from the second semiconductor structure 8206 of the semiconductor light-emitting device 8000 toward the active structure 8204, the transparent base layer 8010 has a first boundary C81 adjacent to the first side S81 and a second boundary C82 opposite to the first boundary C81 and adjacent to the second side S82, wherein the first boundary C81 and the second boundary C82 correspond to each other and are disposed on the sides of the transparent base layer 8010, respectively. The difference between a first distance D81 between the first side S81 and the first boundary C81 and a second distance D82 between the second side S82 and the second boundary C82 is less than 30% of the first distance D81; that is, the difference between the first distance D81 and the second distance D82 is 0≤(D81−D82)/D81≤30%, in another embodiment, 0≤(D81−D82)/D81≤20%; preferably, 0≤(D81−D82)/D81≤15%. In another embodiment, 1%≤(D81−D82)/D81≤10%. In this embodiment, the first distance D81 is equal to the second distance D82.

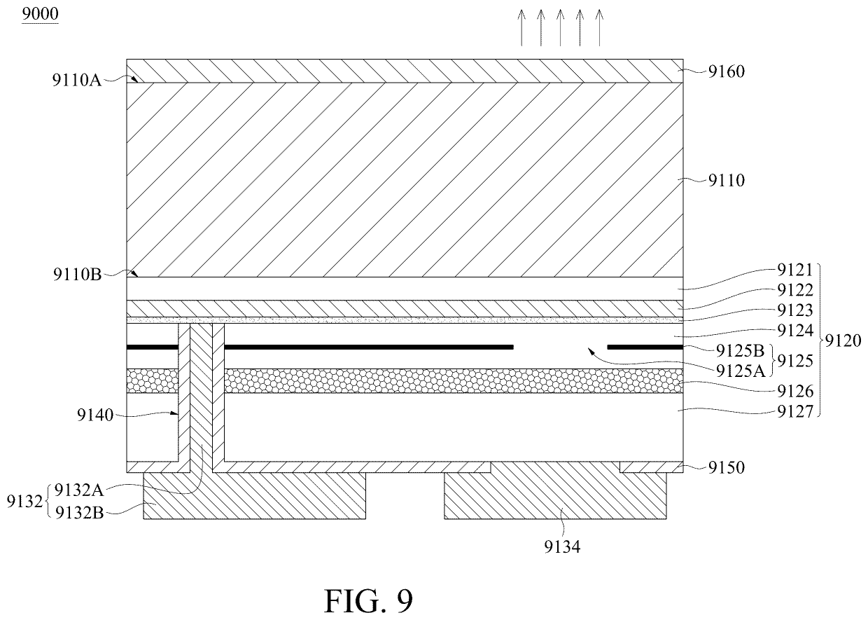

In one or more embodiments, the semiconductor device 32, as shown in FIGS. 3A to 3E, FIGS. 4A to 4D, FIGS. 5A to 5D, and FIGS. 6A to 6D, may be a semiconductor light emitting device 9000, as shown in FIG. 9.

Referring to FIG. 9, which is a schematic cross-sectional view of a semiconductor light emitting device 9000 according to an embodiment. The semiconductor light emitting device 9000 of the embodiment is a laser diode, and includes a substrate 9110, an epitaxial stack 9120 formed on the substrate 9110, and a first electrode structure 9132 and a second electrode structure 9134 disposed on the epitaxial stack 9120. The substrate 9110 is a gallium arsenide (GaAs) substrate with high transmittance and has a first surface 9110A and a second surface 9110B. The light exiting surface of the semiconductor light emitting device 9000 (as indicated by the arrow in FIG. 9) is defined as the first surface 9110A. The epitaxial stack 9120 is disposed on the second surface 9110B of the substrate 9110 and sequentially includes a first semiconductor structure 9121, a second semiconductor structure 9122, an intermediate layer 9123, a third semiconductor structure 9124, an active structure 9126, and a fourth semiconductor structure 9127.

In this embodiment, as shown in FIG. 9, the substrate 9110 includes a dopant to have a p-type or n-type conductivity type. Alternatively, in another embodiment, the substrate 9110 does not include any dopant or the substrate 9110 is an undoped base layer. The first semiconductor structure 9121 is an undoped semiconductor material to reduce light absorption by dopants. The second semiconductor structure 9122, the intermediate layer 9123, the third semiconductor structure 9124, and the fourth semiconductor structure 9127 are semiconductor materials including dopants. The second semiconductor structure 9122, the intermediate layer 9123, and the third semiconductor structure 9124 have the same conductivity type, and the third semiconductor structure 9124 (or the second semiconductor structure 9122 or the intermediate layer 9123) and the fourth semiconductor structure 9127 have different conductivity types. In this embodiment, the second semiconductor structure 9122, the intermediate layer 9123, and the third semiconductor structure 9124 are of p-type conductivity type, and the fourth semiconductor structure 9127 is of n-type conductivity type. In another embodiment, the second semiconductor structure 9122, the intermediate layer 9123, and the third semiconductor structure 9124 are of n-type conductivity type, and the fourth semiconductor structure 9127 is of p-type conductivity type. The first electrode structure 9132 and the second electrode structure 9134 are disposed on the fourth semiconductor structure 9127. The dopants may include beryllium, magnesium, zinc, carbon, silicon or antimony or combination thereof.

Referring to the embodiment shown in FIG. 9 again, selectively, the third semiconductor structure 9124 or the fourth semiconductor structure 9127 includes a current confinement layer 9125. Alternatively, in this embodiment, the current confinement layer 9125 is formed in the third semiconductor structure 9124 or the fourth semiconductor structure 9127. The current confinement layer 9125 includes a current restriction region 9125B and a current conduction region 9125A defined and surrounded by the current restriction region 9125B.

In this embodiment, as shown in FIG. 9, the semiconductor light-emitting device 9000 further includes a recess 9140 and a protection layer 9150. The recess 9140 is formed in the epitaxial stack 9120. More specifically, in this embodiment, the recess 9140 is formed in the fourth semiconductor structure 9127, the active structure 9126, and the third semiconductor structure 9124. In other words, in this embodiment, the recess 9140 passes through the fourth semiconductor structure 9127, the active structure 9126, and the third semiconductor structure 9124, and exposes the intermediate layer 9123. The protection layer 9150 is filled in the recess 9140 and locate between the first electrode structure 9132 and the fourth semiconductor structure 9127. The first electrode structure 9132 has a first portion 9132A and a second portion 9132B. The first portion 9132A is filled in the recess 9140 and is in contact with and electrically connected to the intermediate layer 9123. The second portion 9132B extends from the first portion 9132A and locate on the protection layer 9150. A second electrode structure 9134 is disposed on and electrically connected to the fourth semiconductor structure 127.

In this embodiment, as shown in FIG. 9, the semiconductor light-emitting device 9000 optionally further includes an optics 9160 covering a first surface 9110A of a substrate 9110. For example, the optics 9160 may be an anti-reflection element for further reducing reflection of light emitted from the semiconductor light-emitting device 9000 at an interface between the substrate 9110 and air to avoid reducing light-emitting efficiency of the semiconductor light-emitting device 9000 or to prevent interference between the reflected light from the interface and light emitted from the semiconductor device 9000.

In this embodiment, as shown in FIG. 9, the first semiconductor structure 9121, the second semiconductor structure 9122, the third semiconductor structure 9124, and the fourth semiconductor structure 9127 may each include a plurality of periodically alternately stacked layers having different refractive index (for example, periodically alternately stacked AlGaAs layers having a high aluminum content and AlGaAs layers having a low aluminum content), so as to form a distributed Bragg reflector (DBR), so that the light emitted from the active structure 126 may be reflected in between the DBRs to form coherent light. The refractive index of the first semiconductor structure 9121, the second semiconductor structure 9122 and the third semiconductor structure 9124 are lower than the refractive index of the fourth semiconductor structure 9127, so as to allow the coherent light to be emitted in a direction of the base 9110. The materials of the first semiconductor structure 9121, the second semiconductor structure 9122, the third semiconductor structure 9124, the fourth semiconductor structure 9127 and the active structure 9126 include group III-V compound semiconductors, for example, the AlGaInAs series, AlGaInP series, AlInGaN series, AlAsSb series, InGaAsP series, InGaAsN and series, AlGaAs series, for example, compounds such as AlGaInP, GaAs, InGaAs, AlGaAs, GaAsP, GaP, InGaP, AlInP, GaN, InGaN and AlGaN. Unless otherwise specified in this embodiment, the aforesaid chemical formulas include stoichiometric compounds and non-stoichiometric compounds. The compounds are stoichiometric when, for example, the total stoichiometric amount of group III elements is equal to the total stoichiometric amount of group V elements. The compounds are non-stoichiometric when, for example, the total stoichiometric amount of group III elements is not equal to the total stoichiometric amount of group V elements. For instance, the chemical formula AlGaInAs series includes group III elements, such as aluminum (Al) and/or gallium (Ga) and/or indium (In) and includes group V element arsenic (As), wherein the total stoichiometric amount of group III elements (aluminum and/or gallium and/or indium) is the same as or different from the total stoichiometric amount of group V element (arsenic). In addition, when the aforesaid compounds expressed by chemical formulas are stoichiometric compounds, the consequence is as follows: AlGaInAs series is expressed by (Al_{y1}Ga_{(1-y1)})₁₋ₓ₁Inₓ₁As, where 0≤x1≤1, 0≤y1≤1; AlGaInP series is expressed by (Al_{y2}Ga_{(1-y2)})₁₋ₓ₂Inₓ₂P, where 0≤x2≤1, 0≤y2≤1; AlInGaN series is expressed by (Al_{y3}Ga_{(1-y3)})₁₋ₓ₃Inₓ₃N, where 0≤x3≤1, 0≤y3≤1; AlAsSb series is expressed by AlAsₓ₄Sb₍₁₋ₓ₄₎, where 0≤x4≤1; InGaAsP series is expressed by Inₓ₅Ga₁₋ₓ₅As_{1-y4}P_{y4}, where 0≤x5≤1, 0≤y4≤1; InGaAsN series is expressed by Inₓ₆Ga₁₋ₓ₆As_{1-y5}N_{y5} where 0≤x6≤1, 0≤y5≤1; and AlGaAsP series is expressed by A1ₓ₇Ga₁₋ₓ₇As_{1-y6}P_{y6}, where 0≤x7≤1, 0≤y6≤1.

Depending on different materials, the active structure 9126 can emit infrared light having a peak wavelength between 700 nm and 1700 nm, red light having a peak wavelength between 610 nm and 700 nm, yellow light having a peak wavelength between 530 nm and 570 nm, green light having a peak wavelength between 490 nm and 550 nm, blue or deep blue light having a peak wavelength between 400 nm and 490 nm, or ultraviolet light having a peak wavelength between 250 nm and 400 nm. In this embodiment, the peak wavelength of the active structure 9126 is infrared light between 750 nm and 2000 nm.

The current confinement layer 9125 may be formed by an oxidation process or an ion implantation process. In this embodiment, when the first semiconductor structure 9121, the second semiconductor structure 9122, the third semiconductor structure 9124, the active structure 9126, and the fourth semiconductor structure 9127 include a plurality of layers and all include aluminum element, the aluminum content of one or more of the layers of the third semiconductor structure 9124 may be designed to be greater than 97% (defined as the current confinement layer 9125) and greater than the aluminum contents of the active structure 9126, the other layers of the third semiconductor structure 9124, the second semiconductor structure 9122, the first semiconductor structure 9121, and the fourth semiconductor structure 9127. Thereby, after oxidation is performed, a portion of the layer or layers having the aluminum content greater than 97% is oxidized to form the current restriction region 9125B (e.g., aluminum oxide), and a portion that is not oxidized becomes the current conduction region 9125A. During oxidation process, oxygen undergoes an oxidation reaction with the epitaxial stack 9120 through the recess 9140.

Materials of the first electrode structure 9132 and the second electrode structure 9134 include metal materials, for example, gold (Au), tin (Sn), titanium (Ti), copper (Cu), silver (Au), germanium (Ge), platinum (Pt), palladium (Pd), nickel (Ni), or an alloy thereof.

In this embodiment, as shown in FIG. 9, the material of the intermediate layer 9123 is different from those of the first semiconductor structure 9121, the second semiconductor structure 9122, and the third semiconductor structure 9124. The intermediate layer 9123 may be a single layer or multiple layers and serves as an etch stop layer for controlling the depth of the recess 9140 by an etching process. The intermediate layer 9123 includes a semiconductor material, for example, GaAs or InGaP, and has a thickness that is an odd-number multiple of ¼n of the peak wavelength of light emitted by the active structure 9126, wherein n is a refractive index. In one embodiment, because the material of the intermediate layer 9123 is different from those of the first semiconductor structure 9121, the second semiconductor structure 9122, and the third semiconductor structure 9124, the optical characteristics (for example, reflectance and threshold current (Ith)) of the semiconductor light-emitting device 9000 are affected. Therefore, the thickness of the intermediate layer 9123 is designed to be between 0.05 μm and 0.5 μm. In one embodiment, the intermediate layer 9123 may possibly reduce lateral current spreading, and thus, the second semiconductor layer 9122 may be provided for considerations of optical characteristics and may further serve as a current spreading layer. When the intermediate layer 9123 is multiple layers (for example, including two layers, wherein the first layer is InGaP and the second layer is GaAs), the total of the thicknesses of the multiple layers is between 0.05 μm and 0.5 μm.

In one embodiment, as shown in FIG. 9, when the first semiconductor structure 9121, the second semiconductor structure 9122, and the third semiconductor structure 9124 are all DBRs, the number of pairs of the periodically alternately stacked layers in the first semiconductor structure 9121 may be greater than, equal to, or smaller than that of the second semiconductor structure 9122, and/or the number of pairs of the periodically alternately stacked layers in the first semiconductor structure 9121 may be greater than, equal to, or smaller than that of the third semiconductor structure 9124. In one embodiment, the number of pairs of the layers of the second semiconductor structure 9122 is smaller than the number of pairs of the layers of the third semiconductor structure 9124. In one embodiment, the number of pairs of the layers of the first semiconductor structure 9121 may be 5 to 15 pairs, the number of pairs of the layers of the second semiconductor structure 9122 may be 2 to 5 pairs, and the number of pairs of the layers of the third semiconductor structure 9124 may be 5 to 15 pairs.

In one embodiment, as shown in FIG. 9, according to requirements for optical characteristics, the total of the numbers of pairs of the layers of the first semiconductor structure 9121, the second semiconductor structure 9122, and the third semiconductor structure 9124 is smaller than the number of pairs of the layers of the fourth semiconductor structure 9127. For example, the total of the numbers of pairs of the layer of the first semiconductor structure 9121, the second semiconductor structure 9122, and the third semiconductor structure 9124 is 15 to 25 pairs, and the number of pairs of the layers of the fourth semiconductor structure 9127 is 30 to 60 pairs.

In one embodiment, as shown in FIG. 9, a p-type semiconductor layer has a lower doping concentration than an n-type semiconductor layer in the aspect of a manufacturing process, and the total of the numbers of pairs of the layers of the second semiconductor structure 9122 and the third semiconductor structure 9124 is smaller than the number of pairs of the layers of the fourth semiconductor structure 9127 in the aspect of design. Thus, the conductivity type of the first semiconductor structure 9122 and the third semiconductor structure 9124 may be designed as p-type, and the conductivity type of the fourth semiconductor structure 9127 may be designed as n-type, thereby reducing the series resistance and enhancing the light-emitting efficiency of the overall semiconductor device.

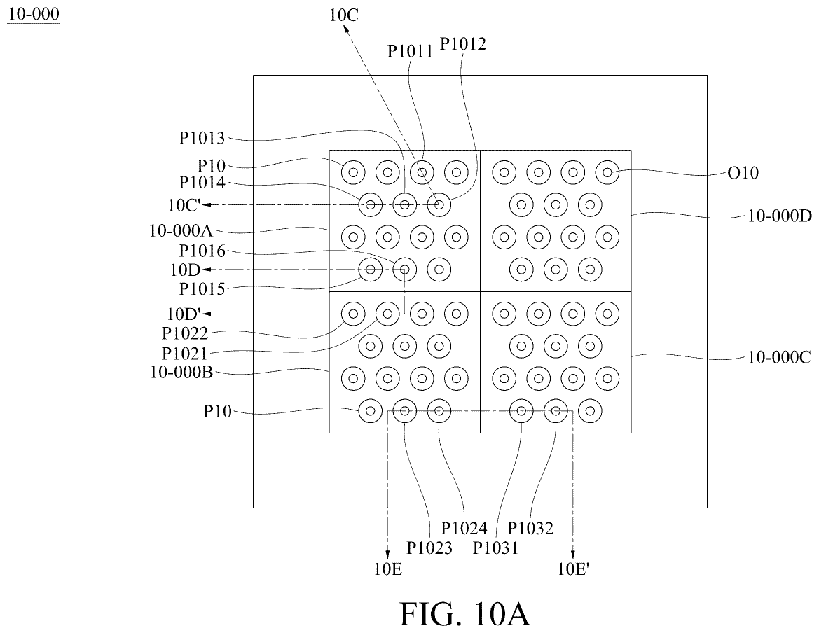

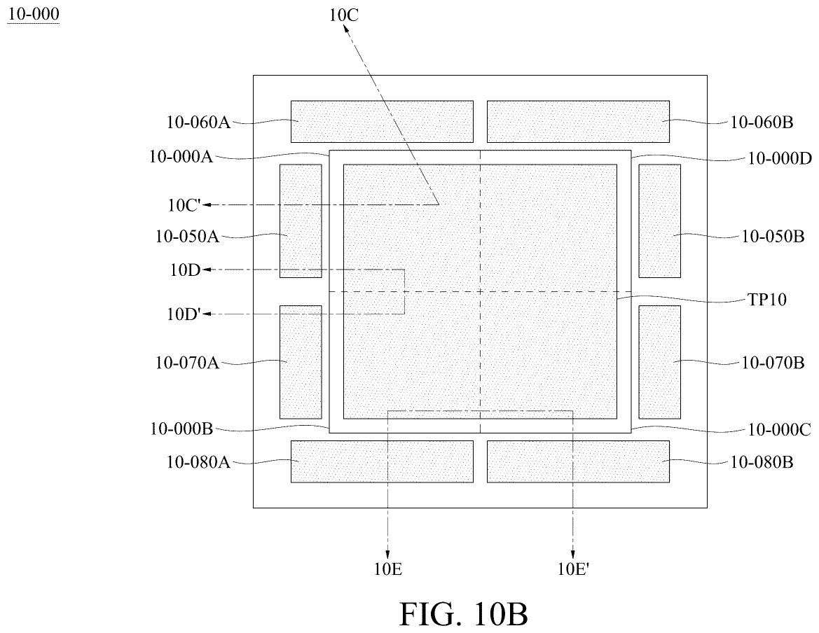

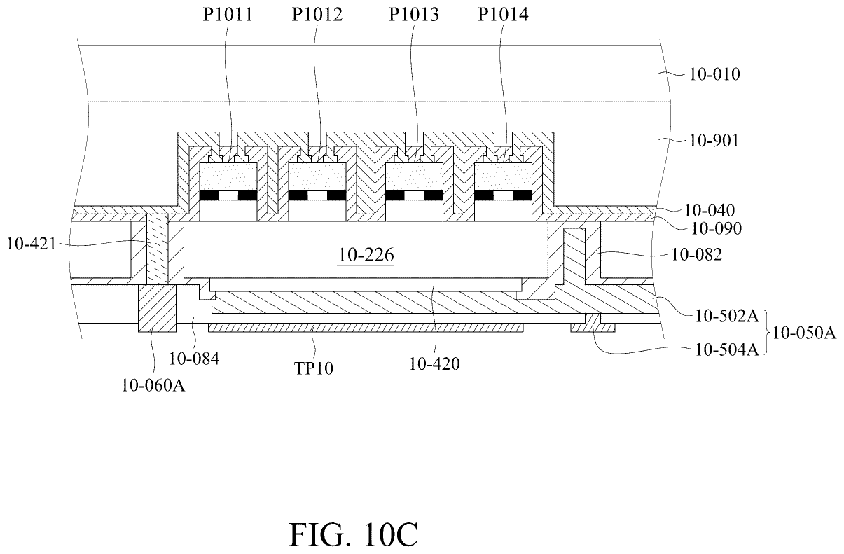

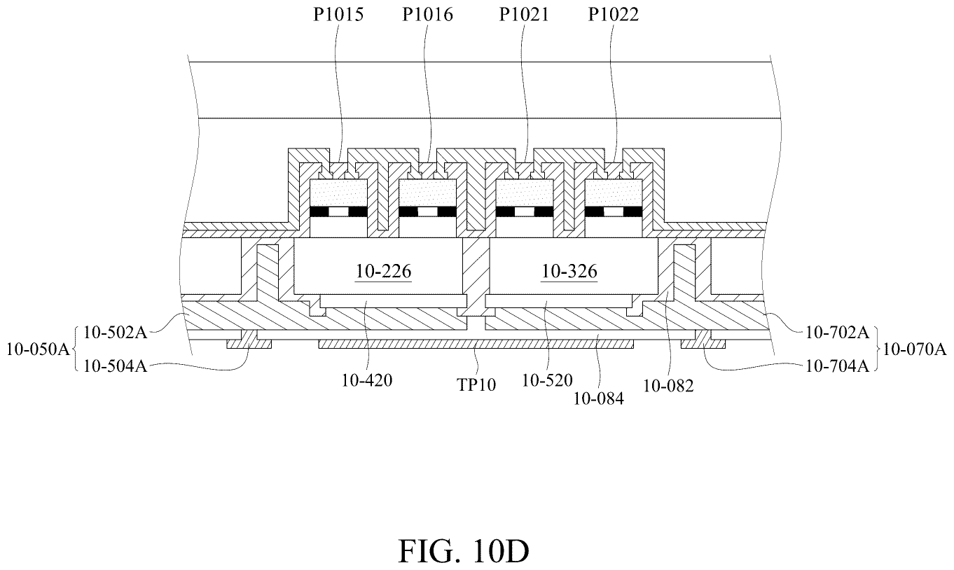

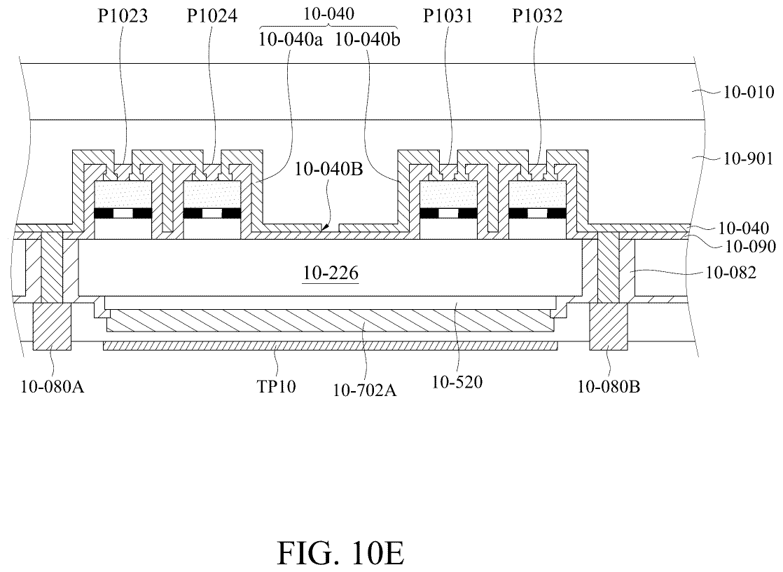

In one or more embodiments, the semiconductor device 32 illustrated in FIGS. 3A to 3E, 4A to 4D, 5A to 5D, and 6A to 6D may be the semiconductor light emitting device 10-000, as shown in FIGS. 10A to 10E. Please refer to FIG. 10C through FIG. 10E, which illustrate schematic cross-sectional views with different cross-sections of a semiconductor light emitting device 10-000 according to an exemplary embodiment. Wherein, FIG. 10C schematically illustrates a cross-sectional structure taken along line 10C-10C′ of FIG. 10A, FIG. 10D schematically illustrates a cross-sectional structure taken along line 10D-10D′ of FIG. 10A, and FIG. 10E schematically illustrates a cross-sectional structure taken along line 10E-10E′ of FIG. 10A.

For clarity, component symbols after FIG. 10A will be presented in the format of XX (figure number)-XXX (random code). For example, the semiconductor light-emitting device is represented as 10-000.

Please refer to FIGS. 10A to 10E, which are a bottom perspective view, a top perspective view, and cross-sectional views with different cross-sections of a semiconductor light emitting device 10-000 according to an exemplary embodiment, respectively. In this embodiment, as shown in FIG. 10C, the semiconductor light emitting device 10-000 comprises a substrate 10-010, an adhesive layer 10-901, a plurality of epitaxial columnar structures P10 (P1011 to P1014), and a mesa structure 10-226, wherein the epitaxial columnar structures P10 are formed on the mesa structure 10-226 and adhered to the substrate 10-010 by the adhesive layer 10-901. The semiconductor light emitting device 10-000 further comprises a metal connecting layer 10-040, disposed between the epitaxial columnar structures P10 and the substrate 10-010, wherein the metal connecting layer 10-040 electrically connects to a first semiconductor structure 10-222 of each of the epitaxial columnar structures P10 (P1011 to P1014), and an passivation layer 10-090 disposed between the metal connecting layer 10-040 and the columnar structures P10. In this embodiment, the semiconductor light-emitting device 10-000 further comprises an passivation layer 10-082, wherein the passivation layer 10-090 covers the metal connection layer 10-420, covers the sides and partial surfaces of the metal connection layer 10-520, and covers the sides and partial surfaces of the mesa structure 10-226 and the mesa structure 10-326.

In this embodiment, as shown in FIGS. 10B to 10E, the semiconductor light emitting device 10-000 further comprises electrode structures 10-050A, 10-050B, 10-060A, 10-060B, 10-070A, 10-070B, 10-080A, 10-080B. In this embodiment, as shown in FIG. 10B, the electrode structures 10-050A, 10-050B, 10-060A, 10-060B, 10-070A, 10-070B, 10-080A, 10-080B of the semiconductor light emitting device 10-000 are at an outer side of light emitting regions 10-000A, 10-000B, 10-000C, 10-000D, and the electrode structures and the light emitting regions do not overlap with each other. Specifically, in this embodiment, the structure of the semiconductor light emitting device 10-000 is formed by a structure of a light emitting section and a structure of a non-light emitting section. The structure of the light emitting section of the semiconductor light emitting device 10-000 comprises four light emitting regions 10-000A, 10-000B, 10-000C, 10-000D, and the structure of the non-light emitting section of the semiconductor light emitting device 10-000 comprises the electrode structures 10-050A, 10-050B, 10-060A, 10-060B, 10-070A, 10-070B, 10-080A, 10-080B, but the numbers of the light emitting regions and the electrode structures are not limited thereto. In this embodiment, shown in FIG. 10B, the electrode structure 10-050A and the electrode structure 10-060A at the outer side of the light emitting region 10-000A are adapted to control the light emitting region 10-000A, the electrode structure 10-070A and the electrode structure 10-080A at the outer side of the light emitting region 10-000B are adapted to control the light emitting region 10-000B, the electrode structure 10-070B and the electrode 10-080B at the outer side of the light emitting region 10-000C are adapted to control the light emitting region 10-000C, and the electrode structure 10-050B and the electrode structure 10-060B at the outer side of the light emitting region 10-000D are adapted to control the light emitting region 10-000D. In this embodiment, shown in FIG. 10B, the electrode structures 10-050A, 10-060A, 10-070A, 10-080A, 10-050B, 10-060B, 10-070B, 10-080B are separated from each other.

In this embodiment, the semiconductor light emitting device 10-000 may optionally further comprise a thermal conductive structure TP10 at a backside of the light emitting regions 10-000A, 10-000B, 10-000C, 10-000D, for conducting heat generated by each of the light emitting regions to the exterior, thereby improving heat dissipation of the semiconductor light emitting device 10-000, wherein a material of the thermal conductive structure TP10 may be, for example, a metal, and a distribution area of the thermal conductive structure TP10 covers a corresponding area of all the epitaxial columnar structures P10, for each of the light emitting regions to dissipate heat. However, the disclosure is not limited thereto. In one embodiment, for example, the electrode structure 10-060A and the electrode structure 10-080A may be electrically connected to each other through an inner connection structure, so that the electrode structure 10-060A and the electrode structure 10-080A form a common electrode structure. In another embodiment, for example, the electrode structure 10-060A and the electrode structure 10-080B at diagonal positions, or the electrode structure 10-060B and the electrode structure 10-080A at diagonal positions are electrically connected to each other through an inner connection structure, so as to form two electrode structures with different electrical properties. Thereby, the current distribution can be further improved. However, the disclosure is not limited thereto.

As shown in FIG. 10C, the four epitaxial columnar structures P1011, P1012, P1013, P1014 (i.e., corresponding to the light emitting apertures) of the light emitting region 10-000A are disposed on the same mesa structure 10-226, and an electrical control signal is transmitted through the electrode structure 10-050A and the electrode structure 10-060A at the outer side of the mesa structure 10-226 to control the light emitting state of the light emitting region 10-000A. In this embodiment, the electrode structure 10-050A is electrically connected to the semiconductor structure (i.e., corresponding to the mesa structure 10-226) via an electrode connecting layer 10-420, and the electrode structure 10-060A is connected to the conductive layer 10-421, and thus electrically connected to the metal connecting layer 10-040 of the semiconductor light emitting device 10-000. In this embodiment, the semiconductor light emitting device 10-000 further comprises a thermal conductive structure TP10 over an insulation layer 10-084 for conducting heat dissipation.

FIG. 10D shows epitaxial columnar structures P1015, P1016, P1021, and P1022 disposed in different light-emitting regions 10-000A and 10-000B, wherein the epitaxial columnar structures P1015 and P1016 are disposed on a mesa structure 10-226 and the epitaxial columnar structures P1021 and P1022 are disposed on a mesa structure 10-326. As shown in FIG. 10D, electrode structures 10-050A and 10-070A are electrically connected to mesa structures 10-226 and 10-326, respectively, and electrode structures 10-050A and 10-070A are not electrically connected to each other (i.e., electrode structures 10-050A and 10-070A are isolated by an passivation layer 10-084), such that electrical control signals can pass through electrode structures 10-050A and 10-070A outside light-emitting regions 10-000A and 10-000B, respectively, to individually control the light emission states of light-emitting regions 10-000A and 10-000B. Similarly, a thermal conductive structure TP10 is disposed on the passivation layer 10-084 and covers all the epitaxial columnar structures P10, so as to conduct and dissipate heat generated by each light-emitting region.

In the cross-sectional view as shown in FIG. 10E, epitaxial columnar structures P1023 and P1024 of light-emitting region 10-000B and epitaxial columnar structures P1031 and P1032 of light-emitting region 10-000C are disposed on the same mesa structure 10-326. As shown in the FIG. 10E, the electrode structures 10-080A and 10-080B, disposed outside the light-emitting regions 10-000B and 10-000C, respectively, are not electrically connected to each other, so that the light emission states of light-emitting regions 10-000B and 10-000C can be individually and independently controlled. Similarly, the thermal conductive structure TP10 is disposed on the passivation layer 10-084 for conducting and dissipating heat generated by the light-emitting regions. As shown in FIG. 10E, a gap 10-040B is formed in the metal connection layer 10-040 on the mesa structure 10-226 to separate the metal connection layer 10-040 into separated portions 10-040a and 10-040b, that is, a trench structure is formed between portions 10-040a and 10-040b, and a portion of the surface of the insulation layer 10-090 is exposed.

Referring again to FIGS. 10A to 10E, in this embodiment, each of electrode structures 10-050A, 10-060A, 10-070A, 10-080A, and 10-080B may comprise a middle layer (e.g., middle layer 10-502A, 10-702A) and an attaching layer (e.g., attaching layer 10-504A, 10-704A).

In this embodiment, as shown in FIGS. 10A to 10E, the semiconductor light-emitting device 10-000 is a flip-chip laser device and is subsequently connected to an external carrier (such as a PCB or a drive IC) by a flip-chip bonding process.

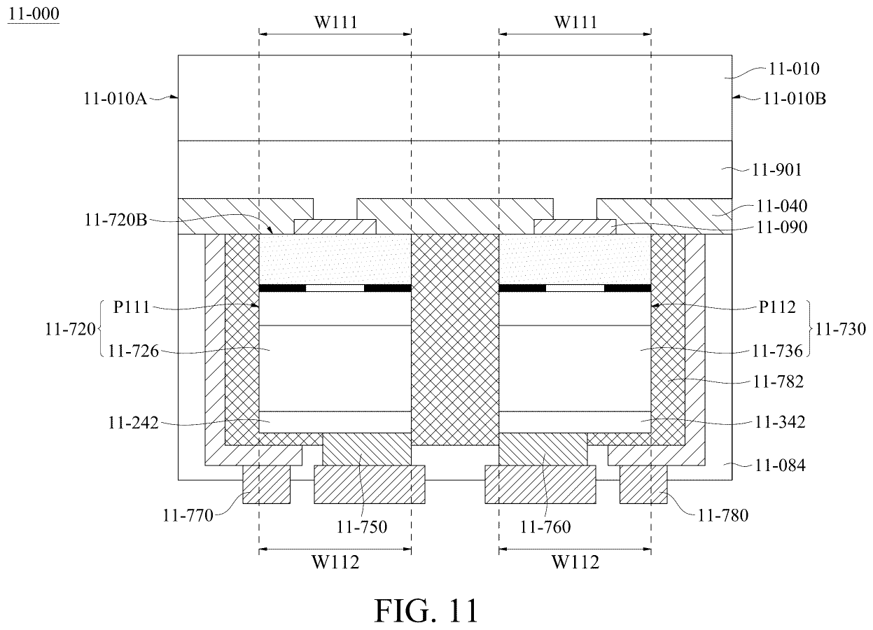

In one or more embodiments, the semiconductor device 32 shown in FIGS. 3A to 3E, 4A to 4D, 5A to 5D, and 6A to 6D may be a semiconductor light-emitting device 11-000, as illustrated in FIG. 11.

According to one or some embodiments of the disclosure, the material selection and configurations of the passivation layer may be further utilized to reduce the overall capacitance value of the semiconductor light-emitting device, thereby improving the operating efficiency of the semiconductor light-emitting device. Please refer to FIG. 11, which is a schematic cross-sectional view of a semiconductor light-emitting device 11-000 according to an embodiment.

As depicted in FIG. 11, the semiconductor light-emitting device 11-000 of this embodiment further comprises a metal connection layer 11-040 disposed between the epitaxial structure 11-720 and the substrate 11-010, and between the epitaxial structure 11-730 and the substrate 11-010. Moreover, the semiconductor light-emitting device 11-000 of this embodiment further comprises an adhesive layer 11-901, wherein the aforementioned epitaxial structures 11-720 and 11-730 are connected to the substrate 11-010 by the adhesive layer 11-901. Additionally, the semiconductor light-emitting device 11-000 of this embodiment further comprises an passivation layer 11-090 that covers the sides and a portion of the upper surfaces of the epitaxial columnar structures P111 and P112, as well as the sides and a portion of the upper surfaces of the epitaxial columnar structures P113 and P114. The passivation layer 11-090 is transparent to the light emitted from each epitaxial columnar structure P111 and P112. Furthermore, the semiconductor light-emitting device 11-000 of this embodiment comprises an passivation layer 11-084 that covers the sides and a portion of the surfaces of the electrode structures 11-770 and 11-780, as well as the sides and a portion of the surfaces of the mesa structures 11-726 and 11-736. As illustrated in FIG. 11, the semiconductor light-emitting device 11-000 of this embodiment comprise an electrode connection layer 11-242 and an electrode connection layer 11-342 disposed on the sides of the mesa structures 11-726 and 11-736 away from the substrate 11-010, respectively. The electrode connection layer 11-242 and the electrode connection layer 11-342 are electrically connected to the epitaxial structures 11-720 and 11-730, respectively.

As illustrated in the embodiment shown in FIG. 11, the electrode structures 11-770 and 11-780 in the semiconductor light-emitting device 11-000 are disposed on the outer sides of the epitaxial structures 11-720 and 11-730, respectively. In other words, in this embodiment, the electrode structure 11-770 is disposed on the side of the epitaxial structure 11-720 which is closer to the side 11-010A of the substrate 11-010, and the electrode structure 11-780 is disposed on the side of the epitaxial structure 11-730 which is closer to the side 11-010B of the substrate 11-010. In this embodiment, the electrode structures 11-770 and 11-780 are disposed on the outer sides of the electrode structures 11-750 and 11-760, respectively, as shown in FIG. 11. In addition, each of the electrode structures 11-750 and 11-760 comprises a middle layer and an attaching layer. In this embodiment, as shown in FIG. 11, the semiconductor light-emitting device 11-000 is a flip-chip laser device and is subsequently connected to an external carrier (such as a PCB or a drive IC) by a flip-chip bonding process.

In the embodiment shown in FIG. 11, each of the epitaxial columnar structures P111 and P112 has a width W111, and each of the mesa structures 11-726 and 11-736 has a width W112. In some embodiments, the width WI11 is less than the width W112; in other words, in some embodiments, the mesa structures 11-726 and 11-736 are formed to protrude outwardly from the epitaxial columnar structures P111, P112, forming a two-staged elevated structure with the epitaxial columnar structures P111, P112.

Alternatively, in the embodiment shown in FIG. 11, the widths W112 of the mesa structures 11-726, 11-736 of the semiconductor light-emitting device 11-000 may be equal to or close to the widths W111 of the epitaxial columnar structures P111, P112; that is, in this embodiment, the width W112 is equal to the width W111. In other words, in this embodiment, the mesa structures 11-726 and 11-736 and the epitaxial columnar structures P111 and P112 are formed as the same stage of the elevated structure, so that the epitaxial structures 11-720 and 11-730 do not have a two-staged elevated structure.

In the embodiment shown in FIG. 11, since each of the epitaxial structures 11-720 and 11-730 is formed as an elevated structure and its electrode structures 11-770 and 11-780 are disposed on the outer sides of the epitaxial structures 11-720 and 11-730, respectively. The aspect ratio of the spacing between the epitaxial structures 11-720 and 11-730 is higher than that of a conventional semiconductor light-emitting device. Therefore, in one or some embodiments of the disclosure, gluing materials with low dielectric constant (low-k) (for example, spin-on-glass (SOG) gluing materials) are adopted as the insulating material for the passivation layer 11-782 in the semiconductor light-emitting device 11-000.

Hence, the gluing materials not only may easily fill into the spacing region between the epitaxial structures 11-720 and 11-730 but also enable the epitaxial structures 11-720, 11-730 and the passivation layer 11-782 therebetween to form a co-planarized surface 11-720B, so as to planarize the entire device surface, which is beneficial for the distribution of the metal layer to reduce resistance. Moreover, the gluing materials may also serve as a buffer layer during a subsequent die attach process to protect the chip. Further, since the gluing materials are used, the thickness of the semiconductor light-emitting device 11-000 is increased, which may further reduce the overall capacitance of the semiconductor light-emitting device 11-000.

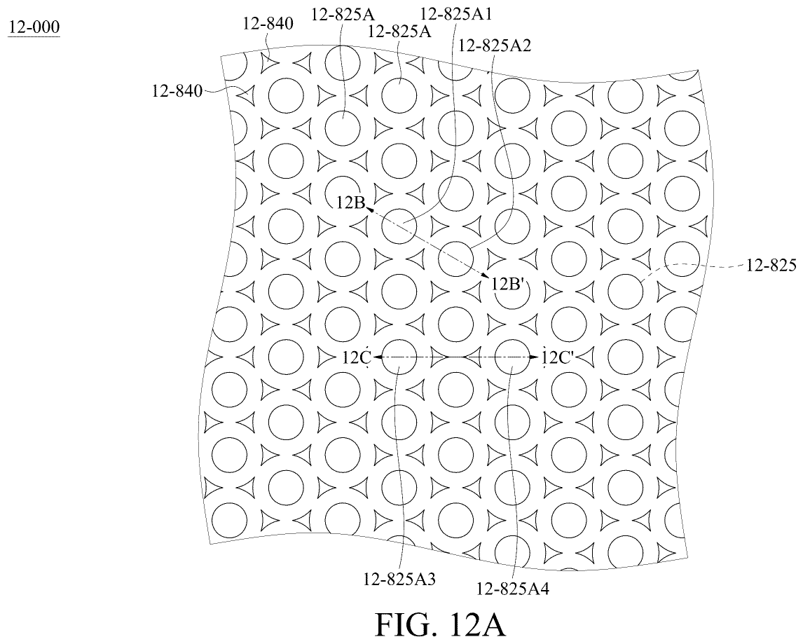

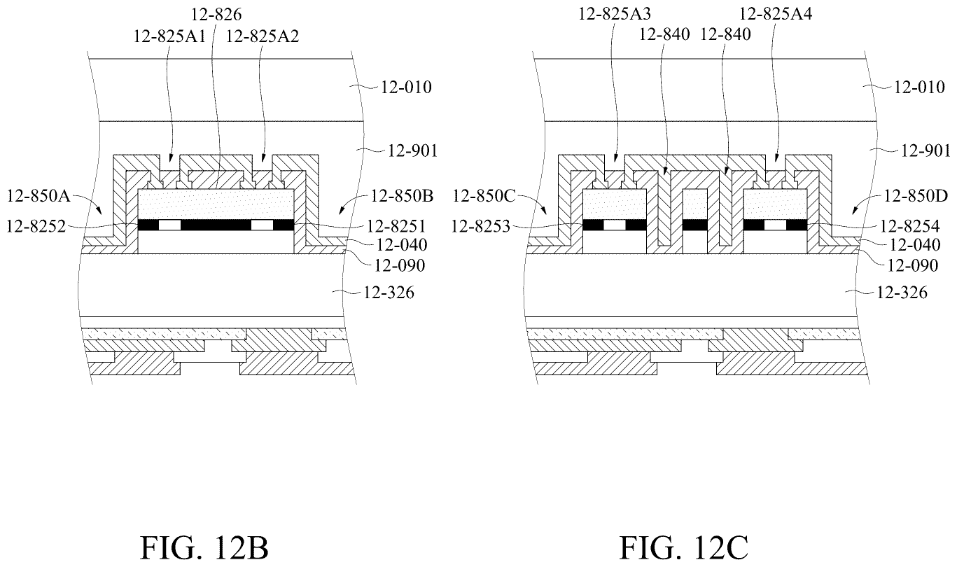

In one or more embodiments, the semiconductor element 32 illustrated in FIGS. 3A to 3E, 4A to 4D, 5A to 5D, and 6A to 6D may be a semiconductor light-emitting device 12-000, as shown in FIGS. 12A to 12C. FIG. 12A illustrates a schematic top perspective view of the semiconductor light-emitting device 12-000 according to an embodiment. FIGS. 12B and 12C illustrate schematic cross-sectional views along the lines 12B-12B′ and 12C-12C′ shown in FIG. 12A, respectively. In this embodiment, as shown in FIGS. 12B and 12C, the semiconductor light-emitting device 12-000 is a flip-chip laser device and is subsequently connected to an external carrier (such as a PCB or a drive IC) by a flip-chip bonding process.

Please refer to the embodiment shown in FIGS. 12A to 12C, which illustrate a schematic top perspective view and cross-sectional views of the semiconductor light-emitting device 12-000 according to another exemplary embodiment, wherein FIG. 12A illustrates a schematic top perspective view of the semiconductor light-emitting device 12-000, and FIGS. 12B and 12C illustrate cross-sectional views along the lines 12B-12B′ and 12C-12C′ shown in FIG. 12A, respectively.

According to one or more embodiments of the present disclosure, when forming the light-emitting apertures of the semiconductor light-emitting device, the structural configurations of the light-emitting region may be adjusted to change the positions and number of the light-emitting apertures, so as to further increase the density of the light-emitting apertures in the light-emitting region and the flexibility of address control. The light-emitting apertures may be formed by, for example, a wet oxidation process.

As shown in the embodiment of FIG. 12A, the semiconductor light-emitting device 12-000 comprises a plurality of light-emitting apertures 12-825A, such as openings 12-825A1, 12-825A2, 12-825A3, and 12-825A4 shown in FIGS. 12B and 12C, and these light-emitting apertures 12-825A are arranged in an array. In the top view shown in FIG. 12A, the multiple openings (light-emitting apertures) 12-825A in the semiconductor light-emitting device 12-000 are arranged in a closest packing arrangement. For example, the multiple light-emitting apertures 12-825A are arranged in a hexagonal closest packing arrangement; that is, in this embodiment, each light-emitting aperture 12-825A is surrounded by six adjacent light-emitting apertures 12-825A, and each light-emitting apertures 12-825A is surrounded by six recessed structures 12-840. Wherein the recessed structures 12-840 are used for performing an oxidation process to form current restriction regions in each of the current confinement layer 12-825 in the semiconductor light-emitting device 12-000, but the disclosure is not limited thereto. Wherein the current confinement layer 12-825 comprises a current confinement layer 12-8251, a current confinement layer 12-8252, a current confinement layer 12-8253 and a current confinement layer 12-8254. In this way, six uniformly distributed recessed structures 12-840 (that is, a configuration with a spacing of 60 degrees around) are formed in the epitaxial structure surrounding each light-emitting aperture. Therefore, by performing the wet oxidation process through the six recessed structures 12-840, substantially circular openings (that is, the light-emitting apertures of the semiconductor light-emitting device) can be formed in the epitaxial structure of the semiconductor light-emitting device. According to one or more embodiments of the present disclosure, each recessed structure is shared by adjacent light-emitting apertures, allowing the multiple light-emitting apertures in the semiconductor light-emitting device of the present disclosure to be arranged in the closest packing arrangement, thereby increasing the layout space for the light-emitting aperture structure in the semiconductor light-emitting device.

As shown in FIG. 12B, in the cross-sectional view along the line 12B-12B′ in FIG. 12A, there is no recessed structure between the openings (i.e., the light-emitting apertures) 12-825A1 and 12-825A2; that is, in the cross-sectional view along the line 12B-12B′, the current restriction regions of the current confinement layers 12-8252 and 12-8251 are formed by the outer walls of the recessed structures 12-850A and 12-850B on two sides of the same mesa structure 12-826 through the wet oxidation process, such that the openings (i.e., the light-emitting apertures) 12-825A1 and 12-825A2 are disposed on the same mesa structure 12-826. Moreover, as shown in FIG. 12C, in the cross-sectional view along the line 12C-12C′ in FIG. 12A, in addition to the outer recessed structures 12-850C and 12-850D, two recessed structures 12-840 are further formed between the opening 12-825A3 and its adjacent opening 12-825A4; that is, in the cross-sectional view along the line 12C-12C′, the outer wall of the recessed structure 12-850C and the sidewall of the recessed structure 12-840 form the current restriction region in the current confinement layer 12-8253 through the wet oxidation process to define the opening 12-825A3, while the sidewall of the recessed structure 12-840 and the outer wall of the recessed structure 12-850D form the current confinement layer 12-8254 through the wet oxidation process to define the opening 12-825A4. In an embodiment, two adjacent openings may share the recessed structure between them, or there may be only one recessed structure between two adjacent openings that is shared by both. Thus, according to one or more embodiments of the disclosure, the distance between two adjacent openings can be further reduced, allowing the light-emitting apertures of the semiconductor light-emitting device to be arranged more densely.

As shown in FIGS. 12B and 12C, the semiconductor light-emitting device 12-000 of this embodiment further comprises a metal connection layer 12-040 disposed between the mesa structure 12-326 and the substrate 12-010. As depicted in FIGS. 12B and 12C, the semiconductor light-emitting device 12-000 of this embodiment also comprises an adhesive layer 12-901, through which the aforementioned mesa structure 12-326 is connected to the substrate 12-010. As illustrated in FIGS. 12B and 12C, the semiconductor light-emitting device 12-000 of this embodiment additionally includes a passivation layer 12-090 covering the sidewalls and the top surface of the epitaxial structure, wherein the passivation layer 12-090 is transparent to the light emitted from each epitaxial structure.

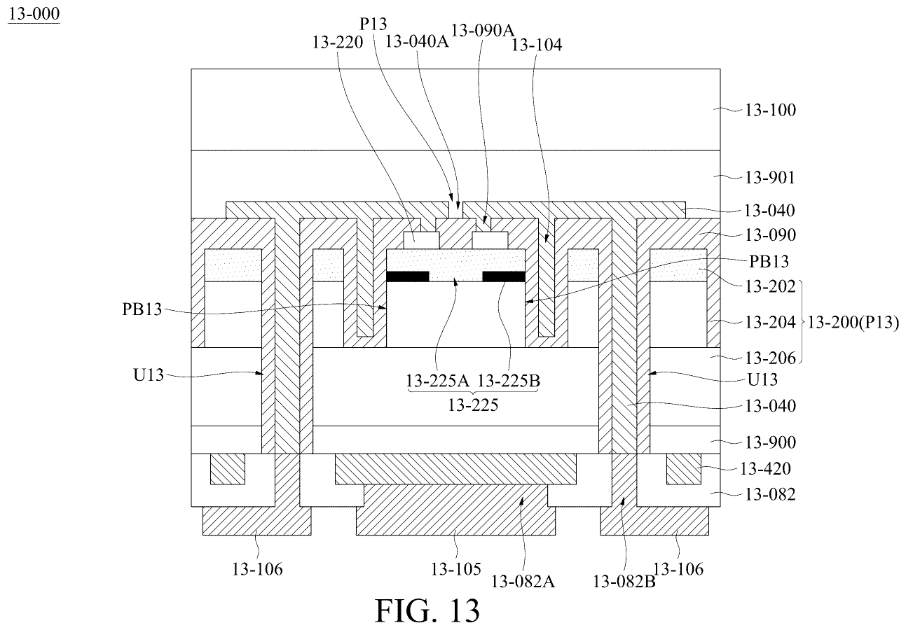

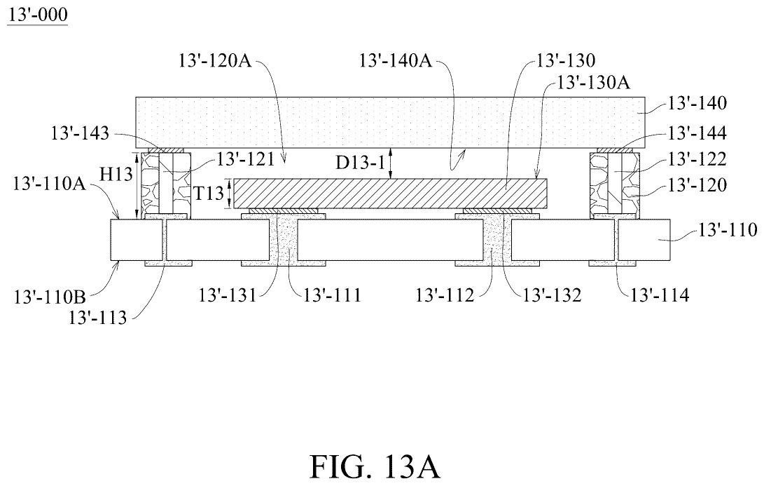

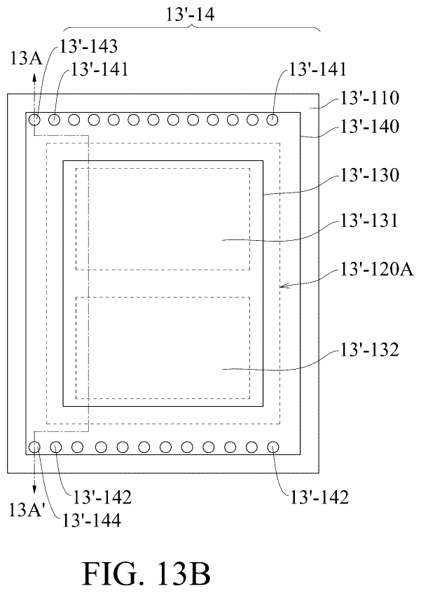

In one or more embodiments, the semiconductor element 32 shown in FIGS. 3A to 3E, 4A to 4D, 5A to 5D, and 6A to 6D can be a semiconductor light-emitting device 13-000, as shown in FIG. 13. FIG. 13 is a schematic cross-sectional view of a semiconductor light-emitting device according to an embodiment. In this embodiment, a semiconductor light-emitting device 13-000 is provided. The semiconductor light-emitting device 13-000 comprises a semiconductor stack layer 13-200 formed on a growth substrate 13-900. The semiconductor stack layer 13-200 sequentially comprises a semiconductor layer 13-206, an active layer 13-204, and a semiconductor layer 13-202 on the growth substrate 13-900. Then, a corresponding contact structure 13-220 is formed on a portion of the semiconductor light-emitting device 13-000 on which an epitaxial columnar structure P13 is to be correspondingly formed. Subsequently, a passivation layer 13-090 is formed on the contact structure 13-220 and the semiconductor stack layer 13-200 as a protective layer. Next, an etching process is performed to form a through-hole U13 to expose an end surface of the growth substrate 13-900, wherein the shape of the through-hole is not limited; in other words, the shape of the through-hole can be an arc-shaped columnar hole, a polygonal columnar hole, or a columnar hole of any shape. Then, an etching process is further performed to form the epitaxial columnar structure P13 and a recessed structure 13-104 to expose a portion of an end surface of the semiconductor layer 13-206, and the epitaxial columnar structure P13 has a side surface PB13.

Next, a current confinement layer is formed in the epitaxial columnar structure P13 by a wet oxidation process. In this embodiment, the current confinement layer 13-225 is formed between the semiconductor layer 13-202 and the active layer 13-204, and the current confinement layer 13-225 comprises a current restriction region 13-225B and a current conduction region 13-225A surrounded by the current restriction region 13-225B. The passivation layer 13-090 is formed in the through-hole U13 and the recessed structure 13-104 and covers the side surface PB13 of the epitaxial columnar structure P13, the end face of the semiconductor layer 13-206, and the end face of the growth substrate 13-900. Then, passivation openings 13-090A are formed in the passivation layer 13-090 to expose a partial surface of the contact structure 13-220, wherein the top view shape of the passivation opening 13-090A may be, for example, a ring shape, a circle shape, an ellipse shape, a square shape, an irregular shape, or the like. In this embodiment, the passivation opening 13-090A is ring-shaped in a top view, but is not limited thereto.

Next, a metal connection layer 13-040 is formed on the passivation layer 13-090. The metal connection layer 13-040 is electrically connected to the semiconductor layer 13-202 by covering the passivation layer 13-090 and being filled in the passivation opening 13-090A to be connected to the contact structure 13-220. The metal connection layer 13-040 has a connection opening 13-040A above the epitaxial columnar structure P13. The position of the connection opening 13-040A corresponds to the position of the current conduction region 13-225A, and the underlying passivation layer 13-090 is exposed. Subsequently, the epitaxial columnar structure P13 and the semiconductor layer 13-206 are bonded to the substrate 13-100 by an adhesive layer 13-901. The substrate 13-100 is a permanent substrate in this embodiment.

Then, part of the growth substrate 13-900 is removed to expose portions of the surface of the metal connection layer 13-040 and the passivation layer 13-090. In this embodiment, the growth substrate 13-900 is, for example, a GaAs substrate. Subsequently, an electrode connection layer 13-420 is formed on the growth substrate 13-900. Then, a passivation layer 13-082 is formed to cover a part of the electrode connection layer 13-420. The passivation layer 13-082 comprises a plurality of openings 13-082A and 13-082B to expose at least a part of the electrode connection layer 13-420 and the metal connection layer 13-040, respectively.

Finally, conductive materials are filled in the openings 13-082A and 13-082B to form an electrode structure 13-105 and an electrode structure 13-106 of the semiconductor light-emitting device, respectively, as shown in FIG. 13.

Please refer to FIGS. 13A and 13B, which are a schematic cross-sectional view and a schematic top view of a chip package structure according to an embodiment of the present disclosure, respectively, wherein FIG. 13A illustrates a schematic structure along the line 13A-13A′ shown in FIG. 13B. As shown in FIG. 13A, a package structure 13′-000 comprises a substrate 13′-110 and a housing 13′-120 disposed on a first surface 13′-110A of the substrate 13′-110. The substrate 13′-110 is adapted to support the package structure 13′-000, and comprises a plurality of electrical conduction posts 13′-111, 13′-112, 13′-113, 13′-114 penetrating therethrough and extending to a second surface 13′-110B of the substrate 13′-110 so as to provide electrical conduction from the package structure 13′-000 to the exterior. The housing 13′-120 is disposed on the first surface 13′-110A of the substrate 13′-110, and encloses a chip region 13′-120A on the first surface 13′-110A of the substrate 13′-110. The package structure 13′-000 comprises a chip set disposed in the chip region 13′-120A and electrically connected to the substrate 13′-110. The chip set comprises a first chip 13′-130 and a second chip 13′-140 opposite to each other, and an active surface 13′-140A of the second chip 13′-140 faces an active surface 13′-130A of the first chip 13′-130.

In this embodiment, the housing 13′-120 is a conductive housing, which comprises a first electrical conduction structure 13′-121 and a second electrical conduction structure 13′-122 penetrating therethrough, and surrounds the first chip 13′-130 disposed on the first surface 13′-110A; wherein a height H13 of the housing 13′-120 is greater than a thickness T13 of the first chip 13′-130, the second chip 13′-140 is disposed on the housing 13′-120 and electrically connected to the substrate 13′-110 through the first electrical conduction structure 13′-121 and the second electrical conduction structure 13′-122. More specifically, as described above, the substrate 13′-110 comprises electrical conduction posts 13′-111, 13′-112, 13′-113, and 13′-114 penetrating therethrough and extending to the second surface 13′-110B of the substrate 13′-110, wherein the electrical conduction posts 13′-111 and 13′-112 are connected to a first conductive structure 13′-131 and a second conductive structure 13′-132 of the first chip 13′-130, respectively, so that the first chip 13′-130 is electrically connected to an external circuit (not shown) of the package structure 13′-000, while the electrical conduction posts 13′-113 and 13′-114 are connected to the first electrical conduction structure 13′-121 and the second electrical conduction structure 13′-122 in the housing 13′-120, respectively, so that the second chip 13′-140 disposed on the housing 13′-120 is electrically connected to the external circuit of the package structure 13′-000 through the first electrical conduction structure 13′-121, the second electrical conduction structure 13′-122, and the electrical conduction posts 13′-113 and 13′-114.

Please also refer to FIG. 13B, the second chip 13′-140 further comprises a connection layer 13′-14. The connection layer 13′-14 comprises a plurality of first alignment connection structures 13′-141, a plurality of second alignment connection structures 13′-142, a first conductive connection structure 13′-143, and a second conductive connection structure 13′-144. The second chip 13′-140 is connected to the first and second electrical conduction structures 13′-121 and 13′-122 of the housing 13′-120 through its first and second conductive connection structures 13′-143 and 13′-144, respectively. The first and second electrical conduction structures 13′-121 and 13′-122 are further connected to the second electrical conduction posts 13′-113 and 13′-114 of the substrate 13′-110, respectively, thereby forming electrical connection of the second chip 13′-140 to the external circuit of the package structure 13′-000. The first and second alignment connection structures 13′-141 and 13′-142 of the connection layer 13′-14 are not electrical connected. The first and second alignment connection structures 13′-141 and 13′-142 are aligned with the first conductive connection structure 13′-143 and the second conductive connection structure 13′-144, respectively, for positioning the second chip 13′-140 in the package structure 13′-000. The configuration of first and second alignment connection structures 13′-141 and 13′-142 are asymmetrical, so that the gripping forces generated by the alignment connection structures on both sides of the chip are different, thereby to prevent the chip shifting during alignment procedure. The asymmetrical configuration may comprise, but is not limited to, different numbers of the first alignment connection structures 13′-141 and the second alignment connection structures 13′-142, and/or different relative positions thereof (for example, the distance between two adjacent first alignment connection structures 13′-141 is different from the distance between two adjacent second alignment connection structures 13′-142).

In this embodiment, the first chip 13′-130 is a light-emitting chip, such as a light-emitting diode (LED) or a laser diode, and an active surface of the light-emitting chip is a light-emitting surface; the second chip 13′-140 is a light-receiving chip, such as a photovoltaic (PV) chip or a photodiode chip, and an active surface of the light-receiving chip is a light-receiving surface or a photosensitive surface. In this embodiment, the first chip 13′-130 may be a vertical cavity surface emitting laser (VCSEL) chip or a flip-chip laser diode. However, the present disclosure is not limited thereto. In other embodiments, the first chip is a light-receiving chip, and the second chip is a light-emitting chip.

In this embodiment, the active surface 13′-130A (light-emitting surface) of the first chip 13′-130 faces the active surface 13′-140A (light-receiving surface) of the second chip 13′-140. The active surface 13′-140A (light-receiving surface) of the second chip 13′-140 receives the light emitted from the first chip 13′-130, and the area of the active surface 13′-140A (light-receiving surface) is larger than the area of the active surface 13′-130A (light-emitting surface) of the first chip 13′-130. In this embodiment, the active surface 13′-130A (light-emitting surface) of the first chip 13′-130 and the active surface 13′-140A (light-receiving surface) of the second chip 13′-140 are spaced apart from each other by a distance D13-1. The magnitude of the distance D13-1 is determined by the application of the package structure, and/or the photoelectric characteristics of the first chip 13′-130 and the second chip 13′-140. In this embodiment, the distance D13-1 between the active surface 13′-130A (light-emitting surface) of the first chip 13′-130 and the active surface 13′-140A (light-receiving surface) of the second chip 13′-140 ranges from 1 micrometer (μm) and 30 micrometers.

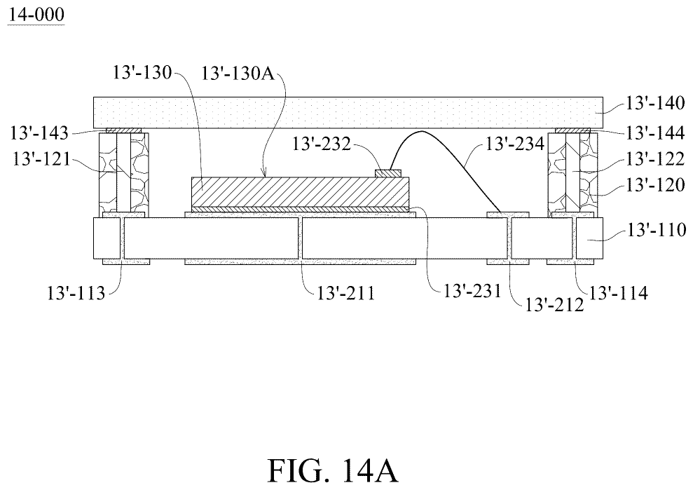

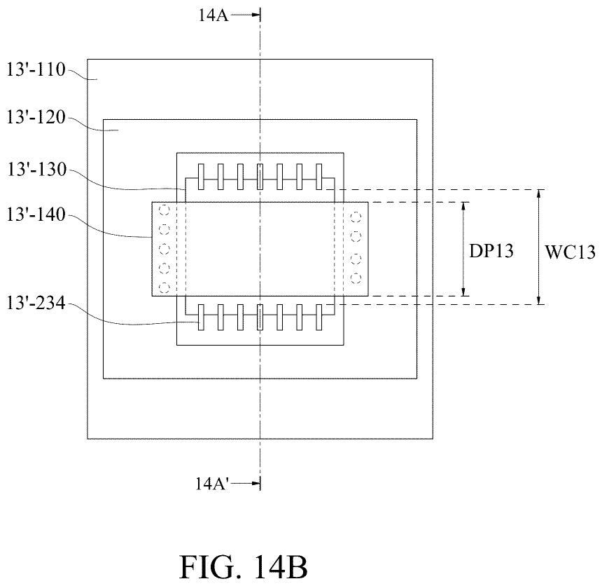

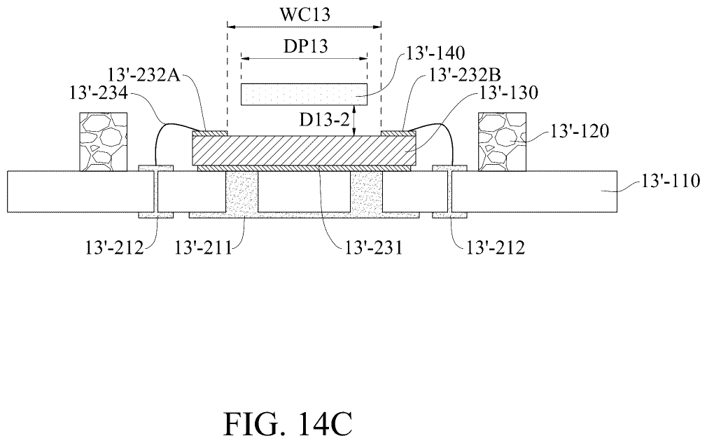

Please refer to FIG. 14A, which illustrates a cross-sectional view of a chip package structure according to another embodiment of the present disclosure. As shown in FIG. 14A, the package structure 14-000 has a configuration and structure similar to that of the package structure 13′-000 in FIG. 13A; however, the difference lies in that, in the package structure 14-000, the first chip 13′-130 is a vertical chip, i.e., the first conductive structure 13′-231 and the second conductive structure 13′-232 are disposed on opposite surfaces of the first chip 13′-130, respectively; wherein the first conductive structure 13′-231 is connected to the first electrical conduction post 13′-211, and the second conductive structure 13′-232 disposed on the active surface 13′-130A (light-emitting surface) of the first chip 13′-130 is connected to the first electrical conduction post 13′-212 via a connecting wire 13′-234. In this embodiment, the first chip 13′-130 is electrically connected to the substrate 13′-110 through the connection between the first conductive structure 13′-231 and the first electrical conduction post 13′-211, and the connection between the second conductive structure 13′-232 and the first electrical conduction post 13′-212 via the connecting wire 13′-234, thereby providing electrical conduction to the exterior of the package structure 14-000.

Please refer to FIGS. 14B and 14C, which are a schematic top view and a schematic cross-sectional view of a chip package structure according to one embodiment of the present disclosure, respectively, wherein FIG. 14C illustrates a schematic cross-sectional structure along the line 14A-14A′ in FIG. 14B. As shown in FIG. 14C, the first chip 13′-130 is a vertical chip, i.e., the first conductive structure 13′-231 and the second conductive structures 13′-232A, 13′-232B are disposed on opposite surfaces of the first chip 13′-130, respectively, wherein the second conductive structures 13′-232A, 13′-232B are disposed on two sides of the active surface 13′-130A of the first chip 13′-130, respectively. In this embodiment, the second conductive structures 13′-232A, 13′-232B on the first chip 13′-130 have different orientation arrangement from the first conductive connection structure 13′-143 and the second conductive connection structure 13′-144 on the second chip 13′-140, thereby avoiding the height of the metal wire (i.e., the connecting wire 13′-234) required for the first chip 13′-130 from limiting the distance D13-2 between the first chip 13′-130 and the second chip 13′-140.

Preferably, referring again to FIG. 14C, there exists a distance DP13 between the second conductive structure 13′-232A and the second conductive structure 13′-232B on two sides of the first chip 13′-130, and the second chip 13′-140 has a width WC13. The distance DP13 being greater than the width WC13, thereby also avoiding the height of the metal wire (i.e., the connecting wire 13′-234) required for the first chip 13′-130 from limiting the distance D13-2 between the first chip 13′-130 and the second chip 13′-140, and preventing the connecting wire 13′-234 from accidentally contacting the second chip 13′-140, but the disclosure is not limited thereto.

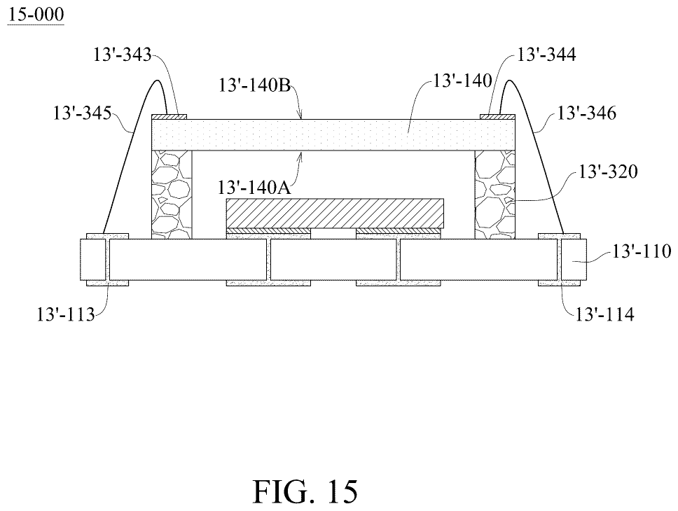

Please refer to FIG. 15, which illustrates a cross-sectional side view of a chip package structure according to another embodiment of the present disclosure. As shown in FIG. 15, the package structure 15-000 has a configuration and structure similar to that of the package structure 13′-000 in FIG. 13A; however, the difference lies in that, in the package structure 15-000, the housing 13′-320 is not a conductive housing (i.e., no electrical conduction structure penetrating therethrough is formed in the housing), but is simply used for supporting the entire device. In this embodiment, the second chip 13′-140 is a horizontal chip, i.e., its conductive connection structures are disposed on the same side of the chip. As shown in FIG. 15, the first conductive connection structure 13′-343 and the second conductive connection structure 13′-344 are both disposed on the opposite surface 13′-140B of the active surface 13′-140A (light-receiving surface) of the second chip 13′-140, and are electrically connected to the electrical conduction posts 13′-113, 13′-114 of the substrate 13′-110 via wires 13′-345, 13′-346, respectively. In other words, in this embodiment, the second chip 13′-140 is electrically connected to the substrate 13′-110 through the connections of the wires 13′-345, 13′-346 between the first conductive connection structure 13′-343 and the electrical conduction post 13′-113, and between the second conductive connection structure 13′-344 and the electrical conduction post 13′-114, respectively, thereby providing electrical conduction to the exterior of the package structure 15-000.

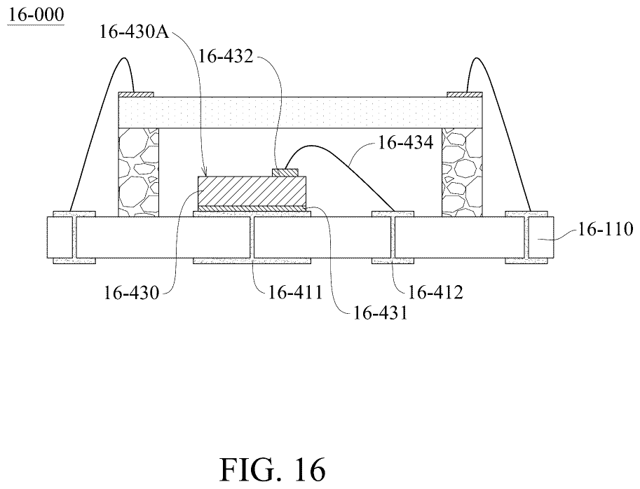

Please refer to FIG. 16, which illustrates a cross-sectional view of a chip package structure according to yet another exemplary embodiment of the present disclosure. As shown in FIG. 16, the package structure 16-000 has a configuration and structure similar to that of the package structure 15-000 in FIG. 15; however, the difference lies in that, in the package structure 16-000, the first conductive structure 16-431 and the second conductive structure 16-432 are disposed on opposite surfaces of the first chip 16-430, respectively. The first conductive structure 16-431 is connected to the first electrical conduction post 16-411, and the second conductive structure 16-432 disposed on the light-emitting surface 16-430A of the first chip 16-430 is connected to the first electrical conduction post 16-412 via a connecting wire 16-434. Similar to the exemplary embodiment shown in FIG. 14A, the first chip 16-430 of the package structure 16-000 is a vertical chip, which is electrically connected to the substrate 16-110 through the connection between the first conductive structure 16-431 and the first electrical conduction post 16-411, and the connection between the second conductive structure 16-432 and the first electrical conduction post 16-412 via the connecting wire 16-434, thereby providing electrical conduction to the exterior of the package structure 16-000.

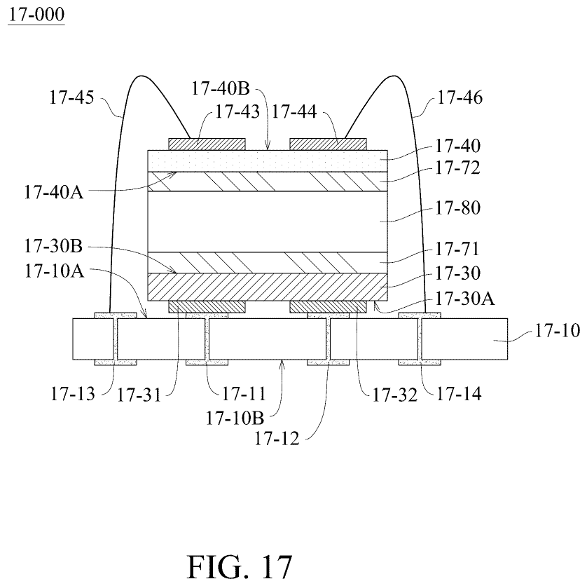

Please refer to FIG. 17, which illustrates a schematic cross-sectional view of a chip package structure according to another exemplary embodiment of the present disclosure. In this exemplary embodiment, the package structure 17-000 is a wafer-level packaging optoelectronic converter; that is, in this embodiment, the first chip 17-30 and the second chip 17-40 of the package structure 17-000 are combined using a wafer-to-wafer bonding process. In some embodiments, the optoelectronic converter includes an optical transformer, wherein the optoelectronic converter can utilize the principle of optoelectronic conversion to convert the input voltage into a different output voltage. For example, the electrical signal is first converted into an optical signal by the first chip, and then the optical signal is converted back into an electrical signal with a different voltage magnitude or a different current magnitude by the second chip.

As shown in FIG. 17, in this exemplary embodiment, the package structure 17-000 comprises a substrate 17-10 having a first surface 17-10A and a second surface 17-10B being opposite surfaces of the substrate 17-10. The package structure 17-000 further comprises at least two first electrical conduction posts 17-11, 17-12 and at least two second electrical conduction posts 17-13, 17-14 penetrating the substrate 17-10. The package structure 17-000 also comprises a chip set disposed on the first surface 17-10A of the substrate 17-10, wherein the chip set includes a first chip 17-30 and a second chip 17-40 opposite to each other. In this exemplary embodiment, the first chip 17-30 and the second chip 17-40 are connected to a light-transmissive middle layer 17-80 through a first bonding layer 17-71 and a second bonding layer 17-72, respectively. The light-receiving surface of the second chip 17-40 faces the light-emitting surface of the first chip 17-30 to receive light emitted by the first chip 17-30. In this exemplary embodiment, the first electrical conduction posts 17-11, 17-12 can connect the first chip 17-30 to the exterior of the optoelectronic converter (the package structure 17-000), and the second electrical conduction posts 17-13, 17-14 can connect the second chip 17-40 to the exterior of the optoelectronic converter (the package structure 17-000).

Specifically, in this exemplary embodiment, the first chip 17-30 comprises a third surface 17-30A facing the first surface 17-10A and a fourth surface 17-30B facing away from the first surface 17-10A, wherein the third surface 17-30A and the fourth surface 17-30B are opposite surfaces of the first chip 17-30. The second chip 17-40 comprises a fifth surface 17-40A facing the fourth surface 17-30B and a sixth surface 17-40B facing away from the fourth surface 17-30B, wherein the fifth surface 17-40A and the sixth surface 17-40B are opposite surfaces of the second chip 17-40. The fourth surface 17-30B is the light-emitting surface of the first chip 17-30, and the fifth surface 17-40A is the light-receiving surface of the second chip 17-40. In this exemplary embodiment, the package structure 17-000 further comprises a first conduction structure 17-31 and a second conduction structure 17-32 disposed on the third surface 17-30A of the first chip 17-30 and connected to the first electrical conduction posts 17-11, 17-12, respectively, so that the first chip 17-30 is electrically connected to the substrate 17-10 through the first electrical conduction posts 17-11, 17-12. As a result, the first chip 17-30 can be electrically connected to the exterior of the optoelectronic converter (the package structure 17-000). The package structure 17-000 further comprises a first conductive connection structure 17-43 and a second conductive connection structure 17-44 are disposed on the sixth surface 17-40B and connected to the second electrical conduction posts 17-13, 17-14 through a first connection wire 17-45 and a second connection wire 17-46, respectively, so that the second chip 17-40 is electrically connected to the substrate 17-10 through the second electrical conduction posts 17-13, 17-14. As a result, the second chip 17-40 can be connected to the exterior of the optoelectronic converter (the package structure 17-000).

In this exemplary embodiment, the first bonding layer 17-71, the second bonding layer 17-72, and/or the light-transmissive middle layer 17-80 of the package structure 17-000 may be made of electrically insulating material(s). Compared with the package structure 13′-000 shown in FIG. 13A, by utilizing the wafer-to-wafer bonding process for packaging, the distance between the first chip 17-30 and the second chip 17-40 can be further reduced, thereby reducing the overall volume of the package structure 17-000, which is advantageous for applications in small-sized devices.

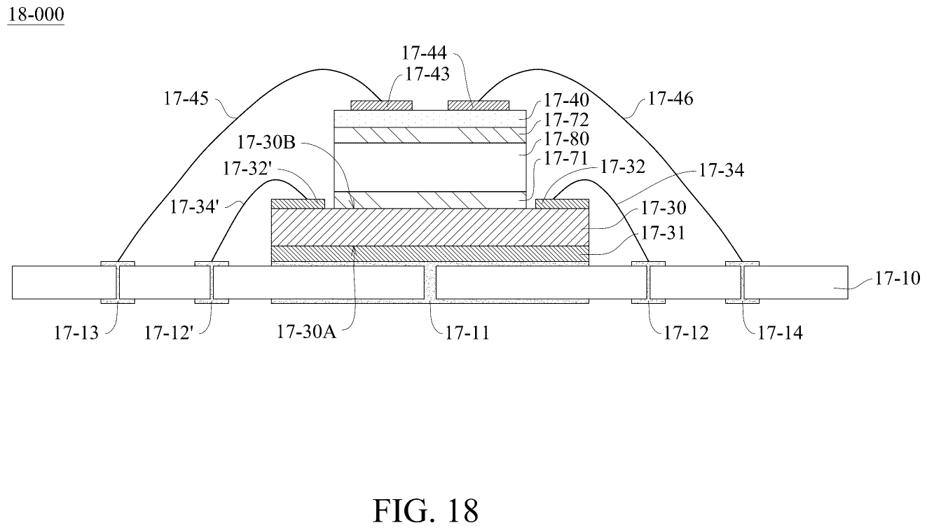

Please refer to FIG. 18, which illustrates a schematic cross-sectional view of a chip package structure according to another exemplary embodiment of the present disclosure. As shown in FIG. 18, the chip package structure 18-000 has a configuration and structure similar to those of the package structure 17-000 shown in FIG. 17, and is also a wafer-level packaging optoelectronic converter; however, the difference lies in that, in the package structure 18-000, the first chip 17-30 is a vertical chip rather than the flip chip in the package structure 17-000, and the width of the first chip 17-30 is greater than the width of the second chip 17-40.

More specifically, in the present embodiment, the package structure 18-000 includes a first conductive structure 17-31 and second conductive structures 17-32, 17-32′ disposed on a third surface 17-30A and a fourth surface 17-30B of a first chip 17-30, respectively. The first conductive structure 17-31 is electrically connected to a first electrical conduction post 17-11, and the second conductive structures 17-32, 17-32′ are electrically connected to first electrical conduction posts 17-12, 17-12′ through corresponding wires 17-34, 17-34′, respectively. This arrangement allows the first chip 17-30 to be electrically connected to a substrate 17-10, thereby enabling electrical connection between the first chip 17-30 and the exterior of the photoelectric converter (i.e., the package structure 18-000). The electrical connection between the second chip 17-40 and the exterior of the photoelectric converter (i.e., the package structure 18-000) is established in the same manner as described in the embodiment of FIG. 17.

In this embodiment, during the fabrication of the packaging structure, multiple second chips are bonded to a first wafer (not shown in the figure) having multiple first chips formed by cutting a light-emitting layer, and then the first wafer is cut. A first conduction structure and a second conduction structure are then formed on the resulting structure, and the first chip is deposited on the substrate. In one embodiment, the first chip and the second chip are electrically connected to the substrate through wires to complete the chip package structure.

As previously described, the second chip is connected to the first chip through a chip-to-wafer bonding process. Similarly, the first chip can also be connected to the second chip through the chip-to-wafer bonding process. In other words, a plurality of first chips can be bonded to a second wafer having a plurality of second chips, followed by cutting the second wafer. A first conduction structure and a second conduction structure are then formed on the resulting structure and deposited and electrically connected to the substrate, thereby forming the chip package structure of the present invention, wherein the width of the second chip is greater than the width of the first chip. In one embodiment, after the packaging process is completed, the chips made from the epitaxial wafer with a higher yield (the first wafer or the second wafer) are positioned closer to the substrate.

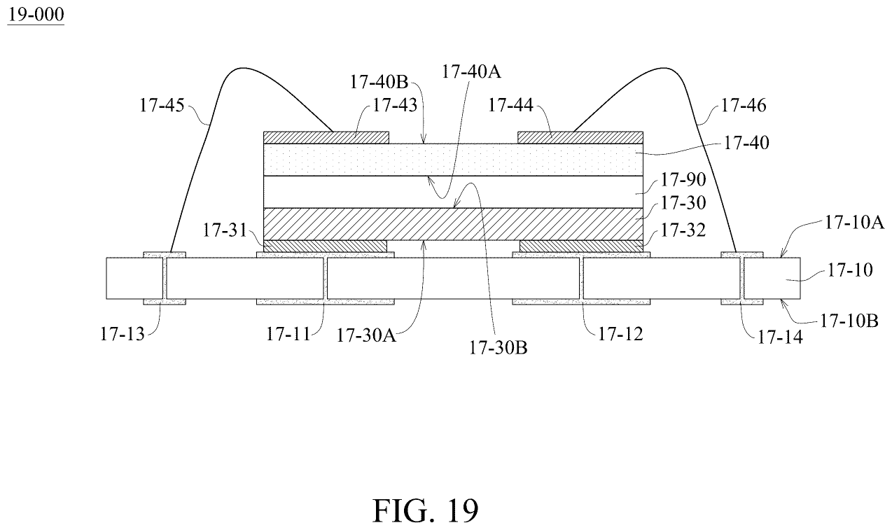

Please refer to FIG. 19, which is a schematic cross-sectional view of a chip package structure according to another embodiment of the present disclosure. In this embodiment, both the first chip 17-30 and the second chip 17-40 of the chip package structure 19-000 are horizontal chips. The difference between this embodiment and the previous embodiments lies in that, in the package structure 19-000 of this embodiment, the first chip 17-30 and the second chip 17-40 are connected to each other via a spacing layer 17-90 and are electrically insulated from each other by the spacing layer 17-90. The spacing layer 17-90 can be a light-transmissive layer, such as a light-transmissive intermediate layer, and can have a single-layer structure or a multi-layer structure, but the present disclosure is not limited thereto. In this embodiment, the electrical connection between the first chip 17-30 and the substrate 17-10, as well as the electrical connection between the second chip 17-40 and the substrate 17-10, are the same as those described in the embodiment of FIG. 17. Specifically, in the package structure 19-000 of this embodiment, the first conductive structure 17-31 and the second conductive structure 17-32 are disposed on the third surface 17-30A of the first chip 17-30 and are connected to the first electrical conduction posts 17-11, 17-12, respectively, thereby allowing the first chip 17-30 to be electrically connected to the first electrical conduction posts 17-11, 17-12 of the substrate 17-10. Consequently, the first chip 17-30 is electrically connected to the exterior of the photoelectric converter (i.e., the package structure 19-000). The first conductive connection structure 17-43 and the second conductive connection structure 17-44 are disposed on the sixth surface 17-40B and are respectively connected to the second electrical conduction posts 17-13, 17-14 through the first wire 17-45 and the second wire 17-46, thereby allowing the second chip 17-40 to be electrically connected to the second electrical conduction posts 17-13, 17-14 of the substrate 17-10. Consequently, the second chip 17-40 is electrically connected to the exterior of the photoelectric converter (i.e., the chip package structure 19-000).

In this embodiment, the spacing layer and the first chip can be sequentially grown by epitaxy on the second chip. The material of the spacing layer can be a semiconductor with low doping concentration (such as a doping concentration between 1×10¹⁵ cm-3 and 5×10¹⁶ cm-3) and high resistivity. In one embodiment, the spacing layer can be made of Al2O3 obtained by oxidizing AlGaAs.

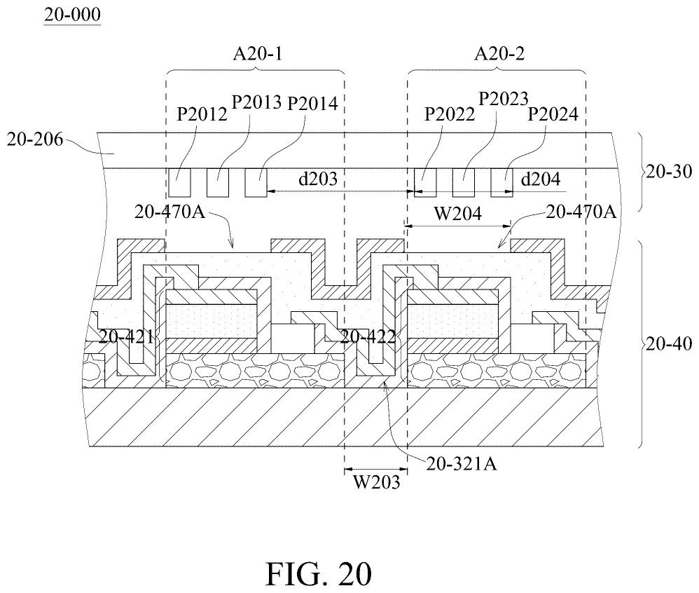

Please refer to FIG. 20, which is a schematic cross-sectional view of a partial structure of a chip package structure according to another embodiment of the present disclosure. As shown in FIG. 20, the package structure 20-000 is inverted compared to the package structure 13′-000 shown in FIG. 13A. In this embodiment, the first chip can be a VCSEL chip, and the second chip can be a PV chip. For clarity of illustration, FIG. 20 does not show most of the structures or layers of the first chip 20-30, and only illustrates the second semiconductor structure 20-206 and a plurality of columnar structures (i.e., the columnar structures P2012, P2013, P2014 in block A20-1 and the columnar structures P2022, P2023, P2024 in block A20-2, as shown in FIG. 20) of the first chip 20-30.

As illustrated in FIG. 20, the first chip 20-30 includes a plurality of columnar structures P2012, P2013, P2014, P2022, P2023, P2024 arranged above second mesa structures 20-421, 20-422 of the second chip 20-40. Specifically, in this embodiment, the columnar structures P2012, P2013, P2014 of the first chip 20-30 are aligned with the second mesa structure 20-421 of the second chip 20-40, and the columnar structures P2022, P2023, P2024 of the first chip 20-30 are aligned with the second mesa structure 20-422 of the second chip 20-40. In other words, the first chip 20-30 and the second chip 20-40 of this embodiment can be operated in a bonded configuration, with a one-to-one correspondence between the light emitting regions (where columnar structures P2012, P2013, P2014 and P2022, P2023, P2024 are disposed) of the first chip 20-30 and the light receiving regions (the second mesa structures 20-421, 20-422) of the second chip 20-40. In some embodiments, considering the space required for electrodes and wiring of the second chip 20-40, the area of the light receiving regions may be slightly smaller than the area of the light emitting regions in the chip package structure.

In this embodiment, as depicted in FIG. 20, the distance d203 between the columnar structure P2014 in block A20-1 and the columnar structure P2022 in block A20-2 is greater than the width W203 of the groove 20-321A. Moreover, the distance d204 between the leftmost columnar structure P2012 or P2022 and the rightmost columnar structure P2014 or P2024 in each block A20-1 or A20-2 is equal to or less than the width W204 of the sixth opening 20-470A in the electrode layer. In other words, all the light emitted by the columnar structures P2012, P2013, P2014, P2022, P2023, P2024 in blocks A20-1, A20-2 of the first chip 20-30 can be fully received by the second mesa structures 20-421, 20-422.

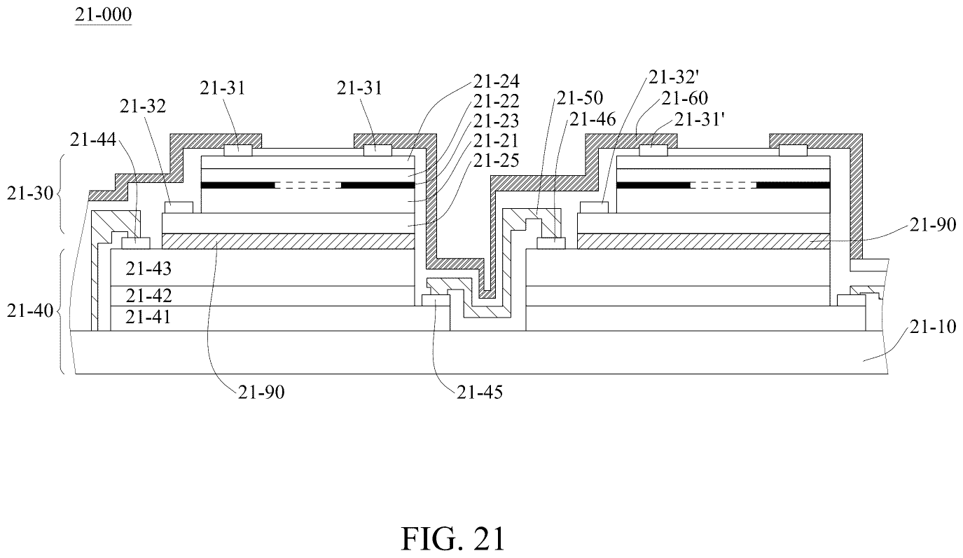

Please refer to FIG. 21, which shows a schematic cross-sectional view of a chip package structure according to another embodiment of the disclosure. As illustrated, the package structure 21-000 includes a first chip 21-30 and a second chip 21-40 disposed on a substrate 21-10, wherein a first chip 21-30 and a second chip 21-40 both are horizontal chips. The first chip 21-30 and the second chip 21-40 are connected to each other via a spacing layer 21-90 positioned between them, which also provides electrical insulation. The spacing layer 21-90 and the first chip 21-30 can be sequentially grown by epitaxy on the second chip 21-40. As previously described, the spacing layer 21-90 is made of a semiconductor material with low doping concentration and high resistivity.

In this embodiment, the first chip 21-30 may be a laser chip. As shown in FIG. 21, the first chip 21-30 comprises a first semiconductor structure 21-21, a second semiconductor structure 21-22, and an active structure 21-23 disposed between the first semiconductor structures 21-21 and the second semiconductor structures 21-22. The first chip 21-30 further comprises a first contact layer 21-24 covering the second semiconductor structure 21-22 and electrically connected to a first conductive structure 21-31. The first chip 21-30 further comprises a second contact layer 21-25 electrically connecting the first semiconductor structure 21-21 to a second conductive structure 21-32.

The second chip 21-40 may be a photovoltaic chip. As illustrated in FIG. 21, the mesa structure of the second chip 21-40 comprises a first semiconductor structure 21-41, an active structure 21-42, a second semiconductor structure 21-43, and contact points 21-44, 21-45 for establishing electrical connections. By connecting the contact points 21-45, 21-46 of two adjacent mesa structures through a connection layer 21-50, the two mesa structures of the second chip 21-40 are connected in series. Furthermore, two adjacent first chips 21-30 are connected in parallel by electrically connecting their respective first conductive structures 21-31, 21-31′ via a first connection structure 21-60. In other words, the first conductive structures 21-31, 21-31′ of two adjacent first chips 21-30 are electrically interconnected through the first connection structure 21-60 Similarly, the second conductive structures 21-32, 21-32′ of the same adjacent first chips 21-30 are electrically interconnected through a second connection structure (not shown).

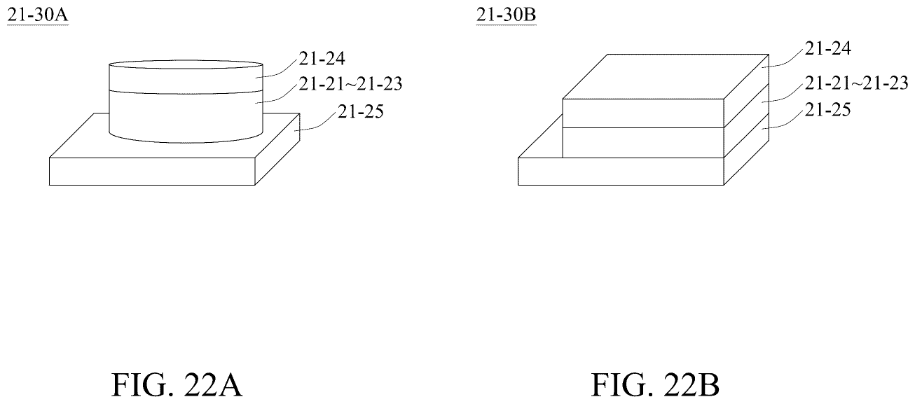

FIG. 22A and FIG. 22B illustrate schematic perspective views of the first chip shapes in two exemplary embodiments of the chip package structure according to the disclosure, respectively. As shown in figures, the first chip in the disclosed chip package structure may be cylindrical, such as the first chip 21-30A in FIG. 22A, which may be a VCSEL chip, or cuboid, such as the first chip 21-30B in FIG. 22B, which may be an LED chip. The first chips 21-30A in FIG. 22A and the first chip 21-30B in FIG. 22B may comprise identical compositions, but the effective light emitting area of the first chip 21-30B is larger than that of the first chip 21-30A, potentially enabling higher energy conversion efficiency in the chip package structure. The material of the light emitting element according to the disclosure may be GaAs or GaN.

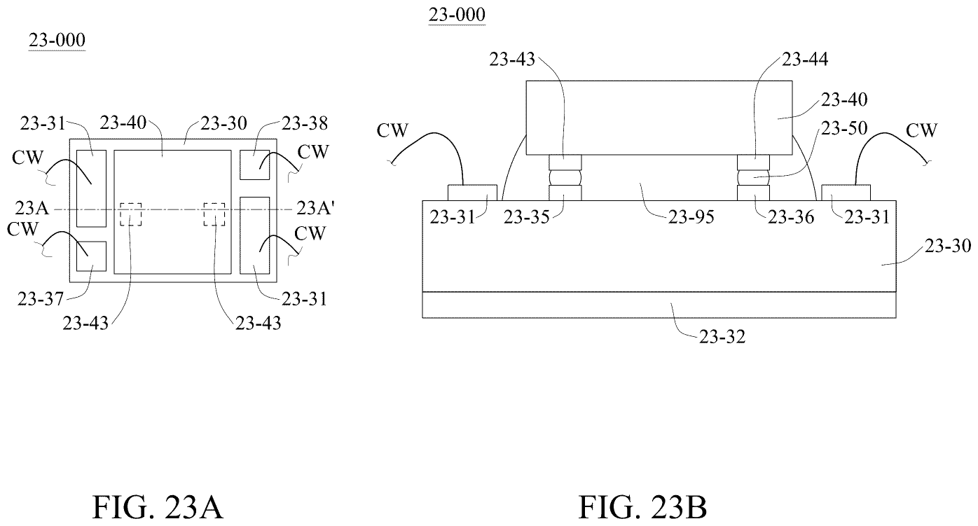

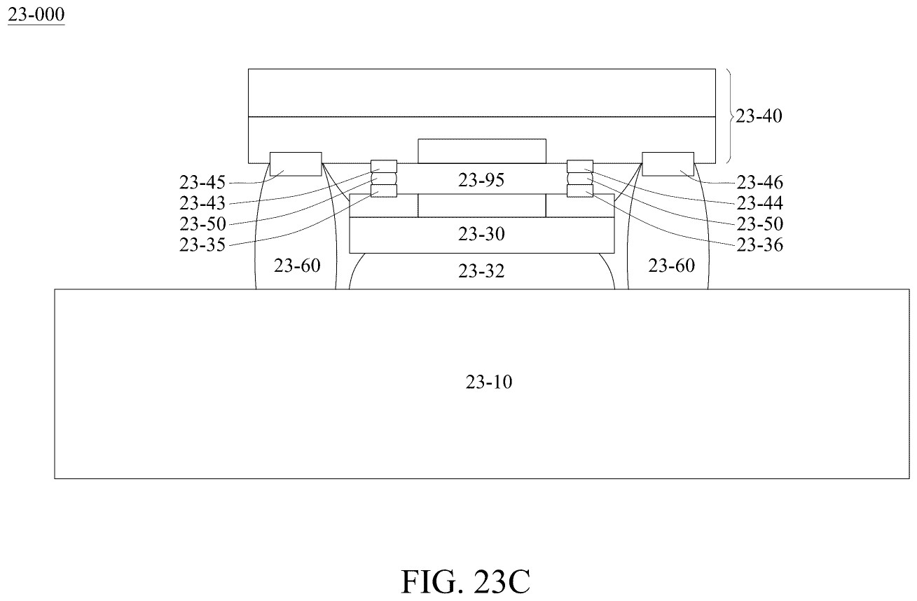

FIG. 23A and FIG. 23B show a top view and a cross-sectional view, respectively, of a chip package structure according to another embodiment of the disclosure, wherein FIG. 23B being a cross-sectional view taken along line 23A-23A′ in FIG. 23A. In this embodiment, as illustrated, the first chip is a vertical chip, the second chip is a horizontal chip, wherein the size of the second chip is smaller than the size of the first chip. The package structure 23-000 of this embodiment has a similar configuration to the package structure 17-000 shown in FIG. 17, with the difference being that the first conductive connection structure 23-43 and the second conductive connection structure 23-44 of the package structure 23-000 are disposed on the side of the second chip 23-40 facing the first chip 23-30. Moreover, the first chip 23-30 comprises conduction structures 23-35, 23-36 that are electrically connected to the first conduction structures 23-43 and the second conduction structures 23-44 of the second chip 23-40 through a bonding structure 23-50. The conduction structures 23-35, 23-36 are electrically insulated from the first conductive structure 23-31 and the second conductive structure 23-32 of the first chip 23-30 and serve to align the first chip 23-30 with the second chip 23-40 in the chip package structure. The package structure 23-000 of this embodiment further comprises bonding pads 23-37, 23-38 electrically connected to the first conduction structures 23-43, the second conduction structures 23-44 and the second chip 23-40. The bonding pads 23-37, 23-38 and the first conduction structure 23-31 are electrically connected to electrical conduction posts (not shown) of the packaging substrate through corresponding connecting wires CW. In this embodiment, the package structure 23-000 further comprises an underfill 23-95 between the first chip 23-30 and the second chip 23-40 to further secure the positioning of the first chip 23-30 and the second chip 23-40. The underfill 23-95 may be a dielectric material and/or a light-transmissive material, such as a BCB (Bisbenzocyclobutene).

In this embodiment, the first chip 23-30 and the second chip 23-40 are bonded through a chip-to-wafer bonding process. During the packaging process, the bonding structure 23-50 bonds a plurality of second chips 23-40 to a first wafer comprising a plurality of the first chips 23-30 (not shown). Subsequently, the underfill 23-95 is applied between the first chip 23-30 and the second chip 23-40. The chips are then singulated, and the resulting chip set (including the first chip 23-30 and the second chip 23-40) is disposed on a substrate (such as the substrate 13′-110 in FIG. 13A or the substrate 17-10 in FIG. 17) to obtain the package structure 23-000 according to the disclosure.

In another embodiment, the size of the first chip is smaller than the size of the second chip. The chip set is disposed on the substrate 23-10 in a flip-chip configuration. FIG. 23C shows a schematic cross-sectional view of a chip package structure according to this embodiment. As illustrated, the first chip is a vertical chip and the second chip is a horizontal chip, wherein the size of the first chip is smaller than the size of the second chip. The first chip 23-30 comprises conduction structures 23-35, 23-36 that are electrically connected to the first conduction structures 23-43 and the second conduction structures 23-44 of the second chip 23-40 through bonding structures 23-50. The conduction structures 23-45, 23-46 are disposed on the second chip 23-40 and are electrically connected to the substrate 23-10 through a bonding structure 23-60. In this embodiment, an underfill 23-95 is also disposed between the first chip 23-30 and the second chip 23-40 to further secure their positioning. The underfill may be a dielectric material and/or a light-transmissive material, such as a BCB (Bisbenzocyclobutene).

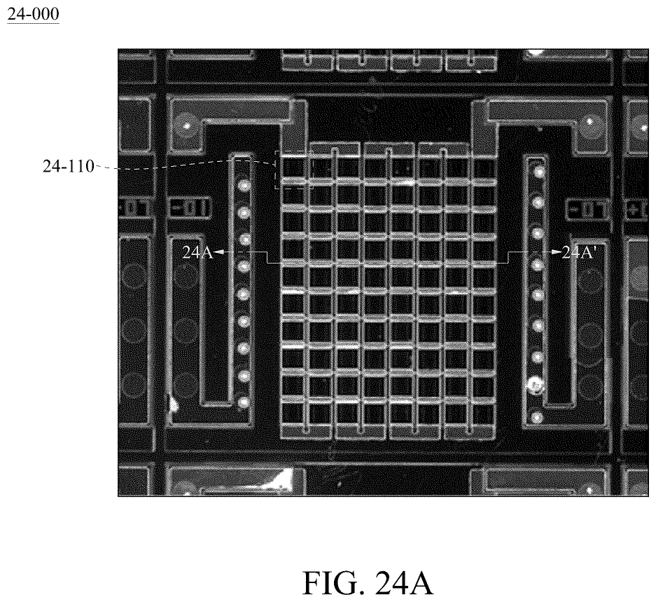

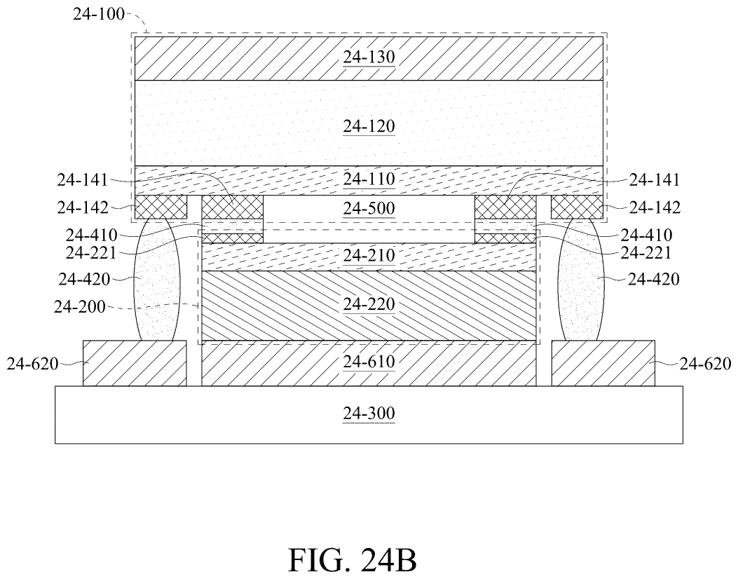

Please refer to FIG. 24A and FIG. 24B. FIG. 24A is a top view of a microscopic image of a light receiving portion of an optoelectronic converter. The optoelectronic converter 24-000 includes a plurality of cells, wherein each unit is substantially rectangular, but the disclosure is not limited thereto. In this exemplary embodiment, the units are connected in series to serve as a high-voltage optoelectronic converter. FIG. 24B illustrates a schematic cross-sectional view along line 24A-24A′ in FIG. 24A. The optoelectronic converter 24-000 includes a light emitting portion 24-200 having electrical pads and a light receiving portion 24-100 having electrical pads, wherein at least a part of the light emitting portion 24-200 faces at least a part of the light receiving portion 24-100. In an embodiment, as shown in FIG. 24B, the optoelectronic converter 24-000 may further comprise a metal core printed circuit board (MCPCB) 24-300 electrically connected to the electrical pads of the light emitting portion 24-200 and/or the electrical pads of the light receiving portion 24-100 through a conductive structure 24-610. In one or more embodiments, the optoelectronic converter 24-000 may further comprise an underfill 24-500 between the light emitting portion 24-200 and the light receiving portion 24-100 to further fix the light emitting portion 24-200 and the light receiving portion 24-100. In this embodiment, the underfill 24-500 may be a dielectric material and/or a light-transmissive material, such as a BCB (Bisbenzocyclobutene). The light emitting portion 24-200 includes an epitaxial layer 24-210. In one or more embodiments, the epitaxial layer 24-210 may be the above-mentioned VCSEL chip. In one or more embodiments, the light emitting portion 24-200 may further comprise a heat dissipation layer, such as a metal layer 24-220 between the epitaxial layer 24-210 and the MCPCB 24-300. In one or more embodiments, if the emitting wavelength of the light emitting portion 24-200 is 840 nm (but not limited thereto), the light receiving portion 24-100 is designed to receive incident light of the same wavelength. The light receiving portion 24-100 comprises a photovoltaic epitaxial layer 24-110, a transparent substrate 24-120, a mirror layer 24-130, and a plurality of conductive layers 24-141, 24-142, wherein each of the conductive layers 24-141, 24-142 may be a single layer or multiple layers. The transparent substrate 24-120 may be sapphire or glass, but is not limited thereto. The photovoltaic epitaxial layer 24-110 and the plurality of conductive layers 24-141, 24-142 are formed on the same side of the transparent substrate 24-120, while the mirror layer 24-130 is formed on the opposite side of the transparent substrate 24-120. The plurality of conductive layers 24-142 are electrically connected to a conductive structure 24-620 of the MCPCB 24-300 through a bonding structure 24-420, wherein some of the conductive layers 24-142 serve as the positive electrode and the negative electrode of the light receiving portion 24-100, respectively. Another portions of the conductive layers 24-142 are connected to the conductive layers 24-141 and further connected to the conductive layers 24-221 of the light emitting portion 24-200 through a bonding structure 24-410, serving as one of the electrodes (e.g., cathode) of the light emitting portion 24-200. In some embodiments, a portion of the conductive structure 24-620 of the MCPCB 24-300 may also serve as one of the electrodes (e.g., the cathode) of the epitaxial layer 24-210, and the conductive structure 24-610 serves as the other electrode (e.g., the anode) of the epitaxial layer 24-210.

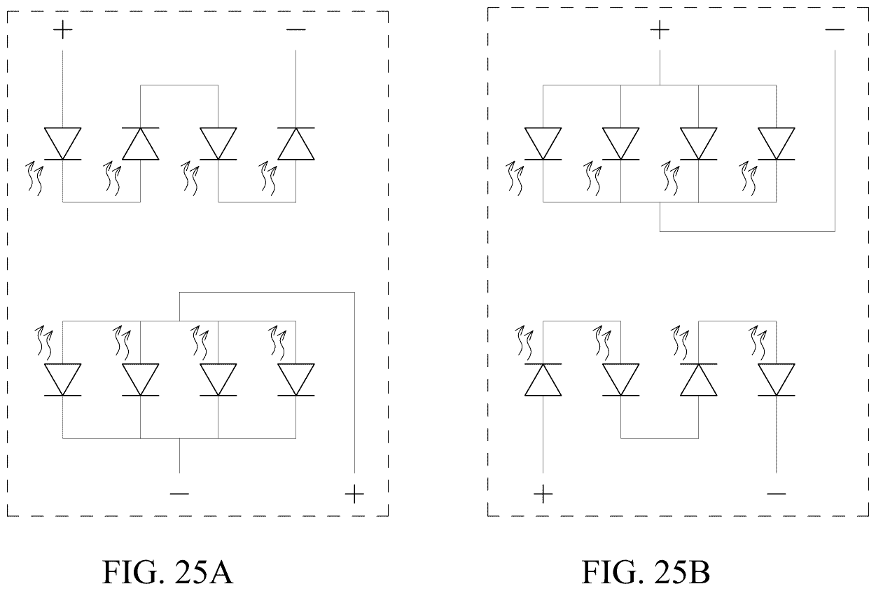

In one or more embodiments, the optoelectronic converter includes a light-emitting portion and a light-receiving portion. Each portion has multiple cells, and the cells are electrically connected through different circuit designs to transform the input voltage and input current into different output voltage and output current, as shown in FIGS. 25A and 25B. FIGS. 25A and 25B are respectively equivalent circuit diagrams of high-voltage optoelectronic converter and low-voltage optoelectronic converter. For a specific output voltage and output current, both the output voltage and current can be optimized through circuit designs for the cells of light-emitting portion and the cells of light-receiving portion. In one or more embodiments, the light-emitting portion includes a plurality of VCSELcells, and the light-receiving portion includes a plurality of photovoltaic cells, but the present disclosure is not limited thereto, as shown in FIGS. 25A and 25B. In one or more embodiments, the number of cells in the light-emitting portion may be equal to the number of cells in the light-receiving portion, but the present disclosure is not limited thereto. In the embodiment shown in FIG. 25A, the plurality of VCSEL cells in the light-emitting portion are electrically connected in parallel, while the plurality of photovoltaic cells in the light-receiving portion are electrically connected in series to function as a high-voltage optoelectronic converter (high voltage optical transformer, HVOT). Specifically, in the embodiment shown in FIG. 25A, the VCSEL cells (represented by diode circuit symbols) of the light-emitting portion at the input side (the lower side of FIG. 25A) are connected in parallel and input a lower voltage with larger current, while the photovoltaic cells (represented by diode circuit symbols) of the light-receiving portion at the output side (the upper side of FIG. 25A) are connected in series to output a higher voltage with smaller current, thereby converting low voltage to high voltage and functioning as a high-voltage optoelectronic converter. In another embodiment shown in FIG. 25B, the plurality of VCSEL cells of the light-emitting portion are electrically connected in series, and the plurality of photovoltaic cells in the light-receiving portion are electrically connected in parallel to function as a low-voltage optoelectronic converter (low voltage optical transformer, LVOT). Specifically, in the embodiment shown in FIG. 25B, the VCSEL cells (represented by diode circuit symbols) of the light-emitting portion at the input side (the lower side of FIG. 25B) are connected in series and input a higher voltage with small current, while the photovoltaic cells (represented by diode circuit symbols) of the light-receiving portion at the output side (the upper side of FIG. 25B) are connected in parallel to generate a lower voltage with larger current, thereby converting high voltage to low voltage and functioning as a low-voltage optoelectronic converter.

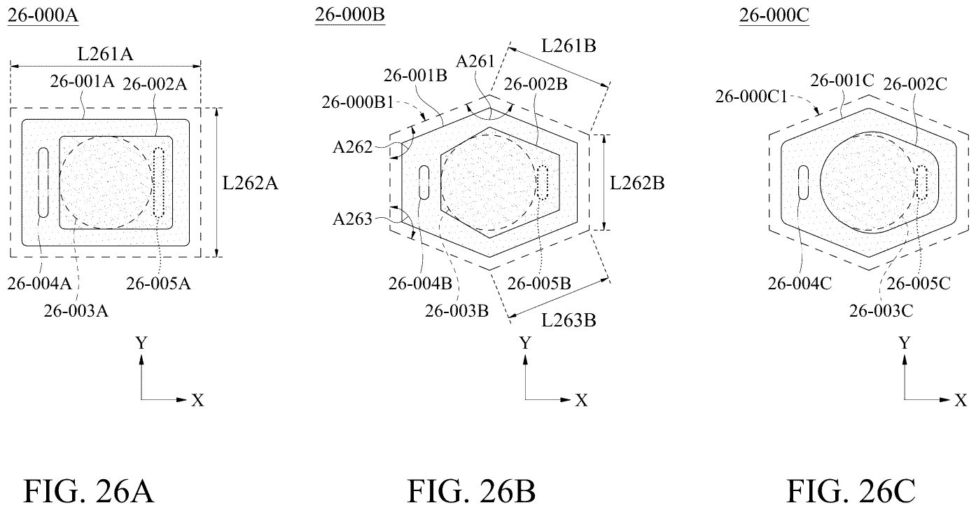

In one embodiment as illustrated in FIG. 24A, the cell of the optoelectronic converter is substantially rectangular. The detailed layout design can be found in FIG. 26A. FIG. 26A illustrates a top view of a rectangular cell 26-000A of the optoelectronic converter according to one embodiment. The cell layout of FIG. 26A can be an transmitting cell, a VCSEL cell, a receiving cell, or a photovoltaic cell, and the light-emitting region or the light-receiving region can be disposed at the center of each cell, but the present disclosure is not limited thereto. Specifically, according to some embodiments, in the rectangular cell 26-000A, a first rectangular region 26-00A defines an isolation structure (composed of a P-type semiconductor layer) of the cell (transmitting cell or receiving cell), a second rectangular region 26-002A defines a mesa structure of an epitaxial layer (composed of an active layer and an N-type semiconductor layer) of the cell (transmitting cell or receiving cell), a circular region 26-003A defines a light-emitting region of the transmitting cell or a light-receiving region of the receiving cell, and elongated regions 26-004A and 26-005A define a P-contact pad and an N-contact pad of the cell (transmitting cell or receiving cell), respectively. As shown in FIG. 26A, in one embodiment, the light-emitting region of the transmitting cell or the light-receiving region of the receiving cell is closer to the N-contact pad and farther away from the P-contact pad of the cell (transmitting cell or receiving cell). In addition, in one embodiment, the side length L261A and the side length L262A of the rectangular cell 26-000A are 0.082 mm and 0.064 mm, respectively. FIG. 26B and FIG. 26C illustrate top views of hexagonal cells 26-000B and 26-000C of the optoelectronic converter according to one embodiment, respectively. The cell of the optoelectronic converter is defined by a hexagonal cell boundary of hexagonal cells 26-000B and 26-000C, as shown in FIGS. 26B and 26C. As shown in FIG. 26B, in the hexagonal cell 26-000B, a first hexagonal region 26-001B defines an isolation structure (composed of a P-type semiconductor layer) of the cell (transmitting cell or receiving cell), a second hexagonal region 26-002B defines a mesa structure of an epitaxial layer (composed of an active layer and an N-type semiconductor layer) of the cell (transmitting cell or receiving cell), a circular region 26-003B defines a light-emitting region of the transmitting cell or a light-receiving region of the receiving cell, and elongated regions 26-004B and 26-005B define a P-contact pad and an N-contact pad of the cell (transmitting cell or receiving cell), respectively. In addition, in one embodiment, the side length L261B, the side length L262B, and the side length L263B of the hexagonal cell 26-000B are 0.0443 mm, 0.0393 mm, and 0.0443 mm, respectively, and the interior angle A261, the interior angle A262, and the interior angle A263 of the hexagonal cell 26-000B are 136 degrees, 112 degrees, and 112 degrees, respectively. In some embodiments, two relatively short side lengths of the six side lengths of the hexagonal cell are disposed at opposite positions, and the two relatively short side lengths are substantially equal to each other, and the other four relatively long side lengths are also substantially equal to each other. In some embodiments, two relatively large interior angles of the six interior angles in the hexagonal cell are disposed at opposite positions, and the two relatively large interior angles are substantially equal to each other in angle, and the angles of the other four relatively small interior angles are also substantially equal to each other. In the hexagonal cell 26-000C, similarly, a first hexagonal region 26-001C defines an isolation structure of the cell (transmitting cell or receiving cell) (composed of a P-type semiconductor layer), a polygonal region 26-002C defines a mesa structure of an epitaxial layer (composed of an active layer and an N-type semiconductor layer) of the cell (transmitting cell or receiving cell), a circular region 26-003C defines a light-emitting region of the transmitting cell or a light-receiving region of the receiving cell, and elongated regions 26-004C and 26-005C define a P-contact pad and an N-contact pad of the cell (transmitting cell or receiving cell), respectively. It should be noted that, as shown in FIG. 26C, in this embodiment, part of the boundary of the polygonal region 26-002C, which defines the mesa structure of the epitaxial layer of the cell (the transmitting cell or the receiving cell), corresponds to the light-emitting region/light-receiving region, and has a rounded corner structure. In addition, in this embodiment, the first hexagonal region 26-001C, which defines the P-type semiconductor layer of the cell (the transmitting cell or the receiving cell), can also have a rounded corner structure (that is, the shape of the first hexagonal region 26-001C is substantially hexagonal). In one or more embodiments, the plurality of cells are arranged in a rectangular grid configuration, wherein the shapes of the cell boundaries are substantially rectangular. In one or more embodiments, the plurality of cells are arranged in a hexagonal grid configuration, wherein the shapes of the cell boundaries are substantially hexagonal. In one or more embodiments, the plurality of cells are arranged in a polygonal grid configuration, wherein the shape of the cell boundary is substantially polygonal. In the embodiment as shown in FIG. 26B and FIG. 26C, the shape of the hexagonal cell boundary is a symmetrical hexagon in the x-axis and y-axis. The hexagonal cell boundary, the light receiving area, and the light emitting area are design lines that do not exhibit on the final product, so these lines are dashed lines in the following drawings. In this embodiment as shown in FIG. 26B, the hexagonal cell might further comprise a mesa hexagon and an isolation hexagon, but is not limited thereto. The shape of the mesa and the isolation might be substantially hexagonal or substantially polygonal. The polygonal shape of the mesa might be offset toward one of the contact pad directions (for example, offset toward the N contact pad direction of the cell (the transmitting cell or the receiving cell)). The isolation hexagon keeps a constant distance away from the mesa and the P contact to ensure voltage isolation. In one or more embodiments, the mesa hexagon might not be designed in a hexagonal shape, as shown in FIG. 26C.

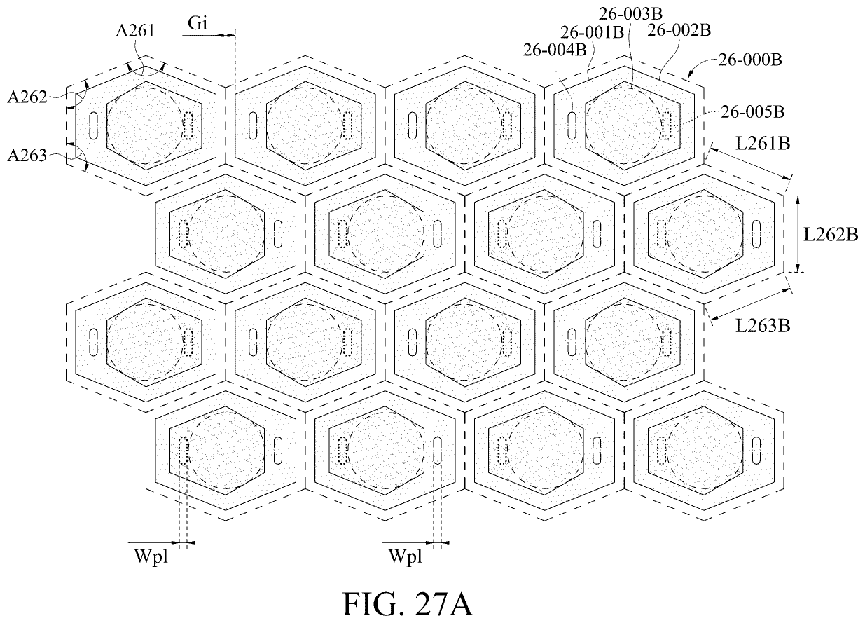

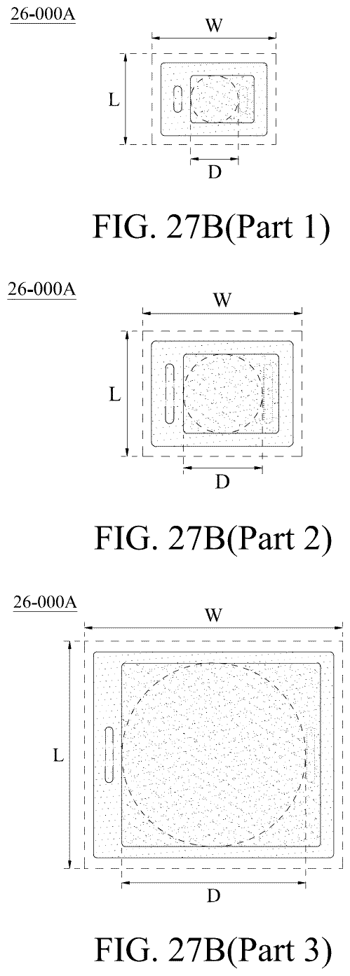

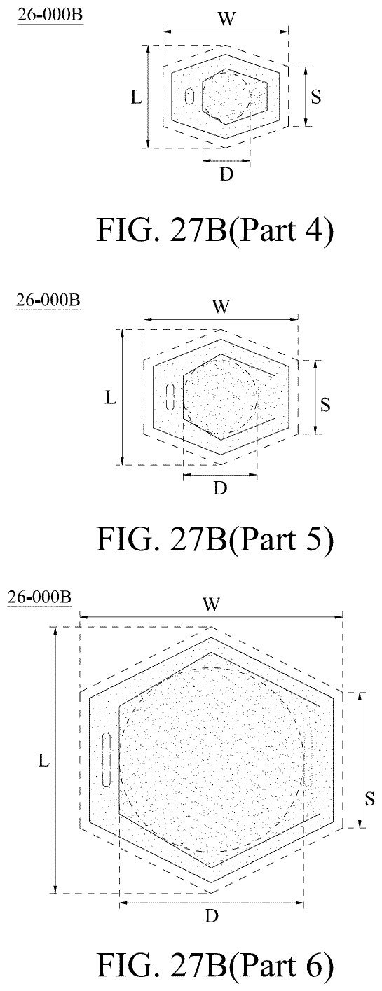

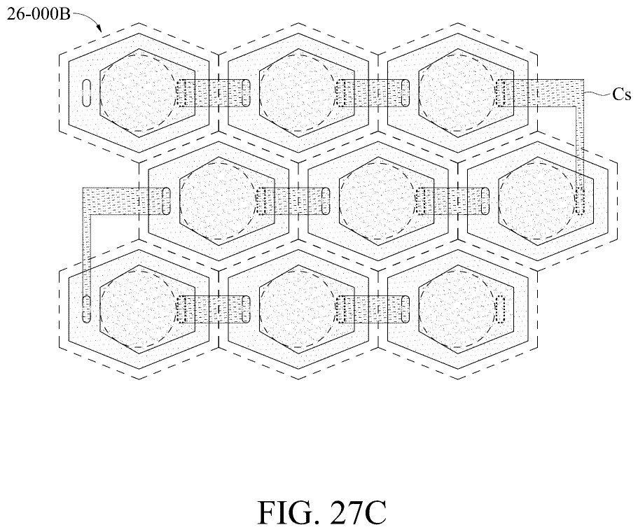

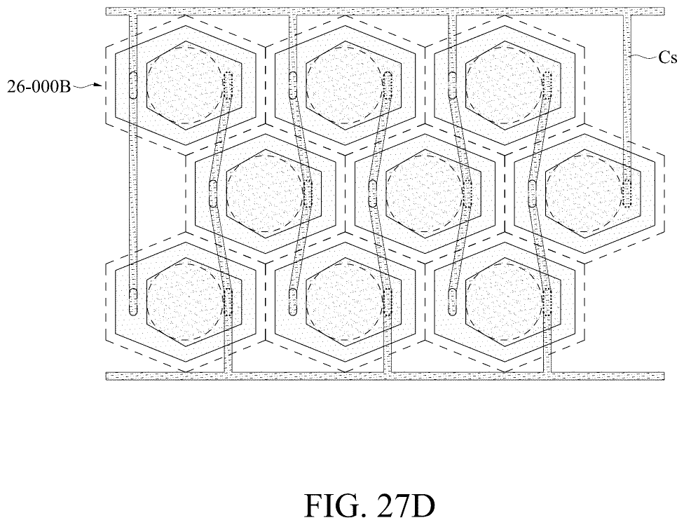

Referring to FIG. 27A, a top perspective schematic view of a plurality of hexagonal cells 26-000B of an optoelectronic converter according to an embodiment is illustrated. In one or more embodiments as illustrated in FIG. 27A, the side lengths (L261B, L262B, L263B) and the interior angles (A261, A262, A263) of the hexagonal cell 26-000B may be adjusted according to the following: (1) a diameter of a light-emitting area or a light-receiving area; (2) a line width Wpl of a conductive connection pad; (3) a spacing Gi between isolation structures. The symmetrical hexagonal cells 26-000B may be arranged in a close-packed hexagonal array. For the same diameter of the light-emitting area or the light-receiving area, the overall chip size can be reduced 10-20% by the hexagonal cell 26-000B design as compared to the rectangular cell design. In some embodiments, in a plurality of hexagonal cells of the optoelectronic converter, the plurality of hexagonal cells in odd rows have the same arrangement direction, and the plurality of hexagonal cells in even rows have the same arrangement direction, wherein the arrangement direction of the plurality of hexagonal cells in the odd rows is opposite to the arrangement direction of the plurality of hexagonal cells in the even rows. For example, in an embodiment as shown in FIG. 27A, an arrangement order of the electrodes of the hexagonal cells 26-000B in the first row is PNPN . . . in order from the left to the right of the drawing, and an arrangement order of the electrodes of the hexagonal cells 26-000B in the second row is NPNP . . . in order from the left to the right of the drawing, and then an arrangement order of the electrodes of the hexagonal cells 26-000B in the third row is PNPN . . . in order from the left to the right of the drawing again, so that those hexagonal cells 26-000B are arranged in an S-shape to be designed for different series or parallel connection. For example, in some embodiments, the hexagonal cells 26-000B in the first row and the hexagonal cells 26-000B in the second row can form one cell group, and the hexagonal cells 26-000B in the third row and the hexagonal cells 26-000B in the fourth row can form another cell group, so that the optoelectronic converter comprises different segment to achieve different voltage transformation combinations. Furthermore, in some embodiments one segment serve as the high voltage transformation segment in the optoelectronic converter (converting low voltage to high voltage), at least one cell group serve as an input end which the transmitting cells in the cell group are electrically connected in parallel to each other, and at least one matched cell group serve as an output end which the receiving cells in the cell group are electrically connected in series to each other. Another segment serve as the low voltage transformation segment in the optoelectronic converter (converting high voltage to low voltage), at least one another cell group serve as an input end which the transmitting cells in the cell group are electrically connected in series to each other, and at least one matched cell group serve as an output end which the receiving cells in the cell group are electrically connected in parallel to each other. In one or more embodiments, FIG. 27B shows a schematic diagram of a layout design of rectangular cells and hexagonal cells having different diameters of the light-emitting area or the light-receiving area. Specifically, in some embodiments, as shown in FIG. 27B (Part 1), the side lengths of the rectangular cell 26-000A are 0.067 mm and 0.049 mm, respectively, and the diameter of the light-emitting area or the light-receiving area of the rectangular cell 26-000A is 0.025 mm; as shown in FIG. 27B (Part 2), the side lengths of the rectangular cell 26-000A are 0.082 mm and 0.064 mm, respectively, and the diameter of the light-emitting area or the light-receiving area of the rectangular cell 26-000A is 0.04 mm; as shown in FIG. 27B (Part 3), the side lengths of the rectangular cell 26-000A are 0.142 mm and 0.124 mm, respectively, and the diameter of the light-emitting area or the light-receiving area of the rectangular cell 26-000A is 0.1 mm. In some embodiments, when the vertical direction in the drawing is defined as the length direction of the hexagonal cell 26-000B and the horizontal direction in the drawing is defined as the width direction of the hexagonal cell 26-000B, as shown in FIG. 27B (Part 4), the length (L) of the hexagonal cell 26-000B is 0.0542 mm, the width W is 0.067 mm, the diameter D of the light-emitting area or the light-receiving area of the hexagonal cell 26-000B is 0.025 mm, and the side length S corresponding to the length direction of the hexagonal cell 26-000B is 0.0317 mm; as shown in FIG. 27B (Part 5), the length L of the hexagonal cell 26-000B is 0.0725 mm, the width W is 0.082 mm, the diameter D of the light-emitting area or the light-receiving area of the hexagonal cell 26-000B is 0.04 mm, and the side length S corresponding to the length direction of the hexagonal cell 26-000B is 0.0393 mm; as shown in FIG. 27B (Part 6), the length L of the hexagonal cell 26-000B is 0.1422 mm, the width W is 0.142 mm, the diameter D of the light-emitting area or the light-receiving area of the hexagonal cell 26-000B is 0.1 mm, and the side length S corresponding to the length direction of the hexagonal cell 26-000B is 0.0727 mm.

Next, the plurality of hexagonal cells 26-000B may be electrically connected in series or in parallel, as shown in FIG. 27C or FIG. 27D, respectively. Please refer to FIG. 27C, a top perspective schematic view of a plurality of hexagonal cells 26-000B of an optoelectronic converter electrically connected in series to each other according to an embodiment is illustrated. Please refer to FIG. 27D, a top perspective schematic view of a plurality of hexagonal cells 26-000B of an optoelectronic converter electrically connected in parallel to each other according to an embodiment is illustrated. When the plurality of hexagonal cells 26-000B are electrically connected in series to each other through conductive connection structures Cs as shown in FIG. 27C, the series circuit is designed to operate at high voltage and low current. In another embodiment, as shown in FIG. 27D, the plurality of hexagonal cells 26-000B are electrically connected in parallel to each other through the conductive connection structures Cs, and the parallel circuit is designed to operate at low voltage and high current.

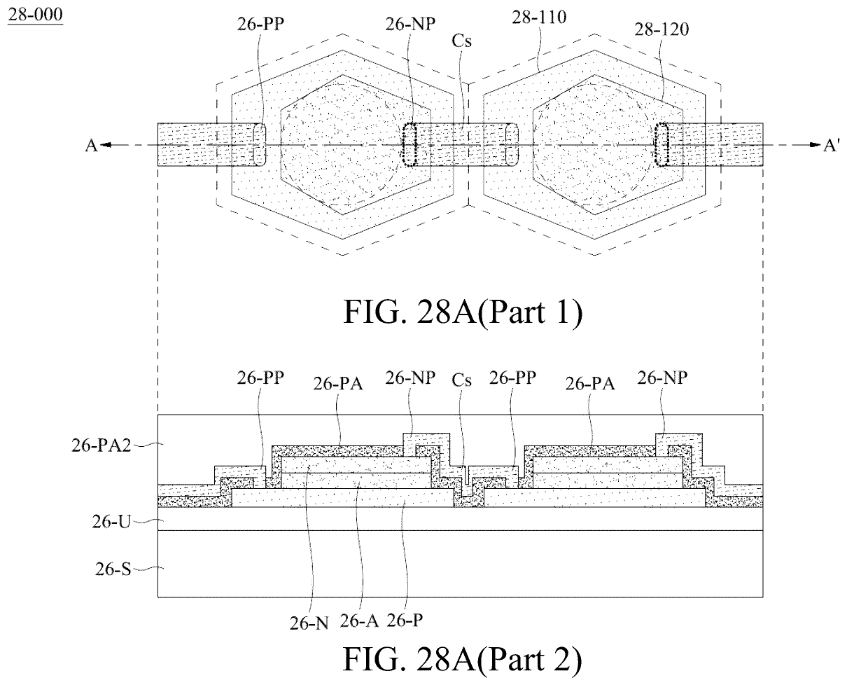

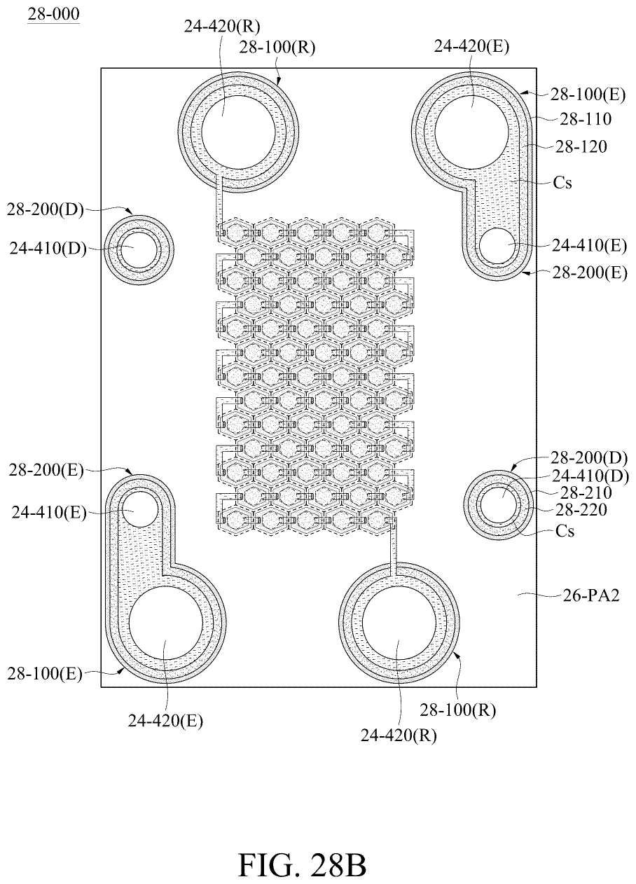

Please refer to FIG. 28A. FIG. 28A (Part 1 and Part 2) illustrates the correlation between the top view layout and cross-section view of the hexagonal cell 26-000B connected in series. FIG. 28A (Part 1) is a top perspective view of the hexagonal cell 26-000B electrically connected by the conductive connection structure Cs. FIG. 28A (Part 2) is a cross-section view of the hexagonal cell 26-000B along the cross-section line A-A′ of FIG. 28A (Part 1). In this embodiment, the hexagonal cell 26-000B may be an optoelectronic chip design or a VCSEL chip design. As shown in FIG. 28A (Part 1) and FIG. 28A (Part 2), two hexagonal cells 26-000B are connected in series by the conductive connection structure Cs. The first hexagonal area 26-001B defines the isolation structure comprise the P-type semiconductor layer 26-P) of the unit (emitting cell or receiving cell). The second hexagonal area 26-002B defines the mesa structure of the epitaxial layer of the unit (emitting cell or receiving cell), (comprise the active layer 26-A and the N-type semiconductor layer 26-N). The circular area 26-003B 28-130 defines the light emitting area of the emitting cell or the light receiving area of the receiving cell. The elongated area 26-004B and 26-005B define the P conductive contact pad 26-PP and the N conductive contact pad 26-NP of the cell (the emitting cell or the receiving cell), respectively. The conductive connection structure Cs may be a metal layer or other conductive materials. As shown in FIG. 28A (Part 2), an adhesion layer 26-U is disposed between the base layer 26-S and an epitaxial layer (comprise P-type semiconductor layer 26-P, active layer 26-A, and N-type semiconductor layer 26-N). The passivation layer 26-PA is disposed on the epitaxial layers of the adjacent hexagonal cells 26-000B. The passivation layer 26-PA has openings so that the P conductive contact pad 26-PP and N conductive contact pad 26-NP of the adjacent hexagonal cells 26-000B can be electrically connected by the conductive connection structure Cs through the openings. In some embodiments, the material of adhesion layer is BCB. In some embodiments, a protection layer 26-PA2 (for example, BCB or other passivation materials) may be further formed on the P conductive contact pad 26-PP and the N conductive contact pad 26-NP to prevent the hexagonal cell 26-000B (for example, a light emitting cell) from interfering with its corresponding cell (for example, a light receiving cell). In one or more embodiments, the P conductive contact pad (first electrode), N conductive contact pad (second electrode), and conductive connection structure Cs may be fabricated by three different fabrication processes, but are not limited thereto. In another embodiment, the N conductive contact pad (second electrode) and the conductive connection structure Cs may be fabricated by the same fabrication process.

In one embodiment, as shown in FIG. 28B, a schematic of a chip layout 28-000 with series connected hexagonal cells as the light receive part of a high voltage optoelectronic converter (HVOT) is illustrated. Those hexagonal cells are arranged in a packed hexagonal arrangement. As shown in FIG. 28B, in addition to the light receiving part composed of hexagonal cells, the chip layout 28-000 also includes a plurality of first connection structures 28-100 and a plurality of second connection structures 28-200. In this embodiment, the chip layout 28-000 includes four first connection structures and four second connection structures. In this embodiment, the four first connection structures disposed at the upper left, lower left, upper right, and lower right of FIG. 28B are the first connection structure 28-100(R), the first connection structure 28-100(E), the first connection structure 28-100(E), and the first connection structure 28-100(R), respectively. The four second connection structures disposed at the upper left, lower left, upper right, and lower right of FIG. 28B are the second connection structure 28-200(D), the second connection structure 28-200(E), the second connection structure 28-200(E), and the second connection structure 28-200(D), respectively. The four bonding structures 24-410 disposed at the upper left, lower left, upper right, and lower right of FIG. 28B are the bonding structure 24-410(D), the bonding structure 24-410(E), the bonding structure 24-410(E), and the bonding structure 24-410(D), respectively. The four bonding structures 24-420 disposed at the upper left, lower left, upper right, and lower right of FIG. 28B are the bonding structure 24-420(R), the bonding structure 24-420(E), the bonding structure 24-420(E), and the bonding structure 24-420(R), respectively. As shown in FIG. 28B, in this embodiment, the first connection structure (i.e., the first connection structure 28-100(R), the first connection structure 28-100(E), the first connection structure 28-100(E), and the first connection structure 28-100(R) located at the top left, bottom left, top right, and bottom right of FIG. 28B) respectively comprises a first mesa structure 28-110, a second mesa structure 28-120, a conductive connection structure Cs, and a bonding structure 24-420 (refer to FIG. 24B). The hexagonal cell 26-000B of the light receiving part can be connected to an external circuit board (for example, the metal core printed circuit board 24-300 in FIG. 24B) through the bonding structure 24-420(R). The second connection structure (i.e., the second connection structure 28-200(D), the second connection structure 28-200(E), the second connection structure 28-200(E), and the second connection structure 28-200(D) located at the top left, bottom left, top right, and bottom right of FIG. 28B) respectively comprises a first mesa structure 28-210, a second mesa structure 28-220, a conductive connection structure Cs, and a bonding structure 24-410 (refer to FIG. 24B). The hexagonal cell 26-000B of the light receiving part can be connected to the light emitting part through the bonding structure 24-410(E). As shown in FIG. 28B, at the upper right corner and at the lower left corner, the first connection structure 28-100 and the second connection structure 28-200 are connected together to form a common first mesa structure 28-110/28-210 and a common second mesa structure 28-120/28-220. The conductive connection structure is formed on the common second mesa structure 28-120/28-220 to connect the bonding structure 24-410(E) and the bonding structure 24-420(E). In some embodiments, the chip layout 28-000 further includes a protection layer 26-PA2 to prevent the hexagonal cell 26-000B (for example, the light emitting cell) from interfering with its corresponding cell (for example, the light receiving cell) and to prevent the separated first connection structure and the second connection structure from being electrically connected to each other and causing a short circuit. The material of the protection layer 26-PA2 can be an insulating material, including but not limited to silicon oxide and silicon nitride.

In some embodiments, a semiconductor laser is provided. By adjusting the element composition ratio, material thickness, and material type of the quantum well layer of the active structure, the gain spectrum of the active structure of the semiconductor laser is expanded. Accordingly, even when the ambient temperature is lowered (e.g., lowered to −40° C.) or raised (e.g., raised to 80° C.), the peak position of the resonance wavelength of the emitted light from the semiconductor laser can still correspond to the relative peak position of the gain spectrum of the active structure.

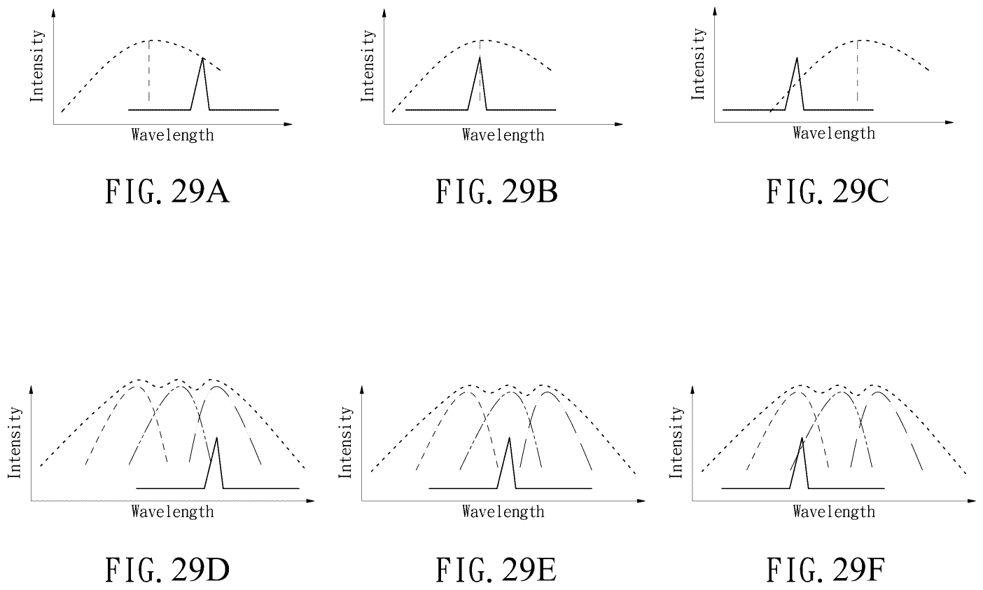

FIGS. 29A to 29C and FIGS. 29D to 29F are schematic diagrams illustrating the relationships between the gain spectrum of the active structures and the resonance wavelengths of the emitted light of semiconductor lasers known to the inventors and semiconductor lasers according to some embodiments of the disclosure, respectively, at different temperatures. FIGS. 29A to 29C illustrate the relationships between the gain spectra of the active structures and the resonance wavelengths of the emitted light of semiconductor lasers known to the inventors at three different temperatures: T1 (FIG. 29A), T2 (FIG. 29B), and T3 (FIG. 29C). FIGS. 29D to 29F illustrate the relationships between the gain spectra of the active structures and the resonance wavelengths of the emitted light of semiconductor lasers according to some embodiments of the disclosure at three different temperatures: T1 (FIG. 29D), T2 (FIG. 29E), and T3 (FIG. 29F).

As can be seen from FIGS. 29A to 29C, for the semiconductor lasers known to the inventors, when operating at T2, the peak position of the resonance wavelength of the emitted light from the semiconductor laser basically corresponds to the relative peak position of the gain spectrum of its active structure. However, temperature changes lead to changes in the energy levels of the active structure and cause the optical thickness of the distributed Bragg reflector (DBR) and the optical resonator cavity or the active structure of the semiconductor laser to change due to thermal expansion and contraction. Moreover, the degree of influence of temperature changes on the energy level changes of the active structure and the optical thickness changes of the DBR and the optical resonator cavity or the active structure is different. As a result, when the temperature changes (for example, decreases to T1 or increases to T3), the peak position of the resonance wavelength of the emitted light from the semiconductor laser will no longer correspond to the relative peak position of the gain spectrum of its active structure, which in turn leads to a deterioration in the maximum light output efficiency of the semiconductor laser.

Referring to FIGS. 29D to 29F, for the semiconductor lasers according to some embodiments of the disclosure, when operating at T2, the peak position of the resonance wavelength of the emitted light of the semiconductor laser also basically corresponds to the relative peak position of the gain spectrum of the active structure. When the temperature changes (for example, decreases to T1 or increases to T3), by adjusting the material composition ratio, material thickness, and material type of the quantum well layer of the active structure, the gain spectrum of the active structure of the semiconductor laser is expanded, so that the peak position of the resonance wavelength of the emitted light of the semiconductor laser can still correspond to the relative peak position of the gain spectrum of the active structure.

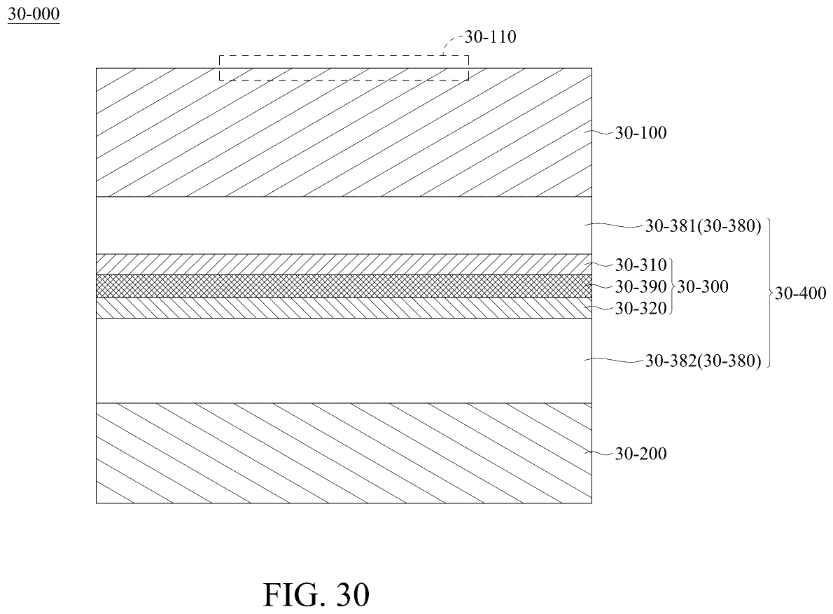

FIG. 30 is a schematic cross-sectional view of a semiconductor laser 30-000 according to an embodiment. As shown in FIG. 30, in some embodiments, the semiconductor laser 30-000 comprises a first type semiconductor layer 30-100, a second type semiconductor layer 30-200, an active structure 30-300, and a spacing layer 30-380. Wherein the active structure 30-300 and the spacing layer 30-380 are stacked to form an optical resonator cavity 30-400 in a vertical space. The first type semiconductor layer 30-100 has a light-emitting aperture 30-110. The active structure 30-300 is disposed between the first type semiconductor layer 30-100 and the second type semiconductor layer 30-200. The spacing layer 30-380 includes a first spacing layer 30-381 and a second spacing layer 30-382, wherein the first spacing layer 30-381 is disposed between the first type semiconductor layer 30-100 and the active structure 30-300, and the second spacing layer 30-382 is disposed between the second type semiconductor layer 30-200 and the active structure 30-300. The active structure 30-300 includes a first quantum well layer 30-310, a second quantum well layer 30-320, and a barrier layer structure 30-390 disposed between the first quantum well layer 30-310 and the second quantum well layer 30-320. The second quantum well layer 30-320 is farther away from the light-emitting aperture 30-110 compared to the first quantum well layer 30-310, wherein the emission wavelength of the second quantum well layer 30-320 is different from the emission wavelength of the first quantum well layer 30-310. In some embodiments, the total thickness of the optical resonator cavity 30-400 is an integer multiple (nλp) of the peak resonance wavelength (λp) of the semiconductor laser 30-000, wherein n is a positive integer.

In some embodiments, the active structure 30-300 of the semiconductor laser 30-000 has at least two or more quantum well layers capable of emitting different wavelengths (for example, but not limited to, the first quantum well layer 30-310 and the second quantum well layer 30-320 shown in FIG. 30), wherein the emission spectrum emitted by the semiconductor laser 30-000 includes at least two or more peaks, and the peak intensities at different wavelengths are not necessarily the same.

In some embodiments, the first type semiconductor layer 30-100 and the second type semiconductor layer 30-200 may include a distributed Bragg reflector (DBR) structure. In some embodiments, the DBR structure may be formed by alternately stacking two or more film layers with different refractive index, such as AlAs/GaAs, AlGaAs/GaAs, AlGaAs/AlGaAs, or InGaP/GaAs.

In some embodiments, the barrier layer structure 30-390 is also disposed between the first type semiconductor layer 30-100 and the first quantum well layer 30-310 and between the second type semiconductor layer 30-200 and the second quantum well layer 30-320.

In some embodiments, the difference between the emission wavelength of the second quantum well layer 30-320 and the emission wavelength of the first quantum well layer 30-310 is in the range of 2 nanometers to 20 nanometers.

In some embodiments, the materials of the first quantum well layer 30-310 and the second quantum well layer 30-320 include III-V compound semiconductors. For example, the III-V compound semiconductor may be a binary compound, such as InP, GaAs, InSb, GaN, GaSb, etc.; may be a ternary compound, such as InGaAs, InGaP, AlGaAs, InGaN, etc.; may be a quaternary compound, such as AlGaInP, InGaAsP, InGaAsN, etc.; or may be a quinary compound, such as InGaAsSbN, AlInGaAsN, etc.

Furthermore, for the semiconductor laser 30-000 that emits red light, the materials of the first quantum well layer 30-310 and the second quantum well layer 30-320 include the group consisting of Al_{S}Ga_{T}As_{W}P_{X} (where 0≤S≤1, 0≤T≤1, 0≤W≤1, 0≤X≤1) and Al_{S}Ga_{T}In_{V}As_{W}P_{X} (where 0≤S≤1, 0≤T≤1, 0≤V≤1, 0≤W≤1, 0≤X≤1). For the semiconductor laser 30-000 that emits infrared light, the materials of the first quantum well layer 30-310 and the second quantum well layer 30-320 include the group consisting of Al_{S}Ga_{T}As_{W}P_{X} (where 0≤S≤1, 0≤T≤1, 0≤W≤1, 0≤X≤1) and Ga_{T}In_{V}As_{W}P_{X} (where 0≤T≤1, 0≤V≤1, 0≤W≤1, 0≤X≤1); for the semiconductor laser 30-000 that emits near-infrared light, the materials of the first quantum well layer 30-310 and the second quantum well layer 30-320 include the group consisting of Al_{S}Ga_{T}In_{V}As_{W}P_{X}Sb_{Y}N_{Z} (where 0≤S≤1, 0≤T≤1, 0≤W≤1, 0≤X≤1, 0≤Y≤1, 0≤Z≤1).

In the embodiments of the disclosure, unless otherwise specified, the above chemical formulas include both “stoichiometric compounds” and “non-stoichiometric compounds”. The compounds are stoichiometric when, for example, the total stoichiometric amount of group III elements is equal to the total stoichiometric amount of group V elements. The compounds are non-stoichiometric when, for example, the total stoichiometric amount of group III elements is not equal to the total stoichiometric amount of group V elements. For example, the chemical formula AlGaAs represents that it includes the group III elements aluminum (Al) and/or gallium (Ga), and the group V element arsenic (As), wherein the total element content of the group III elements (aluminum and/or gallium) may be the same as or different from the total element content of the group V element (arsenic).

In some embodiments, the material types of the first quantum well layer 30-310 and the second quantum well layer 30-320 may be different. In other words, the materials of the first quantum well layer 30-310 and the second quantum well layer 30-320 may include different III-V compound semiconductors. For example, the first quantum well layer 30-310 includes InGaAs and the second quantum well layer 30-320 includes InGaN.

In some embodiments, the material types of the first quantum well layer 30-310 and the second quantum well layer 30-320 may be the same but the element composition ratios are different. In other words, the materials of the first quantum well layer 30-310 and the second quantum well layer 30-320 may include the same III-V compound semiconductor, but the element ratios of the III-V compound semiconductor in the first quantum well layer 30-310 and the second quantum well layer 30-320 are different. For example, the first quantum well layer 30-310 includes In_{0.3}Ga_{0.7}As, while the second quantum well layer 30-320 includes In_{0.4}Ga_{0.6}As.

According to some embodiments, by changing the material types or element composition ratios of the first quantum well layer 30-310 and the second quantum well layer 30-320, the emission wavelengths of the first quantum well layer 30-310 and the second quantum well layer 30-320 can be made different.

In some embodiments, the material of the barrier layer structure 30-390 is GaAs, AlGaAs, GaAsP, or AlInGaAs, wherein the thickness of the barrier layer structure 30-390 is in the range of 3 nanometers to 20 nanometers.

In some embodiments, by changing the thickness of the quantum well layer, the emission wavelengths of the first quantum well layer 30-310 and the second quantum well layer 30-320 can also be made different.

Specifically, in some embodiments, the thickness of the second quantum well layer 30-320 is ±5% of the thickness of the first quantum well layer 30-310. For example, the thickness range of the first quantum well layer 30-310 is 60 angstroms to 80 angstroms. Further assuming that the thickness of the first quantum well layer 30-310 is 60 angstroms then the thickness of the second quantum well layer 30-320 is 57 angstroms (60×(1-5%)) or 63 angstroms (60×(1+5%)), so that the emission wavelengths of the first quantum well layer 30-310 and the second quantum well layer 30-320 are different (for example, the peak spacing between the emission wavelength of the first quantum well layer 30-310 and the emission wavelength of the second quantum well layer 30-320 may be 5-10 nanometers apart due to the thickness difference), thereby expanding the gain spectrum of the active structure 30-300 of the semiconductor laser 30-000.

Please refer to FIG. 30, in some embodiments, the active structure 30-300 comprises a single layer of the first quantum well layer 30-310 and a single layer of the second quantum well layer 30-320.

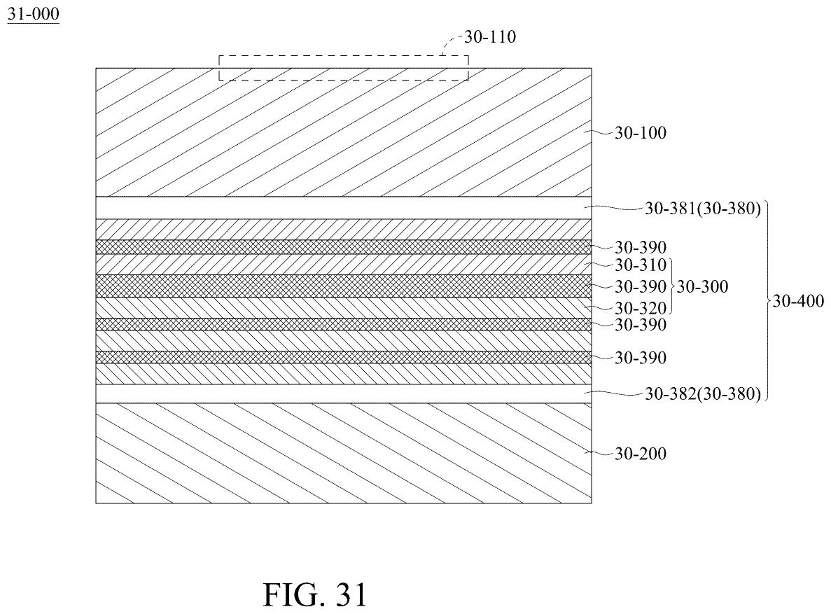

Please refer to FIG. 31, which is a schematic cross-sectional view of a semiconductor laser 31-000 according to an embodiment. In some embodiments, the active structure 30-300 of the semiconductor laser 31-000 may comprises a plurality of first quantum well layers 30-310 and a plurality of second quantum well layers 30-320. Wherein the number of first quantum well layers 30-310 and the number of second quantum well layers 30-320 may be the same or different. Referring to the embodiment of FIG. 31, the first quantum well layer 30-310 comprises two layers and the second quantum well layer 30-320 comprises three layers, but the disclosure is not limited thereto.

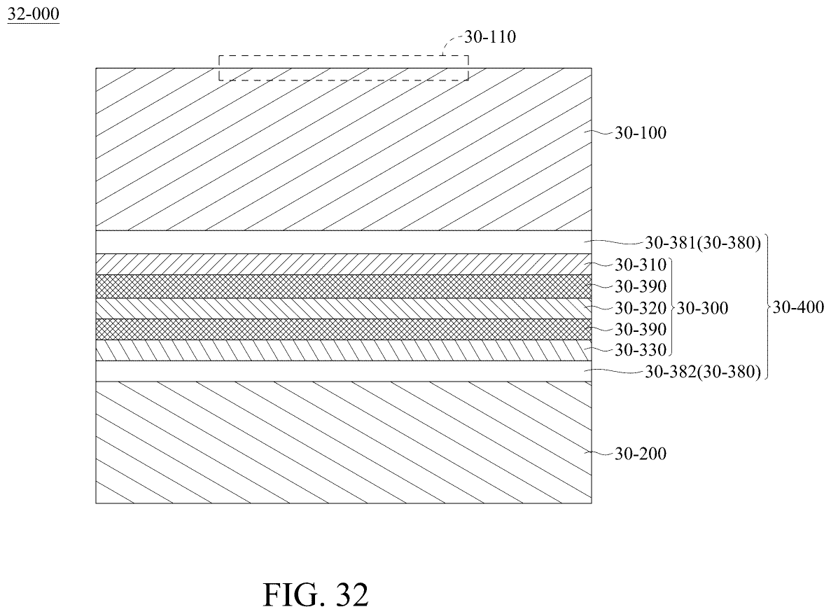

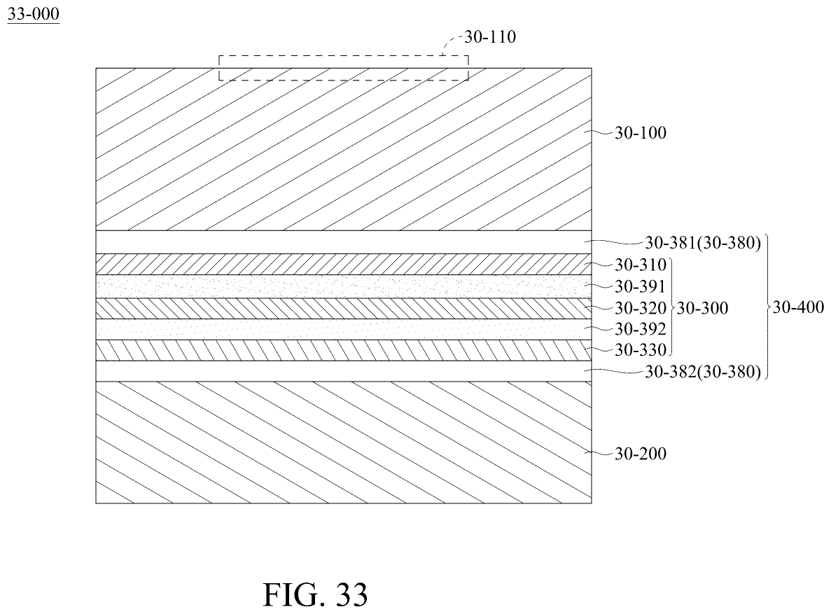

FIG. 32 is a schematic cross-sectional view of a semiconductor laser 32-000 according to an embodiment, and FIG. 33 is a schematic cross-sectional view of a semiconductor laser 33-000 according to an embodiment. Please refer to FIG. 32 and FIG. 33, in some embodiments, the active structure 30-300 of the semiconductor laser 32-000/33-000 may further comprises a third quantum well layer 30-330 disposed between the second quantum well layer 30-320 and the second type semiconductor layer 30-200, wherein a barrier layer structure 30-390 is disposed between the third quantum well layer 30-330 and the second quantum well layer 30-320. Wherein, the emission wavelength of the third quantum well layer 30-330 is greater than the emission wavelength of the second quantum well layer 30-320.

In some embodiments, the materials of the barrier layer structures 30-390 may be the same. Specifically, as shown in the semiconductor laser 32-000 of FIG. 32, in some embodiments, the material of the barrier layer structure 30-390 between the third quantum well layer 30-330 and the second quantum well layer 30-320, the material of the barrier layer structure 30-390 between the first quantum well layer 30-310 and the second quantum well layer 30-320, the material of the barrier layer structure 30-390 between the first type semiconductor layer 30-100 and the first quantum well layer 30-310, and the material of the barrier layer structure 30-390 between the second type semiconductor layer 30-200 and the second quantum well layer 30-320 are all the same.

Alternatively, in some embodiments, the materials of the barrier layer structures may not be completely the same. Specifically, as shown in the semiconductor laser 33-000 of FIG. 33, the material of the barrier layer structure 30-391 between the first type semiconductor layer 30-100 and the first quantum well layer 30-310 and the material of the barrier layer structure 30-391 between the second type semiconductor layer 30-200 and the third quantum well layer 30-330 may be the same, but different from the material of the barrier layer structure 30-392 between the third quantum well layer 30-330 and the second quantum well layer 30-320 and the material of the barrier layer structure 30-392 between the first quantum well layer 30-310 and the second quantum well layer 30-320.

In some embodiments, the active structure 30-300 may comprises a plurality of the first quantum well layers 30-310, a plurality of the second quantum well layers 30-320, and a plurality of the third quantum well layers 30-330, wherein the number of first quantum well layers 30-310, the number of second quantum well layers 30-320, and the number of third quantum well layers 30-330 may be the same or different.

Specifically, in some embodiments, the active structure 30-300 may be a multi-quantum well layers, wherein a plurality of first quantum well layers 30-310 together form a first group of quantum well layers, a plurality of second quantum well layers 30-320 together form a second group of quantum well layers, and a plurality of third quantum well layers 30-330 together form a third group of quantum well layers.

Wherein the barrier layer structures 30-390 are disposed between the plurality of first quantum well layers 30-310 of the first group of quantum well layers, between the plurality of second quantum well layers 30-320 of the second group of quantum well layers, and between the plurality of third quantum well layers 30-330 of the third group of quantum well layers. Wherein the materials of the barrier layer structures 30-390 of different groups of quantum well layers may be the same or different, and the thicknesses of the barrier layer structures 30-390 of different groups of quantum well layers may also be the same or different.

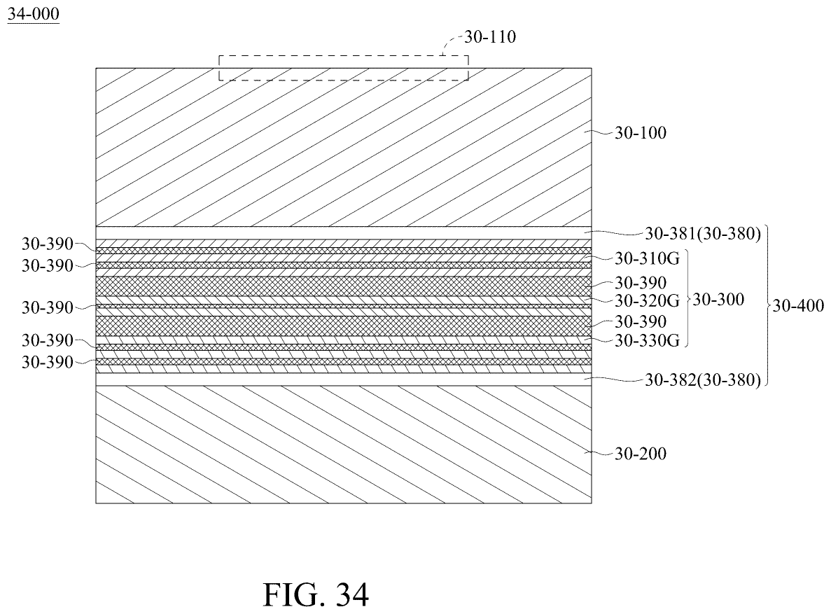

FIG. 34 is a schematic cross-sectional view of a semiconductor laser 34-000 according to an embodiment. Please refer to FIG. 34. In the semiconductor laser 34-000 of this embodiment, the first group of quantum well layers 30-310G comprises three first quantum well layers 30-310, the second group of quantum well layers 30-320G comprises two second quantum well layers 30-320, and the third group of quantum well layers 30-330G comprises three third quantum well layers 30-330.

In some embodiments, tunnel junction (TJ) may be further disposed between different groups of quantum well layers. The tunnel junction may composed of highly doped semiconductor layers (which may be highly doped group III compounds or highly doped group V compounds). When a current passes through the active structure 30-300, carriers (electrons or holes) move between different groups of quantum well layers. The tunnel junctions provide channels that allow carriers to cross the energy band barriers between different groups of quantum well layers, enabling carriers to diffuse more easily throughout the entire structure, achieving more efficient carrier injection and radiative recombination, thereby improving the efficiency and performance of the light-emitting component. In addition, the tunnel junctions can also affect the energy band structure of the active structure 30-300, helping to achieve the desired output spectral characteristics. By adjusting the doping concentration and material composition of the tunnel junctions, the energy band gaps between the quantum well layers can be changed, thereby affecting the emission wavelength and spectral characteristics of the active structure 30-300.

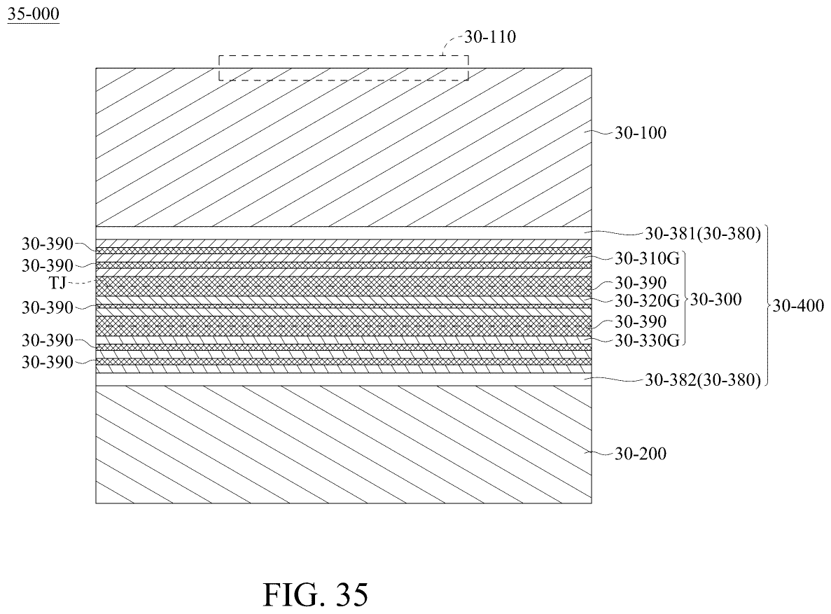

FIG. 35 is a schematic cross-sectional view of a semiconductor laser 35-000 according to an embodiment. Please refer to FIG. 35. In the semiconductor laser 35-000 of this embodiment, a tunnel junction TJ (represented by a dashed line in FIG. 7) with a highly doped semiconductor layer is disposed between the first group of quantum well layers 30-310G and the second group of quantum well layers 30-320G. Similarly, a tunnel junction TJ with a highly doped semiconductor layer is also disposed between the second group of quantum well layers 30-320G and the third group of quantum well layers 30-330G.

In some embodiments, the thickness of the highly doped semiconductor layer is in the range of 5 nanometers to 20 nanometers.

In some embodiments, a semiconductor laser is provided. By fabricating columnar structures with specific dimensions to define light-emitting apertures during the manufacturing process, it may not be necessary to use a relatively difficult-to-control wet oxidation process to fabricate an oxide layer. This allows the pitch between the light-emitting apertures of the semiconductor laser to be reduced, thereby reducing the overall size of the semiconductor laser. Furthermore, because the wet oxidation process may not be required, the surface of the semiconductor laser can be planarized, resulting in uniform aperture diameters for the light-emitting apertures.

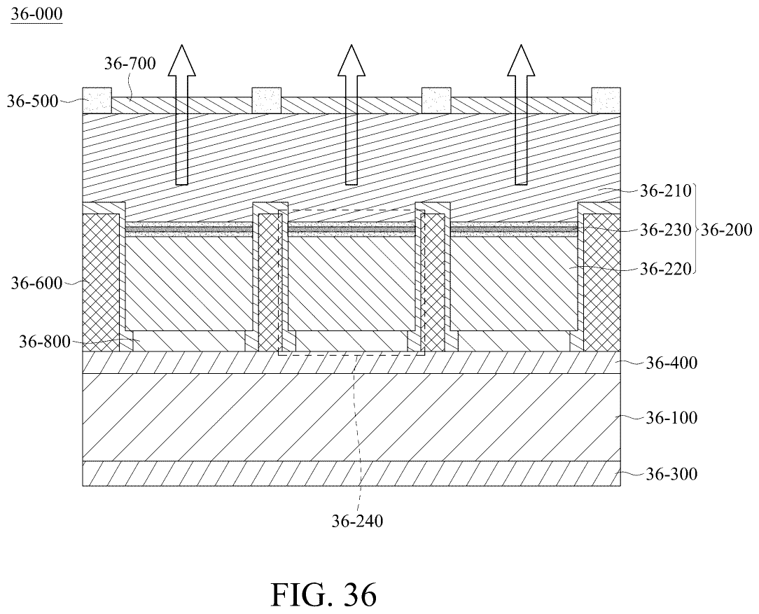

FIG. 36 is a schematic cross-sectional view of a semiconductor laser 36-000 according to some embodiments of the disclosure.

In some embodiments, as shown in FIG. 36, the semiconductor laser 36-000 comprises a conductive substrate 36-100, a semiconductor stack layer 36-200, a contact electrode layer 36-300, a metal bonding layer 36-400, a plurality of first conductive structures 36-500, a plurality of insulating structures 36-600, a plurality of anti-reflective structures 36-700, and a plurality of second conductive structures 36-800. The semiconductor stack layer 36-200 is disposed on the conductive substrate 36-100, wherein the semiconductor stack layer 36-200 comprises a first type semiconductor layer 36-210, a second type semiconductor layer 36-220, and an active structure 36-230. The active structure 36-230 is disposed between the first type semiconductor layer 36-210 and the second type semiconductor layer 36-220. The contact electrode layer 36-300 is disposed on a side of the conductive substrate 36-100 opposite to the semiconductor stack layer 36-200. The metal bonding layer 36-400 is disposed between the conductive substrate 36-100 and the second type semiconductor layer 36-220 of the semiconductor stack layer 36-200. The plurality of first conductive structures 36-500 are disposed between the metal bonding layer 36-400 and the second type semiconductor layer 36-220 of the semiconductor stack layer 36-200. The plurality of insulating structures 36-600 extend from the metal bonding layer 36-400 pass through the second conductive structures 36-800, the second type semiconductor layer 36-220, and the active structure 36-230, and extend to at least a portion of the first type semiconductor layer 36-210. Then, defining the second type semiconductor layer 36-220 and the active structure 36-230 as a plurality of columnar structures 36-240. The plurality of anti-reflective structures 36-700 are disposed on a side of the first type semiconductor layer 36-210 of the semiconductor stack layer 36-200 opposite to the metal bonding layer 36-400 and correspond to the columnar structures 36-240. The plurality of first conductive structures 36-500 are disposed on a side of the first type semiconductor layer 36-210 of the semiconductor stack layer 36-200 opposite to the metal bonding layer 36-400, wherein the first conductive structures 36-500 are disposed between the anti-reflective structures 36-700 and correspond to the insulating structures 36-600.

In some embodiments, the first type semiconductor layer 36-210 and the second type semiconductor layer 36-220 may comprise a distributed Bragg reflector (DBR) structure. In some embodiments, the DBR structure may be formed by alternately stacking two or more layers with different refractive index, such as AlAs/GaAs, AlGaAs/GaAs, or InGaP/GaAs.

In some embodiments, the width of the columnar structures 36-240 is between 3 micrometers and 25 micrometers.

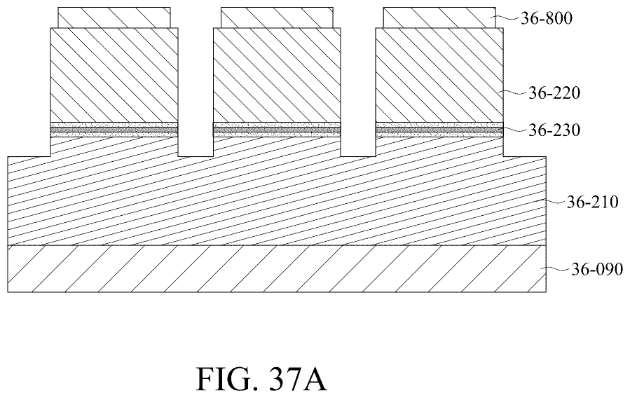

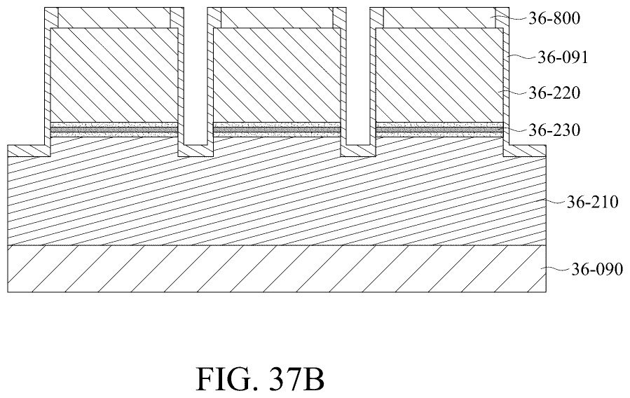

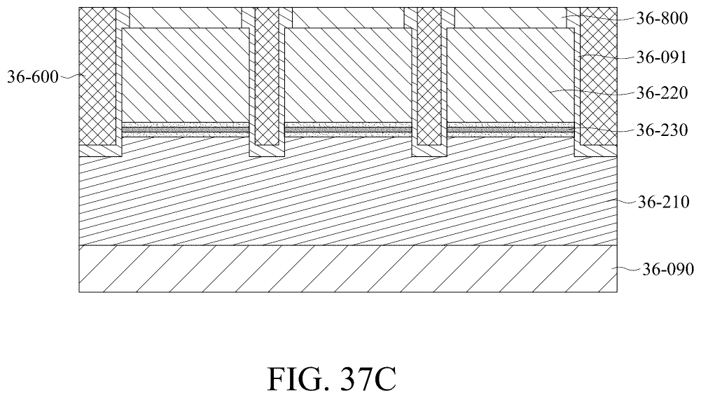

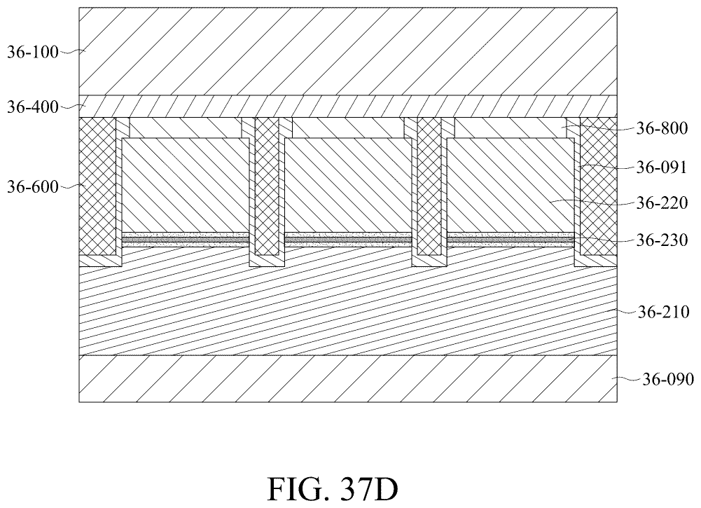

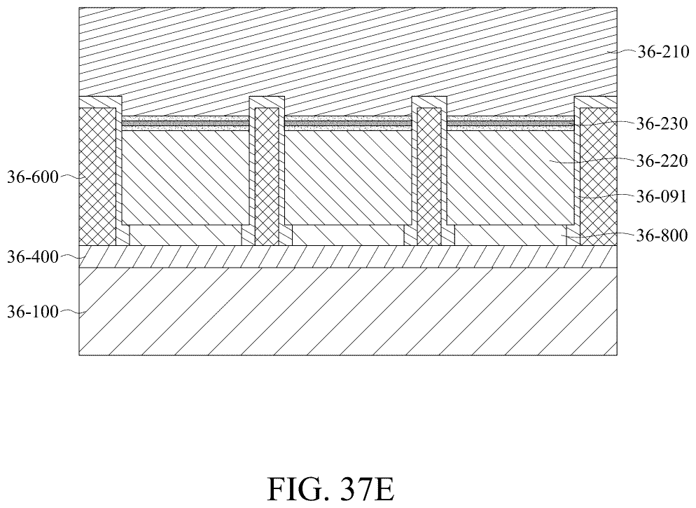

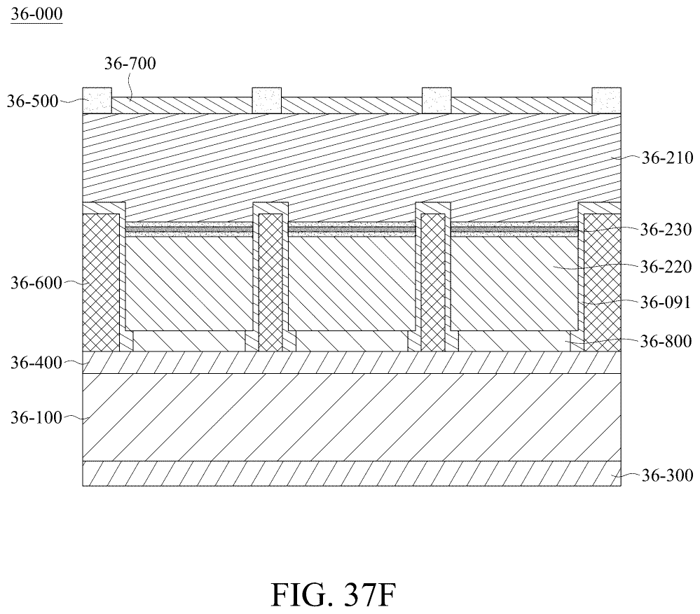

FIGS. 37A to 37F are schematic cross-sectional views illustrating multiple steps of a fabrication process for a semiconductor laser (for example, but not limited to, the semiconductor laser 36-000 shown in FIG. 36) according to some embodiments of the disclosure.

First, please refer to FIG. 37A. An epitaxial wafer is provided. The epitaxial wafer comprises a semiconductor stack layer 36-200 formed on a base layer 36-090. The semiconductor stack layer 36-200 sequentially comprises, from bottom to top, a first type semiconductor layer 36-210, an active structure 36-230, and a second type semiconductor layer 36-220. Wherein the first type semiconductor layer 36-210 and/or the second type semiconductor layer 36-220 may be a multilayer structure. In this embodiment, the first type semiconductor layer 36-210 is an N-type semiconductor layer, and the second type semiconductor layer 36-220 is a P-type semiconductor layer. The semiconductor stack layer 36-200 may be epitaxially grown on the base layer 36-090. The epitaxial growth methods include, but are not limited to, metalorganic chemical vapor deposition, hydride vapor phase epitaxy, molecular beam epitaxy, and liquid phase epitaxy. The base layer 36-090 comprises, but is not limited to, III-V materials having a lattice constant substantially matched to the semiconductor stack layer 36-200. The material of the base layer 36-090 in this embodiment is gallium arsenide (GaAs). In other embodiments, the material of the base layer 36-090 may be indium phosphide (InP), sapphire, gallium nitride (GaN), or silicon carbide (SiC) etc.

Next, please refer to FIG. 37A. A patterned conductive layer is formed on the base layer 36-090. Then, an etching process is performed on the aforementioned epitaxial wafer. A mask with a specific pattern is used to etch away portions of the first type semiconductor layer 36-210, portions of the active structure 36-230, and portions of the second type semiconductor layer 36-220 and to expose portions of the first type semiconductor layer 36-210. Wherein the etched regions of the specific pattern do not overlap with the pattern of the conductive layer. As a result, a plurality of columnar structures 36-240 formed on the second type semiconductor layer 36-220 side of the epitaxial wafer and a plurality of first conductive structures 36-500 disposed on the columnar structures 36-240.

Next, please refer to FIG. 37B. A protective layer 36-091 is formed to cover the surfaces and sidewalls of the columnar structures 36-240. The material of the protective layer 36-091 may be an insulating material, including but not limited to silicon oxide and silicon nitride. In some embodiments, the protective layer 36-091 above the plurality of second conductive structures 36-800 has openings, exposing at least portions of the plurality of second conductive structures 36-800.

Next, please refer to FIG. 37C. A non-conductive material is filled into the trenches between the columnar structures 36-240 to form an insulating structure 36-600 for planarizing the epitaxial wafer, so that the insulating structure 36-600 is substantially coplanar with the second conductive structures 36-800. For example, the non-conductive material may be B-staged bisbenzocyclobutene (BCB), but is not limited thereto. Additionally, in some embodiments, after filling the non-conductive material into the trenches of the epitaxial wafer, a chemical mechanical polishing or etching process may be further performed to make the surface of the epitaxial wafer flatter.

Next, please refer to FIG. 37D. The epitaxial wafer with the columnar structures 36-240 and the insulating structure 36-600 is bonded to a conductive substrate 36-100 via a metal bonding layer 36-400. In this embodiment, the conductive substrate 36-100 may be a silicon substrate, but is not limited thereto, and may also be made of other conductive materials.

Then, please refer to FIG. 37E. The base layer 36-090 is removed to expose the first type semiconductor layer 36-210. In this embodiment, the base layer 36-090 is removed by an etching process. In some embodiments, an etching stop layer (not shown in the figure) is disposed between the first type semiconductor layer 36-210 and the base layer 36-090. After the base layer 36-090 is removed, the etching stop layer is further removed to expose the first type semiconductor layer 36-210.

Then, please refer to FIG. 37F. A plurality of anti-reflective structures 36-700 and a plurality of first conductive structures 36-500 are formed on the first type semiconductor layer 36-210.

Specifically, in some embodiments, an anti-reflective layer is first formed on the first type semiconductor layer 36-210. An etching process is then performed on the anti-reflective layer. A mask with a specific pattern is used to etch away portions of the anti-reflective layer to form a plurality of anti-reflective structures 36-700. Then, another mask with a specific pattern is used to form a plurality of first conductive structures 36-500 between the anti-reflective structures 36-700 and corresponding to the insulating structure 36-600.

Alternatively, in some other embodiments, a mask with a specific pattern is first used to form a plurality of first conductive structures 36-500 on the first type semiconductor layer 36-210 corresponding to the insulating structure 36-600. An anti-reflective layer is then formed on the first type semiconductor layer 36-210 and the first conductive structures 36-500. An etching process is then performed on the anti-reflective layer. Another mask with a specific pattern is used to etch away portions of the anti-reflective layer and form a plurality of anti-reflective structures 36-700, thereby exposing the plurality of first conductive structures 36-500.

Finally, please continue to refer to FIG. 37F. A contact electrode layer 36-300 is formed on the side of the conductive substrate 36-100 opposite to the semiconductor stack layer 36-200.

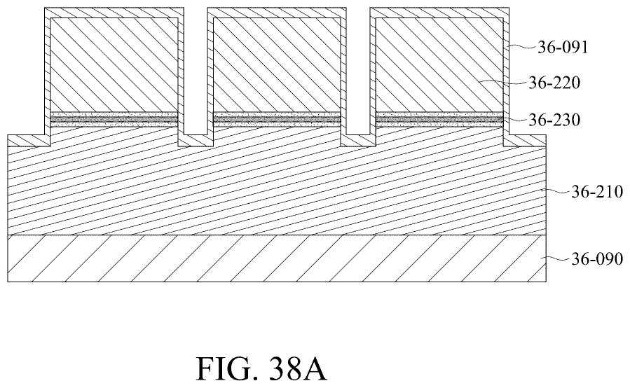

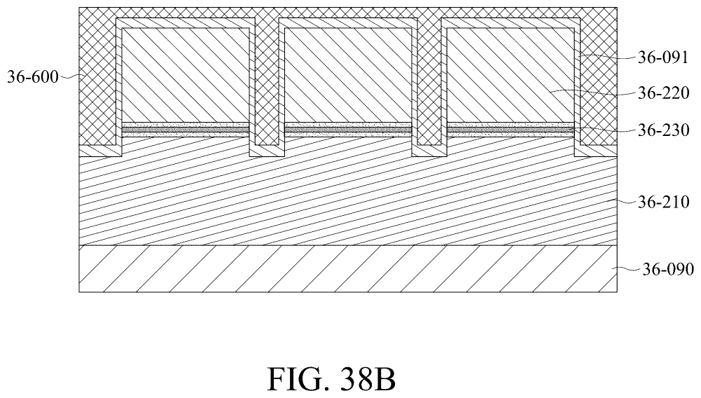

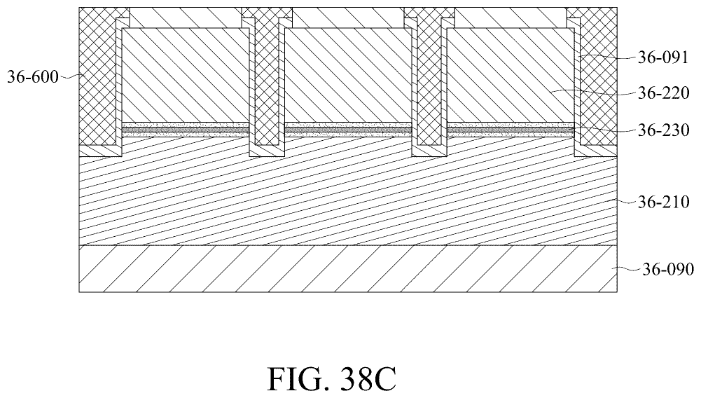

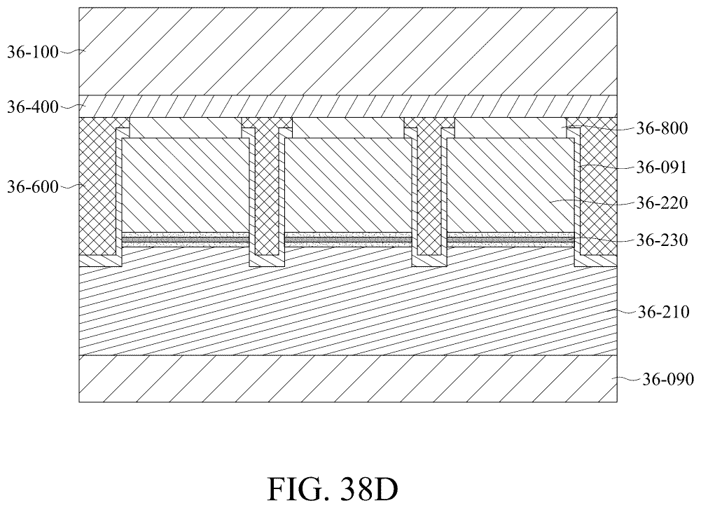

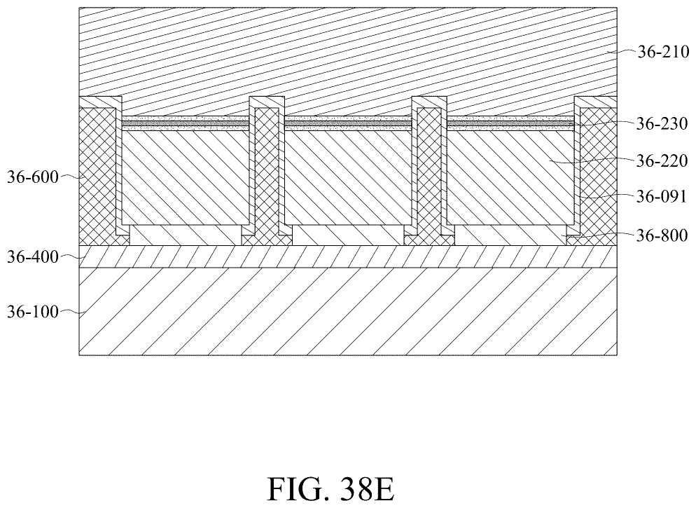

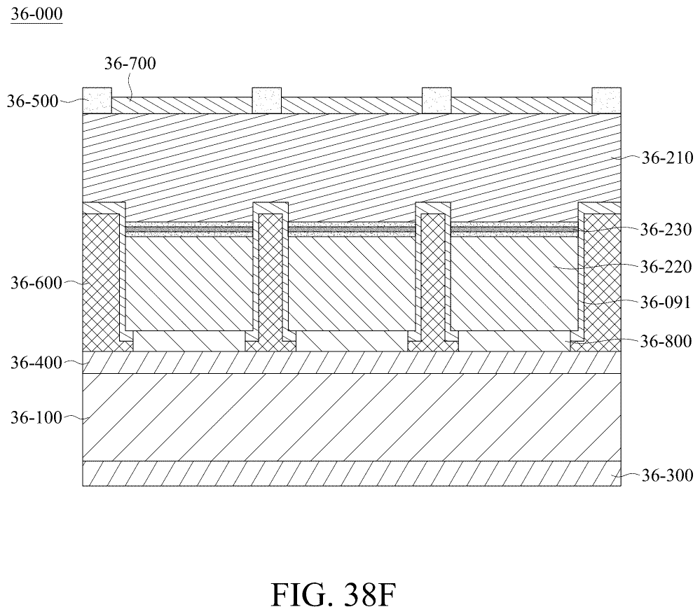

FIGS. 38A to 38F are schematic cross-sectional views illustrating multiple steps of a fabrication process for a semiconductor laser (for example, but not limited to, the semiconductor laser 36-000 shown in FIG. 36) according to some embodiments of the disclosure.

First, please refer to FIG. 38A. An epitaxial wafer is provided. The epitaxial wafer includes a semiconductor stack layer 36-200 formed on a base layer 36-090. The semiconductor stack layer 36-200 sequentially comprises, from bottom to top, a first type semiconductor layer 36-210, an active structure 36-230, and a second type semiconductor layer 36-220.

Next, please continue to refer to FIG. 38A. An etching process is performed on the aforementioned epitaxial wafer. A mask with a specific pattern is used to etch away portions of the first type semiconductor layer 36-210, portions of the active structure 36-230, and portions of the second type semiconductor layer 36-220, thereby exposing portions of the first type semiconductor layer 36-210 and forming a plurality of columnar structures 36-240 on the second type semiconductor layer 36-220 side of the epitaxial wafer.

Next, please continue to refer to FIG. 38A. A protective layer 36-091 is formed to cover the surfaces and sidewalls of the columnar structures 36-240.

Next, please refer to FIG. 38B. A non-conductive material is filled into the trenches between the columnar structures 36-240 to form an insulating structure 36-600 for planarizing the epitaxial wafer, so that the surface of the epitaxial wafer is substantially level. Additionally, in some embodiments, after the non-conductive material is filled into the trenches of the epitaxial wafer, a chemical mechanical polishing or etching process may be further used to make the surface of the epitaxial wafer flatter.

Then, please refer to FIG. 38C. An etching process is performed on the insulating structure 36-600. A mask with a specific pattern is used to etch away portions of the insulating structure 36-600 and portions of the protective layer 36-091 disposed on the surface of the epitaxial wafer, and a plurality of second conductive structures 36-800 are formed, so that the insulating structure 36-600 is substantially coplanar with the second conductive structures 36-800.

Next, please refer to FIG. 38D. The epitaxial wafer with the columnar structures 36-240 and the insulating structure 36-600 is bonded to a conductive substrate 36-100 via a metal bonding layer 36-400.

Then, please refer to FIG. 38E. The base layer 36-090 is removed to expose the first type semiconductor layer 36-210. In this embodiment, the base layer 36-090 is removed by an etching process. In some embodiments, an etching stop layer (not shown in the figure) is disposed between the first type semiconductor layer 36-210 and the base layer 36-090. After the base layer 36-090 is removed, the etching stop layer is further removed to expose the first type semiconductor layer 36-210.

Then, please refer to FIG. 38F. A plurality of anti-reflective structures 36-700 and a plurality of first conductive structures 36-500 are formed on the first type semiconductor layer 36-210.

Specifically, in some embodiments, an anti-reflective layer is first formed on the first type semiconductor layer 36-210. An etching process is then disposed on the anti-reflective layer. A mask with a specific pattern is used to etch away portions of the anti-reflective layer to form a plurality of anti-reflective structures 36-700. Then, a mask with a specific pattern is used to form a plurality of first conductive structures 36-500 between the anti-reflective structures 36-700 and corresponding to the insulating structure 36-600.

Alternatively, in some other embodiments, a mask with a specific pattern is first used to form a plurality of first conductive structures 36-500 on the first type semiconductor layer 36-210 corresponding to the insulating structure 36-600. An anti-reflective layer is then disposed on the first type semiconductor layer 36-210 and the first conductive structures 36-500. An etching process is then performed on the anti-reflective layer. Another mask with a specific pattern is used to etch away portions of the anti-reflective layer and form a plurality of anti-reflective structures 36-700, thereby exposing the plurality of first conductive structures 36-500.

Finally, please continue to refer to FIG. 38F. A contact electrode layer 36-300 is disposed on the side of the conductive substrate 36-100 opposite to the semiconductor stack layer 36-200.

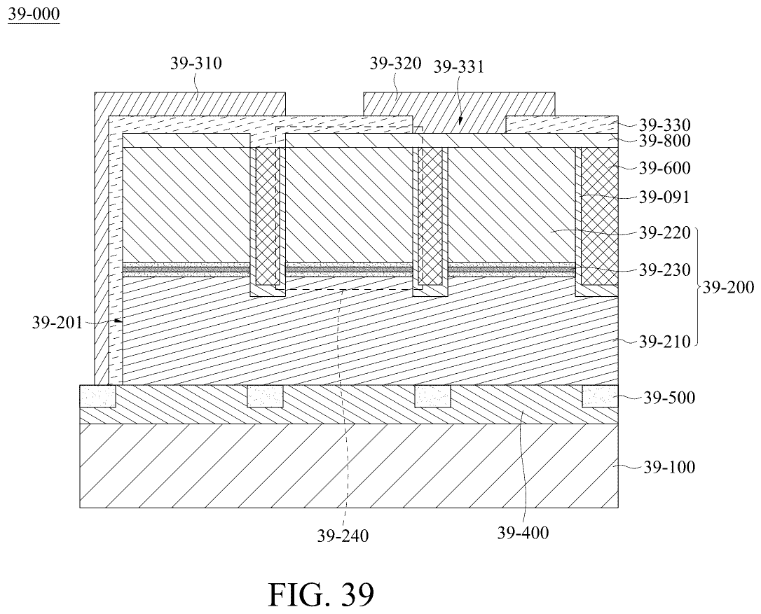

FIG. 39 is a schematic cross-sectional view of a semiconductor laser 39-000 according to some embodiments of the disclosure.

In some embodiments, as shown in FIG. 39, the semiconductor laser 39-000 comprises a transparent substrate 39-100, a semiconductor stack layer 39-200, a light-transmissive bonding layer 39-400, a plurality of insulating structures 39-600, a plurality of first conductive structures 39-500, a plurality of second conductive structures 39-800, a first electrode structure 39-310, a second electrode structure 39-320, and an passivation layer 39-330. The semiconductor stack layer 39-200 is disposed on the transparent substrate 39-100, wherein the semiconductor stack layer 39-200 comprises a first type semiconductor layer 39-210, a second type semiconductor layer 39-220, and an active structure 39-230 disposed between the first type semiconductor layer 39-210 and the second type semiconductor layer 39-220. The light-transmissive bonding layer 39-400 is disposed between the transparent substrate 39-100 and the first type semiconductor layer 39-210 of the semiconductor stack layer 39-200. The plurality of insulating structures 39-600 extend from the second type semiconductor layer 39-220 of the semiconductor stack layer 39-200, pass through the active structure 39-230, and extend to at least a portion of the first type semiconductor layer 39-210. As a result, the second type semiconductor layer 39-220, the active structure 39-230, and the portion of the first type semiconductor layer 39-210 are defined as a plurality of columnar structures 39-240. The plurality of first conductive structures 39-500 are disposed between the first type semiconductor layer 39-210 of the semiconductor stack layer 39-200 and the light-transmissive bonding layer 39-400 and correspond to the insulating structures 39-600. The plurality of second conductive structures 39-800 are disposed on a side of the second type semiconductor layer 39-220 of the semiconductor stack layer 39-200 opposite to the light-transmitting bonding layer 39-400. The first electrode structure 39-310 is disposed on the second type semiconductor layer 39-220 of the semiconductor stack layer 39-200 and extends to a sidewall 39-201 of the semiconductor stack layer 39-200 to connect to at least one of the first conductive structures 39-500, wherein the first electrode structure 39-310 is electrically connected to the first type semiconductor layer 39-210 through the first conductive structures 39-500. In some embodiments, the first electrode structure 39-310 covers at least one of the columnar structure 39-240. The second electrode structure 39-320 is disposed on the second type semiconductor layer 39-220 of the semiconductor stack layer 39-200. The passivation layer 39-330 is disposed between the semiconductor stack layer 39-200 and the first electrode structure 39-310, as well as between the semiconductor stack layer 39-200 and the second electrode structure 39-320. Wherein the passivation layer 39-330 comprises an opening 39-331. The second electrode structure 39-320 is further disposed in the opening 39-331 and contacts the plurality of second conductive structures 39-800. Such that the second electrode structure 39-320 is electrically connected to the second type semiconductor layer 39-220 through the plurality of second conductive structures 39-800.

In some embodiments, the plurality of first conductive structures 39-500 and the plurality of columnar structures 39-240 do not overlap with each other in a vertical projection.

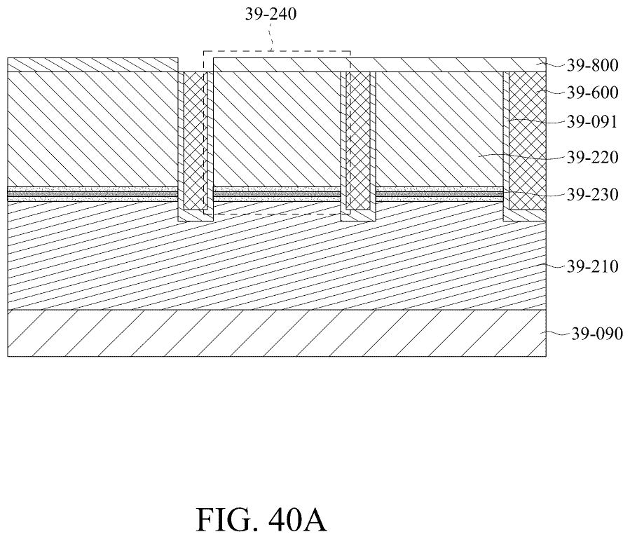

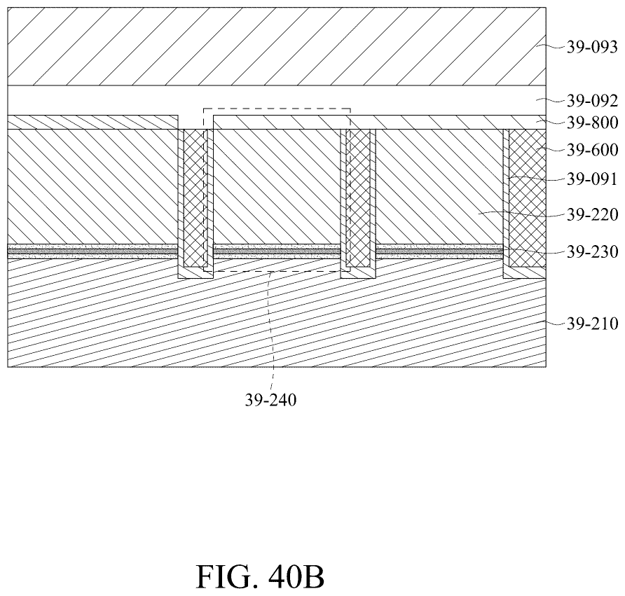

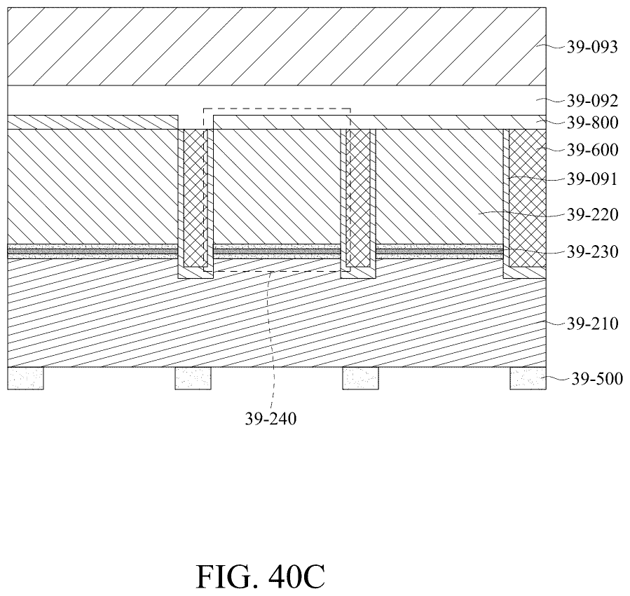

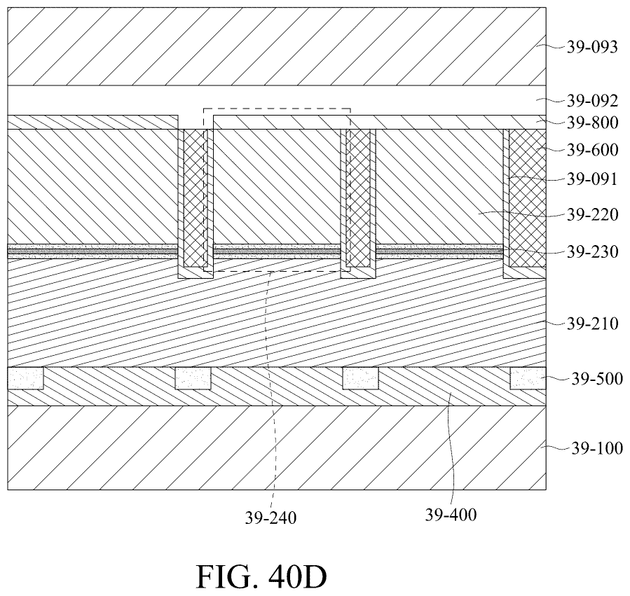

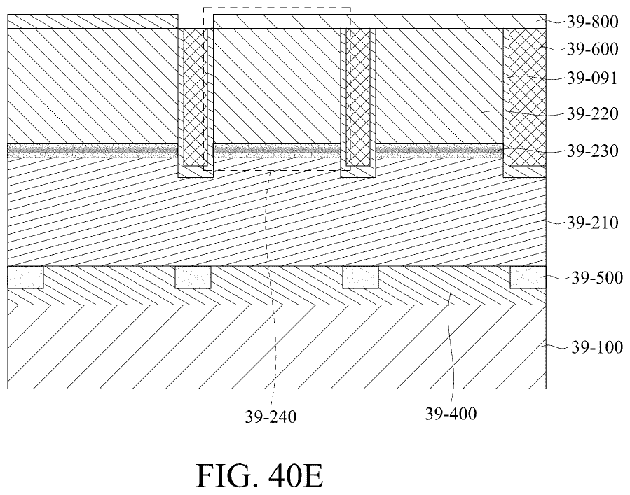

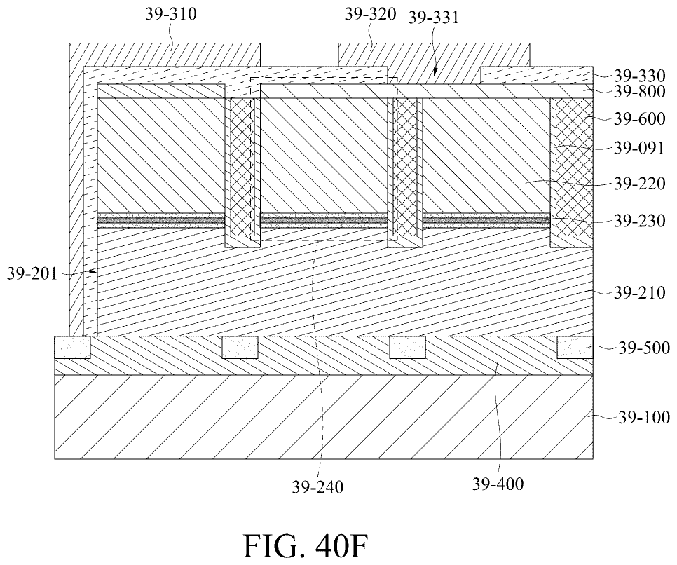

FIGS. 40A to 40F are schematic cross-sectional views illustrating multiple steps of a fabrication process of a semiconductor laser (e.g., but not limited to, the semiconductor laser 39-000 shown in FIG. 39) according to some embodiments of the present disclosure.

First, please refer to FIG. 40A, an epitaxial wafer is provided. The epitaxial wafer comprises a semiconductor stack layer 39-200 disposed on a base layer 39-090. The semiconductor stack layer 39-200 sequentially comprises a first type semiconductor layer 39-210, an active structure 39-230, and a second type semiconductor layer 39-220 are disposed on the base layer 39-090.

Next, please continue to refer to FIG. 40A, an etching process is performed on the epitaxial wafer using a mask with a specific pattern to etch and remove portions of the first type semiconductor layer 39-210, portions of the active structure 39-230, and portions of the second type semiconductor layer 39-220, thereby exposing a portion of the first type semiconductor layer 39-210. As a result, a plurality of columnar structures 39-240 is formed on the side of the epitaxial wafer with the second type semiconductor layer 39-220.

Next, please continue to refer to FIG. 40A, a protective layer 39-091 is disposed to cover the surfaces and sidewalls of the columnar structures 39-240, and portions of the protective layer 39-091 on the surfaces of the columnar structures 39-240 is removed to expose the second type semiconductor layer 39-220, wherein the material of the protective layer 39-091 may be an insulating material, including but not limited to silicon oxide and silicon nitride.

Then, please continue to refer to FIG. 40A, a non-conductive material is filled into the trenches between the columnar structures 39-240 to form an insulating structure 39-600 to planarize the epitaxial wafer, such that the surface of the insulating structure 39-600 is substantially coplanar with the surfaces of the columnar structures 39-240. For example, the non-conductive material may be B-staged bisbenzocyclobutene (BCB) or photoresist, but is not limited thereto. In addition, in some embodiments, after filling the non-conductive material into the trenches of the epitaxial wafer, a chemical mechanical polishing (CMP) process or an etching process may be further performed to make the surface of the epitaxial wafer flatter.

Then, please continue to refer to FIG. 40A, a mask with a specific pattern is used to form at least one second conductive structure 39-800 on the insulating structure 39-600 and the columnar structures 39-240. In some embodiments, the second conductive structure 39-800 is electrically connected to the second type semiconductor layer 39-220 of the plurality of columnar structures 39-240.

Then, please refer to FIG. 40B, the epitaxial wafer with the columnar structures 39-240 and the insulating structure 39-600 formed thereon is bonded to a temporary substrate 39-093 by a bonding layer 39-092, and the base layer 39-090 is removed to expose the first type semiconductor layer 39-210. In some embodiments, an etching stop layer (not shown in the figure) is disposed between the first type semiconductor layer 39-210 and the base layer 39-090. After removing the base layer 39-090, the etching stop layer is further removed to expose the first type semiconductor layer 39-210.

Then, please refer to FIG. 40C, a mask with a specific pattern is used to form a plurality of first conductive structures 39-500 corresponding to the insulating structure 39-600 on the first type semiconductor layer 39-210.

Next, please refer to FIG. 40D, a light-transmissive bonding layer 39-400 is disposed on the first type semiconductor layer 39-210, and the epitaxial wafer with the plurality of first conductive structures 39-500 formed thereon is bonded to a transparent substrate 39-100 by the light-transmissive bonding layer 39-400. In this embodiment, the transparent substrate 39-100 and the light-transmissive bonding layer 39-400 are materials having high transmittance to the light emitted from the active structure 39-230, wherein the transparent substrate 39-100 may be, for example, sapphire having a transmittance greater than 80%, but is not limited thereto. In some embodiments, the light-transmissive bonding layer 39-400 may also be a conductive material layer.

Then, please refer to FIG. 40E, the temporary substrate 39-093 and the bonding layer 39-092 are removed. In this embodiment, the temporary substrate 39-093 is removed by an etching process, but is not limited thereto.

Next, please refer to FIG. 40F, an etching process is performed on the epitaxial wafer using a mask with a specific pattern to etch and remove a portion of the semiconductor stack layer 39-200 and expose portions of the first conductive structures 39-500, thereby forming a mesa structure of the semiconductor stack layer 39-200 and defining sidewalls 39-201 of the semiconductor stack layer 39-200.

Next, referring to FIG. 40F, an passivation layer 39-330 is disposed to cover the mesa structure and the sidewalls 39-201 of the semiconductor stack layer 39-200. Further, an opening 39-331 is formed in the passivation layer 39-330 to expose portions of the second conductive structures 39-800.

Next, please referring to FIG. 40F, a second electrode structure 39-320 is disposed on the passivation layer 39-330 and covers the opening 39-331, so that the second electrode structure 39-320 is electrically connected to the second type semiconductor layer 39-220 through the second conductive structures 39-800. In addition, a first electrode structure 39-310 is formed on the mesa structure and extends over surfaces of the passivation layer 39-330 formed on the sidewalls 39-201 of the semiconductor stack layer 39-200 and the exposed first conductive structures 39-500, so that the first electrode structure 39-310 is electrically connected to the first type semiconductor layer 39-210 through the first conductive structures 39-500. The first electrode structure 39-310 extends from the side of the second type semiconductor layer 39-220 to the side of the first type semiconductor layer 39-210, and the distribution range of the first electrode structure 39-310 is increased by covering the sidewalls 39-201 of the semiconductor stack layer 39-200.

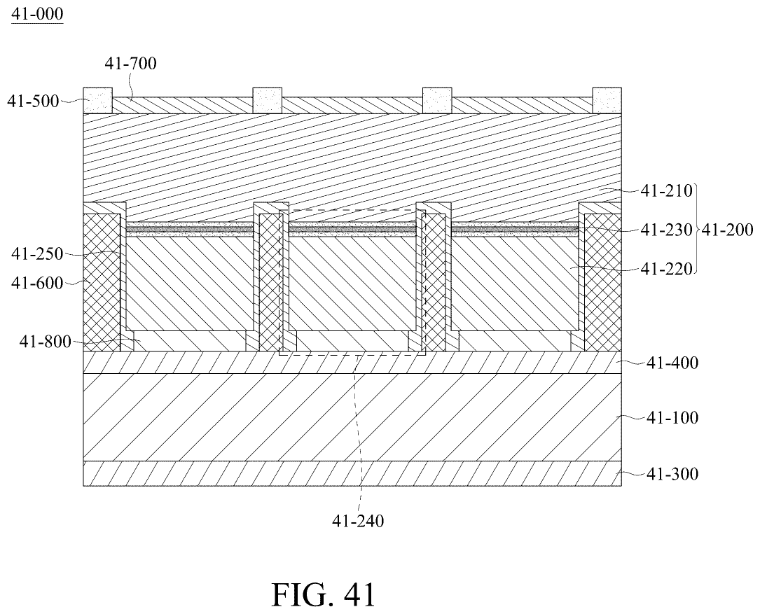

FIG. 41 is a schematic cross-sectional view of a semiconductor laser 41-000 in accordance with some embodiments of the present disclosure.

In some embodiments, as shown in FIG. 41, the semiconductor laser 41-000 comprise a conductive substrate 41-100, a semiconductor stack layer 41-200, a contact electrode layer 41-300, a metal bonding layer 41-400, a plurality of first conductive structures 41-500, a plurality of insulating structures 41-600, a plurality of anti-reflection structures 41-700, and a plurality of second conductive structures 41-800. The semiconductor stack layer 41-200 is disposed on the conductive substrate 41-100, wherein the semiconductor stack layer 41-200 comprises a first type semiconductor layer 41-210, a second type semiconductor layer 41-220, and an active structure 41-230. The active structure 41-230 is disposed between the first type semiconductor layer 41-210 and the second type semiconductor layer 41-220. The contact electrode layer 41-300 is disposed on a side of the conductive substrate 41-100 opposite to the semiconductor stack layer 41-200. The metal bonding layer 41-400 is disposed between the conductive substrate 41-100 and the second type semiconductor layer 41-220 of the semiconductor stack layer 41-200. The plurality of second conductive structures 41-800 are disposed between the metal bonding layer 41-400 and the second type semiconductor layer 41-220 of the semiconductor stack layer 41-200. The plurality of insulating structures 41-600 extend from the metal bonding layer 41-400, pass through the plurality of second conductive structures 41-800, the second type semiconductor layer 41-220, and the active structure 41-230, and extend to at least a portion of the first type semiconductor layer 41-210. As a result, the second type semiconductor layer 41-220, the active structure 41-230, and the portion of the first type semiconductor layer 41-210 are defined as a plurality of columnar structures 41-240. The plurality of anti-reflection structures 41-700 are disposed on the side of the first type semiconductor layer 41-210 of the semiconductor stack layer 41-200 opposite to the metal bonding layer 41-400 and correspond to the plurality of columnar structures 41-240. The plurality of first conductive structures 41-500 are disposed on the side of the first type semiconductor layer 41-210 of the semiconductor stack layer 41-200 opposite to the metal bonding layer 41-400, wherein the plurality of first conductive structures 41-500 are disposed between the plurality of anti-reflection structures 41-700 and correspond to the plurality of insulating structures 41-600.

Referring to FIG. 41, in some embodiments, in order to reduce the possibility of current leakage in subsequent semiconductor laser products, a protection layer 41-250 may be formed by an atomic layer deposition (ALD) process after forming the columnar structures 41-240 to cover the surfaces and sidewalls of the columnar structures 41-240. Compared to the protection layer 41-250 formed by chemical vapor deposition (CVD) or physical vapor deposition (PVD), the protection layer 41-250 formed by the ALD process is denser, which in turn can reduce the possibility of current leakage.

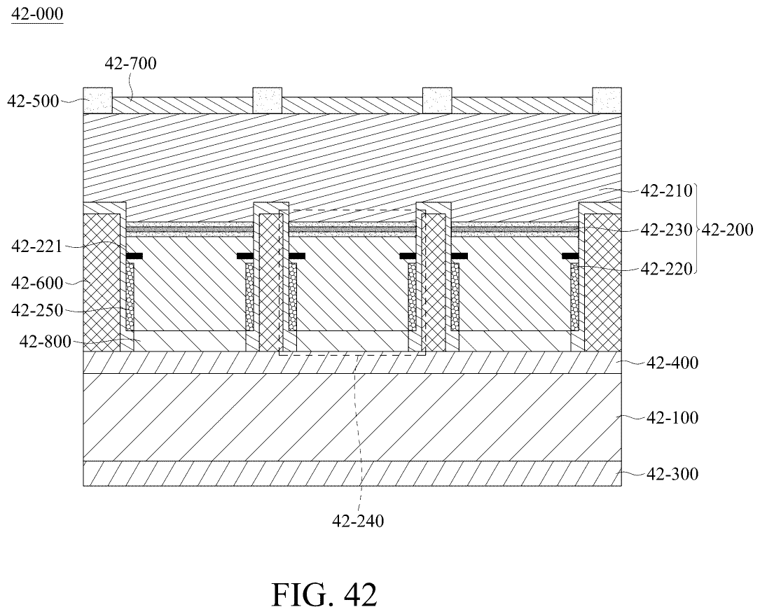

FIG. 42 is a schematic cross-sectional view of a semiconductor laser 42-000 in accordance with some embodiments of the present invention.

In some embodiments, as shown in FIG. 42, the semiconductor laser 42-000 comprises a conductive substrate 42-100, a semiconductor stack layer 42-200, a contact electrode layer 42-300, a metal bonding layer 42-400, a plurality of first conductive structures 42-500, a plurality of insulating structures 42-600, a plurality of anti-reflection structures 42-700, and a plurality of second conductive structures 42-800. The semiconductor stack layer 42-200 is disposed on the conductive substrate 42-100, wherein the semiconductor stack layer 42-200 comprises a first type semiconductor layer 42-210, a second type semiconductor layer 42-220, and an active structure 42-230. The active structure 42-230 is disposed between the first type semiconductor layer 42-210 and the second type semiconductor layer 42-220. The contact electrode layer 42-300 is disposed on a side of the conductive substrate 42-100 opposite to the semiconductor stack layer 42-200. The metal bonding layer 42-400 is disposed between the conductive substrate 42-100 and the second type semiconductor layer 42-220 of the semiconductor stack layer 42-200. The plurality of second conductive structures 42-800 are disposed between the metal bonding layer 42-400 and the second type semiconductor layer 42-220 of the semiconductor stack layer 42-200. The plurality of insulating structures 42-600 extend from the metal bonding layer 42-400, pass through the plurality of second conductive structures 42-800, the second type semiconductor layer 42-220, and the active structure 42-230, and extend to at least a portion of the first type semiconductor layer 42-210, thereby the second type semiconductor layer 42-220 and the active structure 42-230 are defined as a plurality of columnar structures 42-240. The plurality of anti-reflection structures 42-700 are disposed on the side of the first type semiconductor layer 42-210 of the semiconductor stack layer 42-200 opposite to the metal bonding layer 42-400 and correspond to the plurality of columnar structures 42-240. The plurality of first conductive structures 42-500 are disposed on the side of the first type semiconductor layer 42-210 of the semiconductor stack layer 42-200 opposite to the metal bonding layer 42-400, wherein the plurality of first conductive structures 42-500 are disposed between the plurality of anti-reflection structures 42-700 and correspond to the plurality of insulating structures 42-600.

Referring to FIG. 42, in other embodiments, after forming the columnar structures 42-240, a wet oxidation process can also be used to oxidize the sidewalls of the semiconductor stack layer 42-200. The exposed AlGaAs on the sidewalls of the semiconductor stack layer 42-200 is oxidized into an aluminum oxide layer after the oxidation, thereby reducing leakage current. In some embodiments, the second type semiconductor layer 42-220 comprises an AlGaAs layer with a higher aluminum composition, and after the wet oxidation process, a longer aluminum oxide layer 42-221 is formed that extends into the columnar structures.

After the wet oxidation process, a protection layer 42-250 can be further disposed on the surfaces and sidewalls of the columnar structures 42-240, and the formation of the protection layer 42-250 can adopt CVD, PVD, or ALD.

In some embodiments, an optoelectronic device is provided. By keeping the light emitting element constantly on and modulating the switching frequency of the switching unit with the modulation functional block, the light emitted by the optoelectronic device can correspond to high-frequency applications.

In some embodiments, the light emitted by the light emitting element may be further guided to the switching unit through a waveguide unit.

Accordingly, by integrating the components of the optoelectronic device according to some embodiments, the overall size of the optoelectronic device may be reduced, thereby enhancing the application possibilities and convenience of the optoelectronic device.

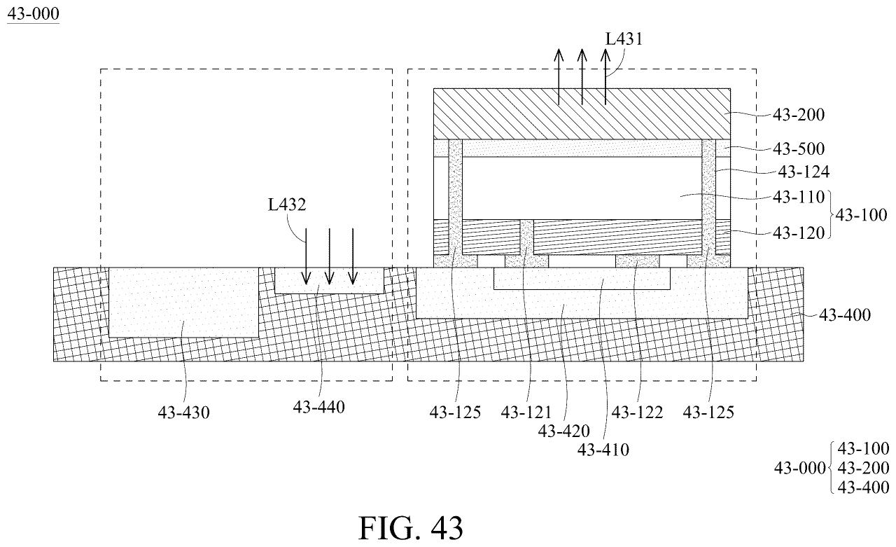

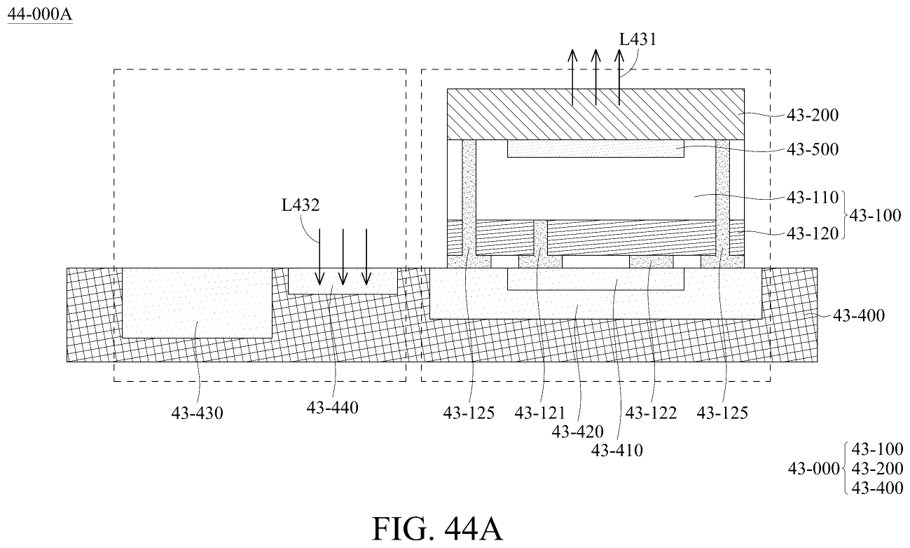

FIG. 43 is a schematic cross-sectional view of an optoelectronic device 43-000 according to some embodiments of the disclosure.

According to some embodiments, as shown in FIG. 43, the optoelectronic device 43-000 comprises a light emitting unit 43-100, a switching unit 43-200, a light receiving element, and a driver chip 43-400. The light emitting unit 43-100 comprises a substrate 43-110 and a light emitting element 43-120 disposed on one side of the substrate 43-110, wherein the light emitting element 43-120 is configured to provide a light beam L431.

The switching unit 43-200 is disposed in the light exit path of the light beam L431, wherein the switching unit 43-200 is configured to allow the light beam L431 to pass through the switching unit 43-200 or to be blocked by the switching unit 43-200. The light receiving element is configured to receive a reflected light beam L432, which is the light beam L431 reflected by an object after being irradiated onto the object. The driver chip 43-400 comprises a drive functional block 43-410, a modulation functional block 43-420, and a signal processing functional block 43-430, which are signal-connected to each other.

The drive functional block 43-410 is electrically connected to the light emitting element 43-120 and the light receiving element, and the modulation functional block 43-420 is electrically connected to the switching unit 43-200 to modulate the switching frequency of the switching unit 43-200. Additionally, the signal processing functional block 43-430 is signal-connected to the light receiving element and is configured to analyze the reflected light beam L432.

In some embodiments, the light emitting element 43-120 is a vertical cavity surface emitting laser (VCSEL), as shown in FIG. 43.

As shown in FIG. 43, in some embodiments, the optoelectronic device 43-000 further comprises an optical layer 43-500 disposed on the light exit path. Specifically, the optical layer 43-500 may comprise a diffraction optics (DOE) structure, a micro lens array structure, a metasurface structure, a metalens structure, or a combination thereof. Among them, the metasurface structure is a structure comprising a plurality of periodically arranged nanostructures.

As shown in FIG. 43, in some embodiments, the light receiving element can be integrated into the driver chip 43-400, such as in the form of a light receiving functional block 43-440. In other words, the driver chip 43-400 may further comprise a light receiving functional block 43-440.

As shown in FIG. 43, in some embodiments, the substrate 43-110 is a transparent substrate, the optical layer 43-500 is disposed on the transparent substrate, and the switching unit 43-200 is disposed on the optical layer 43-500.

Specifically, as shown in FIG. 43, the driver chip 43-400 of the optoelectronic device 43-000 further comprises a light emitting region (corresponding to the dashed box on the right side of FIG. 43) and a light receiving region (corresponding to the dashed box on the left side of FIG. 43). The switching unit 43-200, the optical layer 43-500, the substrate 43-110, the light emitting element 43-120, the drive functional block 43-410, and the modulation functional block 43-420 are disposed in the light emitting region, while the signal processing functional block 43-430 and the light receiving functional block 43-440 are disposed in the light receiving region.

Please continue to refer to FIG. 43, in some embodiments, the positive electrode and the negative electrode of the light emitting element 43-120 are electrically connected to the drive functional block 43-410 by a first conductive structure 43-121 and a second conductive structure 43-122, respectively.

In some embodiments, the switching unit 43-200 is electrically connected to the modulation functional block 43-420 by third conductive structures 43-125. The light emitting element 43-120 and the transparent substrate have a through-hole structure 43-124, t. The inner wall of the through-hole structure 43-124 is insulated, and the third conductive structure 43-125 extends through the through-hole structure 43-124 so that the switching unit 43-200 is electrically connected to the modulation functional block 43-420.

Similarly, in some embodiments, the light emitting element 43-120 comprises a through-hole structure (not shown in the figure), the inner wall of the through-hole structure is insulated, and the first conductive structure 43-121 extends through the through-hole structure so that the positive electrode structure and the negative electrode structure of the light emitting element 43-120 are electrically connected to the drive functional block 43-410.

It should be noted that in the following embodiments, the optoelectronic device may also comprises a through-hole structure; however, for the sake of illustration clarity, the through-hole structure is not specifically shown in the optoelectronic devices of the following embodiments.

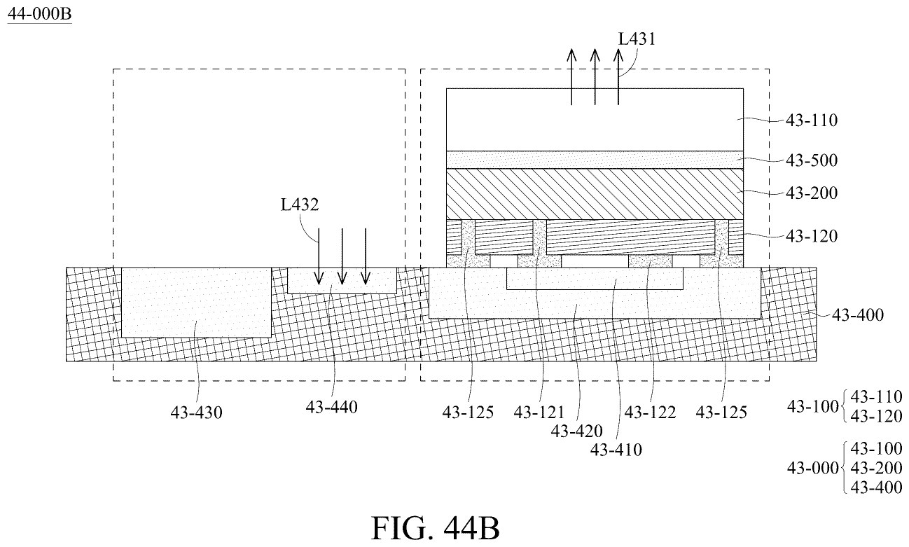

Please refer to FIG. 44A, which is a schematic cross-sectional view of an optoelectronic device 44-000A according to some embodiments of the disclosure.

As shown in the optoelectronic device 44-000A of FIG. 44A, in some embodiments, the substrate 43-110 is a transparent substrate, and a portion of the transparent substrate corresponding to the light emitting region of the light emitting element 43-120 comprises the optical layer 43-500, while the switching unit 43-200 is disposed on the transparent substrate.

In other words, in some embodiments, the optical layer 43-500 is part of the transparent substrate; specifically, the optical layer 43-500 can be fabricated by patterning a portion of the transparent substrate corresponding to the light emitting region of the light emitting element 43-120.

Please refer to FIG. 44B, which is a schematic cross-sectional view of an optoelectronic device 44-000B according to some embodiments of the disclosure.

As shown in the optoelectronic device 44-000B of FIG. 44B, in some embodiments, the switching unit 43-200 is disposed on the light emitting element 43-120, the substrate 43-110 is a transparent substrate, and the optical layer 43-500 is disposed between the switching unit 43-200 and the transparent substrate.

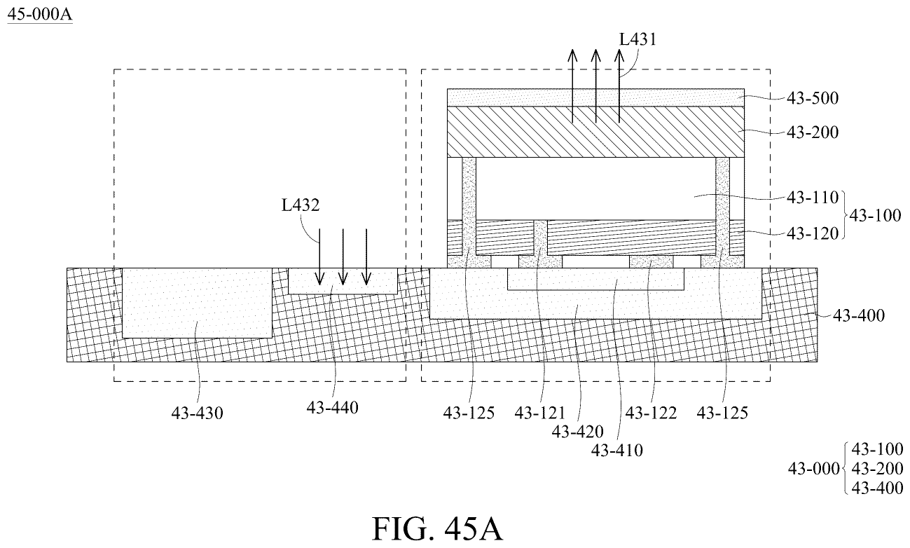

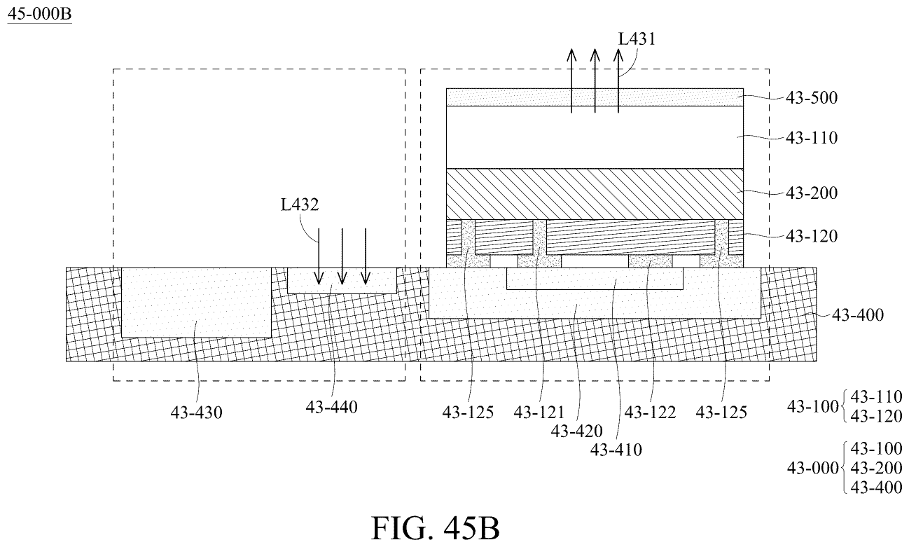

Please refer to FIG. 45A, which is a schematic cross-sectional view of an optoelectronic device 45-000A according to some embodiments of the disclosure.

As shown in the optoelectronic device 45-000A of FIG. 45A, in some embodiments, the substrate 43-110 is a transparent substrate, the switching unit 43-200 is disposed on the transparent substrate, and the optical layer 43-500 is disposed on the switching unit 43-200.

Please refer to FIG. 45B, which is a schematic cross-sectional view of an optoelectronic device 45-000B according to some embodiments of the disclosure.

As shown in the optoelectronic device 45-000B of FIG. 45B, in some embodiments, the switching unit 43-200 is disposed on the light emitting element 43-120, the substrate 43-110 is a transparent substrate, and the transparent substrate is disposed between the switching unit 43-200 and the optical layer 43-500.

It should be noted that in some embodiments, the relative positions of the switching unit 43-200, the light emitting element 43-120, and the substrate 43-110 may also be adjusted, and are not limited to the embodiments illustrated in the figures.

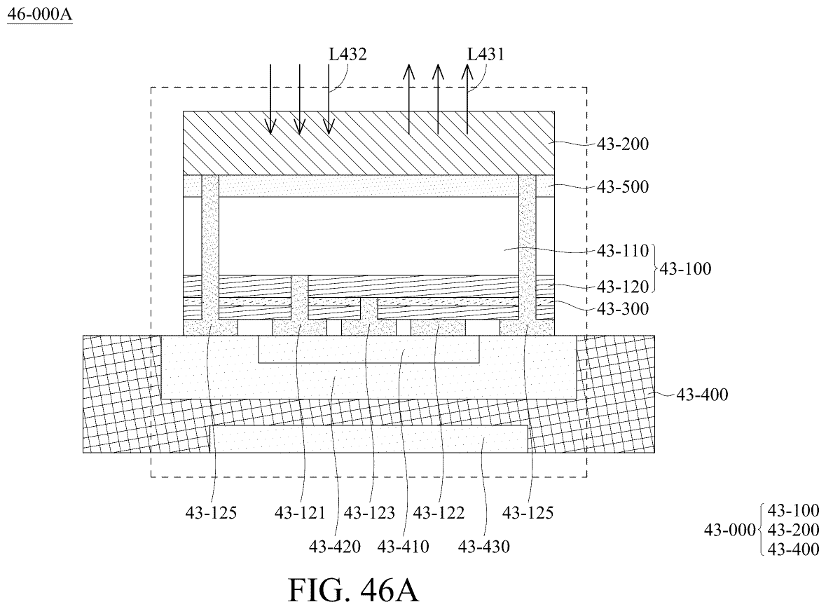

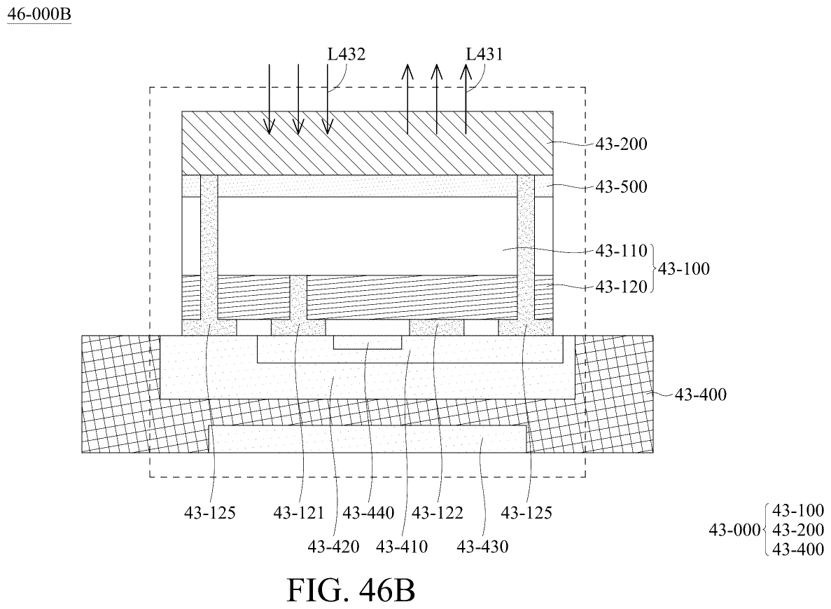

Please refer to FIG. 46A, which is a schematic cross-sectional view of an optoelectronic device 46-000A according to some embodiments of the disclosure.

As shown in the optoelectronic device 46-000A of FIG. 46A, in some embodiments, the substrate 43-110 is a transparent substrate, the optical layer 43-500 is disposed on the transparent substrate, the switching unit 43-200 is disposed on the optical layer 43-500, and the light receiving element 43-300 is disposed on a side of the light emitting element 43-120 opposite to the transparent substrate. It should be noted that in this embodiment, the light emitting element 43-120 and the light receiving element 43-300 share a conductive structure as a common electrode. Specifically, the positive electrode and the negative electrode of the light emitting element 43-120 are electrically connected to the drive functional block 43-410 by a first conductive structure 43-121 and common conductive structure 43-123, respectively. The positive electrode and the negative electrode of the light receiving element 43-300 are electrically connected to the drive functional block 43-410 by the first conductive structure 43-121 and a third conductive structure 43-123, respectively, so that the light emitting element 43-120 and the light receiving element 43-300 constitute a common electrode design. Thereby, according to this embodiment, the purpose of address control of the optoelectronic device 46-000A can be achieved through the design of sharing a common electrode by the light emitting element 43-120 and the light receiving element 43-300.

As shown in FIG. 46A, in some embodiments, the light emitting element 43-120, the light receiving element 43-300, the drive functional block 43-410, and the modulation functional block 43-420 are disposed on the same side of the driver chip 43-400, while the signal processing functional block 43-430 is disposed on the opposite side of the driver chip 43-400. In some embodiments, the aforementioned components are not necessarily disposed on the same side of the driving chip 43-400, but may also be disposed on opposite sides of the driving chip 43-400, thereby realizing a three-dimensional integrated circuit (3DIC) architecture. For example, the above-mentioned components can be manufactured through appropriate processes and then three-dimensionally stacked. For example, the modulation functional block 43-420 or the driving functional block 43-410 may be corresponded to the light emitting element 43-120 or the light receiving element 43-300 (in other words, the modulating functional block 43-420 (or the driving function Blocks 43-410) and the light-emitting elements 43-120 (or the light-receiving elements 43-300) are disposed on opposite sides of the driving chip 43-400, and are connected to the aforementioned electrode structures via through holes. The locations of different functional blocks are not particularly limited.

Please refer to FIG. 46B, which is a schematic cross-sectional view of an optoelectronic device 46-000B according to some embodiments of the disclosure.

As shown in the optoelectronic device 46-000B of FIG. 46B, in some embodiments, the driver chip 43-400 further comprises a light receiving functional block 43-440. The substrate 43-110 is a transparent substrate, the optical layer 43-500 is disposed on the transparent substrate, the switching unit 43-200 is disposed on the optical layer 43-500, and the light receiving functional block 43-440 corresponds to the light emitting region of the light emitting element 43-120. In other words, compared with the embodiment shown in FIG. 46A, the embodiment shown in FIG. 46B does not comprise a light receiving element that shares an common electrode with the light emitting element 43-120, but further comprises a light receiving functional block 43-440 on the driver chip 43-400. Thereby, the light receiving functional block 43-440 can also receive the aforementioned reflected light beam L432 and transform as electrical signal then provide it to the signal processing functional block 43-430 for analysis. In this embodiment, the signal processing functional block 43-430 is disposed on a side of the driver chip 43-400 opposite to the light receiving functional block 43-440.

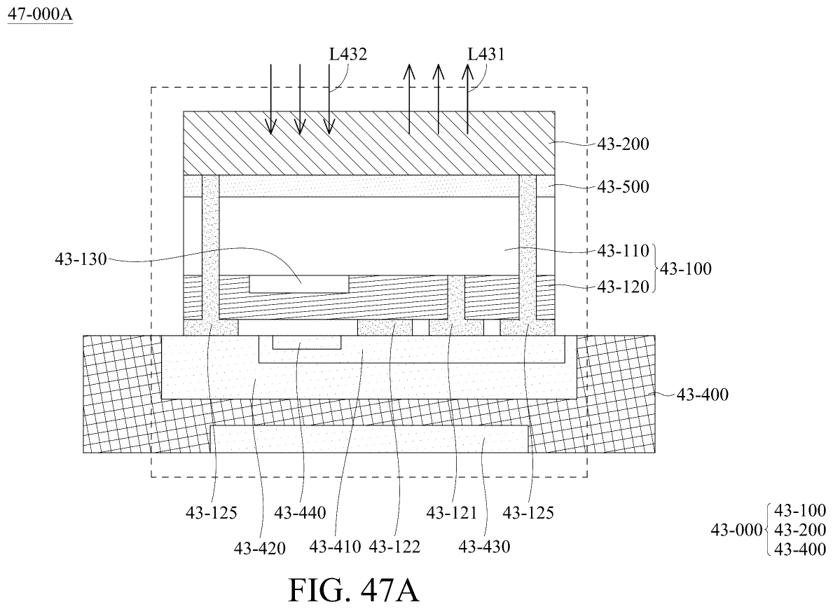

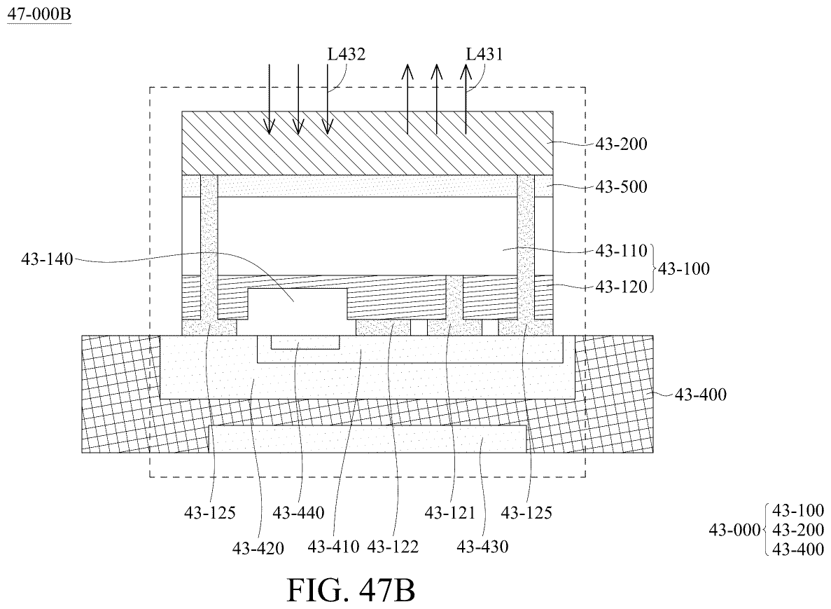

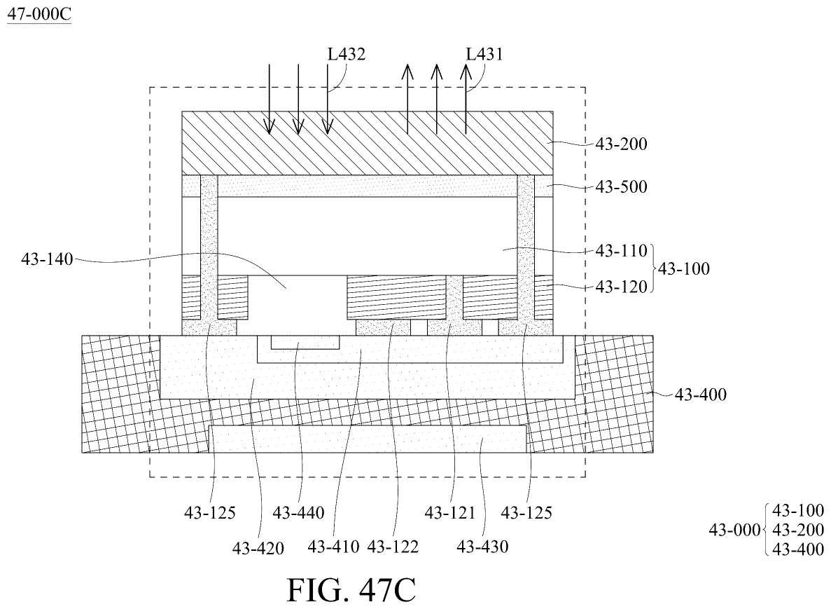

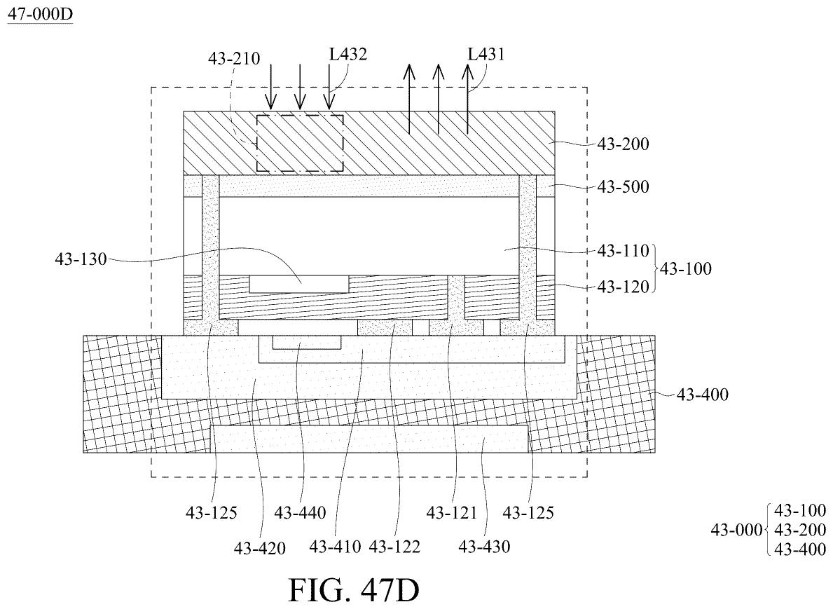

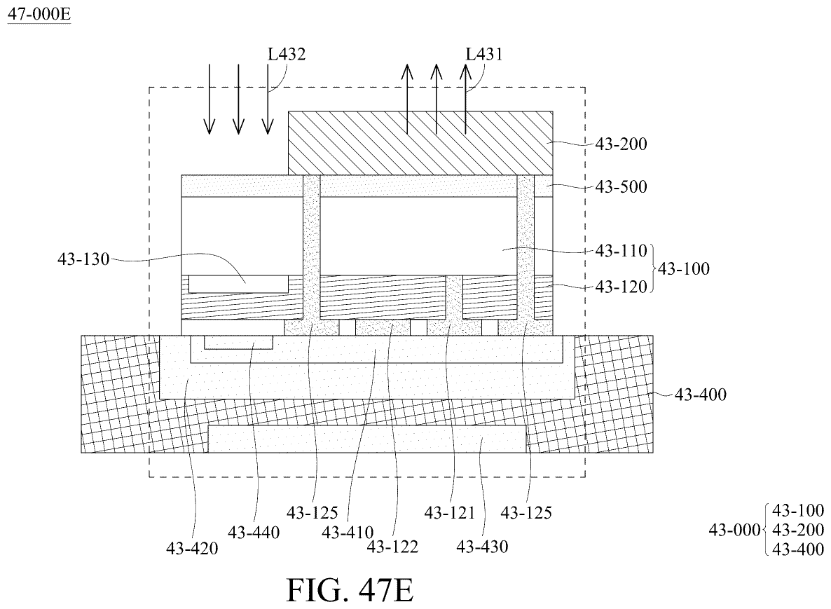

Please refer to FIG. 47A, which is a schematic cross-sectional view of an optoelectronic device 47-000A according to some embodiments of the disclosure.

As shown in the optoelectronic device 47-000A of FIG. 47A, in some embodiments, the driver chip 43-400 further comprises a light receiving functional block 43-440. The substrate 43-110 is a transparent substrate, the optical layer 43-500 is disposed on the transparent substrate, the switching unit 43-200 is disposed on the optical layer 43-500, and the light receiving functional block 43-440 does not completely overlap with the light emitting region of the light emitting element 43-120.

Specifically, in the embodiment shown in FIG. 47A, a part of the semiconductor stack of the light emitting element 43-120 may be removed by a semiconductor process to increase the light transmittance of the portion 43-130, and the portion 43-130 is disposed between the light emitting element 43-120 and the transparent substrate 43-110, so that the reflected light beam L432 reflected by the object can be received by the light receiving functional block 43-440 through the portion 43-130 of the light emitting element 43-120, thereby enhancing the intensity of the received signal.

As shown in FIG. 47A, in some embodiments, the portion 43-130 of the light emitting element 43-120, after a part of the semiconductor stack thereof is removed by a semiconductor process, may be further filled with a transparent material to maintain the structural strength of the light emitting element 43-120, and the transparent material may be, for example, BCB, photoresist, silicon dioxide, but is not limited thereto.

Please refer to FIG. 47B, which is a schematic cross-sectional view of an optoelectronic device 47-000B according to some embodiments of the disclosure.

As shown in the optoelectronic device 47-000B of FIG. 47B, in some embodiments, a part of the semiconductor stack of the light emitting element 43-120 may be partially removed by a semiconductor process, and then a passivation layer 43-140 is used to cover the exposed surface and sidewall (not shown in the figure) of the semiconductor stack after etching.

Please refer to FIG. 47C, which is a schematic cross-sectional view of an optoelectronic device 47-000C according to some embodiments of the disclosure.

As shown in the optoelectronic device 47-000C of FIG. 47C, in some embodiments, a part of the semiconductor stack of the light emitting element 43-120 may removed all of the layers by a semiconductor process, and then a passivation layer 43-140 is used to cover the sidewall of the semiconductor stack and the surface of the substrate exposed after the etching (not shown).

Please refer to FIG. 47D, which is a schematic cross-sectional view of an optoelectronic device 47-000D according to some embodiments of the disclosure.

As shown in the optoelectronic device 47-000D of FIG. 47D, in some embodiments, the portion 43-130 of the semiconductor stack of the light emitting element 43-120, after a part thereof is removed by a semiconductor process, may be filled with a transparent material to maintain the structural strength of the light emitting element 43-120, and a portion of the switching unit 43-200 may be also removed by a semiconductor process to form a hollow region 43-210. A vertical projection of the hollow region 43-210 correspondingly covers the light receiving functional block 43-440.

Please refer to FIG. 47E, which is a schematic cross-sectional view of an optoelectronic device 47-000E according to some embodiments of the disclosure.

As shown in the optoelectronic device 47-000E of FIG. 47E, in some embodiments, the switching unit 43-200 of the light emitting element 43-120 is smaller than the transparent substrate, wherein the vertical projection area of the light receiving functional block 43-440 does not overlap the switching unit 43-200.

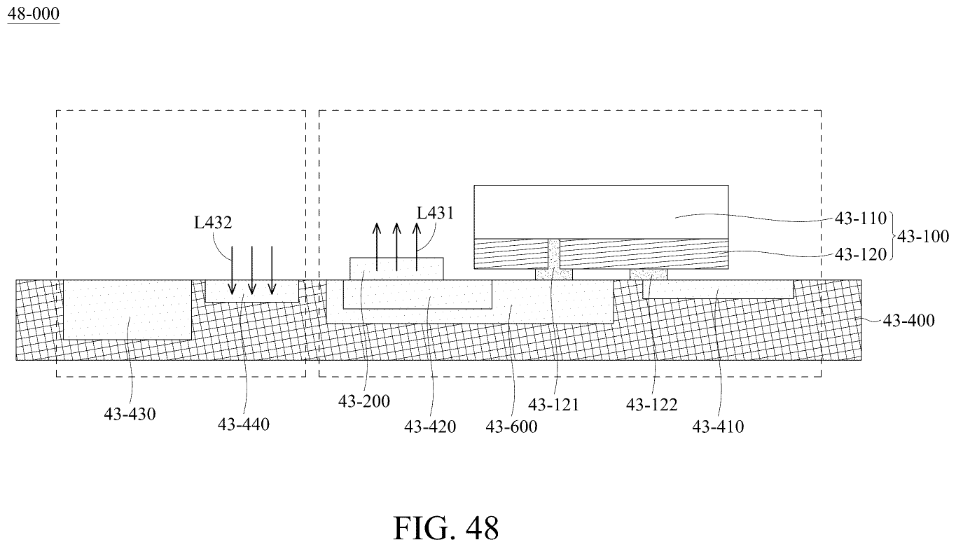

Please refer to FIG. 48, which is a schematic cross-sectional view of an optoelectronic device

As shown in FIG. 48, in some embodiments, the optoelectronic device 48-000 further comprises a waveguide unit 43-600. The waveguide unit 43-600 is disposed on the light exit path of the light beam L431 emitted by the light emitting element 43-120, and is configured to transmit the light beam L431 to the switching unit 43-200.

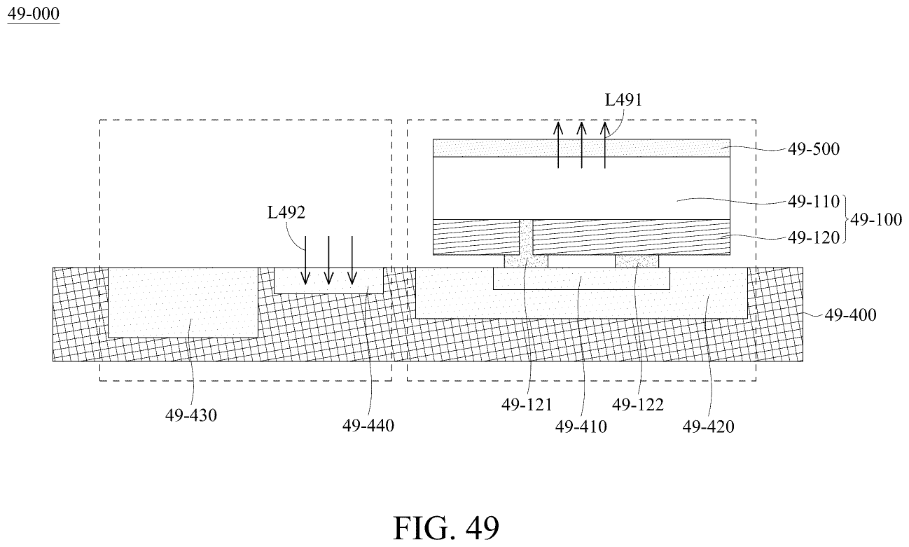

FIG. 49 is a schematic cross-sectional view of an optoelectronic device 49-000 according to some embodiments of the disclosure.

According to some embodiments, as shown in FIG. 49, an optoelectronic device 49-000 comprises a light emitting unit 49-100, a light receiving element, and a driver chip 49-400. The light emitting unit 49-100 comprises a substrate 49-110 and a light emitting element 49-120 disposed on one side of the substrate 49-110, wherein the light emitting element 49-120 is configured to provide a light beam L491.

The light receiving element is configured to receive a reflected light beam L492, which is the light beam L491 reflected by an object after being irradiated onto the object. The driver chip 49-400 comprises a drive functional block 49-410, a modulation functional block and a signal processing functional block 49-430 that are signal-connected to each other.

The drive functional block 49-410 is electrically connected to the light emitting element 49-120 and the light receiving element. The modulation functional block 49-420 is used to apply a signal to the driving power supply output by the driving functional block 49-410. The signal processing functional block 49-430 is signal-connected to the light receiving element and configured to analyze the reflected light beam L492.

Similarly, in some embodiments, the light emitting element 49-120 is a vertical cavity surface emitting laser (VCSEL), as shown in FIG. 49.

Likewise, as shown in FIG. 49, in some embodiments, the optoelectronic device 49-000 further includes an optical layer 49-500 disposed on the light exit path.

Similarly, as illustrated in FIG. 49, in some embodiments, the light receiving element can be integrated into the driver chip 49-400, for example, in the form of a light receiving functional block 49-440. In other words, the driver chip 49-400 may further comprise a light receiving functional block 49-440 in some embodiments.

As shown in FIG. 49, in some embodiments, the substrate 49-110 is a transparent substrate, and the optical layer 49-500 is disposed on the transparent substrate.

Specifically, as depicted in FIG. 49, the driver chip 49-400 of the optoelectronic device 49-000 further comprises a light emitting region (corresponding to the dashed box on the right side of FIG. 49) and a light receiving region (corresponding to the dashed box on the left side of FIG. 49). The optical layer 49-500, the substrate 49-110, the light emitting element 49-120, the modulation functional block 49-420, and the drive functional block 49-410 are disposed in the light emitting region, while the signal processing functional block 49-430 and the light receiving functional block 49-440 are disposed in the light receiving region.

Continuing to refer to FIG. 49, in some embodiments, the positive electrode and the negative electrode of the light emitting element 49-120 are electrically connected to the drive functional block 49-410 by a first conductive structure 49-121 and a second conductive structure 49-122, respectively.

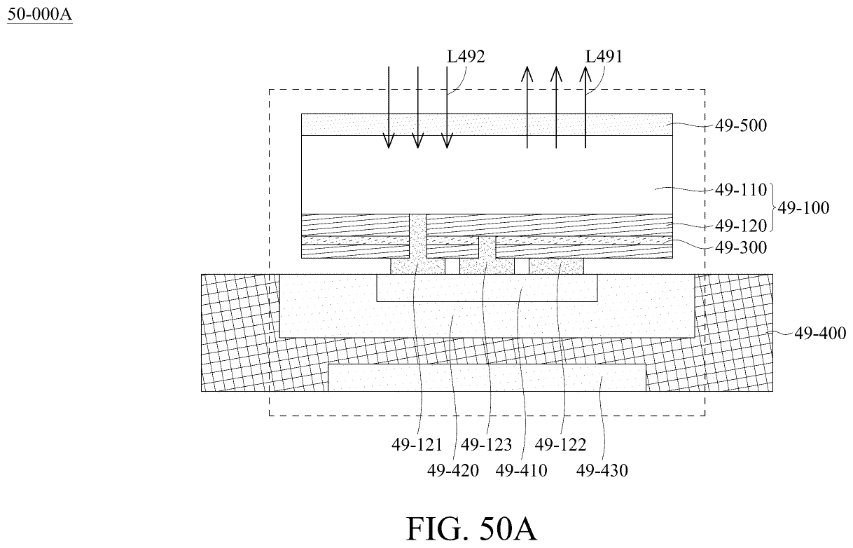

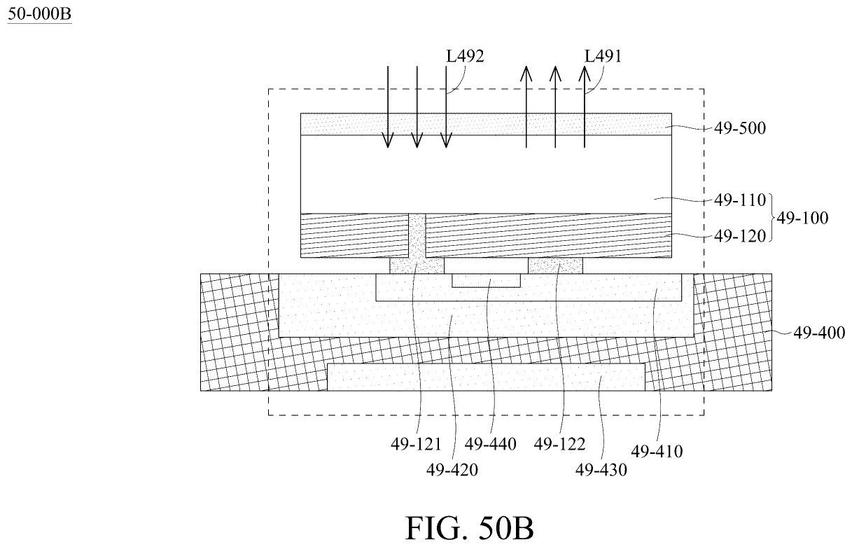

Please refer to FIG. 50A, which is a schematic cross-sectional view of an optoelectronic device 50-000A according to some embodiments of the disclosure.

As shown in the optoelectronic device 50-000A of FIG. 50A, in some embodiments, the substrate 49-110 is a transparent substrate, the optical layer 49-500 is disposed on the transparent substrate, and the light receiving element 49-300 is disposed on a side of the light emitting element 49-120 opposite to the transparent substrate. The light emitting element 49-120 and the light receiving element 49-300 share a common conductive structure 49-123 as a common electrode. Specifically, in this embodiment, the positive electrode and the negative electrode of the light emitting element 49-120 are electrically connected to the drive functional block 49-410 by a first conductive structure 49-121 and a common conductive structure 49-123, respectively. The positive electrode and the negative electrode of the light receiving element 49-300 are also electrically connected to the drive functional block 49-410 by the second conductive structure 49-122 and the common conductive structure 49-123, respectively, so that the light emitting element 49-120 and the light receiving element 49-300 constitute a common electrode design. As a result, according to this embodiment, the purpose of address control for the optoelectronic device 50-000A can be achieved through the design of the light emitting element 49-120 and the light receiving element 49-300 sharing a common electrode.

Please refer to FIG. 50B, which is a schematic cross-sectional view of an optoelectronic device 50-000B according to some embodiments of the disclosure.

As shown in the optoelectronic device 50-000B of FIG. 50B, in some embodiments, the driver chip 49-400 further comprises a light receiving functional block 49-440. The substrate 49-110 is a transparent substrate, the optical layer 49-500 is disposed on the transparent substrate, and the light receiving functional block 49-440 corresponds to the light emitting region of the light emitting element 49-120. In other words, compared with the embodiment shown in FIG. 50A, the embodiment shown in FIG. 50B does not comprise a light receiving element that shares an common electrode with the light emitting element 49-120, but further comprises a light receiving functional block 49-440 on the driver chip 49-400. Thereby, the light receiving functional block 49-440 can also receive the aforementioned reflected light beam L492 and transform it as electrical signal then provide it to the signal processing functional block 49-430 for analysis.

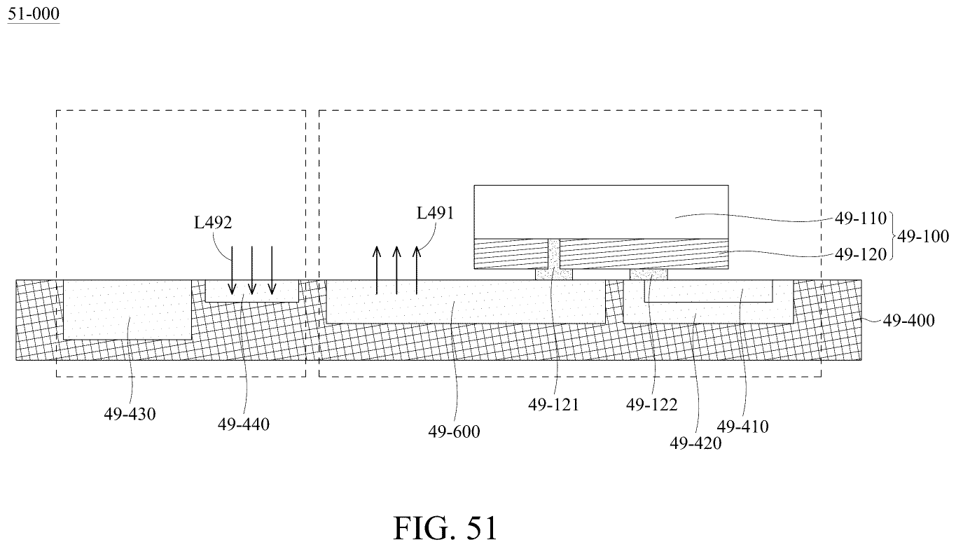

Please refer to FIG. 51, which is a schematic cross-sectional view of an optoelectronic device 51-000 according to some embodiments of the disclosure.

As shown in FIG. 51, in some embodiments, the optoelectronic device 51-000 further comprises a waveguide unit 49-600, and the waveguide unit 49-600 is disposed on the light exit path of the light beam L491 emitted by the light emitting element 49-120.

In some embodiments, the switching unit 43-200 of the optoelectronic device can be implemented through various optical switches. For example, the optical switch can be a microelectromechanical systems (MEMS) switch, a liquid crystal switch, an acousto-optic switch, a thermo-optic switch, a holographic switch, or a bubble switch, but is not limited thereto.

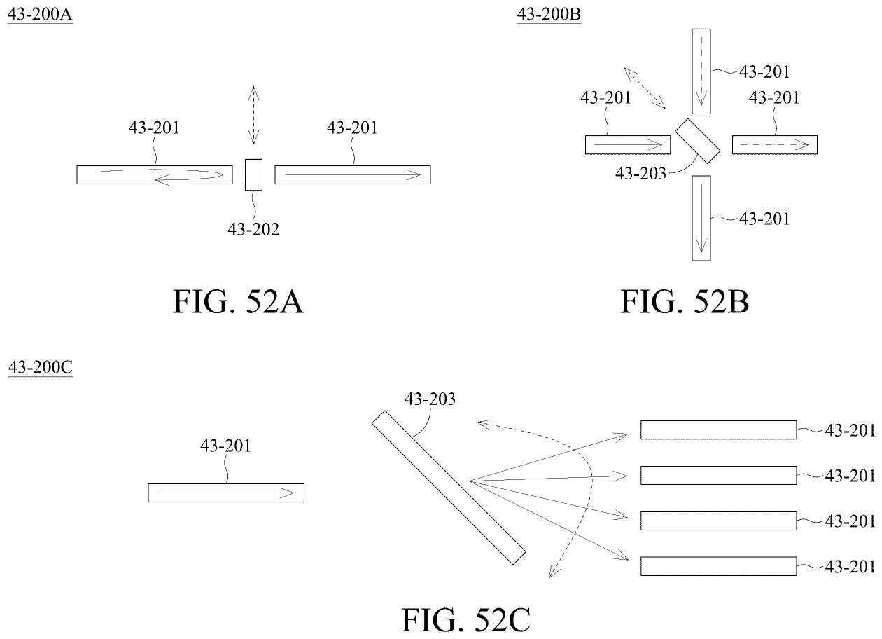

Please refer to FIGS. 52A to 52C, which respectively illustrate schematic diagrams of the switching unit 43-200 according to some embodiments. As shown in FIGS. 52A to 52C, in some embodiments, the switching unit 43-200 can be implemented as a MEMS switch.

Specifically, as shown in FIG. 52A, the switching unit 43-200A can be a one-to-one gate, and the switching unit 43-200A can be combined with a waveguide structure 43-201 so that light can pass through the switching unit 43-200A or be blocked by the switching unit 43-200A. More specifically, the position of the gate 43-202 can be controlled by MEMS to allow the light guided by the waveguide structure 43-201 to be blocked or not blocked by the gate 43-202. In some embodiments, as shown in FIG. 52B, the switching unit 43-200B can be a 2×2 switch. Similarly, the switching unit 43-200B can be combined with the waveguide structure 43-201 so that light can pass through the switching unit 43-200B or be blocked by the switching unit 43-200B. Specifically, the position of a reflector 43-203 can be controlled by MEMS, so that the light guided by the waveguide structure 43-201 can be reflected and blocked by the reflector 43-203 or not reflected and not blocked by the reflector 43-203. In some embodiments, as shown in FIG. 52C, the switching unit 43-200C can be a one-to-many switch; likewise, the switching unit 43-200C can be combined with the waveguide structure 43-201 so that light can pass through the switching unit 43-200C or be blocked by the switching unit 43-200C. Specifically, in some embodiments, a reflector 43-203 can be disposed on the MEMS structure, and the rotation of the reflector 43-203 can be controlled by MEMS, so that the light can pass through the switching unit 43-200C or be blocked by the switching unit 43-200C as the angle of the reflector 43-203 changes.

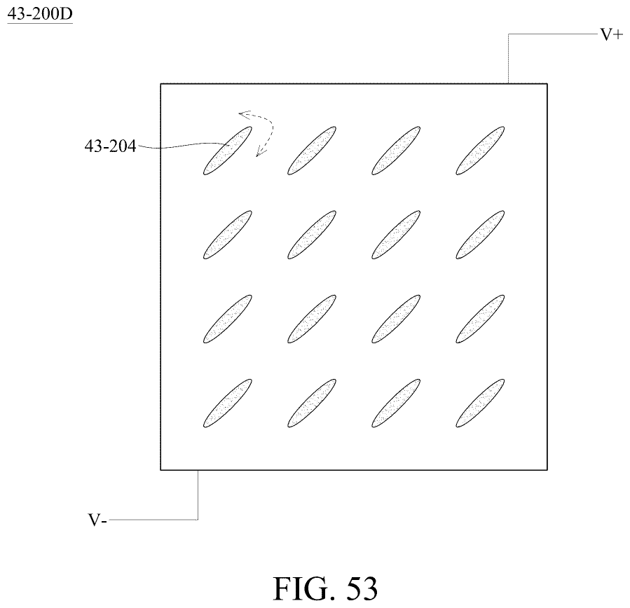

Please refer to FIG. 53, which is a schematic diagram of a switching unit 43-200D according to some embodiments. As shown in FIG. 53, in some embodiments, the switching unit 43-200D can be implemented as a liquid crystal switch. Specifically, as illustrated in FIG. 53, a voltage can be applied to cause the deflection of the liquid crystal molecular in the liquid crystal molecules 43-204, thereby allowing light to pass through the switching unit 43-200D or be blocked by the switching unit 43-200D.

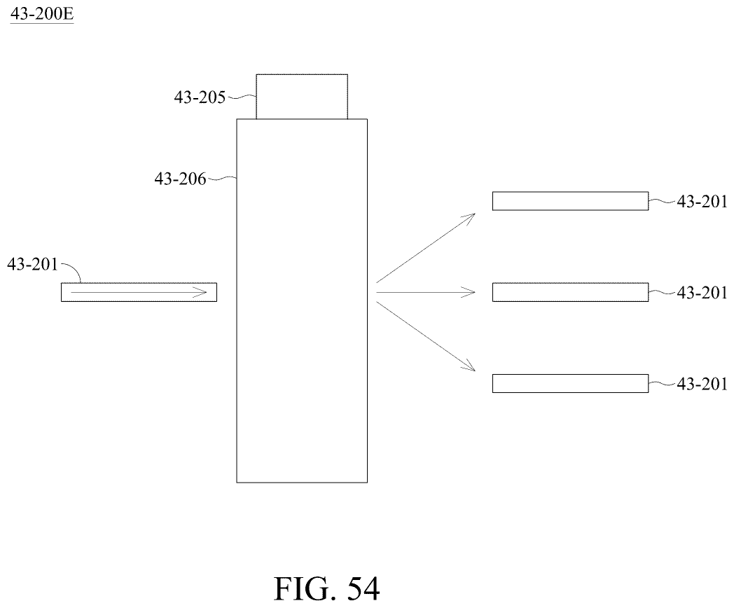

Please refer to FIG. 54, which is a schematic diagram of a switching unit 43-200E according to some embodiments. As shown in FIG. 54, in some embodiments, the switching unit 43-200E can be implemented as an acousto-optic switch. Specifically, the acousto-optic switch may comprise a sound wave generator 43-205 and a sound wave deflector 43-206. By adjusting the density of the sound waves generated by the sound wave generator 43-205, after the light is guided through the waveguide structure 43-201 and passes through the sound waves, the deflection angle can be varied so that the light can pass through the switching unit 43-200E or be blocked by the switching unit 43-200E.

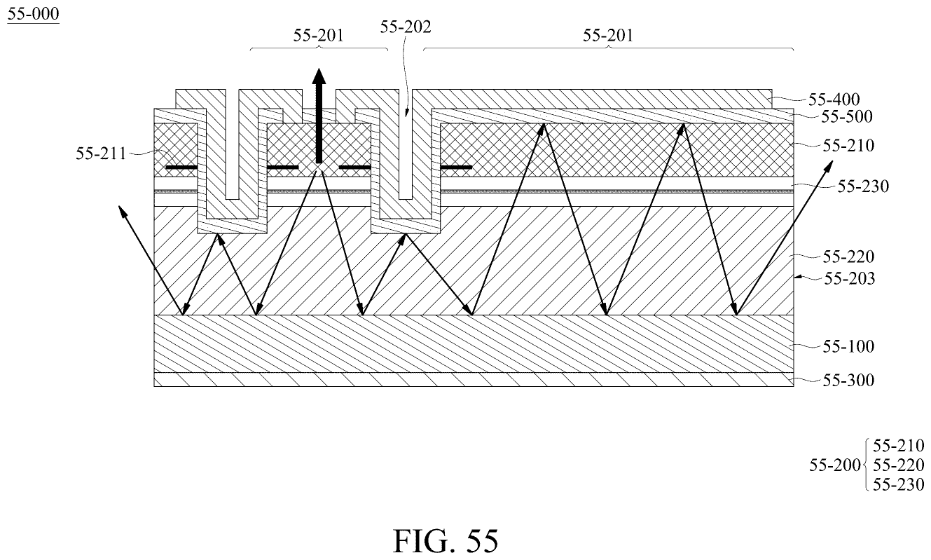

Please refer to FIG. 55, which is a schematic cross-sectional view of a semiconductor laser 55-000 known to the inventors.

As shown in FIG. 55, the semiconductor laser 55-000 known to the inventors comprises a conductive substrate 55-100, a semiconductor stack layer 55-200, a contact electrode layer 55-300, a conductive layer 55-400, and an passivation layer 55-500. The semiconductor stack layer 55-200 is disposed on the conductive substrate 55-100 and sequentially comprises, from top to bottom, a first type semiconductor layer 55-210, an active structure 55-230, and a second type semiconductor layer 55-220. A patterned semiconductor etching process is performed to remove portions of the first type semiconductor layer 55-210, portions of the active structure 55-230, and portions of the second type semiconductor layer 55-220 of the semiconductor stack layer 55-200, thereby exposing the second type semiconductor layer 55-220 and defining a plurality of mesa structures 55-201 separated by trenches 55-202.

The contact electrode layer 55-300 is disposed on a side of the conductive substrate 55-100 opposite to the semiconductor stack layer 55-200, and the contact electrode layer 55-300 is electrically connected to the second type semiconductor layer 55-220 of the semiconductor stack layer 55-200 through the conductive substrate 55-100.

The conductive layer 55-400 is disposed on the mesa structures 55-201 and extends through the trenches 55-202 to the first type semiconductor layer 55-210, wherein the conductive layer 55-400 is electrically connected to the first type semiconductor layer 55-210 of the semiconductor stack layer 55-200.

The passivation layer 55-500 is disposed between the conductive layer and the mesa structures and between the conductive layer 55-400 and the trenches 55-202. The passivation layer 55-500 only covers the surface of the semiconductor stack layer 55-200, such that the sidewalls 55-203 of the semiconductor stack layer 55-200 are exposed.

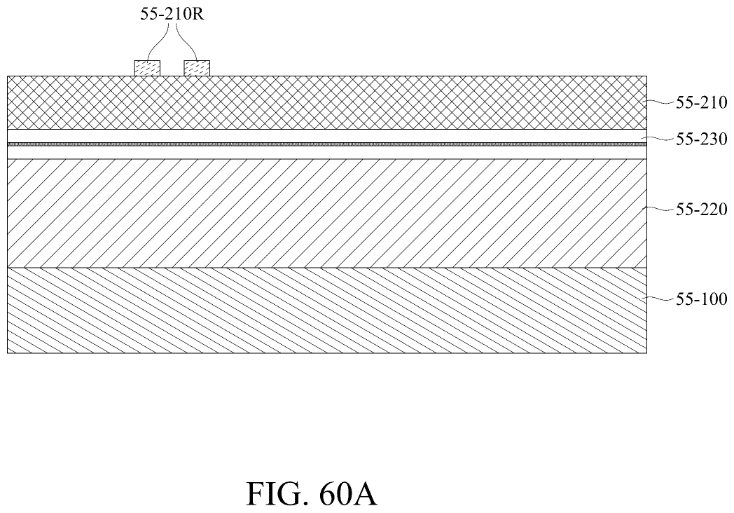

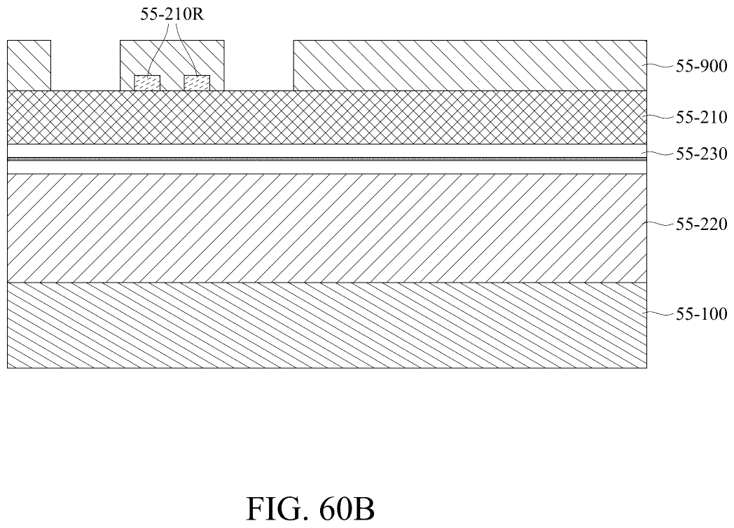

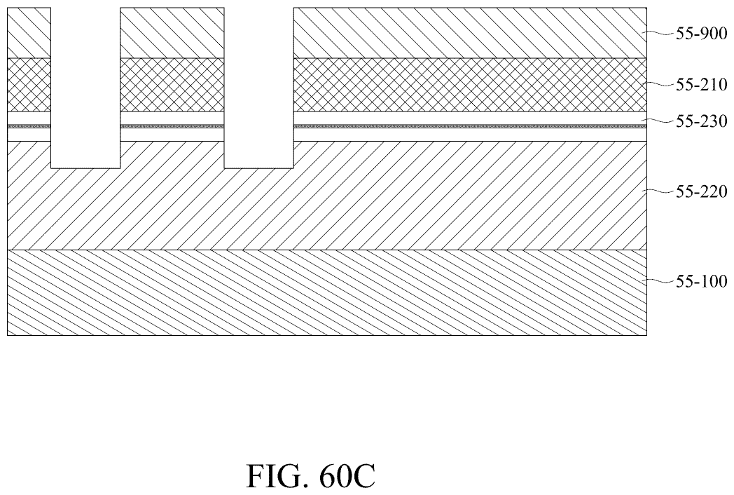

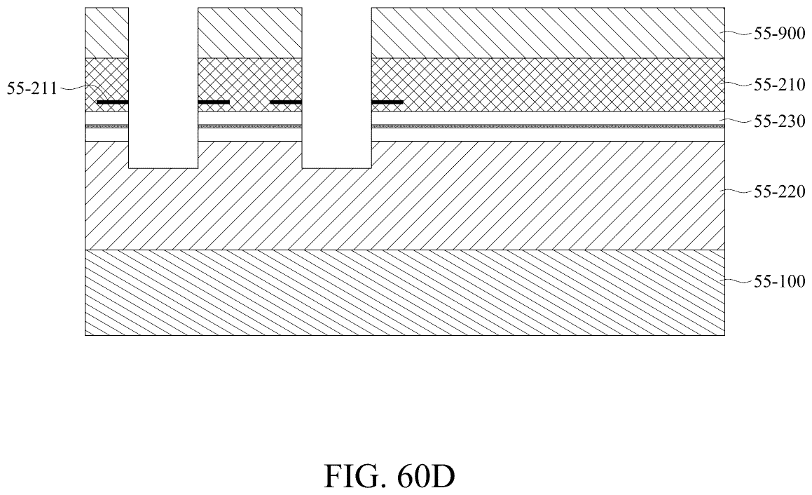

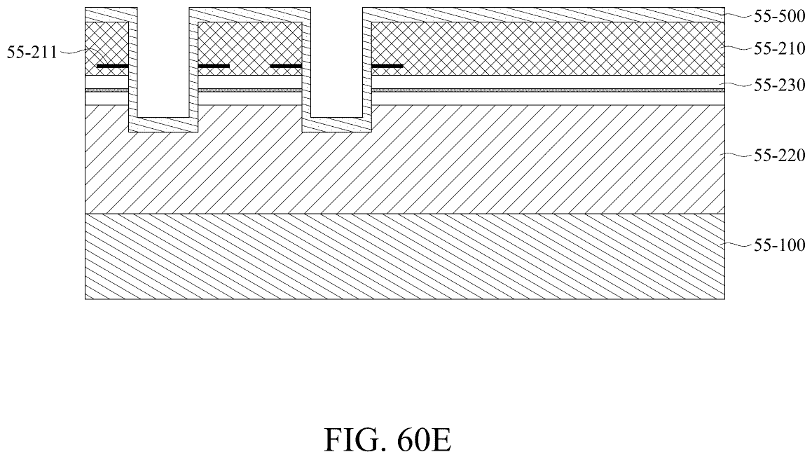

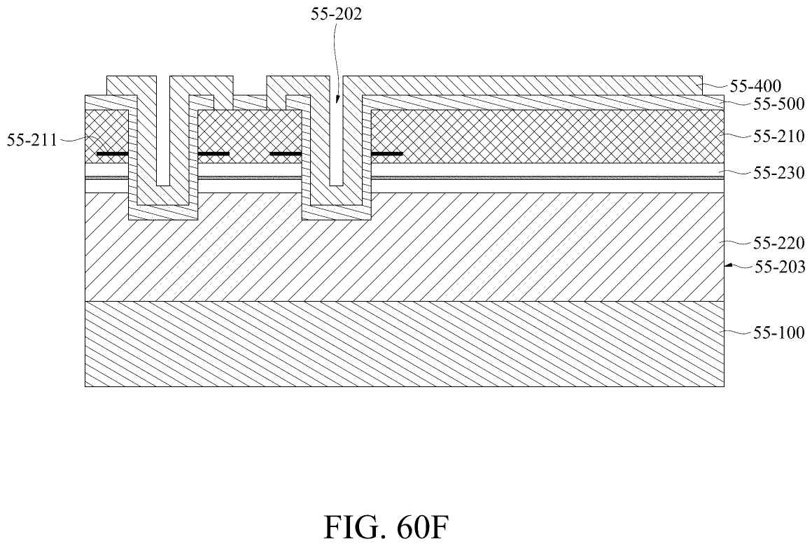

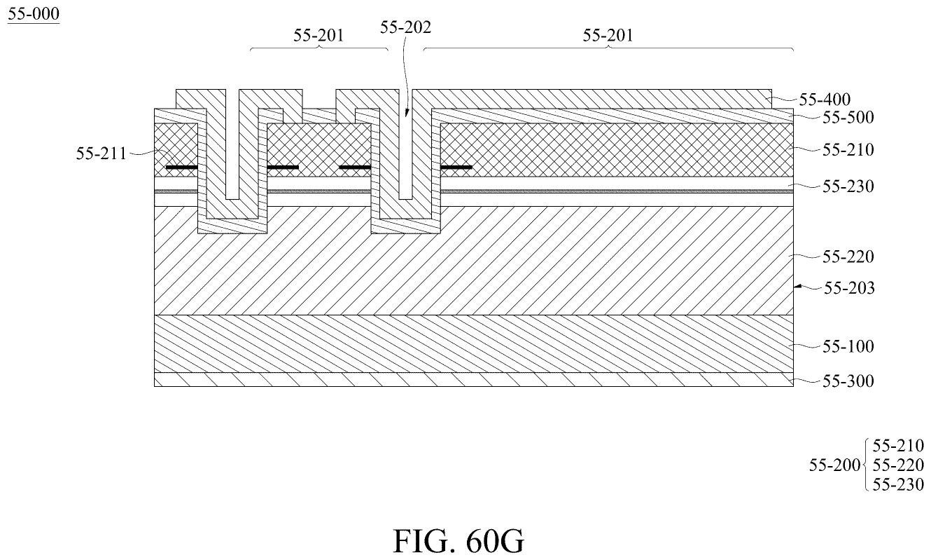

FIGS. 60A to 60G are schematic cross-sectional views illustrating multiple steps of a manufacturing process for the semiconductor laser 55-000 known to the inventors, as shown in FIG. 55.

First, please refer to FIG. 60A, an epitaxial wafer is provided. The epitaxial wafer includes a semiconductor stack layer 55-200 disposed on a conductive substrate 55-100, wherein the semiconductor stack layer 55-200 sequentially comprises a first type semiconductor layer 55-210, an active structure 55-230, and a second type semiconductor layer 55-220 disposed on the conductive substrate 55-100.

Next, still referring to FIG. 60A, a ring-shaped electrode structure 55-210R is formed on the first type semiconductor layer 55-210 of the epitaxial wafer, wherein the ring-shaped electrode structure 55-210R is electrically connected to the first type semiconductor layer 55-210. It should be noted that, for the sake of clearly presenting the arrangement relationships between other components, the ring-shaped electrode structure is not separately depicted in FIGS. 60C to 60E.

Next, please refer to FIG. 60B, a hard mask 55-900 is deposited on the first type semiconductor layer 55-210 of the epitaxial wafer, and a portion of the hard mask 55-900 is removed to expose a portion of the first type semiconductor layer 55-210.

Next, please refer to FIG. 60C, an etching procedure is performed on the semiconductor stack layer 55-200 of the epitaxial wafer to etch away portions of the first type semiconductor layer 55-210, portions of the active structure 55-230, and portions of the second type semiconductor layer 55-220, thereby exposing the second type semiconductor layer 55-220 and forming mesa structures 55-201 and trenches 55-202 between the mesa structures 55-201.

Next, as shown in FIG. 60D, the first type semiconductor layer 55-210 of the semiconductor stack layer 55-200 is oxidized to form a current confinement layer 55-211 in the semiconductor stack layer 55-200.

Next, as shown in FIG. 60E, the hard mask 55-900 is first removed, and then an passivation layer 55-500 is formed to cover the mesa structures 55-201 and the trenches 55-202 of the semiconductor stack layer 55-200.

Next, please refer to FIG. 60F, portions of the passivation layer 55-500 on the mesa structures are first removed to form ring-shaped openings, thereby exposing the ring-shaped electrode structure 55-210R on the first type semiconductor layer 55-210. Then, a conductive layer 55-400 is formed to electrically connect to the ring-shaped electrode structure 55-210R on the first type semiconductor layer 55-210 of the semiconductor stack layer 55-200, and extend onto the mesa structures 55-201 and into the trenches 55-202 of the semiconductor stack layer 55-200.

Finally, as shown in FIG. 60G, a contact electrode layer 55-300 is formed on the side of the conductive substrate 55-100 opposite to the semiconductor stack layer 55-200. The contact electrode layer 55-300 is electrically connected to the second type semiconductor layer 55-220 through the conductive conductive substrate 55-100. In some embodiments, before forming the contact electrode layer 55-300 on the conductive substrate 55-100, the conductive substrate 55-100 undergoes a thinning process.

However, in the semiconductor laser 55-000 known to the inventors, since the sidewall 55-203 of the semiconductor stack layer 55-200 is exposed, when the semiconductor laser 55-000 is in operation, some light may emit from the sidewall of the semiconductor stack layer 55-200, thereby causing noise.

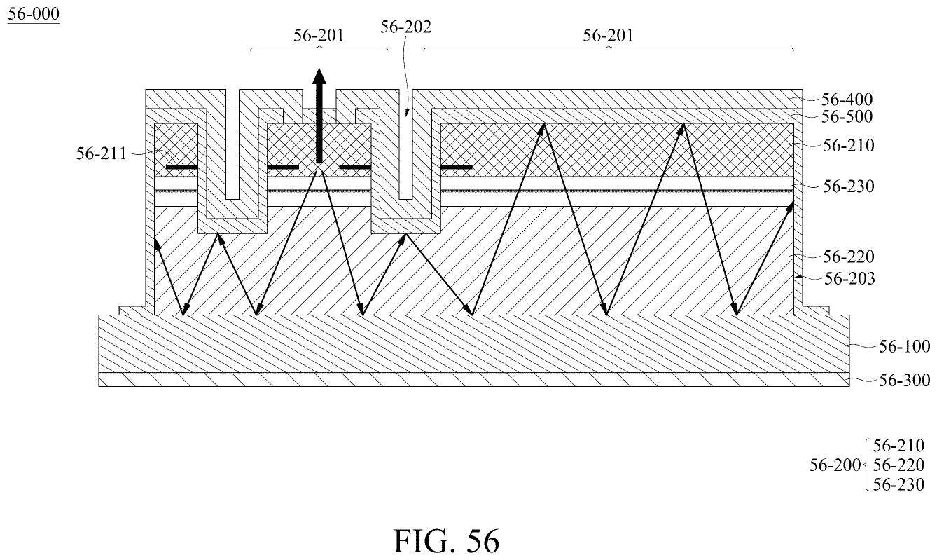

Please refer to FIG. 56, which is a schematic cross-sectional diagram of a semiconductor laser 56-000 according to some embodiments of the disclosure.

As shown in FIG. 56, according to some embodiments, a semiconductor laser 56-000 is provided, including a conductive substrate 56-100, a semiconductor stack layer 56-200, a contact electrode layer 56-300, a conductive layer 56-400, and an passivation layer 56-500. The semiconductor stack layer 56-200 is disposed on the conductive substrate 56-100, wherein the semiconductor stack layer 56-200 comprises a first type semiconductor layer 56-210, a second type semiconductor layer 56-220, and an active structure 56-230 disposed between the first type semiconductor layer 56-210 and the second type semiconductor layer 56-220.

The contact electrode layer 56-300 is disposed on the side of the conductive substrate 56-100 opposite to the semiconductor stack layer 56-200 and is electrically connected to the second type semiconductor layer 56-220 through the conductive substrate 56-100.

A patterned semiconductor etching process is performed to remove portions of the first type semiconductor layer 56-210, portions of the active structure 56-230, and portions of the second type semiconductor layer 56-220 of the semiconductor stack layer 56-200, thereby exposing the second type semiconductor layer 56-220 and defining a plurality of mesa structures 56-201 separated by trenches 56-202.

The conductive layer 56-400 is disposed on the mesa structures 56-201 and extends through the trenches 56-202 to the first type semiconductor layer 56-210, wherein the conductive layer 56-400 is electrically connected to the first type semiconductor layer 56-210.

The passivation layer 56-500 is disposed between the conductive layer 56-400 and the mesa structures 56-201 and between the conductive layer 56-400 and the trenches 56-202, wherein the passivation layer 56-500 further extends over the sidewall 56-203 of the semiconductor stack layer 56-200 onto the conductive substrate 56-100.

Therefore, according to some embodiments, since the passivation layer 56-500 extends to the conductive substrate 56-100 and covers the sidewall of semiconductor stack layer 56-200 When the semiconductor laser 56-000 is in operation, light no longer emits from the sidewall 56-203 of the semiconductor stack layer 56-200, thereby reducing noise.

In some embodiments, the semiconductor laser 56-000 is a vertical cavity surface emitting laser (VCSEL).

In some embodiments, the first type semiconductor layer 56-210 and the second type semiconductor layer 56-220 may comprise a distributed Bragg reflector (DBR) structure. In some embodiments, the DBR structure may be formed by alternately stacking two or more film layers with different refractive index, such as AlAs/GaAs, AlGaAs/GaAs, or InGaP/GaAs, but not limit thereto.

In some embodiments, the active structure 56-230 may be a quantum well layer, and the material of the quantum well layer includes a III-V compound semiconductor. For example, the III-V compound semiconductor may be a binary compound, such as InP, GaAs, InSb, GaN, GaSb, etc.; may be a ternary compound, such as InGaAs, InGaP, AlGaAs, InGaN, etc.; may be a quaternary compound, such as AlGaInP, InGaAsP, InGaAsN, etc.; or may be a quinary compound, such as InGaAsSbN, AlInGaAsN, etc.

In the embodiments of the disclosure, unless otherwise specified, the above chemical formulas include both “stoichiometric compounds” and “non-stoichiometric compounds”. The compounds are stoichiometric when, for example, the total stoichiometric amount of group III elements is equal to the total stoichiometric amount of group V elements. The compounds are non-stoichiometric when, for example, the total stoichiometric amount of group III elements is not equal to the total stoichiometric amount of group V elements. For example, the chemical formula AlGaAs represents that it includes the group III elements aluminum (Al) and/or gallium (Ga), and the group V element arsenic (As), wherein the total element content of the group III elements (aluminum and/or gallium) may be the same as or different from the total element content of the group V element (arsenic).

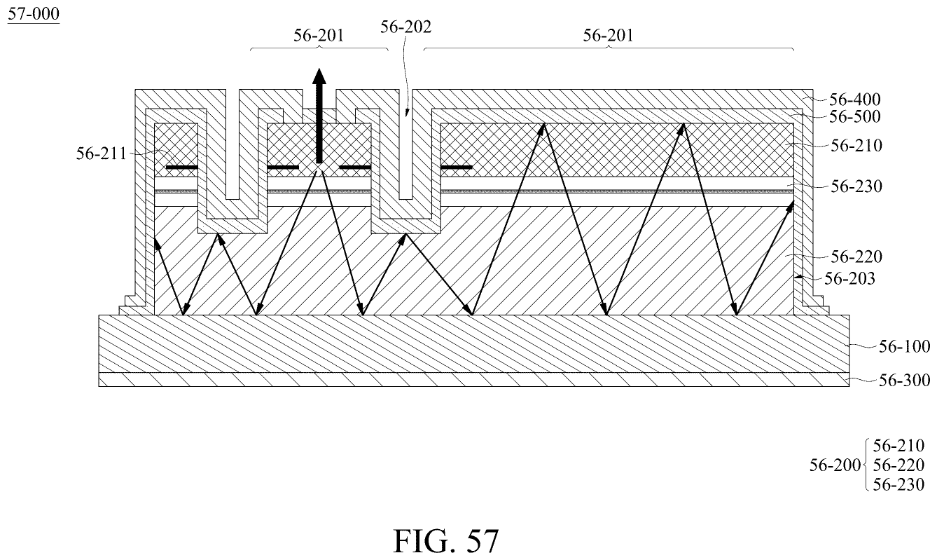

Please refer to FIG. 57, which is a schematic cross-sectional diagram of a semiconductor laser 57-000 according to some embodiments of the disclosure.

As shown in FIG. 57, in some embodiments, the conductive layer 56-400 further extends over the sidewall 56-203 of the semiconductor stack layer 56-200 onto the conductive substrate 56-100. This further prevents light escaping from the sidewalls of the semiconductor stack layer 56-200, thereby further reducing noise.

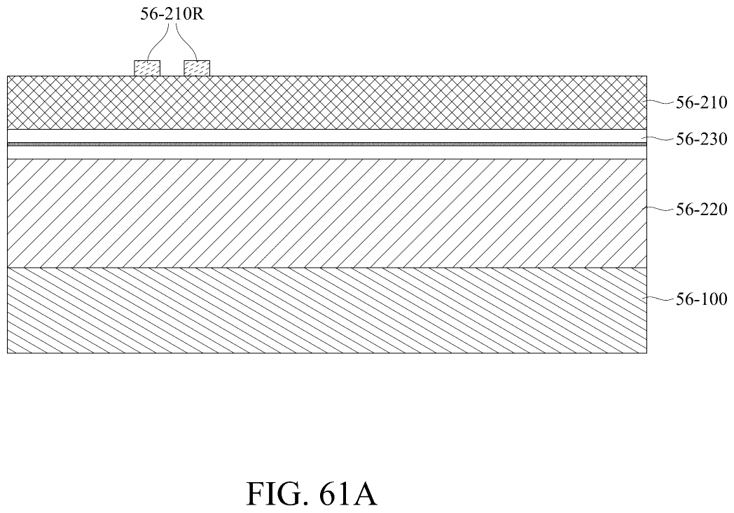

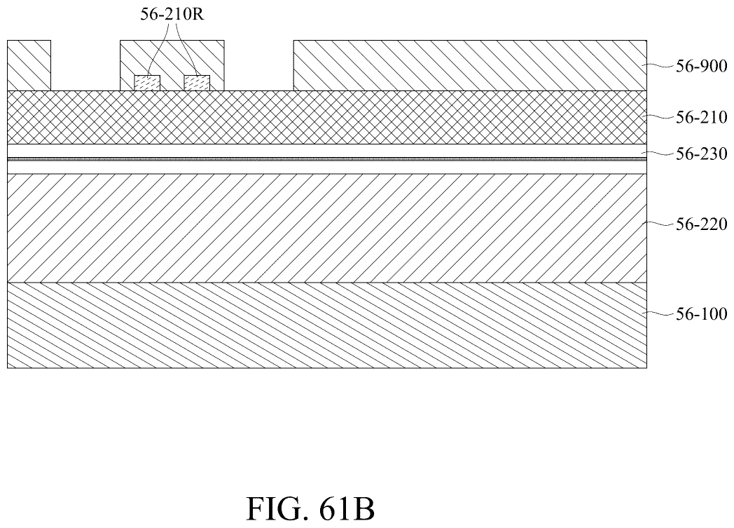

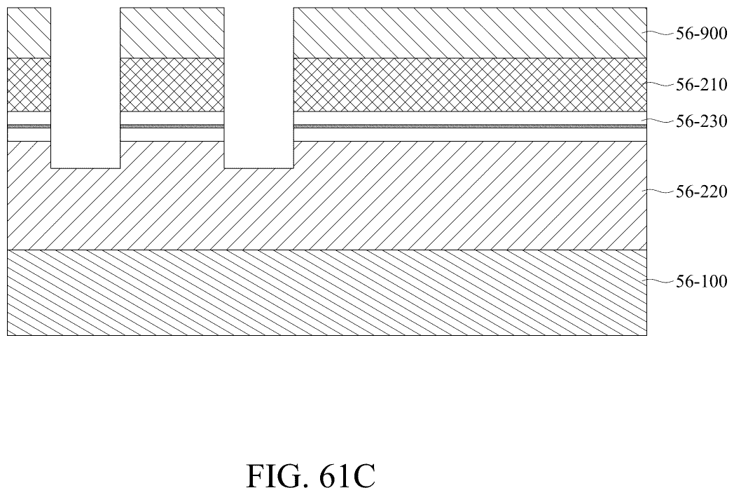

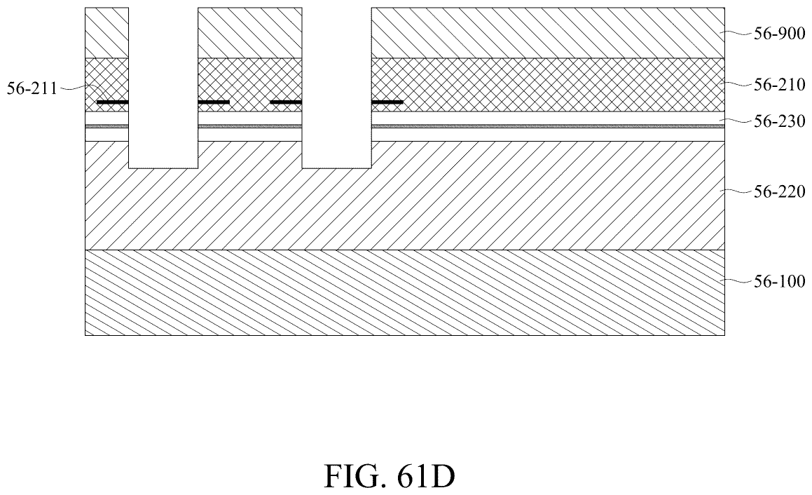

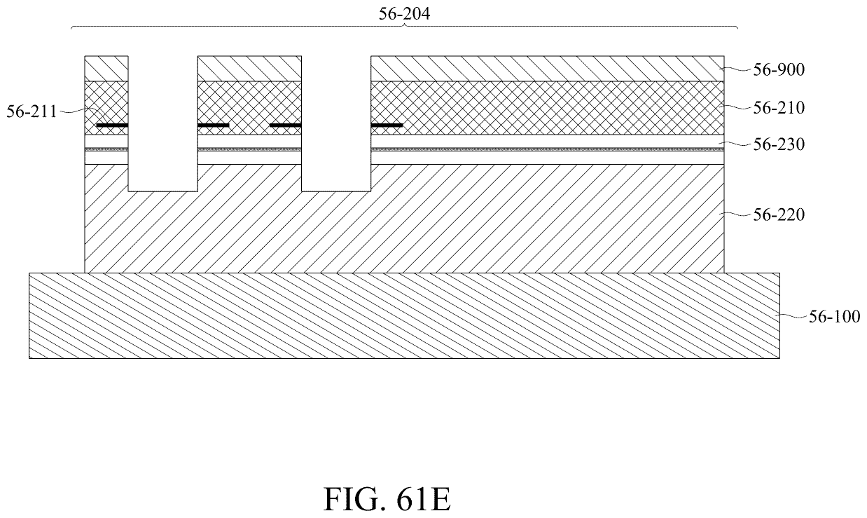

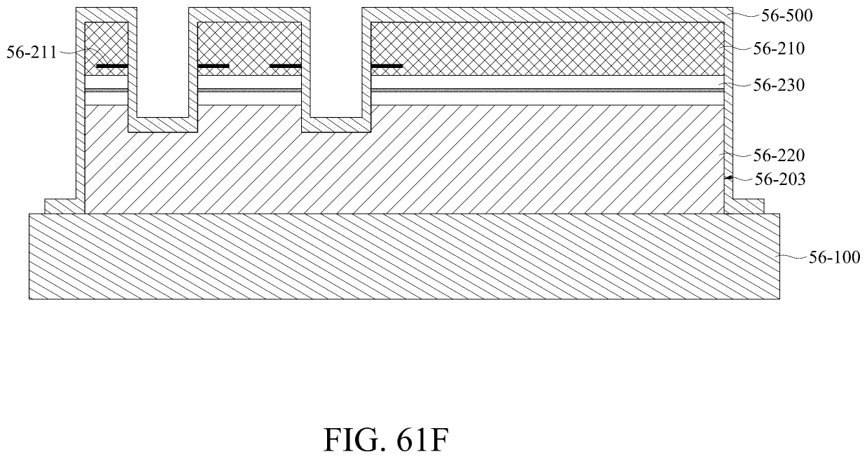

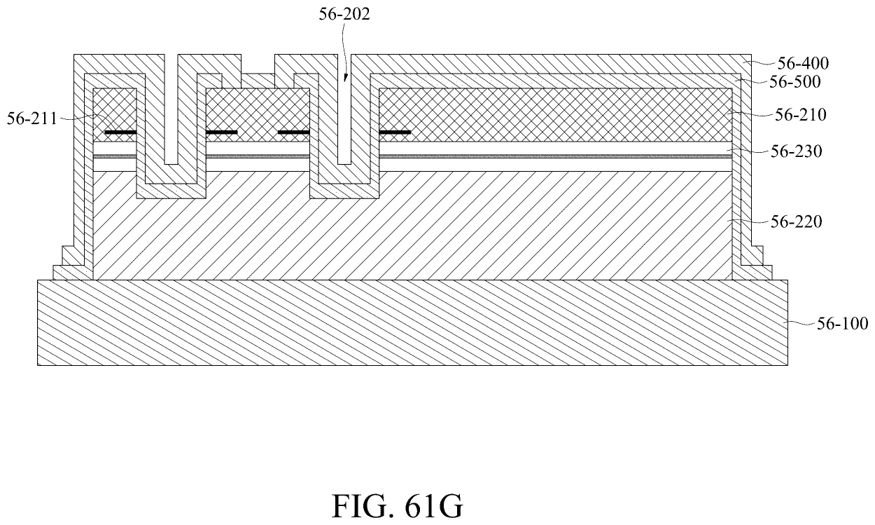

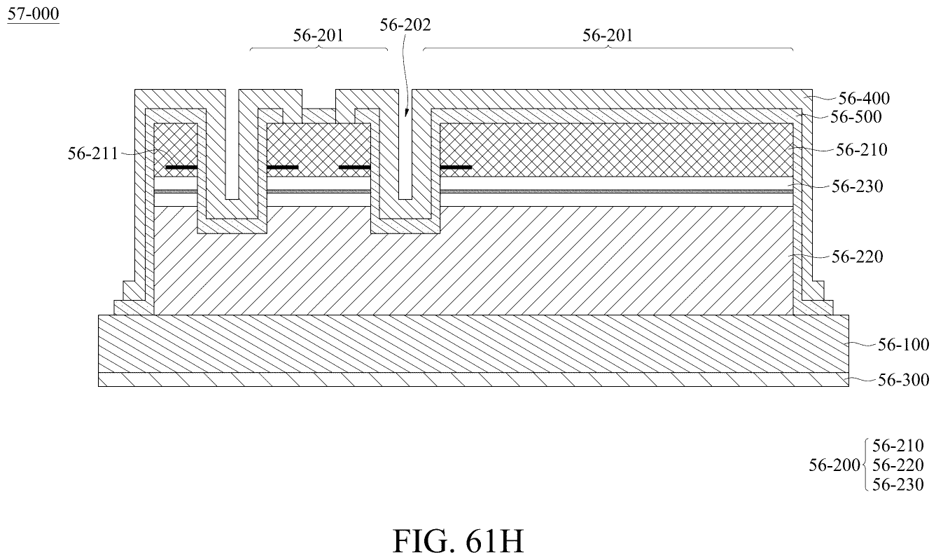

FIGS. 61A to 61H are schematic cross-sectional views illustrating multiple steps of a fabrication process for the semiconductor laser 57-000 according to some embodiments.

First, referring to FIG. 61A, an epitaxial wafer is provided. The epitaxial wafer comprises a semiconductor stack layer 56-200 formed on a conductive substrate 56-100, wherein the semiconductor stack layer 56-200 sequentially comprises, from top to bottom, a first type semiconductor layer 56-210, an active structure 56-230, and a second type semiconductor layer 56-220. The first type semiconductor layer 56-210 and/or the second type semiconductor layer 56-220 may be a multilayer structure. In this embodiment, the first type semiconductor layer 56-210 is a P-type semiconductor layer, and the second type semiconductor layer 56-220 is an N-type semiconductor layer. The semiconductor stack layer 56-200 may be epitaxially grown on the conductive substrate 56-100. The epitaxial growth methods include, but are not limited to, metalorganic chemical vapor deposition, hydride vapor phase epitaxy, molecular beam epitaxy, and liquid phase epitaxy. The conductive substrate 56-100 comprises, but is not limited to, III-V materials having a lattice constant matched to the semiconductor stack layer 56-200. The material of the conductive substrate 56-100 in this embodiment is gallium arsenide (GaAs). In other embodiments, the material of the conductive substrate 56-100 may be indium phosphide (InP), sapphire, gallium nitride (GaN), or silicon carbide (SiC).

Still referring to FIG. 61A, a ring-shaped electrode structure 56-210R is formed on the first type semiconductor layer 56-210 of the epitaxial wafer, wherein the ring-shaped electrode structure 56-210R is electrically connected to the first type semiconductor layer 56-210. The material of the ring-shaped electrode structure 56-210R may be a conductive metal. It should be noted that for the sake of clarity in presenting the arrangement relationships between other components, the ring-shaped electrode structure 56-210R is not separately depicted in FIGS. 61C to 61F.

Next, referring to FIG. 61B, a hard mask 56-900 is disposed over the first type semiconductor layer 56-210 of the epitaxial wafer, and a portion of the hard mask 56-900 is removed to expose a portion of the first type semiconductor layer 56-210.

Next, referring to FIG. 61C, an etching procedure is performed on the semiconductor stack layer 56-200 of the epitaxial wafer. The etching procedure uses the hard mask 56-900 with a specific pattern to etch away portions of the first type semiconductor layer 56-210, portions of the active structure 56-230, and portions of the second type semiconductor layer 56-220 and to expose the second type semiconductor layer 56-220, thereby forming mesa structures 56-201 and trenches 56-202 between the mesa structures 56-201. Specifically, the aforementioned mesa structures 56-201 and trenches 56-202 can be formed by inductively coupled plasma (ICP) technology. In this embodiment, although the figure shows that the semiconductor stack layer 56-200 only defines three mesa structures 56-201 and two trenches 56-202, this is merely an example and is not intended to be limiting.

Next, as shown in FIG. 61D, a current confinement layer 56-211 is formed in the semiconductor stack layer 56-200. In this embodiment, the formation method of the current confinement layer 56-211 can be achieved through an oxidation process to oxidize the material in the regions predetermined to form the current confinement areas. For example, the aluminum content of at least one of the layers in the first type semiconductor layer 56-210 (defined as the layer predetermined to form the current confinement layer 56-211) is greater than 97% and greater than the aluminum content of the active structure 56-230 and the second type semiconductor layer 56-220. Therefore, during the oxidation process, the high-aluminum-content layer region (defined as the regions predetermined to form the current confinement layer 56-211) in the semiconductor stack layer 56-200 has a higher inward oxidation rate than other regions, thereby forming a current restriction region with low conductivity in the current confinement layer 56-211. Alternatively, in some embodiments, a current restriction region with low conductivity may be formed in the semiconductor stack layer 56-200 by an ion implantation process, and a current conduction region may be defined by a mask at the same time. Ion implantation may be performed by implanting hydrogen ions (H+), helium ions (He+), or argon ions (Ar+) in the regions predetermined to form the current confinement area. The ion concentration in the current restriction region is much higher than that in the current conduction region so that the current restriction region has a lower conductivity.

Next, referring to FIG. 61E, an etching procedure is again performed on the semiconductor stack layer 56-200 of the epitaxial wafer. A mask with a specific pattern is used to etch and remove a portion of the semiconductor stack layer 56-200 and expose the upper surface of the conductive substrate 56-100. As a result, the semiconductor stack layer 56-200 as a whole forms a mesa structure 56-204.

Then, as shown in FIG. 61F, the aforementioned hard mask 56-900 is first removed, and then an passivation layer 56-500 is formed to cover the mesa structures 56-201 of the semiconductor stack layer 56-200 and in the trenches 56-202, wherein the passivation layer 56-500 further extends past the sidewalls 56-203 of the semiconductor stack layer 56-200 to the conductive substrate 56-100.

Next, as shown in FIG. 61G, a conductive layer 56-400 is formed to electrically connect to the ring-shaped electrode structure 56-210R on the first type semiconductor layer 56-210 of the semiconductor stack layer 56-200, and extends over the mesa structures 56-201 and into the trenches 56-202 of the semiconductor stack layer 56-200. The conductive layer 56-400 further extends through the sidewalls 56-203 of the semiconductor stack layer 56-200 to the conductive substrate 56-100.

Finally, as shown in FIG. 61H, a contact electrode layer 56-300 is formed on the side of the conductive substrate 56-100 opposite to the semiconductor stack layer 56-200. The contact electrode layer 56-300 is electrically connected to the second type semiconductor layer 56-220 through the conductive conductive substrate 56-100.

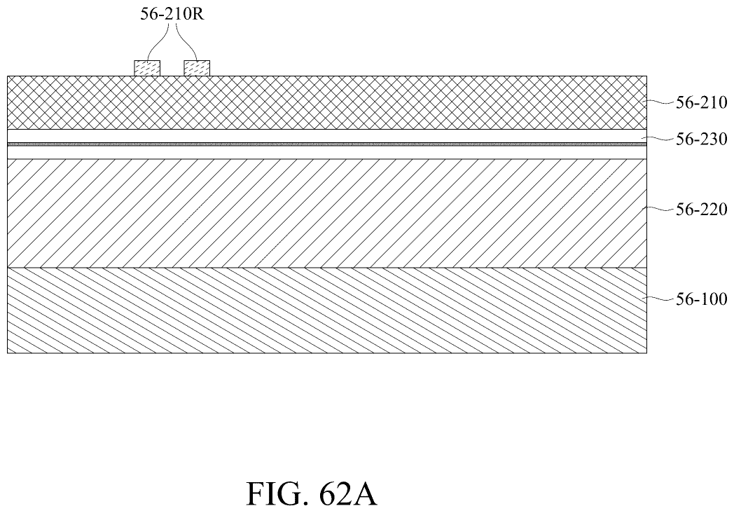

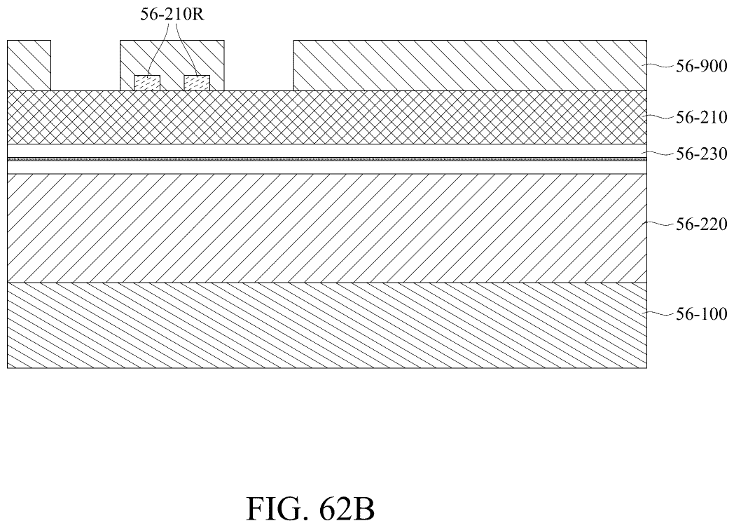

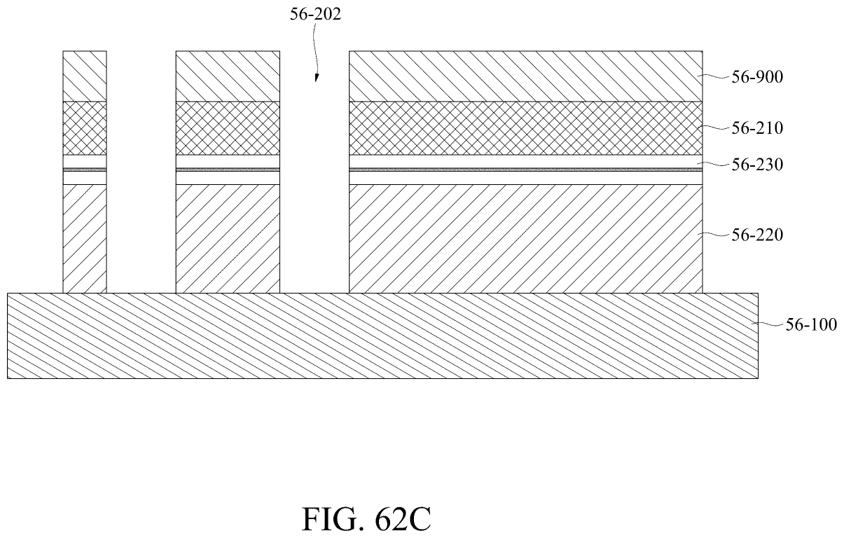

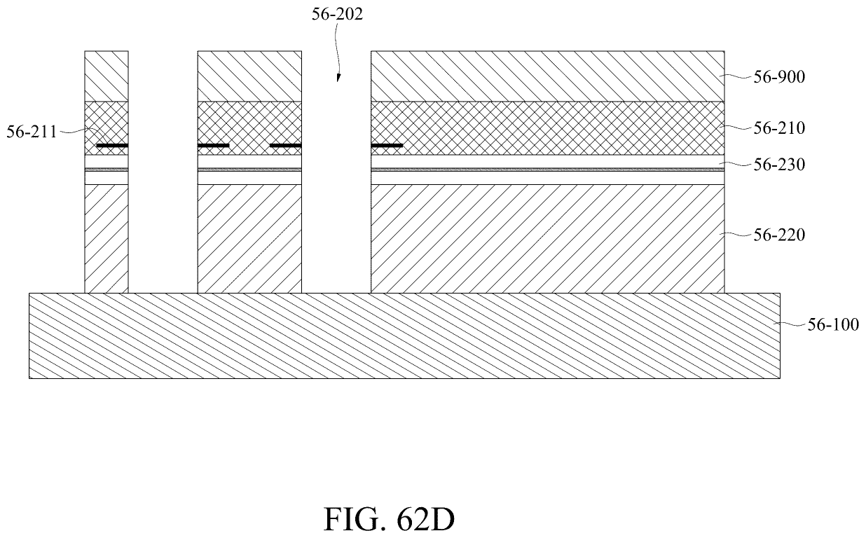

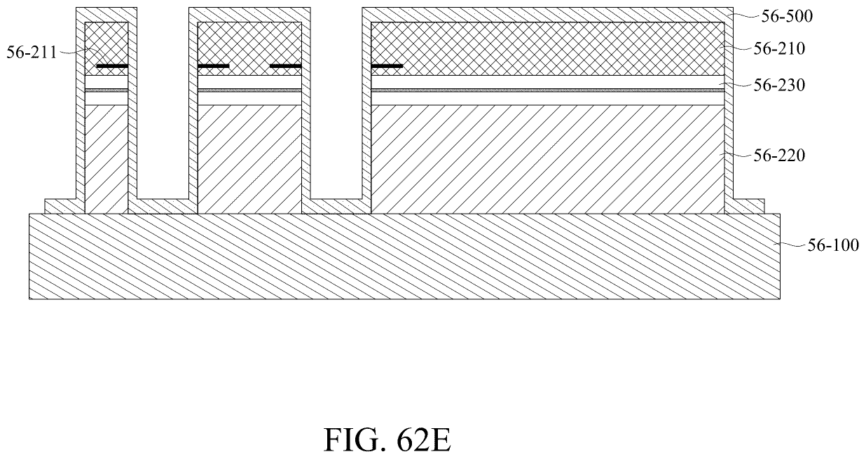

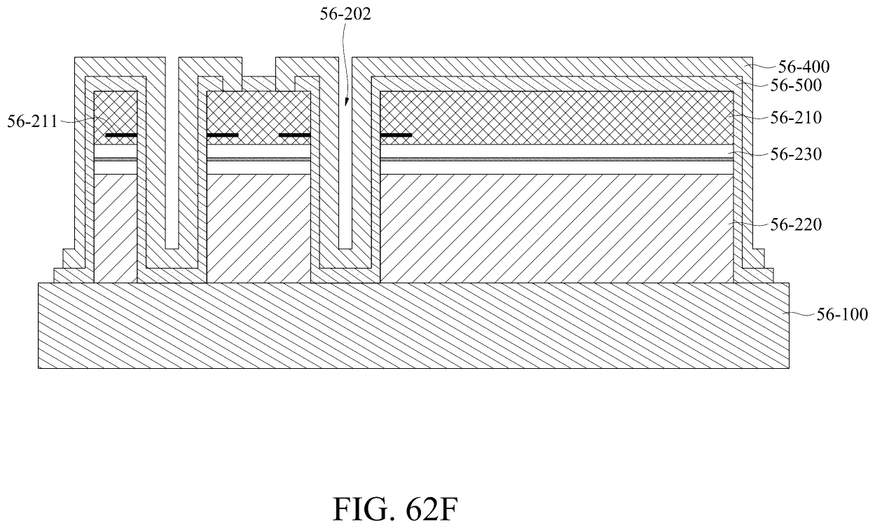

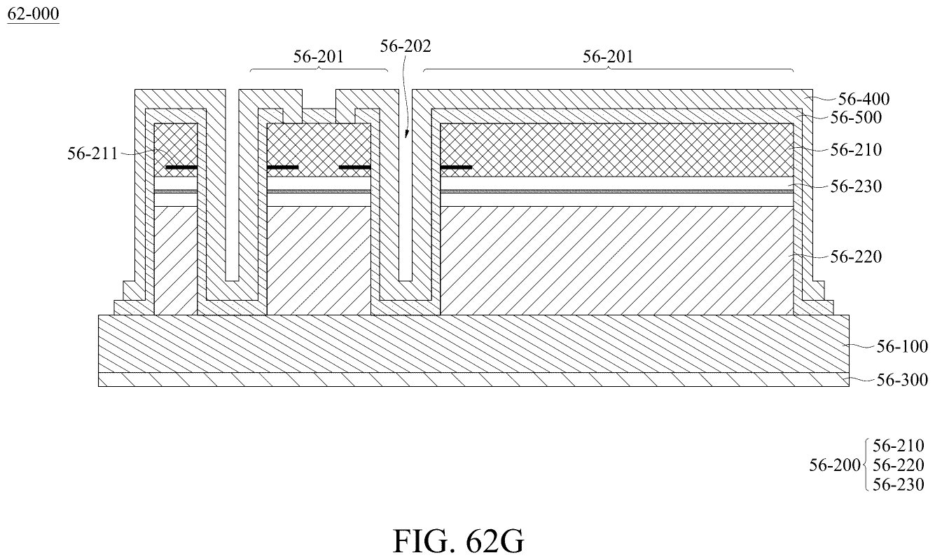

FIGS. 62A to 62G are schematic cross-sectional views illustrating multiple steps of a fabrication process for a semiconductor laser 62-000 according to some embodiments. It should be noted that the main difference between the semiconductor laser 62-000 of this embodiment and the semiconductor laser 57-000 of the previous embodiment is that the bottom of the trenches 56-202 of the semiconductor laser 62-000 in this embodiment is substantially leveled with the surface of the conductive substrate 56-100, so the remaining structures will not be described herein again.

First, referring to FIG. 62A, an epitaxial wafer is provided. The epitaxial wafer includes a semiconductor stack layer 56-200 formed on a conductive substrate 56-100, wherein the semiconductor stack layer 56-200 sequentially comprises a first type semiconductor layer 56-210, an active structure 56-230, and a second type semiconductor layer 56-220. The first type semiconductor layer 56-210 and/or the second type semiconductor layer 56-220 may be a multilayer structure. In this embodiment, the first type semiconductor layer 56-210 is a P-type semiconductor layer, and the second type semiconductor layer 56-220 is an N-type semiconductor layer. The semiconductor stack layer 56-200 may be epitaxially grown on the conductive substrate 56-100. The epitaxial growth methods include, but are not limited to, metalorganic chemical vapor deposition, hydride vapor phase epitaxy, molecular beam epitaxy, and liquid phase epitaxy. The conductive substrate 56-100 comprises, but is not limited to, III-V materials having a lattice constant matched to the semiconductor stack layer 56-200. The material of the conductive substrate 56-100 in this embodiment is gallium arsenide (GaAs). In other embodiments, the material of the conductive substrate 56-100 may be indium phosphide (InP), sapphire, gallium nitride (GaN), or silicon carbide (SiC).

Still referring to FIG. 62A, a ring-shaped electrode structure 56-210R is formed on the first type semiconductor layer 56-210 of the epitaxial wafer, wherein the ring-shaped electrode structure 56-210R is electrically connected to the first type semiconductor layer 56-210. The material of the ring-shaped electrode structure 56-210R may be a conductive metal. It should be noted that for the sake of clarity in illustrating the arrangement relationships between other components, the ring-shaped electrode structure 56-210R is not separately depicted in FIGS. 62C to 62G.

Next, referring to FIG. 62B, a hard mask 56-900 is applied over the first type semiconductor layer 56-210 of the epitaxial wafer.

Next, referring to FIG. 62C, an etching procedure is performed on the semiconductor stack layer 56-200 of the epitaxial wafer. The etching procedure uses the hard mask 56-900 with a specific pattern to etch away portions of the first type semiconductor layer 56-210, portions of the active structure 56-230, and portions of the second type semiconductor layer 56-220, and to expose the conductive substrate 56-100 from the side of the hard mask 56-900, thereby forming mesa structures 56-201 and trenches 56-202 between the mesa structures 56-201. Specifically, the aforementioned mesa structures 56-201 and trenches 56-202 can be formed by inductively coupled plasma (ICP) technology. In this embodiment, although the figure shows that the semiconductor stack layer 56-200 defines three mesa structures 56-201 and two trenches 56-202, this is merely an example and is not intended to be limiting.

Next, as shown in FIG. 62D, a current confinement layer 56-211 is formed in the semiconductor stack layer 56-200. In this embodiment, the current confinement layer 56-211 may be formed by oxidizing the material in a region where a current restriction region is to be formed by an oxidation process. For example, the aluminum content of at least one of the layers in the first type semiconductor layer 56-210 (defined as the layer predetermined to form the current confinement layer 56-211) is greater than 97% and greater than the aluminum content of the active structure 56-230 and the second type semiconductor layer 56-220. Therefore, during the oxidation process, the high-aluminum-content layer region (defined as the regions predetermined to form the current confinement layer 56-211) in the semiconductor stack layer 56-200 has a higher inward oxidation rate than other regions, thereby forming a current restriction region with low conductivity in the current confinement layer 56-211. Alternatively, in some embodiments, a current restriction region with low conductivity may be formed in the semiconductor stack layer 56-200 by an ion implantation process, and a current conduction region may be defined by a mask at the same time. Ion implantation may be performed by implanting hydrogen ions (H+), helium ions (He+), or argon ions (Ar+) in the regions predetermined to form the current confinement area. The ion concentration in the current restriction region is much greater than that in the current conduction region so that the current restriction region has a lower conductivity.

Then, as shown in FIG. 62E, the aforementioned hard mask 56-900 is first removed, and then an passivation layer 56-500 is formed to cover the mesa structures 56-201 of the semiconductor stack layer 56-200 and in the trenches 56-202, wherein the passivation layer 56-500 further extends over the sidewalls 56-203 of the semiconductor stack layer 56-200 to the conductive substrate 56-100.

Next, as shown in FIG. 62F, a conductive layer 56-400 is formed to electrically connect to the ring-shaped electrode structure 56-210R on the first type semiconductor layer 56-210 of the semiconductor stack layer 56-200, and extends over the mesa structures 56-201 and into the trenches 56-202 of the semiconductor stack layer 56-200, wherein the conductive layer 56-400 further extends over the sidewalls 56-203 of the semiconductor stack layer 56-200 to the conductive substrate 56-100.

Finally, as shown in FIG. 62G, a contact electrode layer 56-300 is formed on the side of the conductive substrate 56-100 opposite to the semiconductor stack layer 56-200. The contact electrode layer 56-300 is electrically connected to the second type semiconductor layer 56-220 through the conductive substrate 56-100.

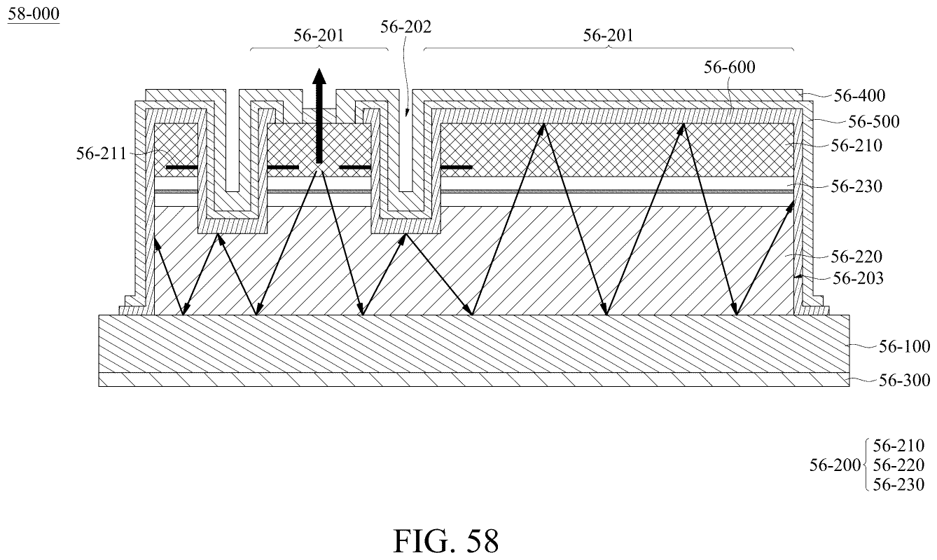

Please refer to FIG. 58, which is a schematic cross-sectional diagram of a semiconductor laser 58-000 according to some embodiments of the disclosure.

As shown in FIG. 58, in some embodiments, the semiconductor laser 58-000 further comprises a high reflection layer 56-600 disposed between the mesa structures 56-201 and the passivation layer 56-500 and between the trenches 56-202 and the passivation layer 56-500, wherein the high reflection layer 56-600 further extends over the sidewall 56-203 of the semiconductor stack layer 56-200 to the conductive substrate 56-100. This further prevents light escaping from the sidewalls of the semiconductor stack layer 56-200, thereby further reducing noise.

In some embodiments, the high reflection layer 56-600 may be a single layer or a multilayer structure made of one or a combination of materials such as metal, SiNx, SiOx, SiOxNy, etc., and may be formed by a deposition process, but is not limited thereto.

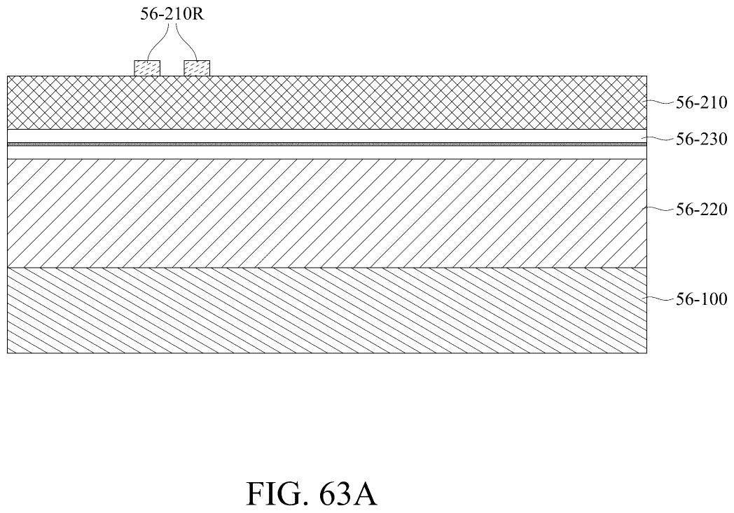

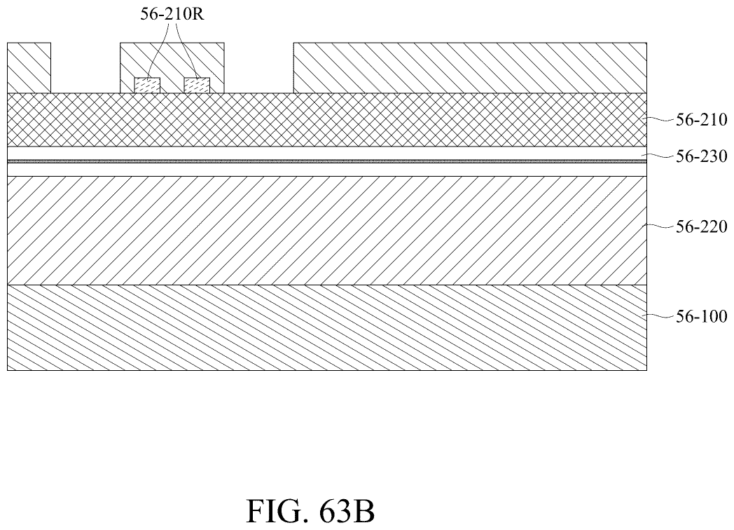

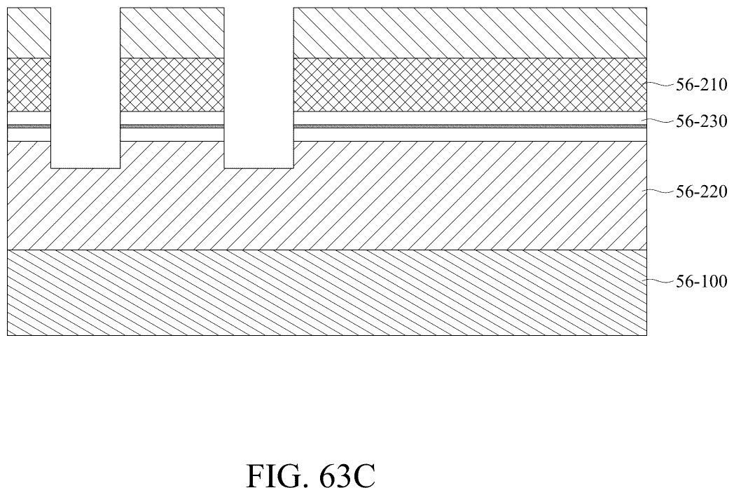

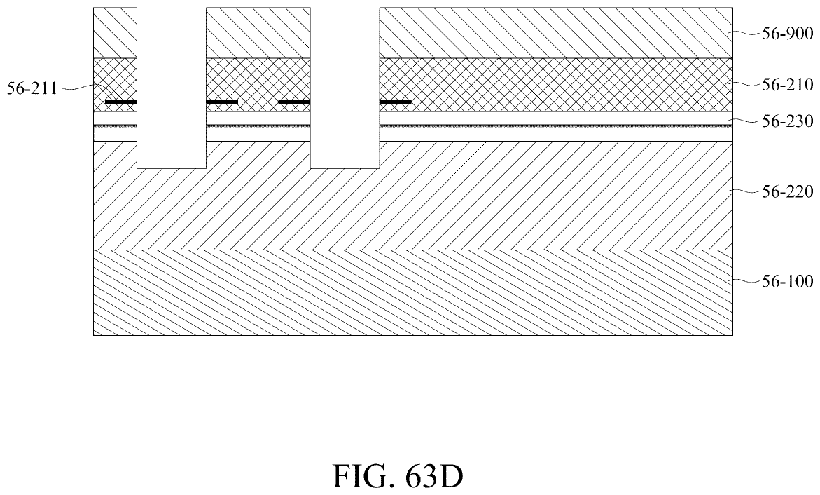

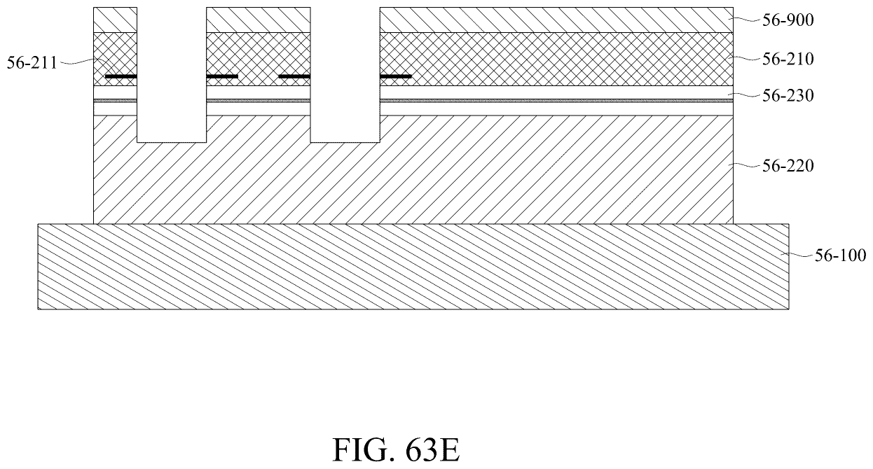

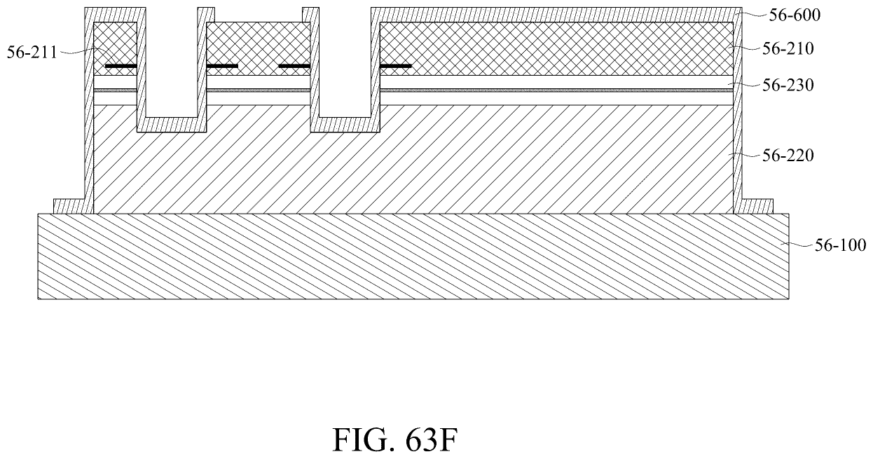

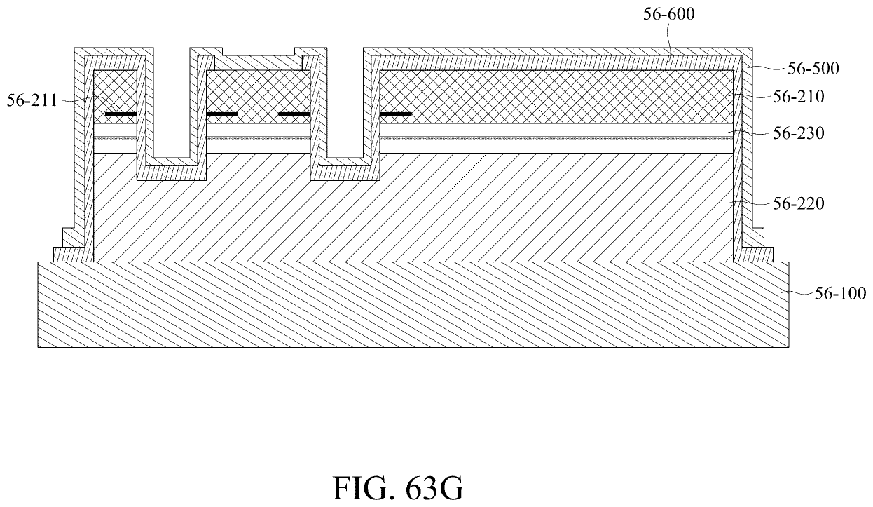

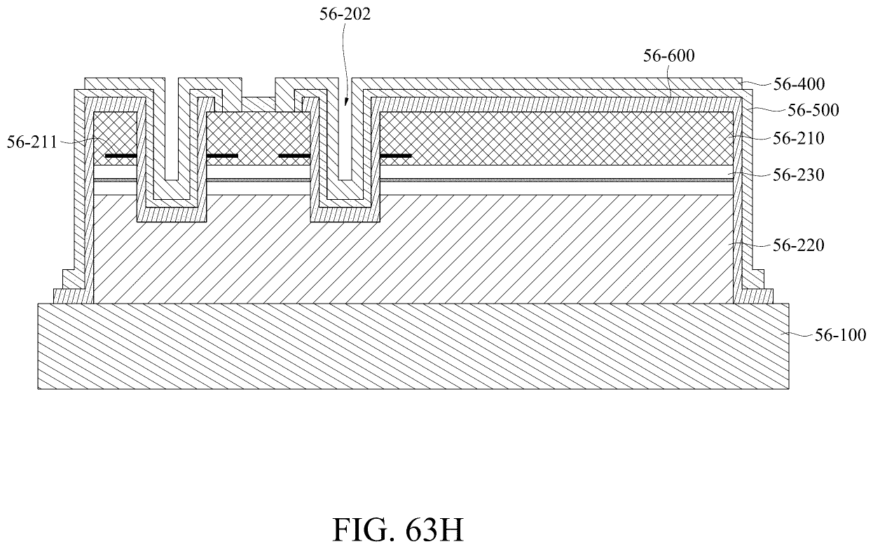

FIGS. 63A to 631 are schematic cross-sectional views illustrating multiple steps of a fabrication process for the semiconductor laser 58-000 according to some embodiments depicted in FIG. 58.

First, referring to FIG. 63A, an epitaxial wafer is provided. The epitaxial wafer comprises a semiconductor stack layer 56-200 formed on a conductive substrate 56-100, wherein the semiconductor stack layer 56-200 sequentially comprises a first type semiconductor layer 56-210, an active structure 56-230, and a second type semiconductor layer 56-220 on a conductive substrate 56-100.

Still referring to FIG. 63A, a ring-shaped electrode structure 56-210R is formed on the first type semiconductor layer 56-210 of the epitaxial wafer, wherein the ring-shaped electrode structure 56-210R is electrically connected to the first type semiconductor layer 56-210. It should be noted that for the sake of clarity in illustrating the arrangement relationships between other components, the ring-shaped electrode structure 56-210R is not separately depicted in FIGS. 63C to 63G.

Next, referring to FIG. 63B, a hard mask 56-900 is applied over the first type semiconductor layer 56-210 of the epitaxial wafer.

Next, referring to FIG. 63C, an etching procedure is performed on the semiconductor stack layer 56-200 of the epitaxial wafer. The etching procedure uses the hard mask 56-900 with a specific pattern to etch away portions of the first type semiconductor layer 56-210, portions of the active structure 56-230, and portions of the second type semiconductor layer 56-220 and expose the second type semiconductor layer 56-220, thereby forming mesa structures 56-201 and trenches 56-202 between the mesa structures 56-201. Specifically, the aforementioned mesa structures 56-201 and trenches 56-202 can be formed by inductively coupled plasma (ICP) technology.

Next, as shown in FIG. 63D, a current confinement layer 56-211 is formed in the semiconductor stack layer 56-200.

Next, referring to FIG. 63E, an etching procedure is again performed on the semiconductor stack layer 56-200 of the epitaxial wafer. A mask with a specific pattern is used to etch and remove a portion of the semiconductor stack layer 56-200 and expose the upper surface of the conductive substrate 56-100. As a result, the semiconductor stack layer 56-200 as a whole forms a platform structure 56-204.

Then, as shown in FIG. 63F, the aforementioned hard mask 56-900 is first removed, and then a high reflection layer 56-600 is formed to cover the mesa structures 56-201 of the semiconductor stack layer 56-200 and in the trenches 56-202, wherein the high reflection layer 56-600 further extends over the sidewalls 56-203 of the semiconductor stack layer 56-200 to the conductive substrate 56-100. The high reflection layer 56-600 has an opening above the light emitting region, and the width of the opening of the high reflection layer 56-600 is larger than the width of the current conduction region of the current confinement layer 56-211 to maximize the energy of the emitted light. In some embodiments, the width of the opening of the high reflection layer 56-600 is smaller than the width of the current conduction region of the current confinement layer 56-211 to control the mode of the emitted light.

Next, as shown in FIG. 63G, an passivation layer 56-500 is formed to cover the high reflection layer 56-600. In other words, in this embodiment, the passivation layer 56-500 also covers the mesa structures 56-201 of the semiconductor stack layer 56-200 and in the trenches 56-202, and the passivation layer 56-500 further extends over the sidewalls 56-203 of the semiconductor stack layer 56-200 to the conductive substrate 56-100.

Next, as shown in FIG. 63H, a conductive layer 56-400 is formed to electrically connect to the ring-shaped electrode structure 56-210R on the first type semiconductor layer 56-210 of the semiconductor stack layer 56-200, and extends over the mesa structures 56-201 and into the trenches 56-202 of the semiconductor stack layer 56-200.

Finally, as shown in FIG. 631, a contact electrode layer 56-300 is formed on the side of the conductive substrate 56-100 opposite to the semiconductor stack layer 56-200. The contact electrode layer 56-300 is electrically connected to the second type semiconductor layer 56-220 through the conductive substrate 56-100.

In some embodiments, the conductive layer 56-400 of the semiconductor laser 58-000 further extends over the sidewalls 56-203 of the mesa structures 56-201 to the conductive substrate 56-100.

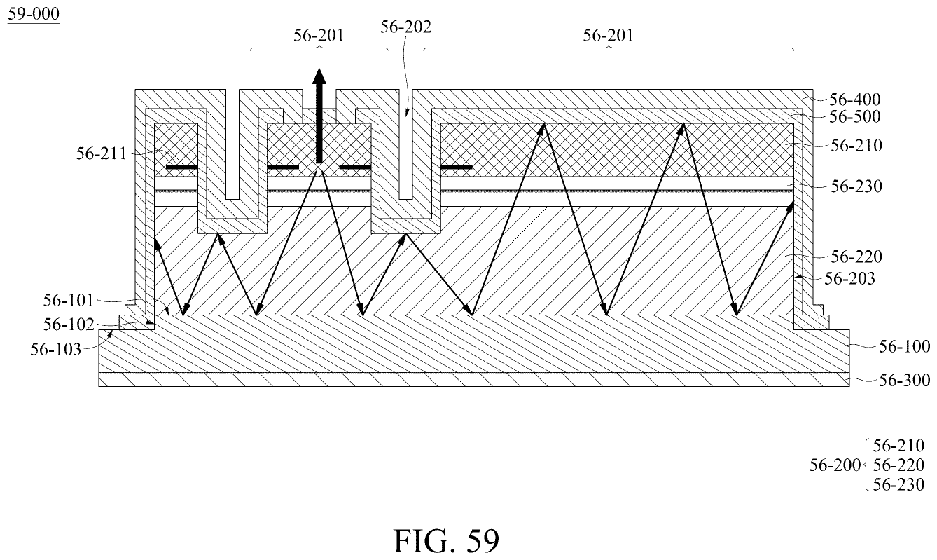

Please refer to FIG. 59, which is a schematic cross-sectional diagram of a semiconductor laser 59-000 according to some embodiments of the disclosure.

As shown in FIG. 59, in some embodiments, the conductive substrate 56-100 comprises a platform surface 56-101, a platform sidewall 56-102, and a substrate surface 56-103, wherein the platform sidewall 56-102 connecting the platform surface 56-101 and the substrate surface 56-103. The passivation layer 56-500 and the conductive layer 56-400 further extend over the platform sidewall 56-102 of the conductive substrate 56-100 to the substrate surface 56-103 of the conductive substrate 56-100.

According to some embodiments illustrated in FIG. 59, during the etching step, in addition to forming the semiconductor stack layer 56-200 into mesa structures 56-201, the conductive substrate 56-100 is also formed into a platform structure, thereby creating a height difference between the platform surface 56-101 and the substrate surface 56-103 of the platform structure (for example, the height of the platform sidewall 56-102). Therefore, in the subsequent steps of forming the passivation layer 56-500 and the conductive layer 56-400, the passivation layer 56-500 and the conductive layer 56-400 further extend over the platform sidewall 56-102 of the platform structure and extend to the substrate surface 56-103 of the platform structure. This further prevents light escaping from the sidewalls of the semiconductor stack layer 56-200 and the platform sidewall 56-102, thereby further reducing noise.

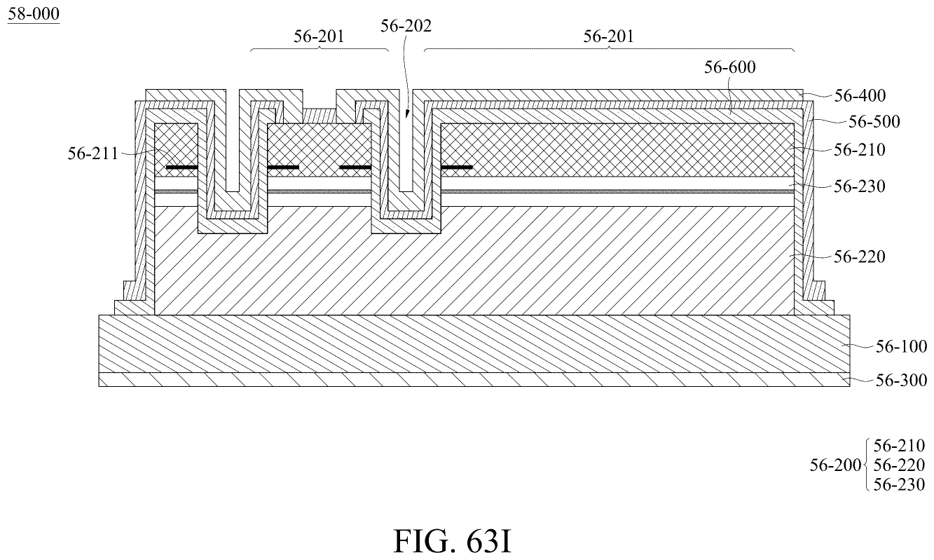

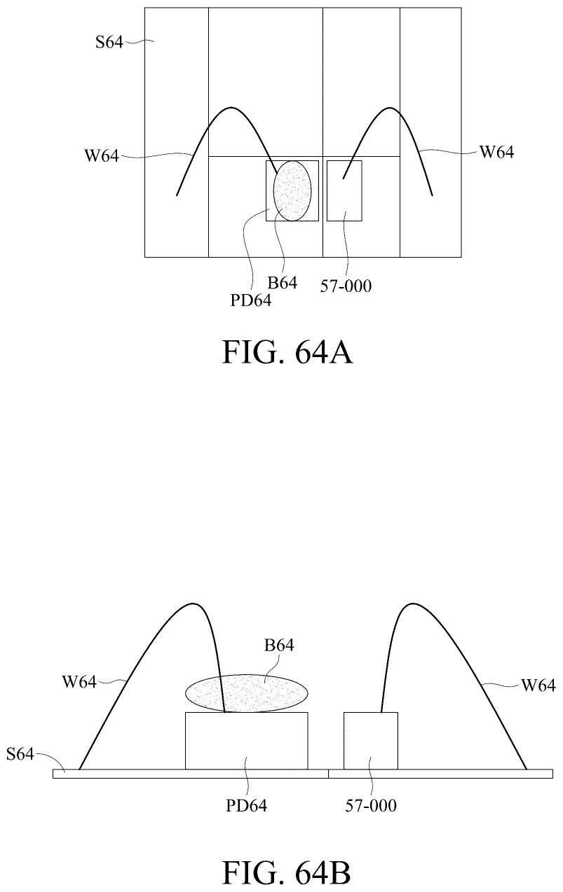

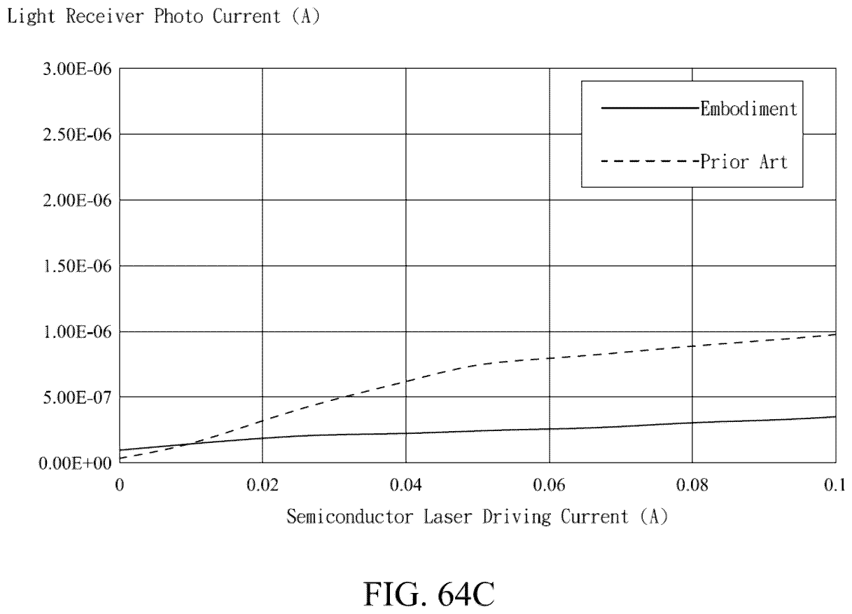

FIG. 64A is a top view schematic diagram illustrating a noise test for a semiconductor laser by using a photodetector. FIG. 64B is a cross-sectional view schematic diagram illustrating a noise test for a semiconductor laser by using a photodetector. FIG. 64C is a comparison diagram illustrating noise test results of a semiconductor laser known to the inventors and a semiconductor laser according to some embodiments.

Please refer to FIGS. 64A and 64B, which illustrate schematic diagrams of a noise test for a semiconductor laser (for example, the semiconductor laser 57-000 shown in FIG. 57) by using a photodetector PD64. Specifically, to detect whether there is light leakage from the sidewall of the semiconductor laser 57-000, the semiconductor laser 57-000 and the photodetector PD are arranged as shown in FIGS. 64A and 64B. Specifically, in some embodiments, one electrode of the semiconductor laser 57-000 is disposed on a test substrate S64, and the other electrode of the semiconductor laser 57-000 is electrically connected to the test substrate S64 by a bonding wire W64. Similarly, one electrode of the photodetector PD64 is disposed on the test substrate S64, and the other electrode of the photodetector PD64 is electrically connected to the test substrate S64 by a bonding wire W64. Moreover, a front surface of the photodetector PD64 is covered with a light-blocking substance B64 (for example, but not limited to, black glue) to ensure that an optical signal received by the photodetector PD64 is from the light emitted from the sidewall of the semiconductor laser 57-000.

Please refer to FIG. 64C, which is a comparison diagram illustrating noise test results of a semiconductor laser known to the inventors and a semiconductor laser according to some embodiments using a photodetector. As shown in the figure, compared with the semiconductor laser known to the inventors, the semiconductor laser according to some embodiments of the present disclosure (for example, the semiconductor laser 57-000 shown in FIG. 57) have reduced noise. This is because the passivation layer 56-500 and the conductive layer 56-400 further extend over the sidewall 56-203 of the semiconductor stack layer 56-200 to the conductive substrate 56-100. As a result, light can be effectively reflected back into the semiconductor stack layer 56-200, preventing the light from escaping through the sidewall 56-203 of the semiconductor stack layer 56-200, thereby reducing noise.

The above description of the embodiments in this application is provided for the purpose of illustration and description. It is not exhaustive and is not intended to limit the embodiments of the present invention to the precise forms disclosed in this application.

It is apparent to those with ordinary knowledge in the technical field to which the present invention pertains that, based on the above description of the embodiments, various modifications, variations, or combinations of the above embodiments can be made.

What is claimed is:

1. An optoelectronic device, comprising:
a base layer, comprising a first side and a second side, the second side being opposite to the first side;
a functional area, disposed on the first side of the base layer;
a semiconductor element, disposed on the second side of the base layer, the semiconductor element comprising a first electrode and a second electrode, and the semiconductor element corresponding to the functional area; and
an encapsulation layer, disposed on the second side of the base layer and surrounding the semiconductor element, wherein a portion of the first electrode and a portion of the second electrode are exposed outside the encapsulation layer.

2. The optoelectronic device according to claim 1, wherein the semiconductor element is a flip-chip vertical cavity surface emitting laser chip.

3. The optoelectronic device according to claim 1, further comprising a plurality of the functional areas and a plurality of the semiconductor elements, wherein the number of the functional areas is the same as the number of the semiconductor elements.

4. The optoelectronic device according to claim 1, further comprising a light-transmissive substrate, disposed on the first side of the base layer.

5. The optoelectronic device according to claim 4, wherein the light-transmissive substrate is disposed between the functional area and the base layer.

6. The optoelectronic device according to claim 1, wherein the functional area comprises a microstructure with dimensions ranging from nanometers to micrometers.

7. The optoelectronic device according to claim 6, wherein the microstructure comprises a metasurface structure, a diffractive optical element structure, a microlens array structure, or a combination of at least two of the aforementioned structures.

8. The optoelectronic device according to claim 1, wherein at least one of the first electrode and the second electrode is coplanar with the encapsulation layer.

9. The optoelectronic device according to claim 1, wherein the range of the functional area is smaller than the optoelectronic device and larger than the semiconductor element.

10. The optoelectronic device according to claim 1, wherein the width of the first side of the base layer is smaller than the width of the encapsulation layer.

11. The optoelectronic device according to claim 1, wherein the width of the first side of the base layer is smaller than the width of the semiconductor element.
